(19) United States
(12) Patent Application Publication
(10) Pub. No.: US 2025/0057045 A1
(43) Pub. Date: Feb. 13, 2025

(54) LIGHT EMITTING DEVICE, FUSED POLYCYCLIC COMPOUND FOR THE LIGHT EMITTING DEVICE, AND DISPLAY APPARATUS INCLUDING THE LIGHT EMITTING DEVICE

(71) Applicant: Samsung Display Co., Ltd., Yongin-si (KR)

(72) Inventors: SUN YOUNG PAK, Yongin-si (KR); MUN-KI SIM, Yongin-si (KR); JUNHA PARK, Yongin-si (KR); CHANSEOK OH, Yongin-si (KR); Chihyun RYOO, Yongin-si (KR); Giwoong HAN, Yongin-si (KR)

(21) Appl. No.: 18/735,073

(22) Filed: Jun. 5, 2024

(30) Foreign Application Priority Data
Jul. 28, 2023 (KR) 10-2023-0098786

(51) Int. Cl. H10K 85/60; C07F 5/02; C09K 11/06; H10K 50/12

(52) U.S. Cl. CPC H10K 85/658; C07F 5/027; C09K 11/06; C07B 2200/05; C09K 2211/1018; H10K 50/12

(57) ABSTRACT

A light emitting device of an embodiment includes a first electrode, a second electrode on the first electrode, and an emission layer between the first electrode and the second electrode and including a fused polycyclic compound represented by Formula 1. Accordingly, the light emitting device of an embodiment may show a low driving voltage, high efficiency and long-life characteristics.

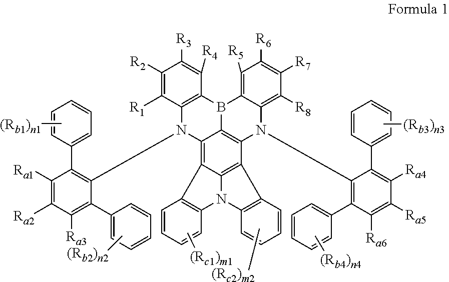

### CROSS-REFERENCE TO RELATED APPLICATIONS

The present application claims priority to and the benefit of Korean Patent Application No. 10-2023-0098786, filed on Jul. 28, 2023, in the Korean Intellectual Property Office, the entire content of which is incorporated herein by reference.

### BACKGROUND

### 1. Field

Embodiments of the present disclosure described herein are related to a light emitting device, a fused polycyclic compound for the light emitting device, and a display apparatus including the light emitting device.

### 2. Description of the Related Art

Recently, the development of an organic electroluminescence display apparatus as an image display apparatus is being actively conducted. The organic electroluminescence display apparatus is a display apparatus including a self-luminescent type or kind light emitting device in which holes and electrons (e.g., respectively or separately) injected from a first electrode and a second electrode recombine in an emission layer so that a light emitting material in the emission layer emits light to achieve display (e.g., of images).

In the application of a light emitting device to a display apparatus, the increase of emission efficiency and lifetime is required/or desired, and thus development on materials for a light emitting device, stably achieving the requirement is being consistently required and/or pursued.

### 1 SUMMARY

Aspects according to one or more embodiments of the present disclosure are directed toward a light emitting device having improved light efficiency and lifetime, and a display apparatus including the same.

Aspects according to one or more embodiments of the present disclosure are directed toward a fused polycyclic compound which is a material for a light emitting device and improves light efficiency and lifetime.

Additional aspects will be set forth in part in the description which follows and, in part, will be apparent from the description, or may be learned by practice of the presented embodiments of the present disclosure.

According to one or more embodiments, a light emitting device may include: a first electrode; a second electrode disposed on the first electrode; and an emission layer disposed between the first electrode and the second electrode, and including a first compound represented by Formula 1.

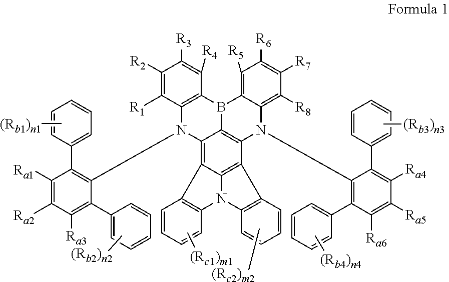

In Formula 1, R₁ to R₈ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined (e.g., bonded) with an adjacent group to form a ring, n1 to n4 may each independently be an integer of 0 to 5, Rₐ₁ to Rₐ₆ and R_{b1} to R_{b4} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring, m1 and m2 may each independently be an integer of 0 to 4, and R_{c1} and R_{c2} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms.

According to one or more embodiments, the emission layer may further include at least one selected from among a second compound represented by Formula HT-1, a third compound represented by Formula ET-1, and a fourth compound represented by Formula D-1.

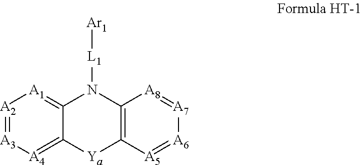

In Formula HT-1, A₁ to A₈ may each independently be N or CR₅₁, L₁ is a direct linkage, a substituted or unsubstituted arylene group of 6 to 30 ring-forming carbon atoms, or a substituted or unsubstituted heteroarylene group of 2 to 30 ring-forming carbon atoms, Yₐ is a direct linkage, CR₅₂R₅₃, or SiR₅₄R₅₅, Ar₁ is a substituted or unsubstituted aryl group of 6 to 30 ring-forming carbon atoms, or a substituted or unsubstituted heteroaryl group of 2 to 30 ring-forming carbon atoms, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group or 2 to 60 ring-forming carbon atoms, and/or combined with an adjacent group to form a ring.

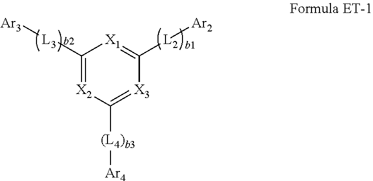

In Formula ET-1, at least one selected from among X₁ to X₃ is N, and the remainder are CR₅₆, R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group or 2 to 60 ring-forming carbon atoms, b1 to b3 may each independently be an integer of 0 to 10, Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group or 2 to 30 ring-forming carbon atoms, and L₂ to L₄ may each independently be a direct linkage, a substituted or unsubstituted arylene group of 6 to 30 ring-forming carbon atoms, or a substituted or unsubstituted heteroarylene group or 2 to 30 ring-forming carbon atoms.

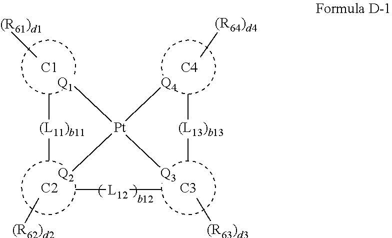

In Formula D-1, Q₁ to Q₄ may each independently be C or N, C1 to C4 may each independently be a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms, L₁₁ to L₁₃ may each independently be a direct linkage,

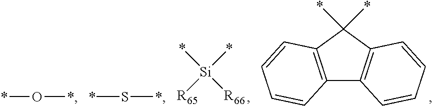

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and d1 to d4 may each independently be an integer of 0 to 4.

According to one or more embodiments, Formula 1 may be represented by Formula 1-A.

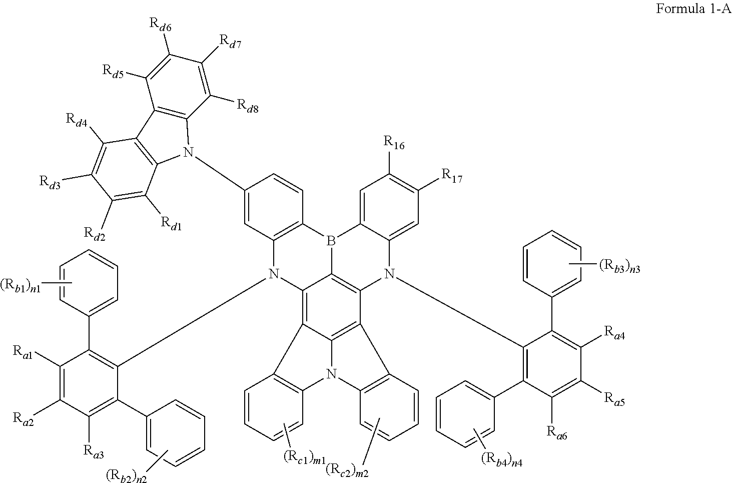

In Formula 1-A, R₁₆ and R₁₇ may each independently be a hydrogen atom, a deuterium atom, a halogen atom, a substituted or unsubstituted oxy group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, R_{d1} to Rₐ₈ may each independently be a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and n1 to n4, Rₐ₁ to Rₐ₆, R_{b1} to R_{b4}, m1, m2, R_{c1}, and R_{c2} may each independently be the same as defined in Formula 1.

According to one or more embodiments, Formula 1-A may be represented by Formula 1-A1.

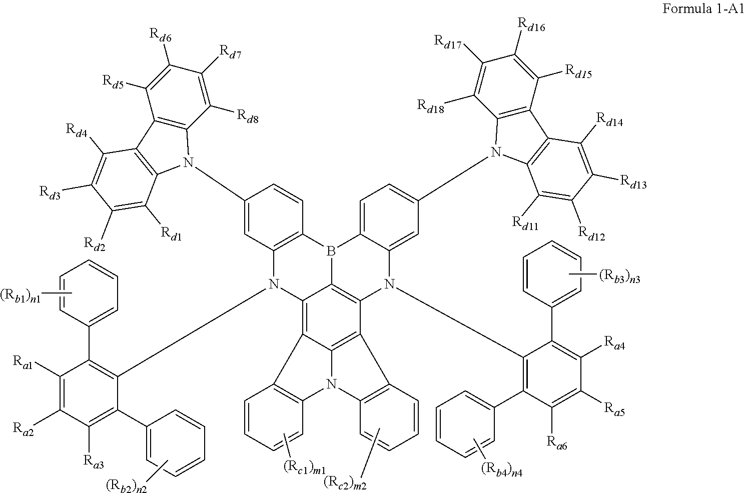

In Formula 1-A1, R_{d11} to R_{d18} may each independently be a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and n1 to n4, Rₐ₁ to Rₐ₆, R_{b1} to R_{b4}, m1, m2, R_{c1}, R_{c2}, R₁₆, R₁₇, and R_{d1} to R_{d8} may each independently be the same as defined in Formula 1-A.

According to one or more embodiments, in Formula 1, R₁ to R₆ may each independently be a hydrogen atom, a deuterium atom, or represented by one selected from among R-1 to R-26.

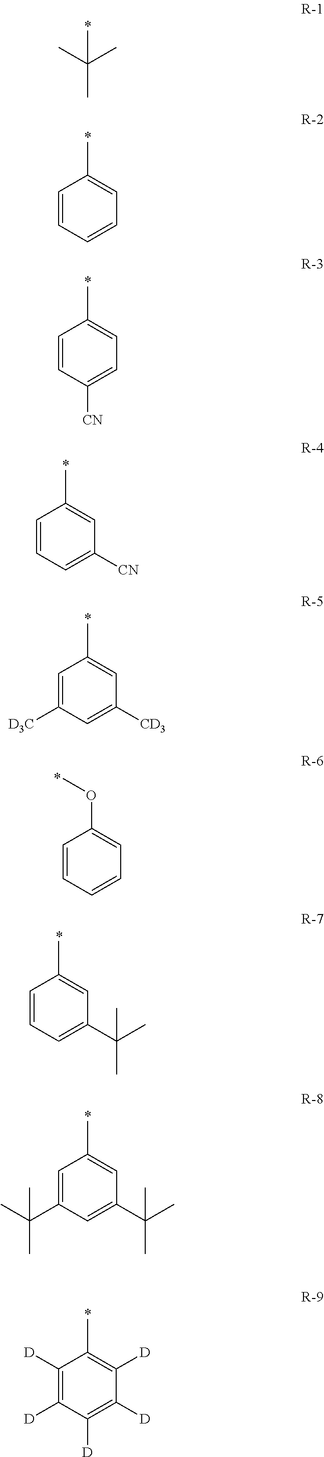

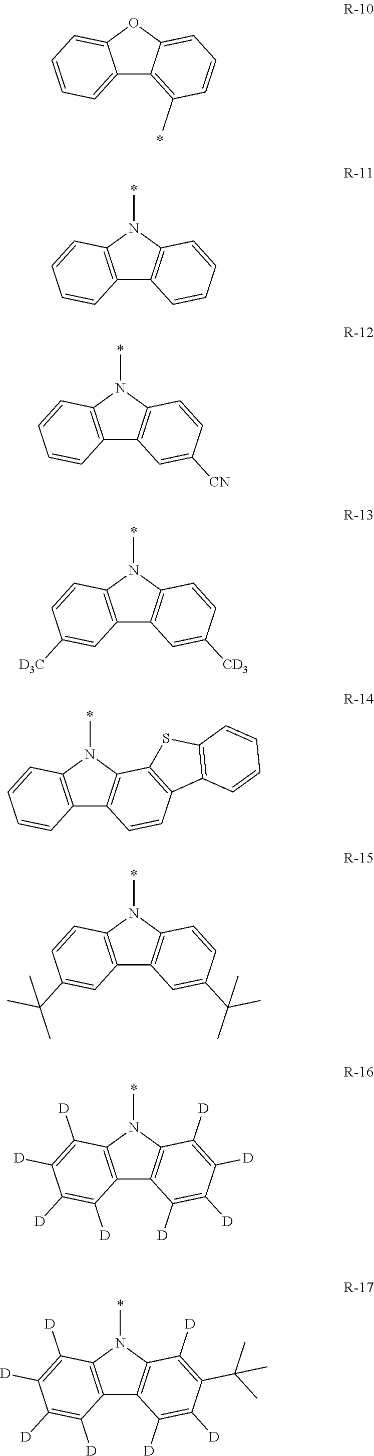

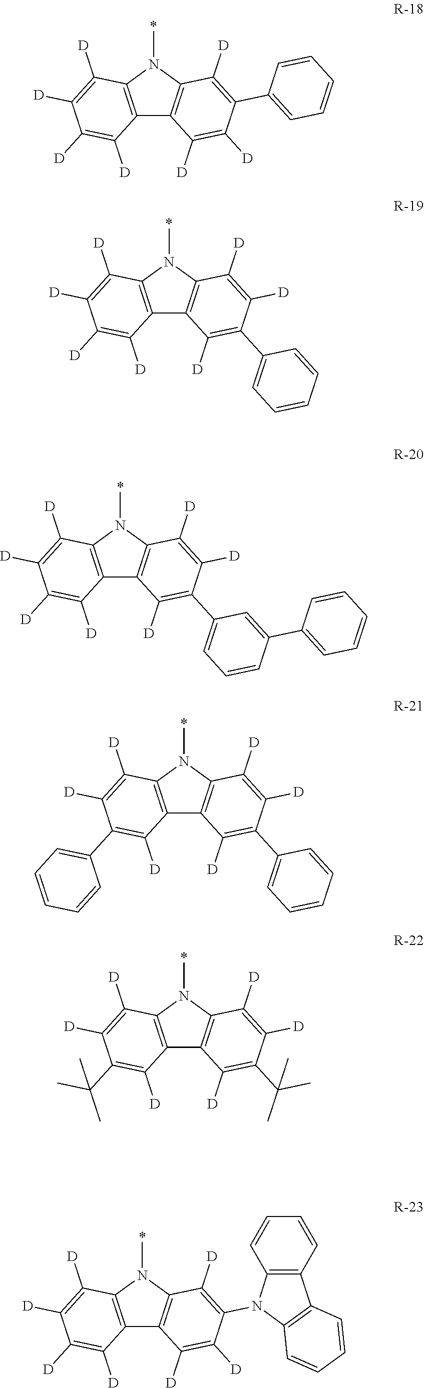 [SMILES: [2H]c1c([2H])c([2H])c2c(c1[2H])c1c([2H])c([2H])c(-c3ccccc3)c([2H])c1n2C ; [2H]c1c([2H])c([2H])c2c(c1[2H])c1c([2H])c(-c3ccccc3)c([2H])c([2H])c1n2C ; [2H]c1c([2H])c([2H])c2c(c1[2H])c1c([2H])c(-c3cccc(-c4ccccc4)c3)c([2H])c([2H])c1n2C ; [2H]c1c(-c2ccccc2)c([2H])c2c3c([2H])c(-c4ccccc4)c([2H])c([2H])c3n(C)c2c1[2H] ; [2H]c1c(C(C)(C)C)c([2H])c2c3c([2H])c(C(C)(C)C)c([2H])c([2H])c3n(C)c2c1[2H] ; [2H]c1c([2H])c([2H])c2c(c1[2H])c1c([2H])c([2H])c(-n3c4ccccc4c4ccccc43)c([2H])c1n2C]

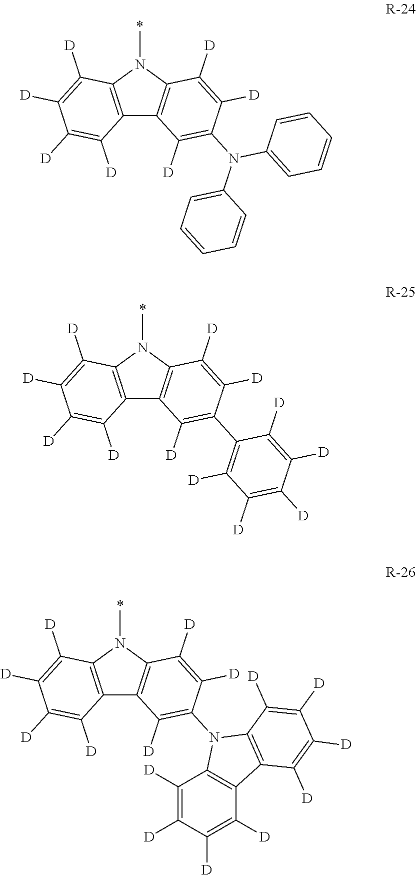 [SMILES: [2H]c1c([2H])c([2H])c2c(c1[2H])c1c([2H])c(N(c3ccccc3)c3ccccc3)c([2H])c([2H])c1n2C ; [2H]c1c([2H])c([2H])c(-c2c([2H])c([2H])c3c(c2[2H])c2c([2H])c([2H])c([2H])c([2H])c2n3C)c([2H])c1[2H] ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2C]

In R-5, R-9, R-13, and R-16 to R-26, D is a deuterium atom.

According to one or more embodiments, in Formula 1, R₁ to R₈ may each independently be a hydrogen atom, a deuterium atom, a substituted or unsubstituted t-butyl group, a substituted or unsubstituted aryl oxy group, a substituted or unsubstituted phenyl group, a substituted or unsubstituted carbazole group, a substituted or unsubstituted dibenzofuran group, or a substituted or unsubstituted benzo thieno carbazole group.

According to one or more embodiments, Formula 1 may be represented by one selected from among Formula 1-B1 to Formula 1-B3.

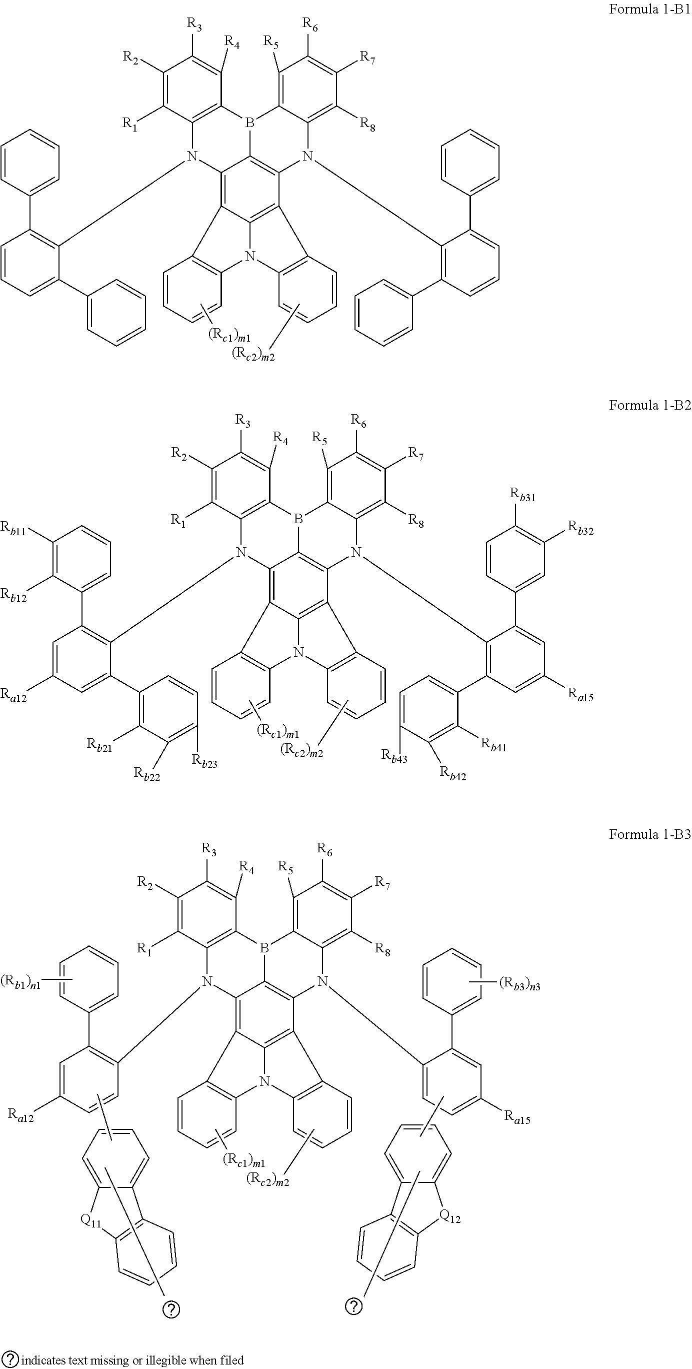

In Formula 1-B2, R_{b11}, R_{b12}, R_{b21} to R_{b23}, R_{b31}, R_{b32}, and R_{b41} to R_{b43} may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 30 carbon atoms, a substituted or unsubstituted alkenyl group of 2 to 30 carbon atoms, or a substituted or unsubstituted aryl group of 6 to 30 ring-forming carbon atoms, and/or combined with an adjacent group to form a ring, in Formula 1-B3, Q₁₁ and Q₁₂ may each independently be NR₂₁, O, or S, n5 and n6 may each independently be an integer of 0 to 7, and R₂₁ to R₂₃ may each independently be a hydrogen atom, a deuterium atom, or a substituted or unsubstituted aryl group of 6 to 30 ring-forming carbon atoms, in Formula 1-B2 and Formula 1-B3, Rₐ₂₁ and Rₐ₁₅ may each independently be a hydrogen atom, a deuterium atom, a cyano group, a substituted or unsubstituted alkyl group of 1 to 30 carbon atoms, or a substituted or unsubstituted aryl group of 6 to 30 ring-forming carbon atoms, and in Formula 1-B1 to Formula 1-B3, R₁ to R₈, n1, n3, R_{b1}, R_{b3}, m1, m2, R_{c1}, and R_{c2} may each independently be the same as defined in Formula 1.

According to one or more embodiments, in Formula 1, R_{c1} and R_{c2} may each independently be a hydrogen atom, a deuterium atom, a substituted or unsubstituted methyl group, a substituted or unsubstituted t-butyl group, or a substituted or unsubstituted phenyl group.

According to one or more embodiments, in Formula 1, R_{c1} and R_{c2} may each independently be a hydrogen atom, a deuterium atom, or represented by one selected from among RC-1 to RC-4.

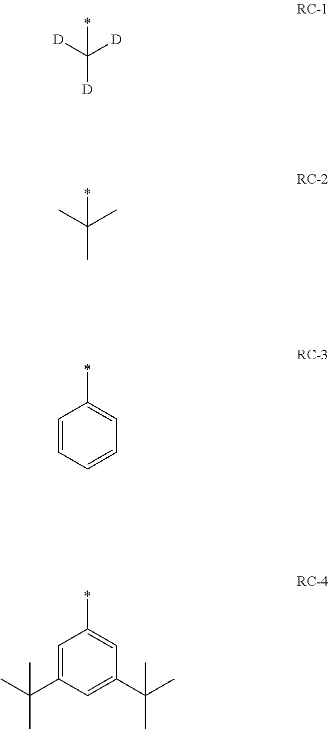

In RC-1, D is a deuterium atom.

According to one or more embodiments, the first compound may include a deuterium atom, or a substituent including a deuterium atom.

According to one or more embodiments, the fused polycyclic compound may be represented by Formula 1.

According to one or more embodiments, a display apparatus may include: a base layer; a circuit layer disposed on the base layer; and a display device layer disposed on the circuit layer and including a light emitting device, wherein the light emitting device includes a first electrode, a second electrode disposed on the first electrode, and an emission layer disposed between the first electrode and the second electrode and including the fused polycyclic compound represented by Formula 1.

According to one or more embodiments, the light emitting device may include a first light emitting device configured to emit red light, a second light emitting device configured to emit green light, and a third light emitting device configured to emit blue light, and the fused polycyclic compound may be included in the third light emitting device.

According to one or more embodiments, the light emitting device may be configured to emit blue light.

According to one or more embodiments, the display apparatus may further include a light control layer disposed on the display device layer and including a quantum dot.

### BRIEF DESCRIPTION OF THE FIGURES

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIG. 1 is a plan view showing a display apparatus according to an embodiment;

FIG. 2 is a cross-sectional view showing a part corresponding to line I-l′ of FIG. 1;

FIG. 3 is a cross-sectional view schematically showing a light emitting device of an embodiment;

FIG. 4 is a cross-sectional view schematically showing a light emitting device of an embodiment;

FIG. 5 is a cross-sectional view schematically showing a light emitting device of an embodiment;

FIG. 6 is a cross-sectional view schematically showing a light emitting device of an embodiment;

FIG. 7 is a cross-sectional view schematically showing a light emitting device of an embodiment;

FIG. 8 is a cross-sectional view showing a display apparatus according to an embodiment;

FIG. 9 is a cross-sectional view showing a display apparatus according to an embodiment;

FIG. 10 is a cross-sectional view showing a display apparatus according to an embodiment;

FIG. 11 is a cross-sectional view showing a display apparatus according to an embodiment; and

FIG. 12 is a diagram showing the interior of a vehicle in which the display apparatus of an embodiment is disposed.

### DETAILED DESCRIPTION

Because the present disclosure may have diverse modified embodiments, specific embodiments are illustrated in the drawings and are described in the detailed description of the present disclosure. However, this does not limit the present disclosure within specific embodiments and it should be understood that the present disclosure covers all the modifications, equivalents, and replacements within the idea and technical scope of the present disclosure.

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

Like reference numerals refer to like elements throughout, and duplicative descriptions thereof may not be provided. Also, in the drawings, the thickness, ratio, and dimensions of components are exaggerated for clarity of illustration. The term “and/or” includes any and all combinations of one or more of the associated components.

It will be understood that although the terms such as ‘first’ and ‘second’ are utilized herein to describe one or more suitable elements, these elements should not be limited by these terms. These terms are utilized only to distinguish one component from other components. For example, a first element referred to as a first element in an embodiment can be referred to as a second element in another embodiment without departing from the scope of the appended claims. The terms of a singular form may include plural forms unless referred to the contrary.

Also, “under”, “below”, “above”, “upper”, and/or the like are utilized for explaining relation association of the elements illustrated in the drawings. The terms may be a relative concept and described based on directions expressed in the drawings.

The meaning of ‘include’ or ‘comprise’ specifies a property, a fixed number, a process, an operation, an element, a component or a combination thereof, but does not exclude other properties, fixed numbers, processes, operations, elements, components or combinations thereof.

Unless otherwise defined, all terms (including technical and scientific terms) utilized herein have the same meaning as commonly understood by a person of ordinary skill in the art to which the present disclosure belongs. In some embodiments, terms such as terms defined in commonly utilized dictionaries should be interpreted as having a meaning consistent with the meaning in the context of the related technology, and unless explicitly defined here, they are interpreted as too ideal or too formal sense.

In the specification, the term “substituted or unsubstituted” may refer to substituted or unsubstituted with at least one substituent selected from among the group including a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents described previously may be substituted or unsubstituted. For example, a biphenyl group may be interpreted as an aryl group or a phenyl group substituted with a phenyl group.

In the specification, the phrase “bonded to an adjacent group to form a ring” may refer to that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In some embodiments, the rings formed by being bonded to each other may be connected to another ring to form a spiro structure.

In the specification, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In some embodiments, two methyl groups in 4,5-dimethylphenanthrene may be interpreted as “adjacent groups” to each other.

In the specification, examples of the halogen atom may include a fluorine atom, a chlorine atom, a bromine atom, or an iodine atom.

In the specification, the alkyl group may be linear or branched. The number of carbon atoms in the alkyl group is 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the specification, a cycloalkyl group may refer to a cyclic alkyl group. The number of carbon atoms in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment of the present disclosure is not limited thereto.

In the specification, an alkenyl group refers to a hydrocarbon group including at least one carbon double bond in the middle or terminal of an alkyl group having 2 or more carbon atoms. The alkenyl group may be linear or branched. The number of carbon atoms in the alkenyl group is not specifically limited, but is 2 to 60, 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the specification, an alkynyl group refers to a hydrocarbon group including at least one carbon triple bond in the middle or terminal of an alkyl group having 2 or more carbon atoms. The alkynyl group may be linear or branched. Although the number of carbon atoms is not specifically limited, it is 2 to 60, 2 to 30, 2 to 20, or 2 to 10. Specific examples of the alkynyl group may include an ethynyl group, a propynyl group, etc., but are not limited thereto.

In the specification, the hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the specification, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but the embodiment of the present disclosure is not limited thereto.

In the specification, the fluorenyl group may be substituted, and two substituents may be bonded to each other to form a spiro structure. Examples of the substituted fluorenyl group are as follows. However, the embodiment of the present disclosure is not limited thereto.

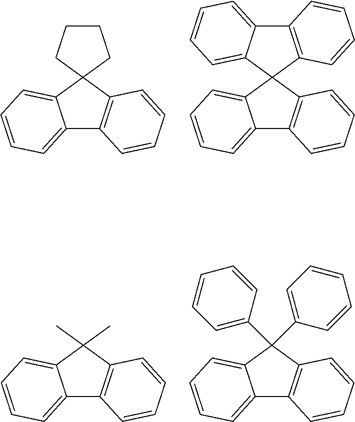

The heterocyclic group herein refers to any functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. When the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but the embodiment of the present disclosure is not limited thereto.

In the specification, the heteroaryl group may contain at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the specification, the previous description of the aryl group may be applied to an arylene group except that the arylene group is a divalent group. The previous description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiment of the present disclosure is not limited thereto.

In the specification, the number of ring-forming carbon atoms in the carbonyl group is not specifically limited, but may be 1 to 40, 1 to 30, or 1 to 20. For example, the carbonyl group may have the following structures, but the embodiment of the present disclosure is not limited thereto.

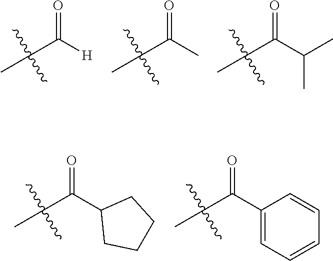

In the specification, the number of carbon atoms in the sulfinyl group and the sulfonyl group is not particularly limited, but may be 1 to 30. The sulfinyl group may include an alkyl sulfinyl group and an aryl sulfinyl group. The sulfonyl group may include an alkyl sulfonyl group and an aryl sulfonyl group.

In the specification, the thio group may include an alkylthio group and an arylthio group. The thio group may refer to that a sulfur atom is bonded to the alkyl group or the aryl group as defined previously. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the specification, an oxy group may refer to that an oxygen atom is bonded to the alkyl group or the aryl group as defined previously. The oxy group may include an alkoxy group and an aryl oxy group. The alkoxy group may be a linear chain, a branched chain or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but the embodiment of the present disclosure is not limited thereto.

The boron group herein may refer to that a boron atom is bonded to the alkyl group or the aryl group as defined previously. The boron group includes an alkyl boron group and an aryl boron group. Examples of the boron group may include a dimethylboron group, a trimethylboron group, a t-butyldimethylboron group, a diphenylboron group, a phenylboron group, etc., but the embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but the embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described previously.

In the specification, the aryl group among an aryloxy group, an arylthio group, an arylsulfoxy group, an arylamino group, an arylboron group, an arylsilyl group, an arylamine group is the same as the examples of the aryl group described previously.

In the specification, a direct linkage may refer to a single bond. In the specification,

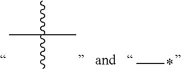

may refer to a position to be connected.

Hereinafter, embodiments of the present disclosure will be described with reference to the accompanying drawings.

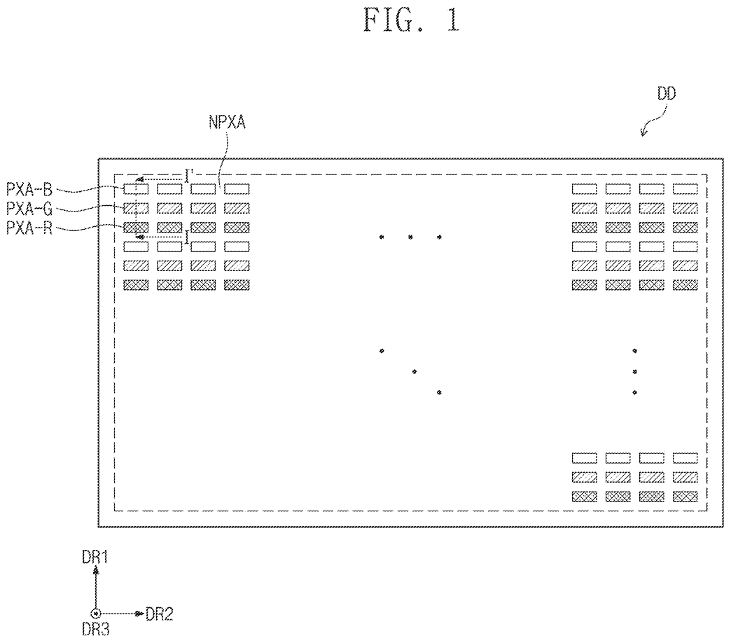

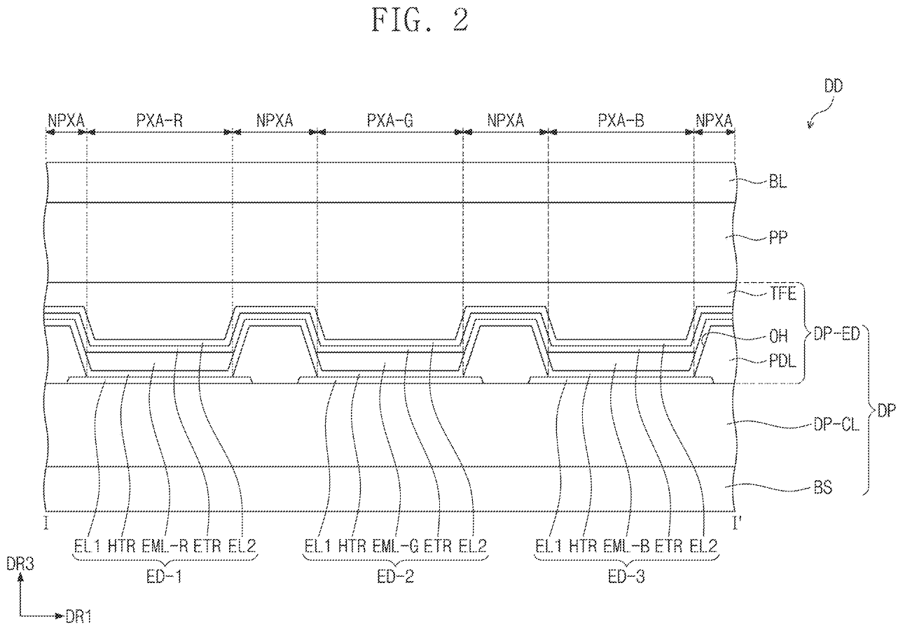

FIG. 1 is a plan view illustrating an embodiment of a display apparatus DD. FIG. 2 is a cross-sectional view of the display apparatus DD of the embodiment. FIG. 2 is a cross-sectional view illustrating a part taken along line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include a plurality of light emitting devices ED-1, ED-2, and ED-3. The optical layer PP may be disposed on the display panel DP to control reflected light in the display panel DP due to external light. The optical layer PP may include, for example, a polarization layer or a color filter layer. In some embodiments, unlike the configuration illustrated in the drawing, the optical layer PP may not be provided from the display apparatus DD of an embodiment.

A base substrate BL may be disposed on the optical layer PP. The base substrate BL may be a member which provides a base surface on which the optical layer PP disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

The display apparatus DD according to an embodiment may further include a filling layer. The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is disposed on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

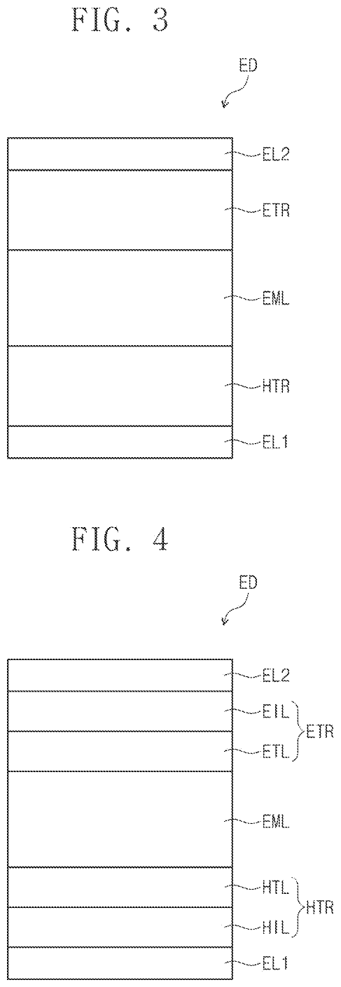

Each of the light emitting devices ED-1, ED-2, and ED-3 may have a structure of each light emitting device ED of embodiments according to FIGS. 3 to 7, which will be described later. Each of the light emitting devices ED-1, ED-2, and ED-3 may include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are provided as a common layer in the entire light emitting devices ED-1, ED-2, and ED-3. However, the embodiment of the present disclosure is not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in an embodiment may be provided by being patterned in an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be disposed on the second electrode EL2 and may be disposed filling the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, in the specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of an embodiment illustrated in FIGS. 1 and 2, three light emitting regions PXA-R, PXA-G, and PXA-B, which emit red light, green light, and blue light, respectively, are illustrated examples.

For example, the display apparatus DD of an embodiment may include the red light emitting region PXA-R, the green light emitting region PXA-G, and the blue light emitting region PXA-B that are separated from each other.

In the display apparatus DD according to an embodiment, the plurality of light emitting devices ED-1, ED-2 and ED-3 may be configured to emit light beams having wavelengths different from each other. For example, in an embodiment, the display apparatus DD may include a first light emitting device ED-1 that is configured to emit red light, a second light emitting device ED-2 that is configured to emit green light, and a third light emitting device ED-3 that is configured to emit blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be configured to emit light beams in substantially the same wavelength range or at least one light emitting device may be configured to emit a light beam in a wavelength range different from the others. For example, the first to third light emitting devices ED-1, ED-2, and ED-3 may all be configured to emit blue light.

The light emitting regions PXA-R, PXA-G, and PXA-B in the display apparatus DD according to an embodiment may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In some embodiments, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light.

In this case, the areas of the light emitting regions PXA-R, PXA-G, and PXA-B may refer to areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE™) arrangement form or a diamond (Diamond Pixel™) arrangement form.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

Hereinafter, FIG. 3 to FIG. 7 are cross-sectional views schematically showing light emitting devices according to embodiments. The light emitting device ED according to an embodiment may include a first electrode EL1, a hole transport region HTR, an emission layer EML, an electron transport region ETR, and a second electrode EL2, stacked in order.

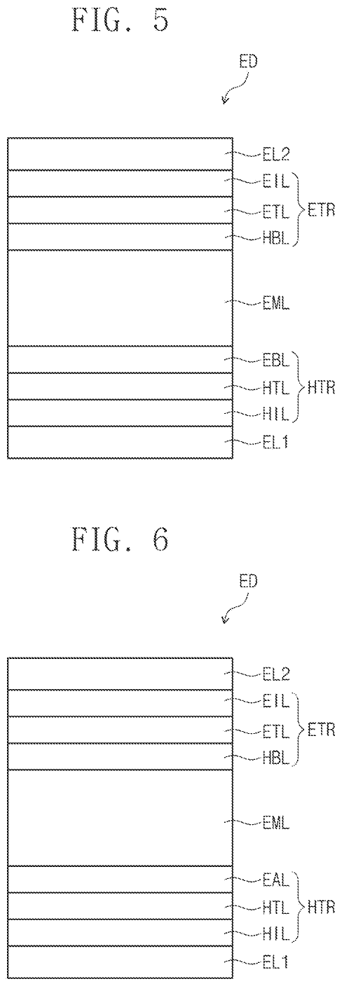

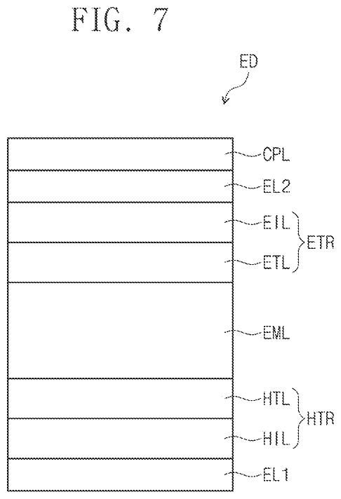

When compared to FIG. 3, FIG. 4 shows the cross-sectional view of a light emitting device ED of an embodiment, wherein a hole transport region HTR includes a hole injection layer HIL and a hole transport layer HTL, and an electron transport region ETR includes an electron injection layer EIL and an electron transport layer ETL. In some embodiments, when compared to FIG. 3, FIG. 5 shows the cross-sectional view of a light emitting device ED of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared to FIG. 3, FIG. 6 shows a cross-sectional view of a light emitting device ED of an embodiment, wherein a hole transport region HTR includes a hole injection layer HIL, a hole transport layer HTL, and an emission auxiliary layer EAL, and an electron transport region ETR includes an electron injection layer EIL, an electron transport layer ETL, and a hole blocking layer HBL. When compared to FIG. 4, FIG. 7 shows the cross-sectional view of a light emitting device ED of an embodiment, including a capping layer CPL disposed on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

When the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the previously described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. In some embodiments, the embodiment of the present disclosure is not limited thereto, and the first electrode EL1 may include the previously described metal materials, combinations of at least two metal materials of the previously described metal materials, oxides of the previously described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, an emission auxiliary layer EAL, or an electron blocking layer EBL. The thickness of the hole transport region HTR may be, for example, from about 50 Å to about 15,000 Å. The emission auxiliary layer EAL may refer to as a buffer layer.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTLemission auxiliary layer EAL, a hole injection layer HIL/emission auxiliary layer EAL, a hole transport layer HTL/emission auxiliary layer EAL, or a hole injection layer HIL/hole transport layer HTL/electron blocking layer EBL are stacked in order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1:

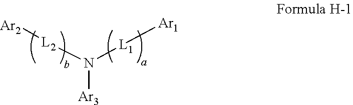

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ includes the amine group as a substituent. In some embodiments, the compound represented by Formula H-1 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be represented by any one selected from among the compounds in Compound Group H. However, the compounds listed in Compound Group H are examples, and the compounds represented by Formula H-1 are not limited to those represented by Compound Group H:

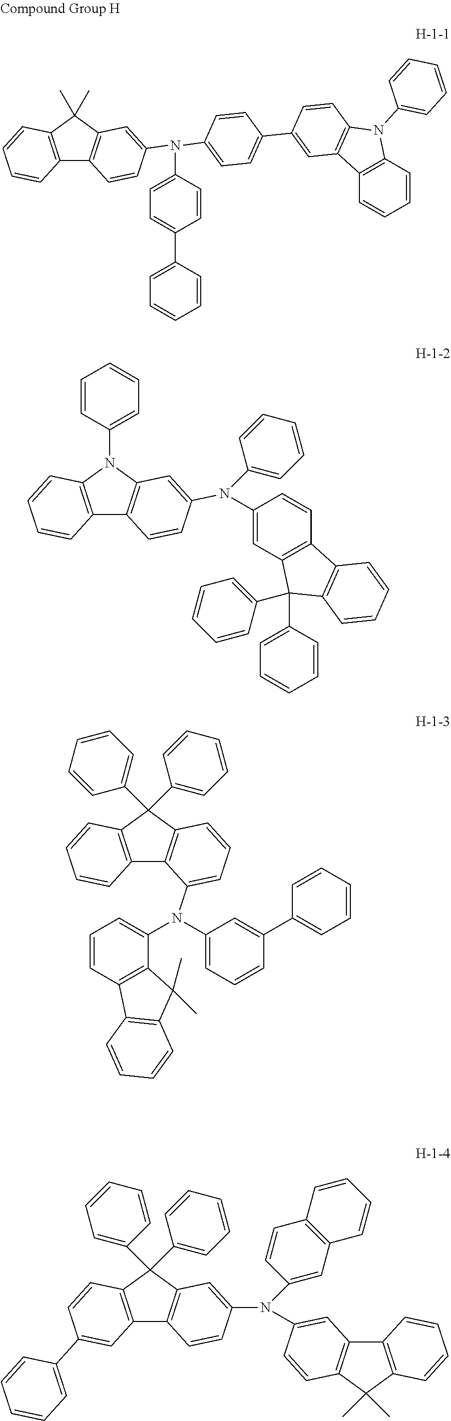 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

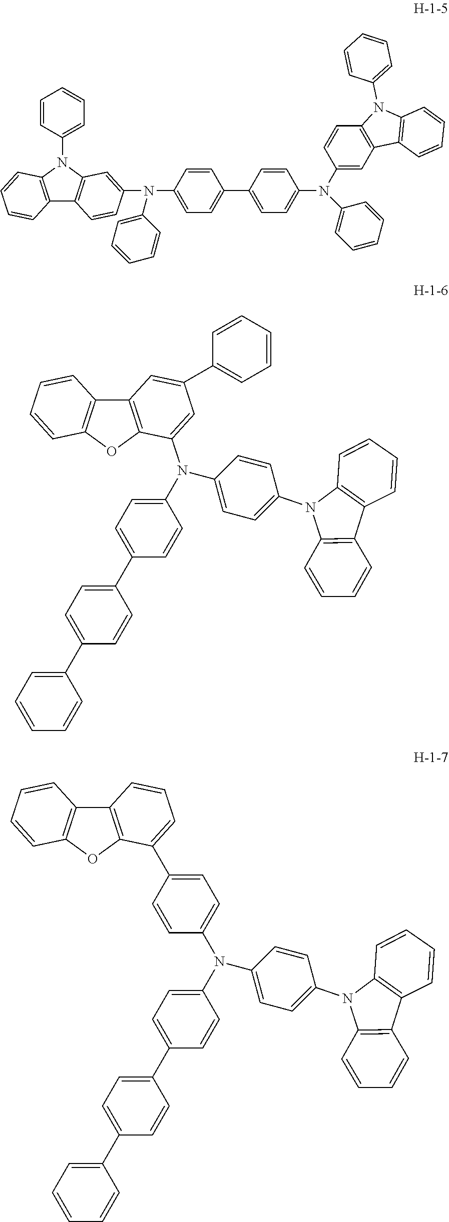 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

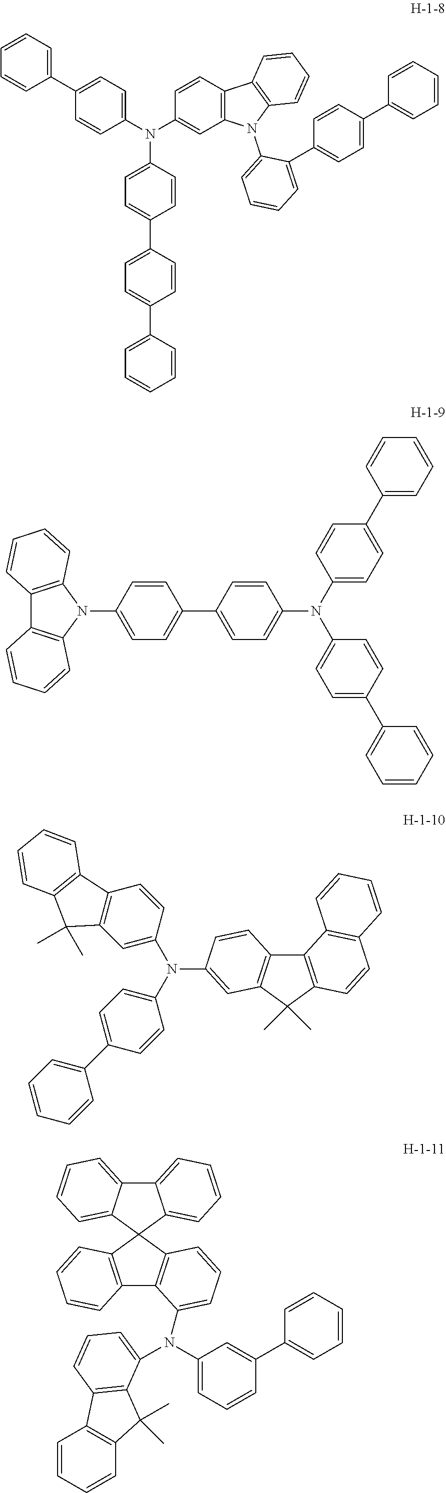

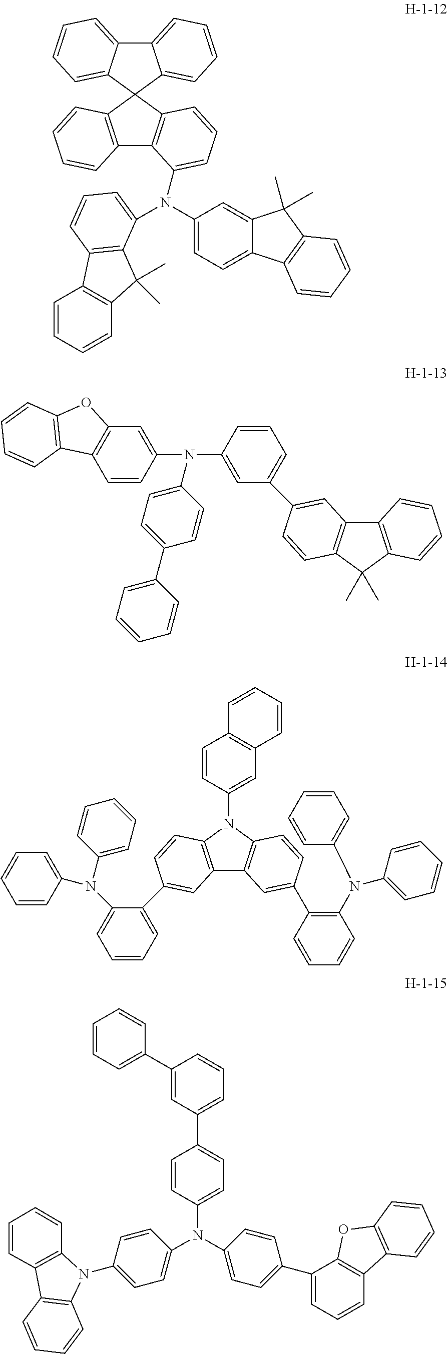 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

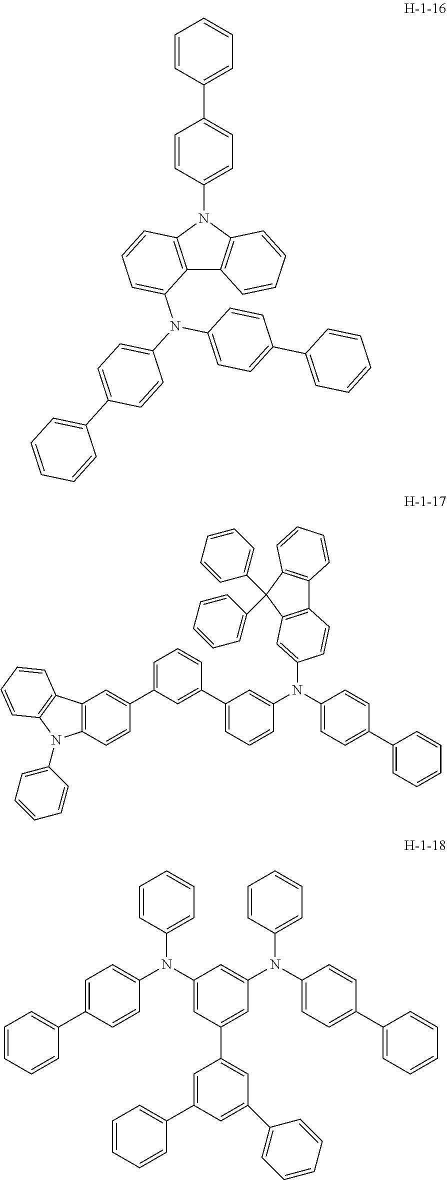 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

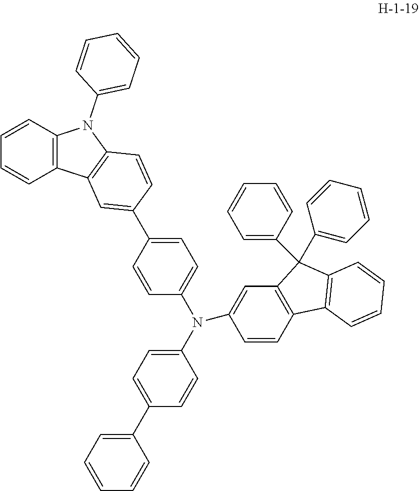 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N1,N1′-([1,1′-biphenyl]-4,4′-diyl)bis(N1-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris [N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N, N′-diphenyl-benzidine (NPB), triphenylamine-containing polyetherketone (TPAPEK), 4-isopropyl-4′-methyldiphenyliodonium [tetrakis(pentafluorophenyl) borate], dipyrazino[2,3-f: 2′,3′-h] quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the previously described compounds of the hole transport region in at least one of a hole injection layer HIL, a hole transport layer HTL, an emission auxiliary layer EAL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the previously described ranges, satisfactory hole transport properties may be achieved without a substantial increase in driving voltage.

The hole transport region HTR may further include a charge generating material to increase conductivity in addition to the previously described materials. The charge generating material may be dispersed substantially uniformly or substantially non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as Cul or Rbl, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h] quinoxaline-2,3,6,7,10,11-hexacarbonitrile (HATCN) or 4-[2,3-bis[cyano-(4-cyano-2,3,5,6-tetrafluorophenyl)methylidene] cyclopropylidene]-cyanomethyl]-2,3,5,6-tetrafluorobenzonitrile (NDP9), etc., but the embodiment of the present disclosure is not limited thereto.

As described previously, the hole transport region HTR may further include at least one selected from among an emission auxiliary layer EAL and an electron blocking layer EBL in addition to the hole injection layer HIL and the hole transport layer HTL. The emission auxiliary layer EAL may compensate a resonance distance according to the wavelength of light emitted from the emission layer EML and control hole charge balance to increase light emitting efficiency. In some embodiments, the emission auxiliary layer EAL may play the role of preventing or reducing electron injection to the hole transport region HTR. The materials included in the hole transport region HTR may be utilized as the materials included in the emission auxiliary layer EAL. The electron blocking layer EBL may be a layer playing the role of preventing or reducing electron injection from the electron transport region ETR to the hole transport region HTR.

In the light emitting device ED of an embodiment, the emission layer EML may include the first compound of an embodiment. In some embodiments, the emission layer EML according to an embodiment may further include at least one selected from among second to fourth compounds. The second compound may include a fused ring of three rings including a nitrogen atom as a ring-forming atom. The third compound may include a hexagonal ring group including at least one nitrogen atom as a ring-forming atom. The fourth compound may include an organometallic complex. The second to fourth compounds will be explained in more detail, later.

In the description, the first compound may be referred to as the fused polycyclic compound of an embodiment. The fused polycyclic compound of an embodiment may include a fused ring of nine rings, including three nitrogen atoms and one boron atom as ring-forming atoms, as a central structure. Two nitrogen atoms and one boron atom among the ring-forming atoms are in para relations, and may form a fused ring of two rings in the fused ring of nine rings. In the fused polycyclic compound of an embodiment, the fused ring of nine rings may include an indolocarbazole moiety. In the fused ring of nine rings, ortho terphenyl groups may be directly bonded, respectively, to the two nitrogen atoms in para positions.

The light emitting device ED of an embodiment may include the fused polycyclic compound of an embodiment. The fused polycyclic compound of an embodiment may be represented by Formula 1.

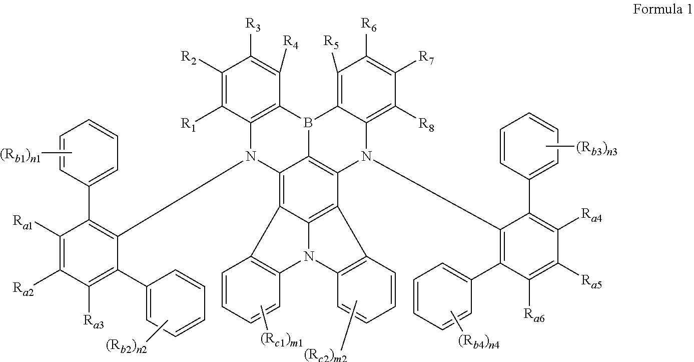

In Formula 1, R₁ to R₈ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring. For example, R₁ to R₈ may each independently be a hydrogen atom, a deuterium atom, a substituted or unsubstituted t-butyl group, a substituted or unsubstituted aryl oxy group, a substituted or unsubstituted phenyl group, a substituted or unsubstituted carbazole group, a substituted or unsubstituted dibenzofuran group, or a substituted or unsubstituted benzo thieno carbazole group. In some embodiments, R₁ to R₈ may each independently be a hydrogen atom, a deuterium atom, or represented by one selected from among R-1 to R-26.

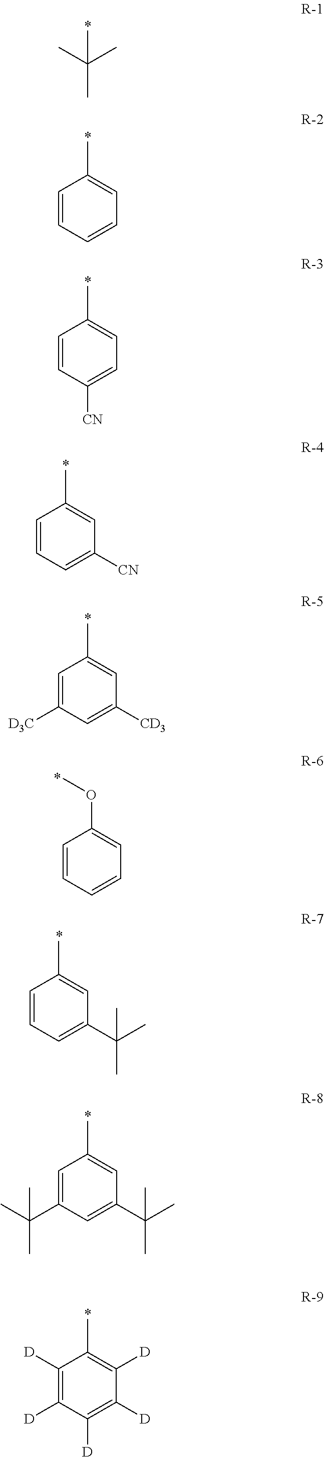

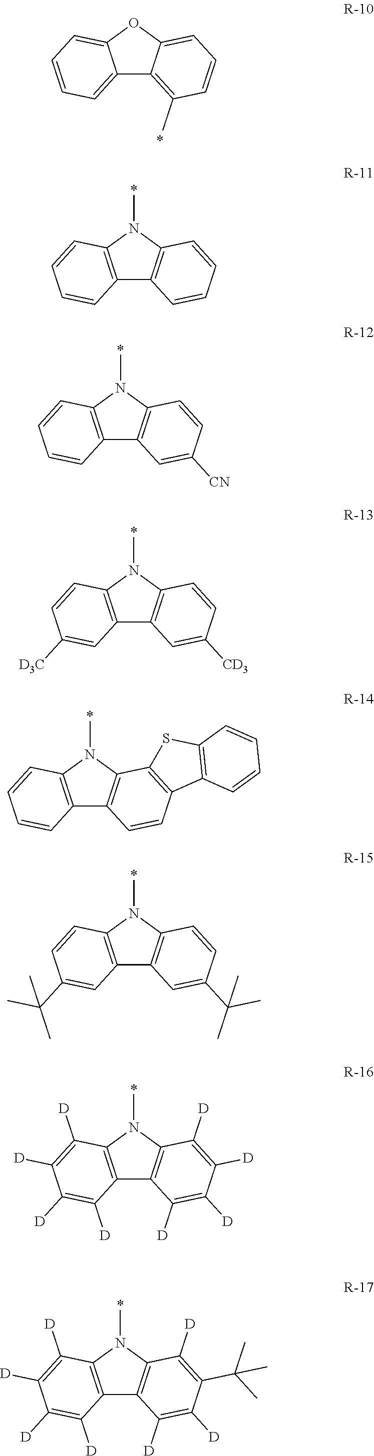

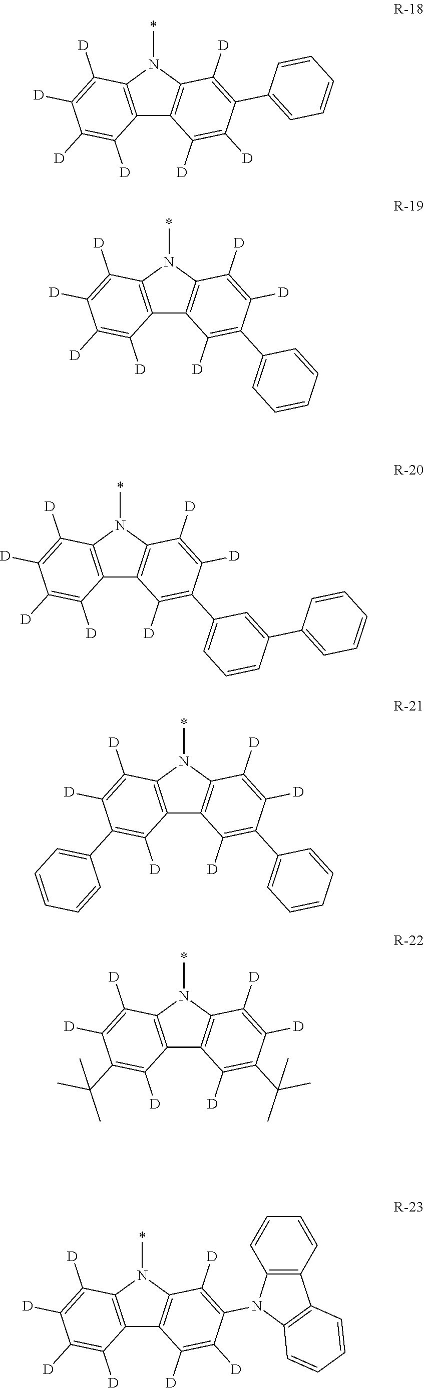 [SMILES: [2H]c1c([2H])c([2H])c2c(c1[2H])c1c([2H])c([2H])c(-c3ccccc3)c([2H])c1n2C ; [2H]c1c([2H])c([2H])c2c(c1[2H])c1c([2H])c(-c3ccccc3)c([2H])c([2H])c1n2C ; [2H]c1c([2H])c([2H])c2c(c1[2H])c1c([2H])c(-c3cccc(-c4ccccc4)c3)c([2H])c([2H])c1n2C ; [2H]c1c(-c2ccccc2)c([2H])c2c3c([2H])c(-c4ccccc4)c([2H])c([2H])c3n(C)c2c1[2H] ; [2H]c1c(C(C)(C)C)c([2H])c2c3c([2H])c(C(C)(C)C)c([2H])c([2H])c3n(C)c2c1[2H] ; [2H]c1c([2H])c([2H])c2c(c1[2H])c1c([2H])c([2H])c(-n3c4ccccc4c4ccccc43)c([2H])c1n2C]

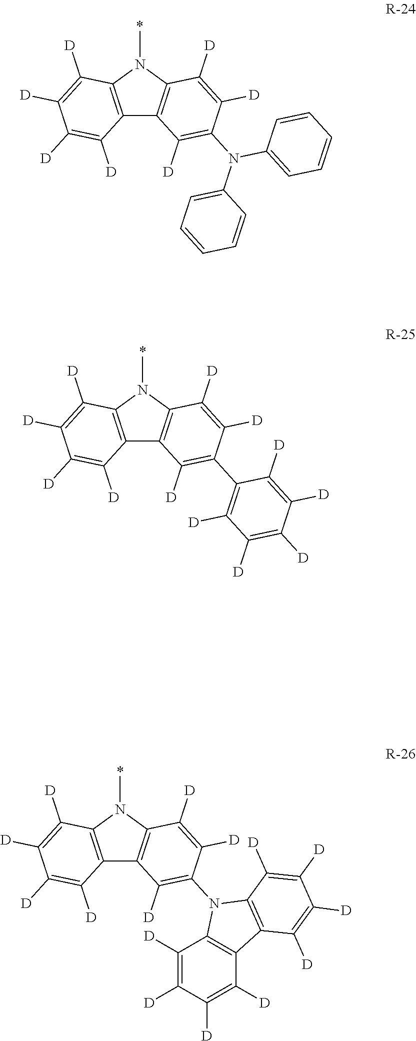 [SMILES: [2H]c1c([2H])c([2H])c2c(c1[2H])c1c([2H])c(N(c3ccccc3)c3ccccc3)c([2H])c([2H])c1n2C ; [2H]c1c([2H])c([2H])c(-c2c([2H])c([2H])c3c(c2[2H])c2c([2H])c([2H])c([2H])c([2H])c2n3C)c([2H])c1[2H] ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2C]

R-14 may represent an unsubstituted benzo thieno carbazole group. In R-5, R-9, R-13 and R-16 to R-26, D is a deuterium atom. For example, in Formula 1, R₆ may be represented by R-6, and R₆ may form a dibenzofuran group via the combination of R₇ adjacent to R₆ with the ring group at which R₆ is substituted.

In Formula 1, n1 to n4 may each independently be an integer of 0 to 5. Rat to Rₐ₆ and R_{b1} to R_{b4} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring. For example, R_{d8} and R_{b2} may be combined with each other to form a ring. n2 may be an integer of 2 or more, and multiple R_{b2} may be combined with each other to form a ring. However, this is an embodiment, and an embodiment of the present disclosure is not limited thereto.

When n1 is an integer of 2 or more, multiple R_{b1} may be the same, or at least one may be different. When n1 is 0, the fused polycyclic compound represented by Formula 1 may be unsubstituted with R_{b1}. A case where n1 is 0, may be the same as a case where n1 is 5, and five R_{b1} are hydrogen atoms. When n2 is an integer of 2 or more, multiple R_{b2} may be the same, or at least one may be different. When n2 is 0, the fused polycyclic compound represented by Formula 1 may be unsubstituted with R_{b2}. A case where n2 is 0, may be the same as a case where n2 is 5, and five R_{b2} are hydrogen atoms.

When n3 is an integer of 2 or more, multiple R_{b3} may be the same, or at least one may be different. When n3 is 0, the fused polycyclic compound represented by Formula 1 may be unsubstituted with R_{b3}. A case where n3 is 0, may be the same as a case where n3 is 5, and five R_{b3} are hydrogen atoms. When n4 is an integer of 2 or more, multiple R_{b4} may be the same, or at least one may be different. When n4 is 0, the fused polycyclic compound represented by Formula 1 may be unsubstituted with R_{b4}. A case where n4 is 0, may be the same as a case where n4 is 5, and five R_{b4} are hydrogen atoms.

In Formula 1, m1 and m2 may each independently be an integer of 0 to 4. R_{c1} and R_{c2} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms.

When m1 is an integer of 2 or more, multiple R_{c1} may be the same, or at least one may be different. When m1 is 0, the fused polycyclic compound represented by Formula 1 may be unsubstituted with R_{c1}. A case where m1 is 0, may be the same as a case where m1 is 4, and four R_{c1} are hydrogen atoms. When m2 is an integer of 2 or more, multiple R_{c2} may be the same, or at least one may be different. When m2 is 0, the fused polycyclic compound represented by Formula 1 may be unsubstituted with R_{c2}. A case where m2 is 0, may be the same as a case where m2 is 4, and four R_{c2} are hydrogen atoms.

For example, R_{c1} and R_{c2} may each independently be a hydrogen atom, a deuterium atom, a substituted or unsubstituted methyl group, a substituted or unsubstituted t-butyl group, or a substituted or unsubstituted phenyl group. In some embodiments, R_{c1} and R_{c2} may each independently be a hydrogen atom, a deuterium atom, or represented by one selected from among RC-1 to RC-4. In RC-1, D is a deuterium atom.

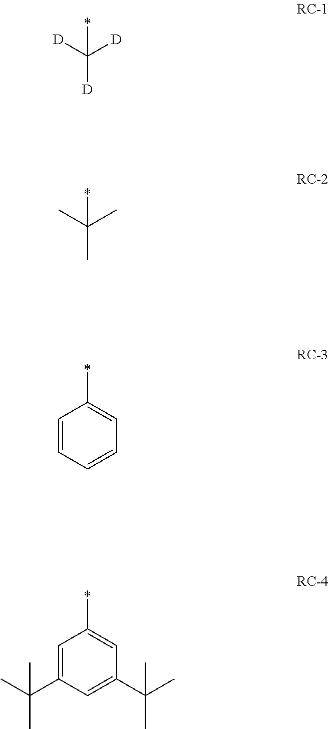

The fused polycyclic compound of an embodiment may include a deuterium atom, or a substituent including a deuterium atom. In Formula 1, at least one selected from among R₁ to R₈, Rₐ₁ to Rₐ₆, R_{b1} to R_{b4}, R_{c1}, and R_{c2} may be a deuterium atom, or include a substituent including a deuterium atom. For example, in Formula 1, at least one selected from among R₁ to R₈ may be a carbazole group substituted with a deuterium atom. At least one selected from among Rₐ₁ to Rₐ₆, R_{c1}, and R_{c2} may be a deuterium atom. However, this is an illustration, and an embodiment of the present disclosure is not limited thereto.

In an embodiment, Formula 1 may be represented by Formula 1-A. Formula 1-A may represent Formula 1 in which R₂ is a substituted or unsubstituted carbazole group, and R₁, R₃ to R₅, and R₅ are hydrogen atoms.

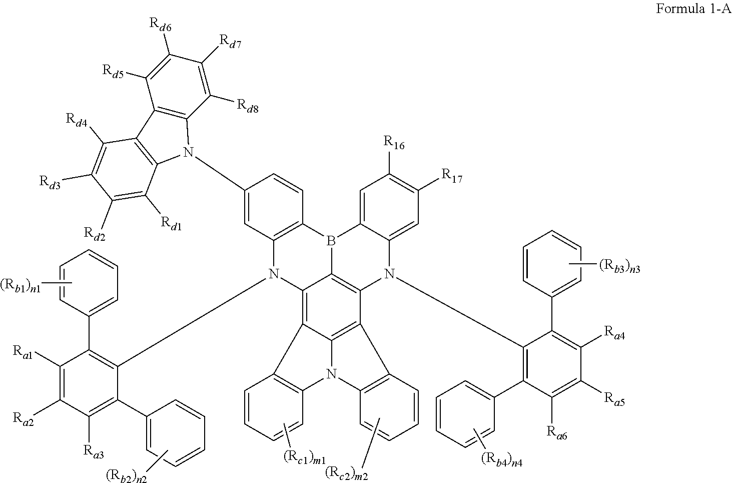

In Formula 1-A, the same contents explained in Formula 1 may be applied for n1 to n4, Rₐ₁ to Rₐ₆, R_{b1} to R_{b4}, m1, m2, R_{c1}, and R_{c2}. R₁₆ and R₁₇ may each independently be a hydrogen atom, a deuterium atom, a halogen atom, a substituted or unsubstituted oxy group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. For example, R₁₆ and R₁₇ may each independently be a hydrogen atom, a substituted or unsubstituted t-butyl group, a substituted or unsubstituted phenyl group, a substituted or unsubstituted carbazole group, a substituted or unsubstituted benzo thieno carbazole group, or a substituted or unsubstituted dibenzofuran group. In some embodiments, R₁₆ and R₁₇ may each independently be a hydrogen atom, or represented by one selected from among R-1 to R-26.

Rₐ₁ to R_{d8} may each independently be a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. For example, Rai to R_{d8} may each independently be a hydrogen atom, a deuterium atom, a cyano group, a substituted or unsubstituted diphenylamine group, a substituted or unsubstituted methyl group, a substituted or unsubstituted t-butyl group, a substituted or unsubstituted phenyl group, or a substituted or unsubstituted carbazole group, and/or combined with an adjacent group to form a ring. In some embodiments, a carbazole group combined with R_{d1} to R_{d8} may be represented by one selected from among the previously described R-11 to R-26.

In an embodiment, Formula 1-A may be represented by Formula 1-A1. Formula 1-A1 may represent Formula 1-A in which R₁₆ is a hydrogen atom, and R₁₇ is a substituted or unsubstituted carbazole group.

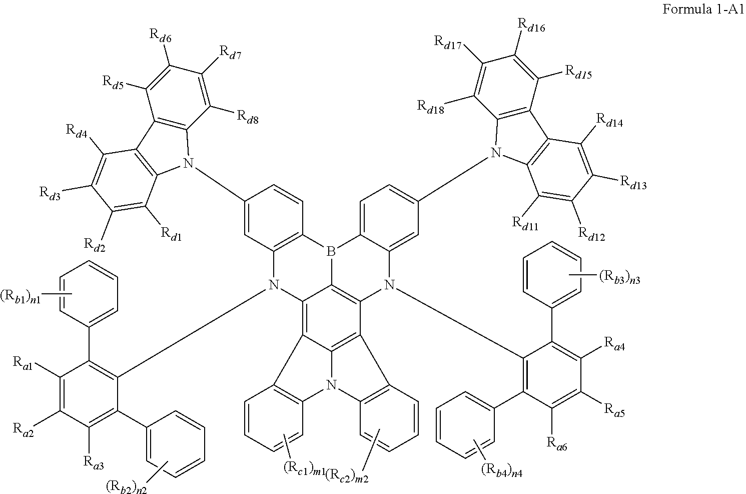

In Formula 1-A1, the same contents explained in Formula 1-A may be applied for n1 to n4, Rₐ₁ to Rₐ₆, R_{b1} to R_{b4}, m1, m2, R_{c1}, R_{c2}, R₁₆, R₁₇, and Rai to Rₐ₈. R_{d11} to R_{d18} may each independently be a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring. For example, a carbazole group in which R_{d11} to R_{d12} are combined may be represented by one selected from among the previously described R-11 to R-26.

In an embodiment, Formula 1 may be represented by one selected from among Formula 1-B1 to Formula 1-B3. Formula 1-B1 represents Formula 1 in which Rₐ₁ to Rₐ₆, and R_{b1} to R_{b4} are hydrogen atoms. Formula 1-B2 represents Formula 1 in which Rat, Rₐ₃, Rₐ₄, and Rₐ₆ are hydrogen atoms. Formula 1-B3 represents Formula 1 in which Rₐ₁, Rₐ₃, Rₐ₄, and R_{d8} are hydrogen atoms, multiple R_{b2} are combined with each other to form a ring, and multiple R_{b4} are combined with each other to form a ring. Multiple R_{b2} may be adjacent groups to each other. Multiple R_{b4} may be adjacent groups to each other.

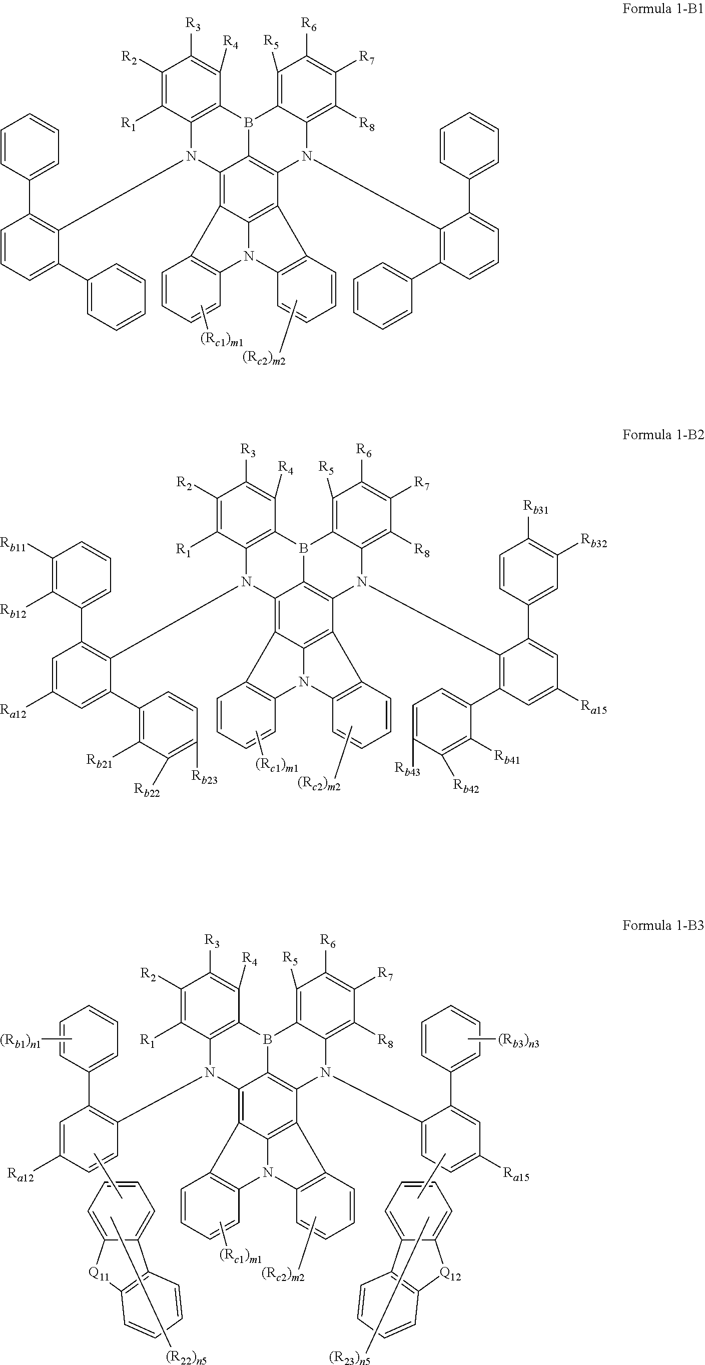

In Formula 1-B1 to Formula 1-B3, the same contents explained in Formula 1 may be applied for R₁ to R₈, n1, n3, R_{b1}, R_{b3}, m1, m2, R_{c1}, and R_{c2}.

In Formula 1-B2, R_{b11}, R_{b12}, R_{b21} to R_{b23}, R_{b31}, R_{b32}, and R_{b41} to R_{b43} may each independently be a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 30 carbon atoms, a substituted or unsubstituted alkenyl group of 2 to 30 carbon atoms, a substituted or unsubstituted aryl group of 6 to 30 ring-forming carbon atoms, and/or combined with an adjacent group to form a ring. For example, R_{b11}, R_{b12}, R_{b21} to R_{b23}, R_{b31}, R_{b32}, and R_{b41} to R_{b43} may each independently be a hydrogen atom, a cyano group or a substituted or unsubstituted phenyl group. However, this is an illustration, and an embodiment of the present disclosure is not limited thereto.

In Formula 1-B3, Q₁₁ and Q₁₂ may each independently be NR₂₁, O, or S. When Q₁₁ is NR₂₁, the fused ring of three rings including Q₁₁ may be a substituted or unsubstituted carbazole group. When Q₁₁ is O, the fused ring of three rings including Q₁₁ may be a substituted or unsubstituted dibenzofuran group. When Q₁₁ is S, the fused ring of three rings including Q₁₁ may be a substituted or unsubstituted dibenzothiophene group. When Q₁₂ is NR₂₁, the fused ring of three rings including Q₁₂ may be a substituted or unsubstituted carbazole group. When Q₁₂ is O, the fused ring of three rings including Q₁₂ may be a substituted or unsubstituted dibenzofuran group. When Q₁₂ is S, the fused ring of three rings including Q₁₂ may be a substituted or unsubstituted dibenzothiophene group.

In Formula 1-B3, n5 and n6 may each independently be an integer of 0 to 7. R₂₁ to R₂₃ may each independently be a hydrogen atom, a deuterium atom, or a substituted or unsubstituted aryl group of 6 to 30 ring-forming carbon atoms.

When n5 is an integer of 2 or more, multiple R₂₂ may be the same, or at least one may be different. When n5 is 0, the fused polycyclic compound represented by Formula 1-B3 may be unsubstituted with R₂₂. A case where n5 is 0, may be the same as a case where n5 is 7, and seven R₂₂ are hydrogen atoms. When n6 is an integer of 2 or more, multiple R₂₃ may be the same, or at least one may be different. When n6 is 0, the fused polycyclic compound represented by Formula 1-B3 may be unsubstituted with R₂₃. A case where n6 is 0, may be the same as a case where n6 is 7, and seven R₂₃ are hydrogen atoms.

In Formula 1-B2 and Formula 1-B3, Rₐ₁₂ and Rₐ₁₅ may each independently be a hydrogen atom, a deuterium atom, a cyano group, a substituted or unsubstituted alkyl group of 1 to 30 carbon atoms, or a substituted or unsubstituted aryl group of 6 to 30 ring-forming carbon atoms. Rₐ₁₂ and Rₐ₁₅ may each independently be a substituted or unsubstituted t-butyl group or a substituted or unsubstituted phenyl group.

For example, Formula 1-B3 may be represented by one selected from among Formula 1-B31 to Formula 1-B33. Formula 1-B31 to Formula 1-B33 may be Formula 1-B3 in which the bonding positions of the fused ring of three rings including Q₁₁ and the fused ring of three rings including Q₁₂ are embodied.

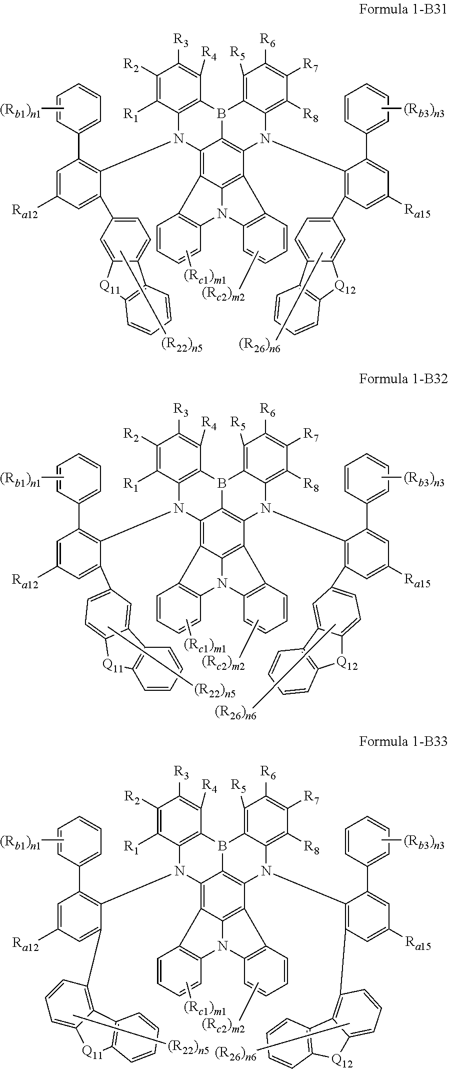

In Formula 1-B31 to Formula 1-B33, the same contents explained in Formula 1-B3 may be applied for R₁ to R₈, n1, n3, R_{b1}, R_{b3}, m1, m2, R_{c1}, R_{c2}, Q₁₁, Q₁₂, n5, n6, R₂₂, and R₂₃.

The fused polycyclic compound of an embodiment may be represented by one selected from among the compounds in Compound Group 1. The light emitting device ED of an embodiment may include at least one selected from among the compounds in Compound Group 1. In Compound Group 1, D is a deuterium atom.

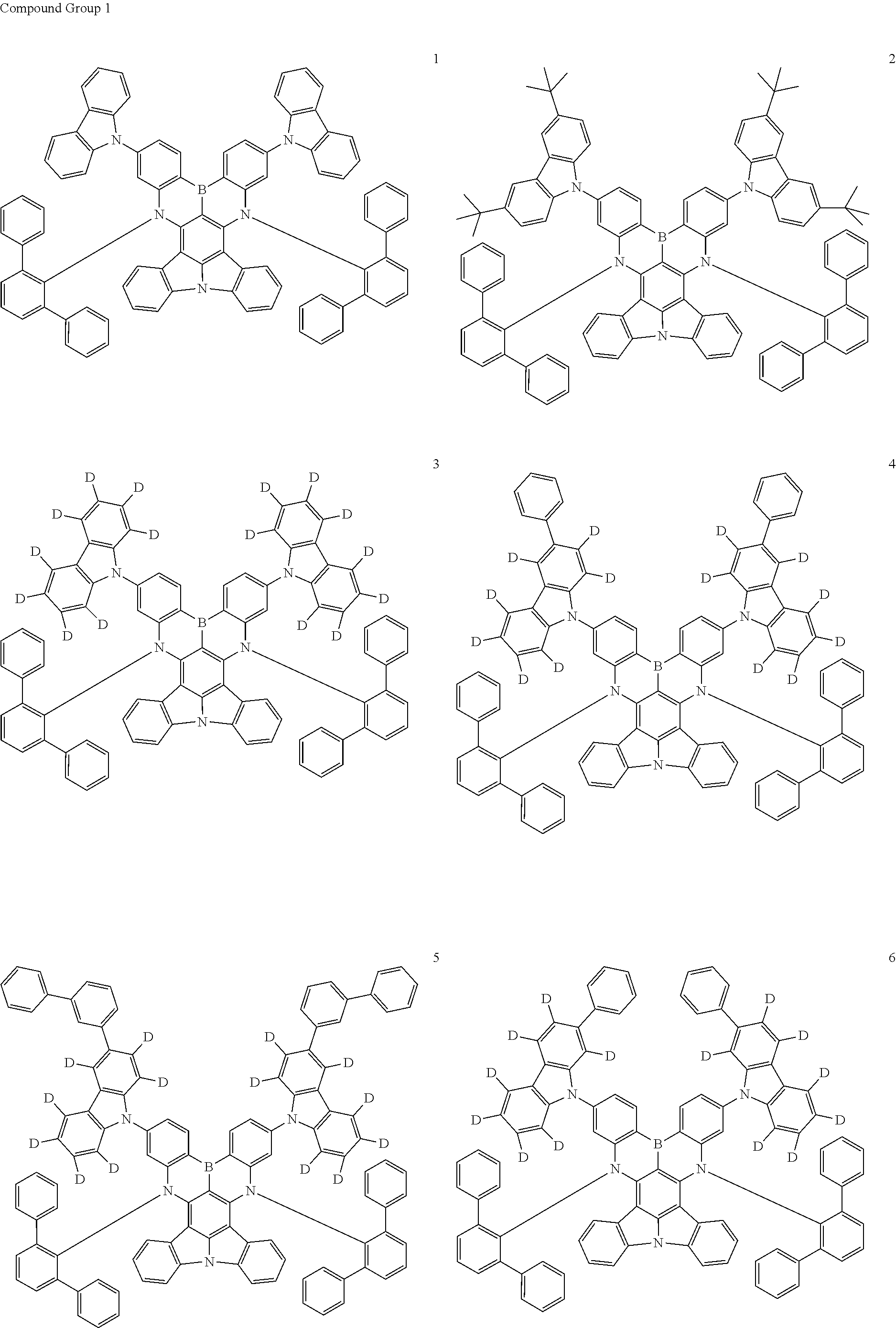

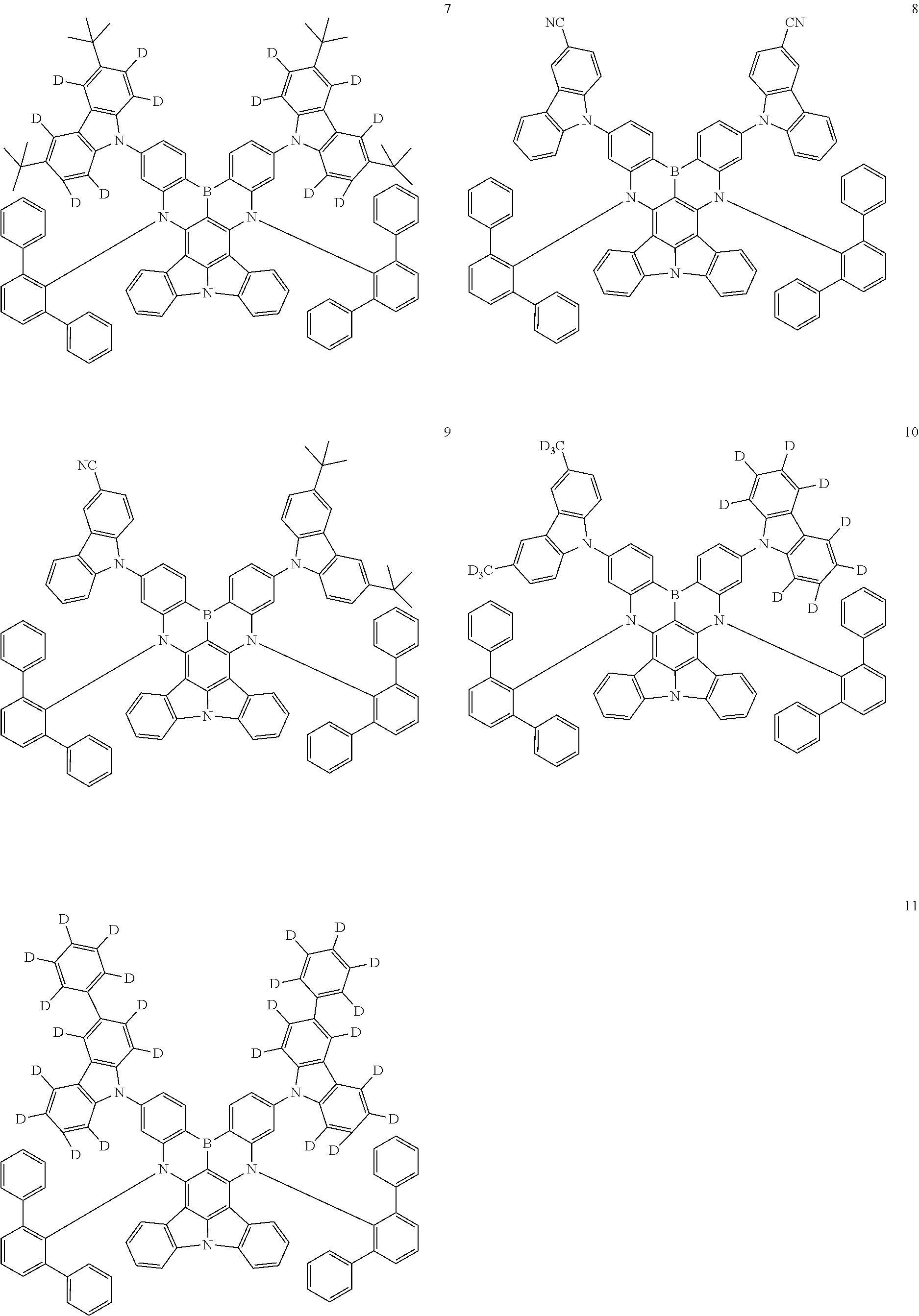

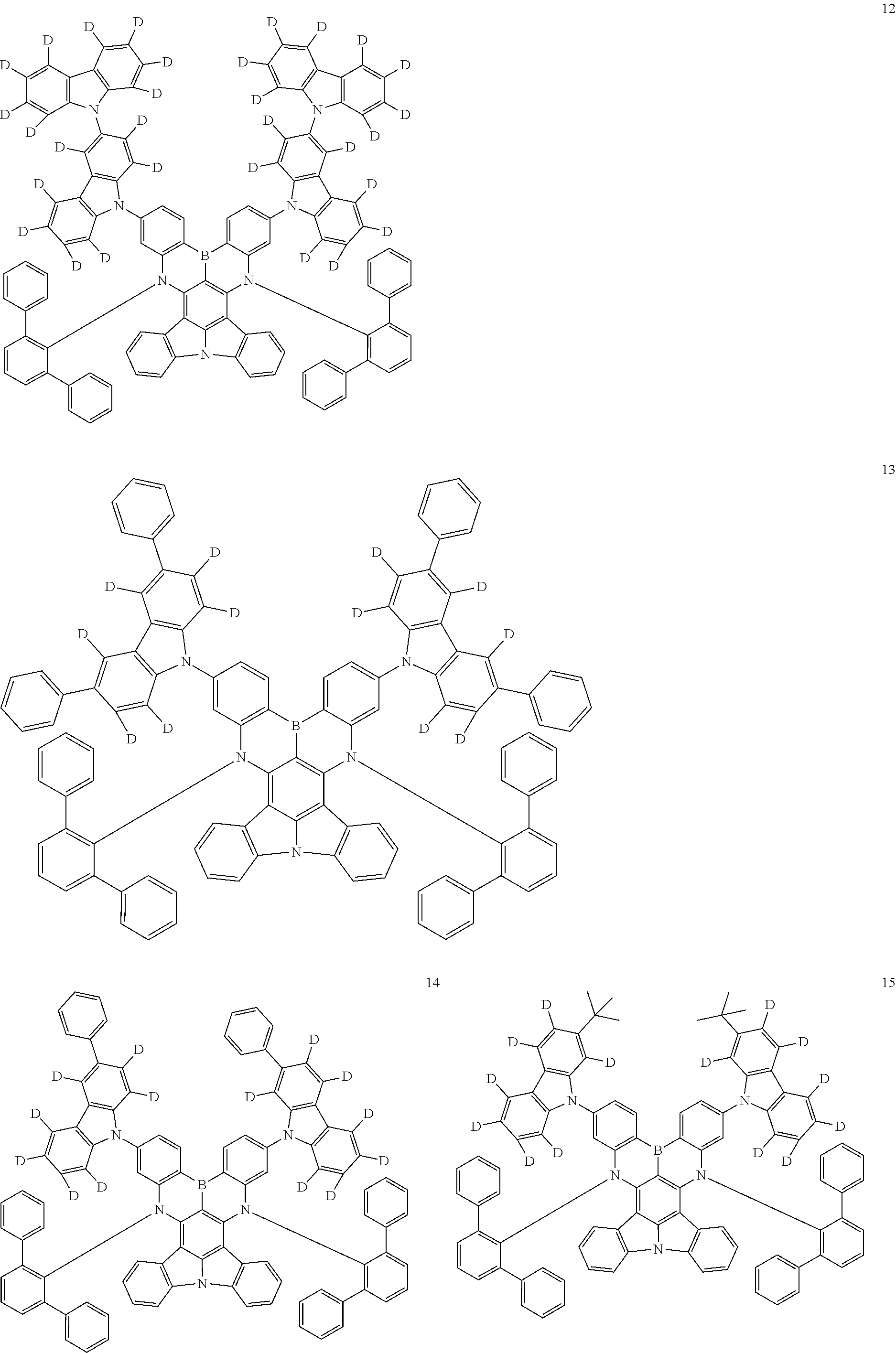

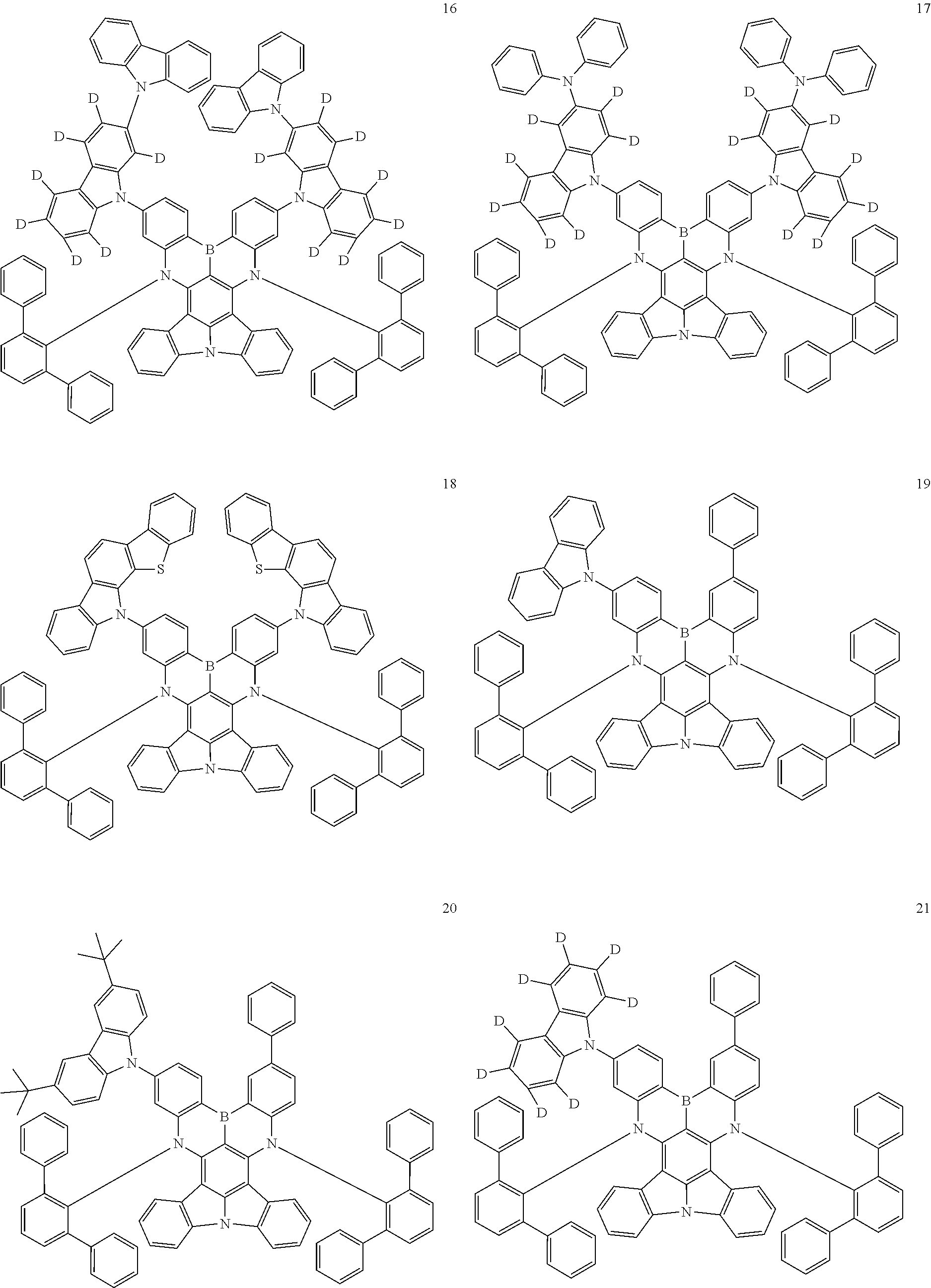

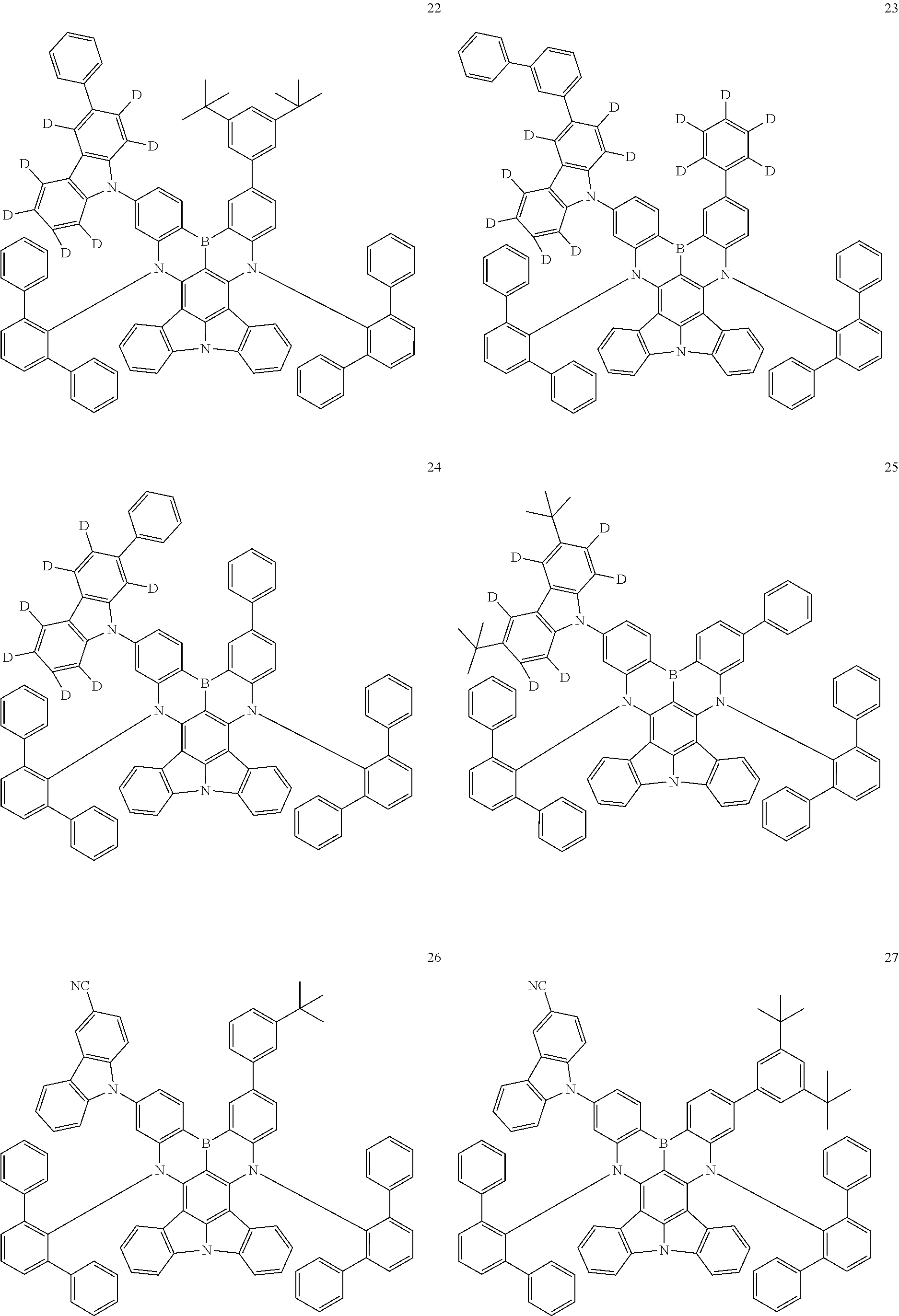

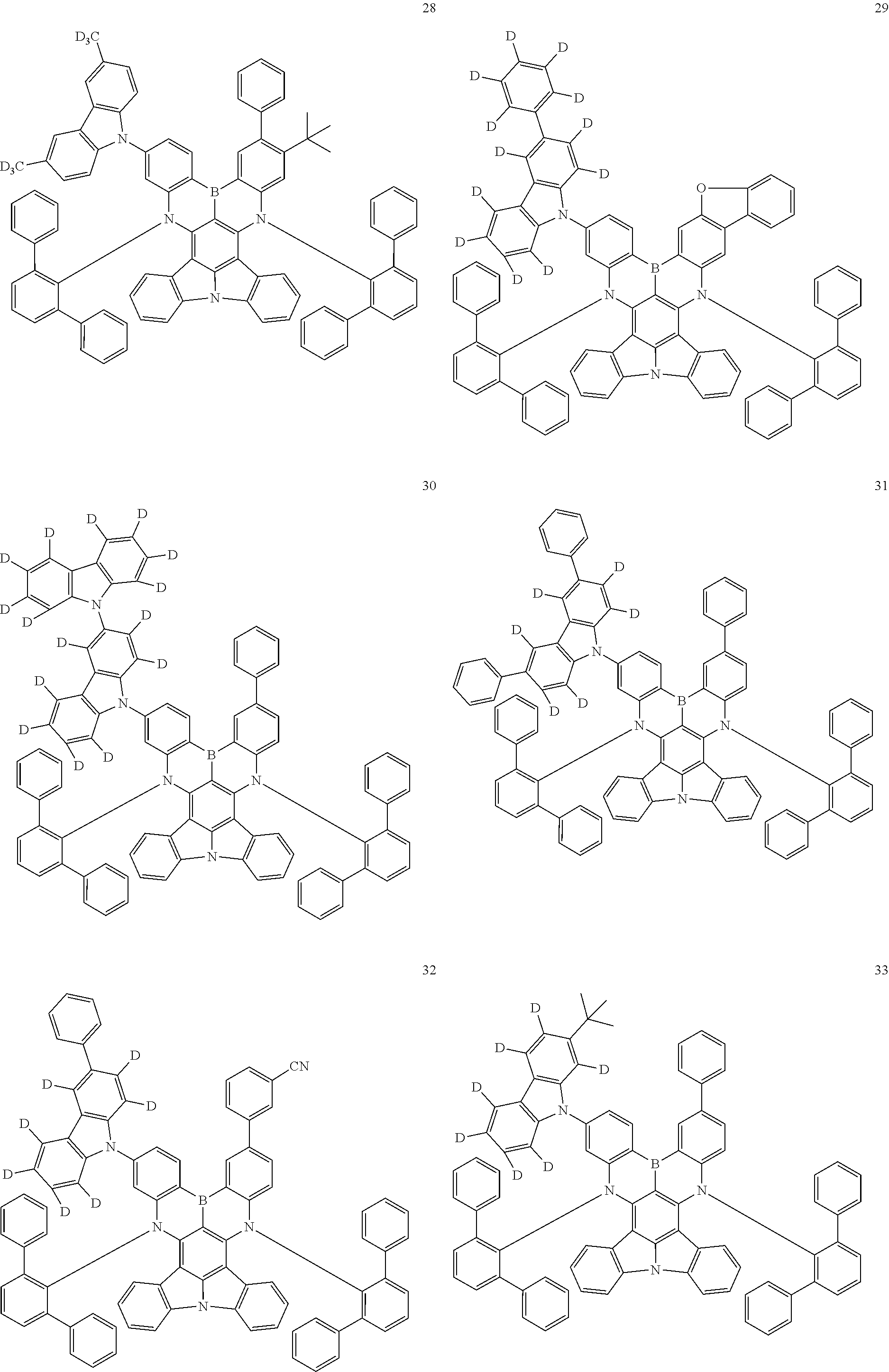

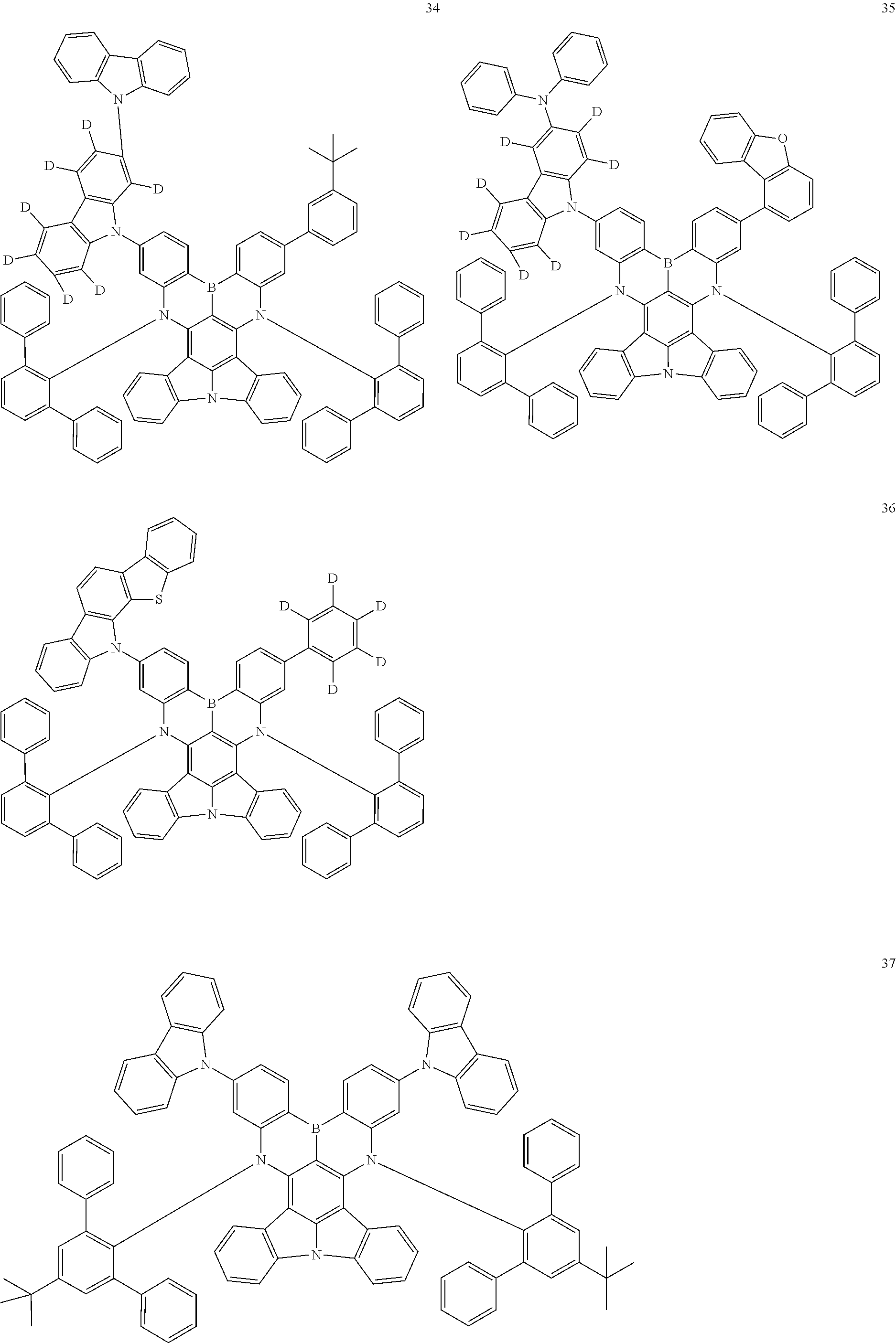

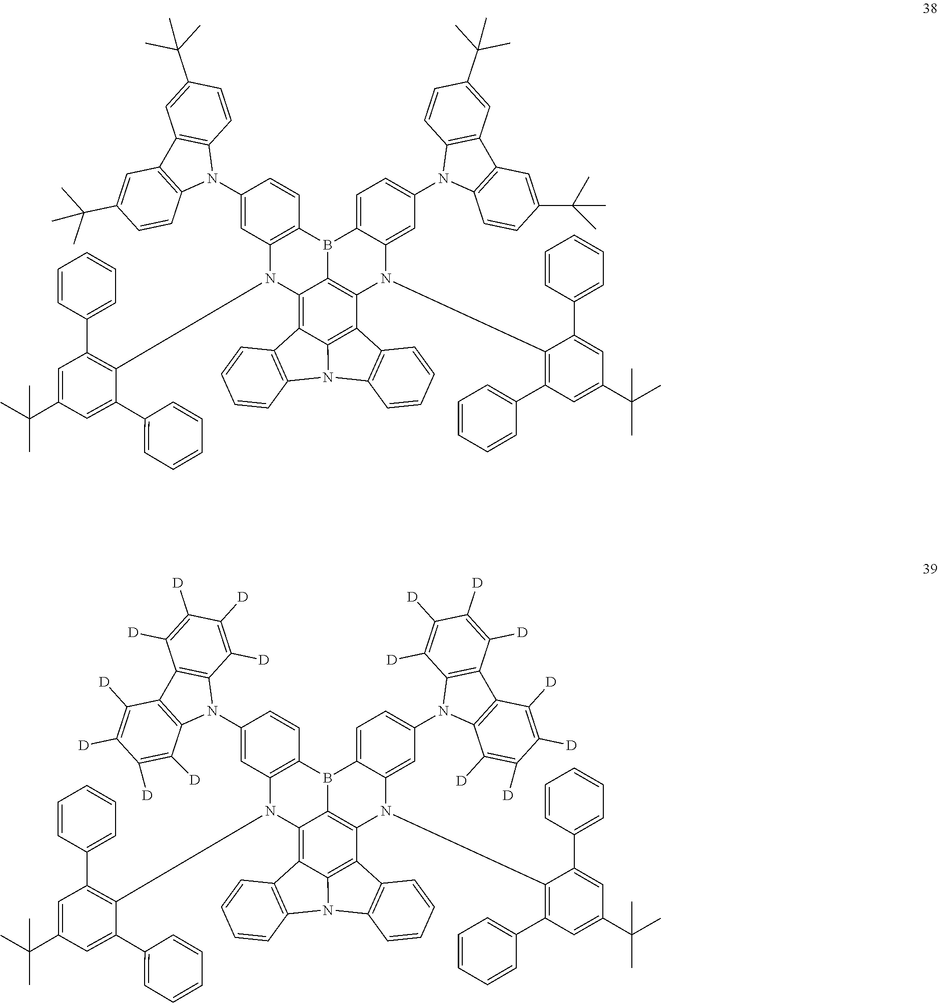

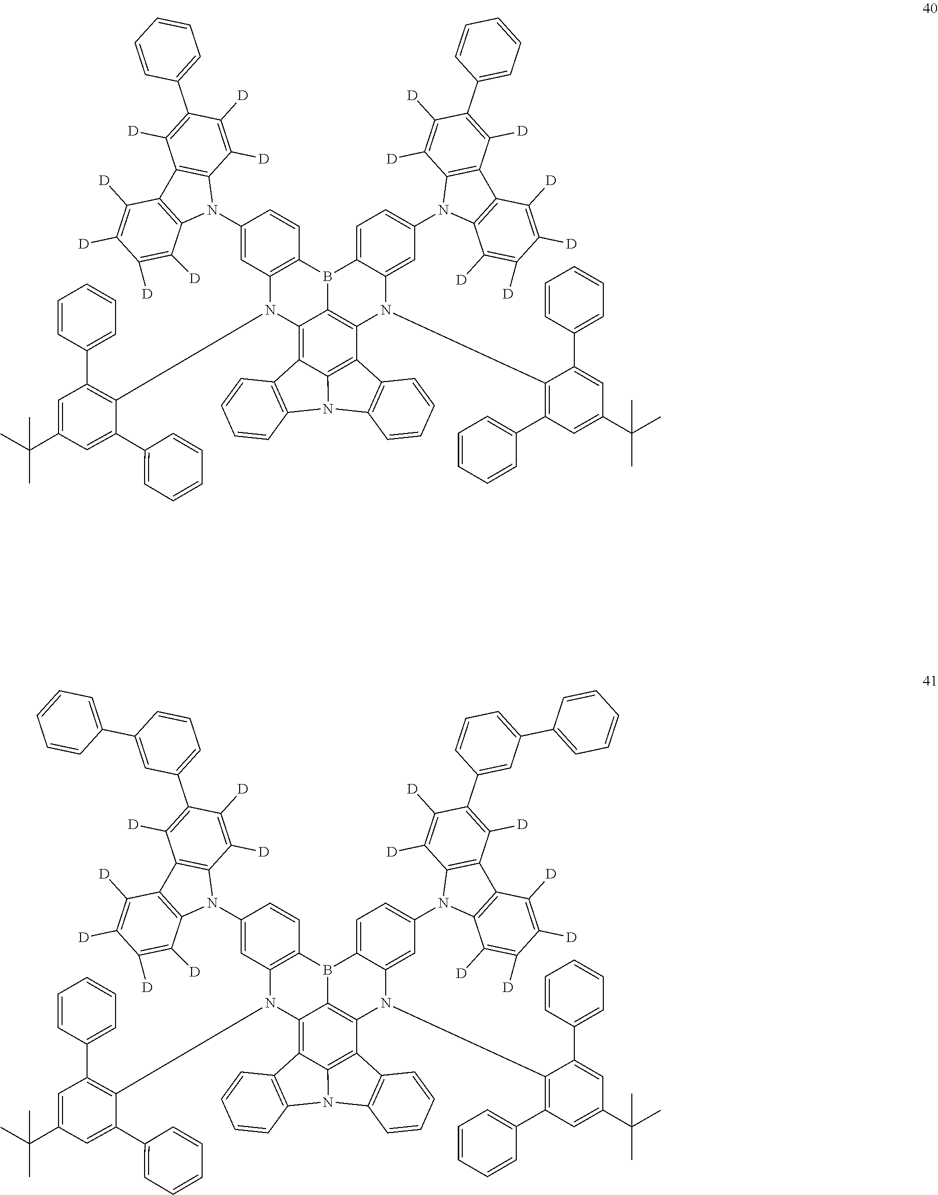

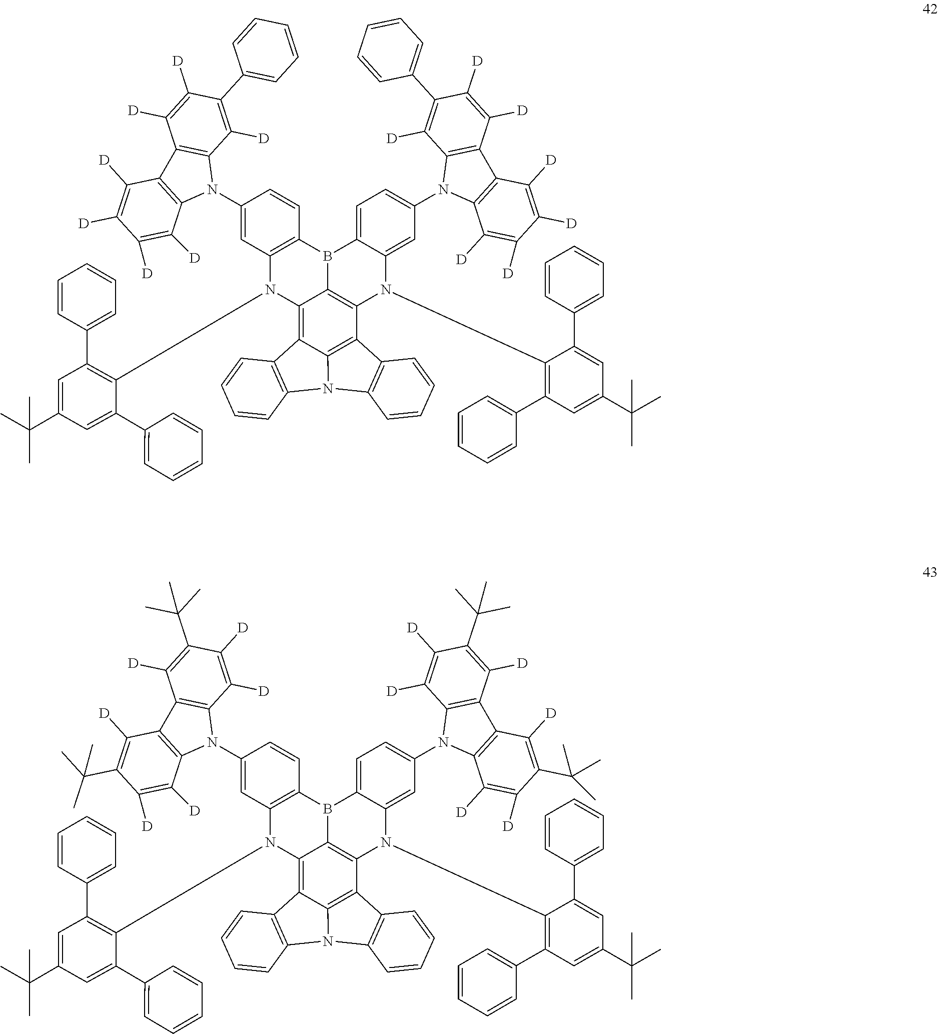

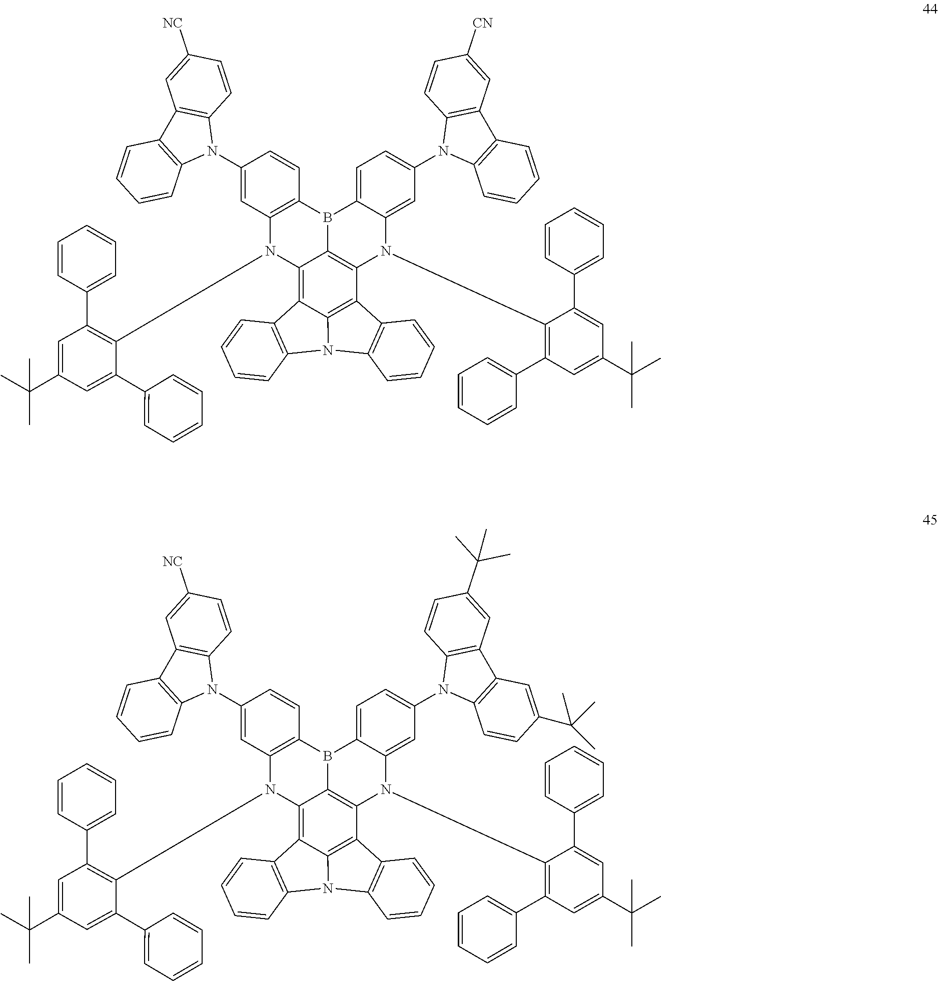

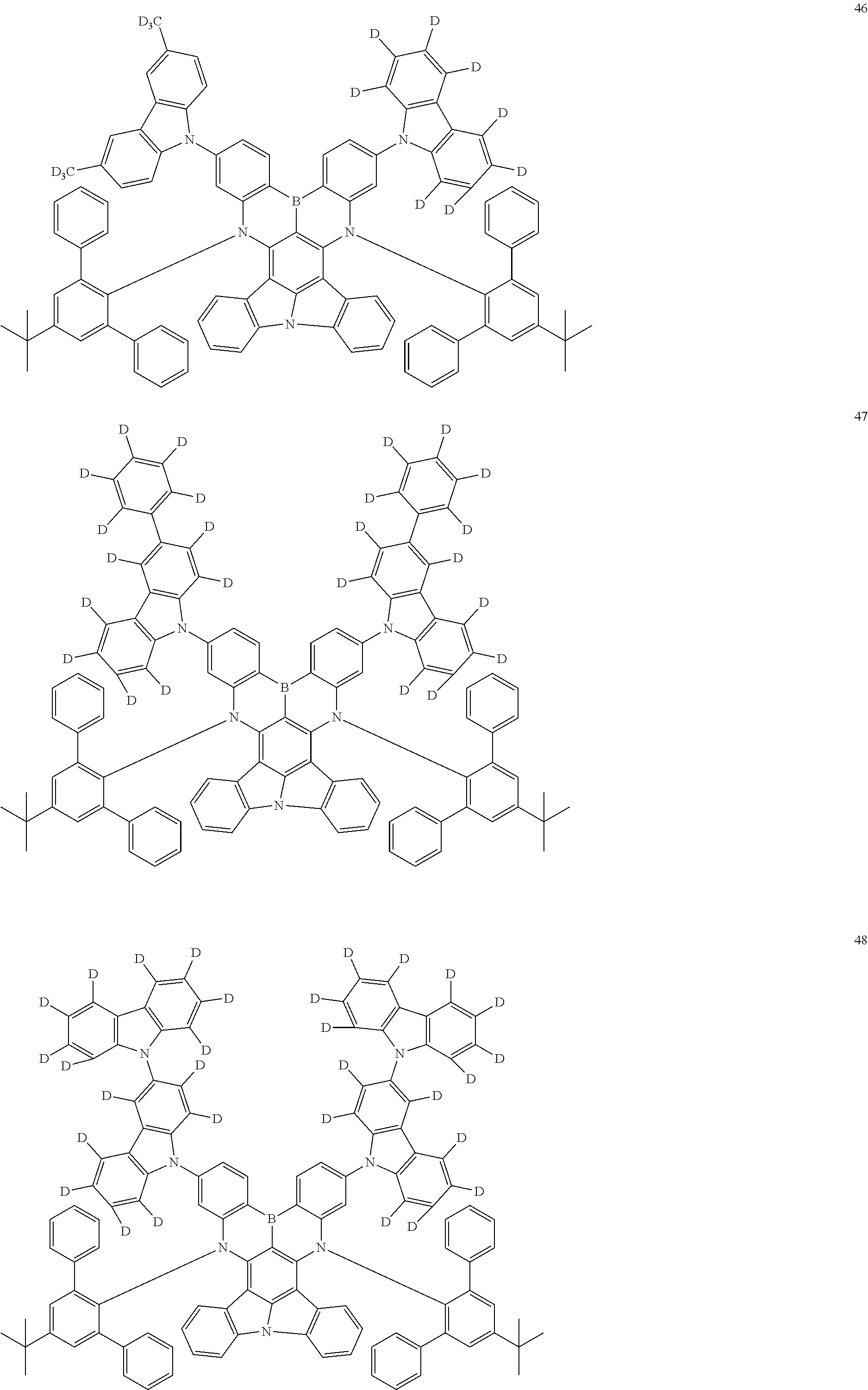

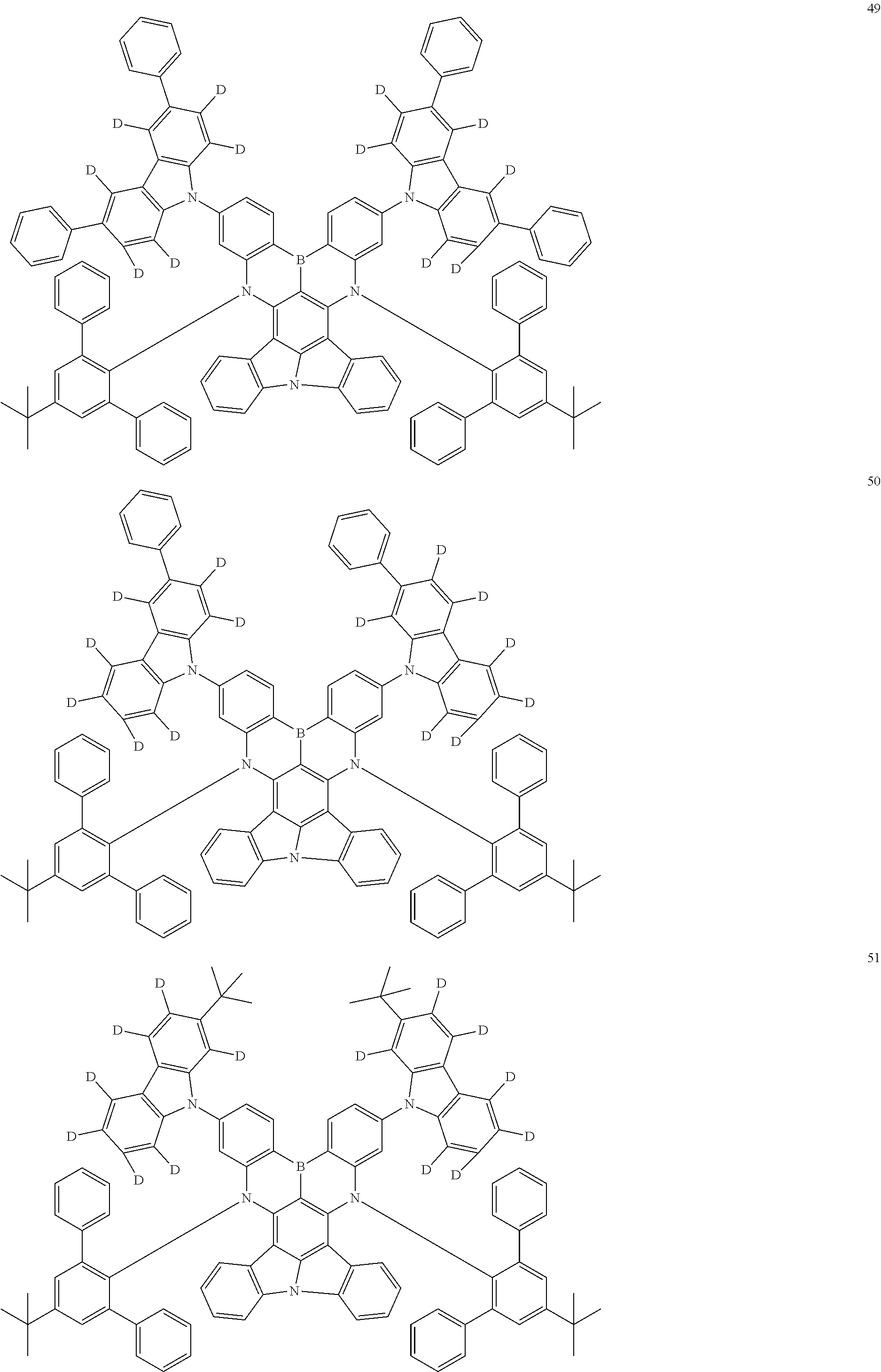

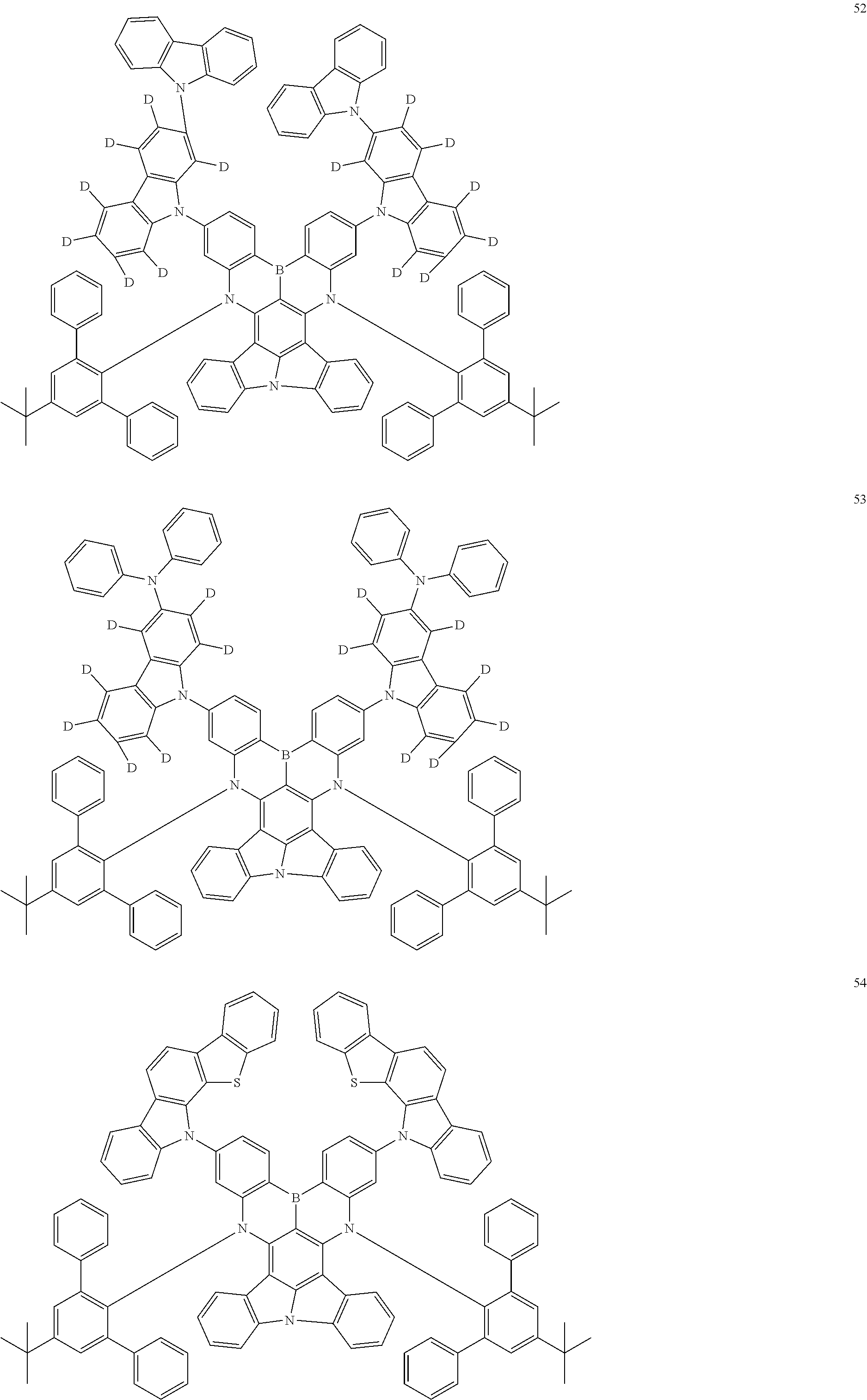

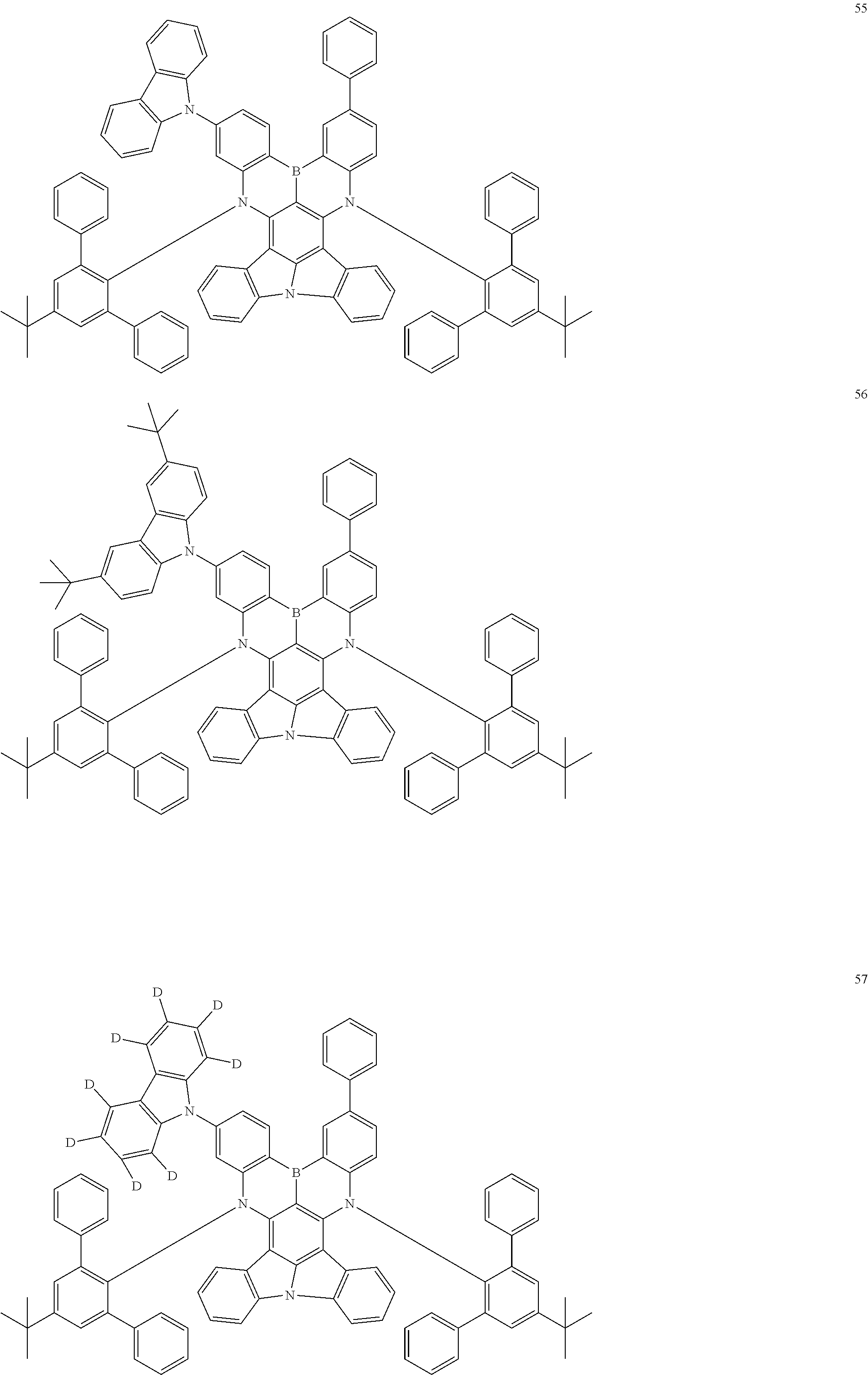

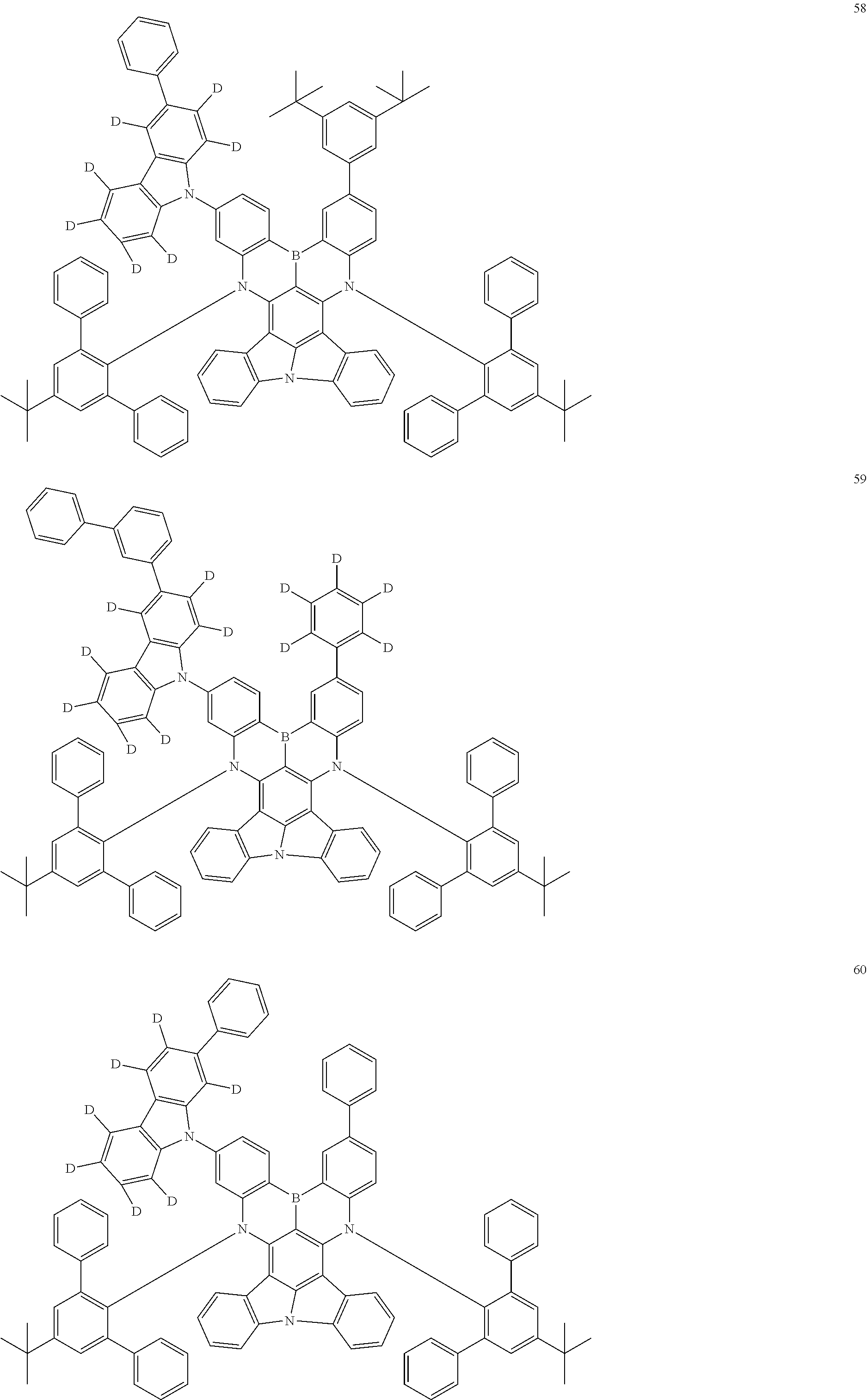

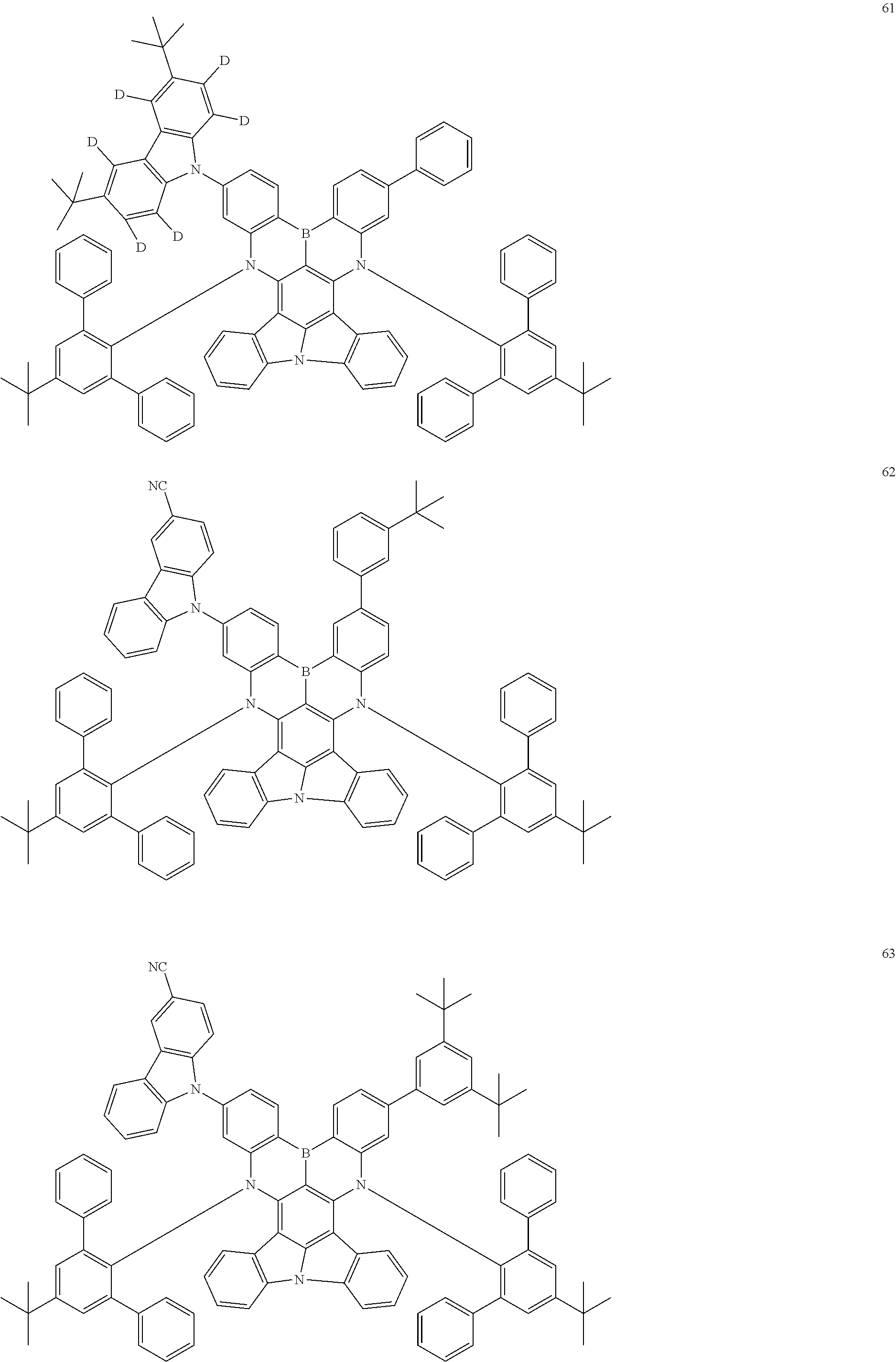

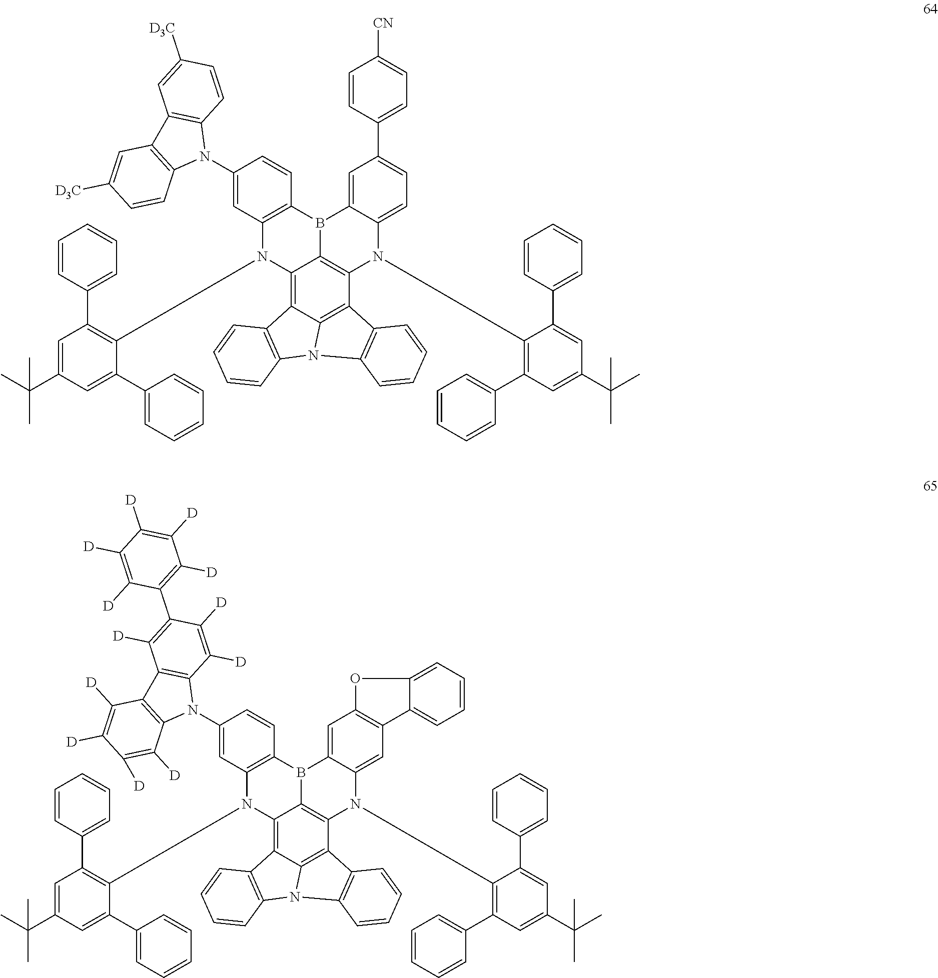

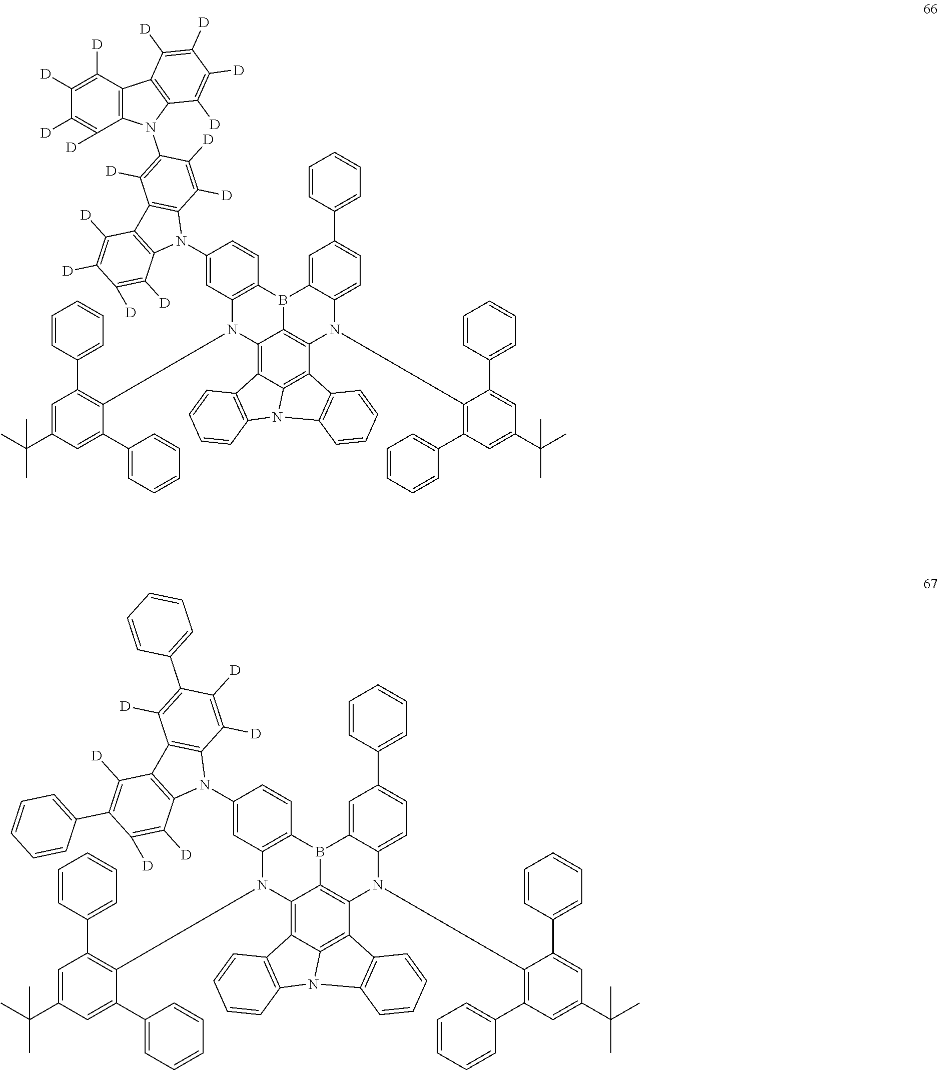

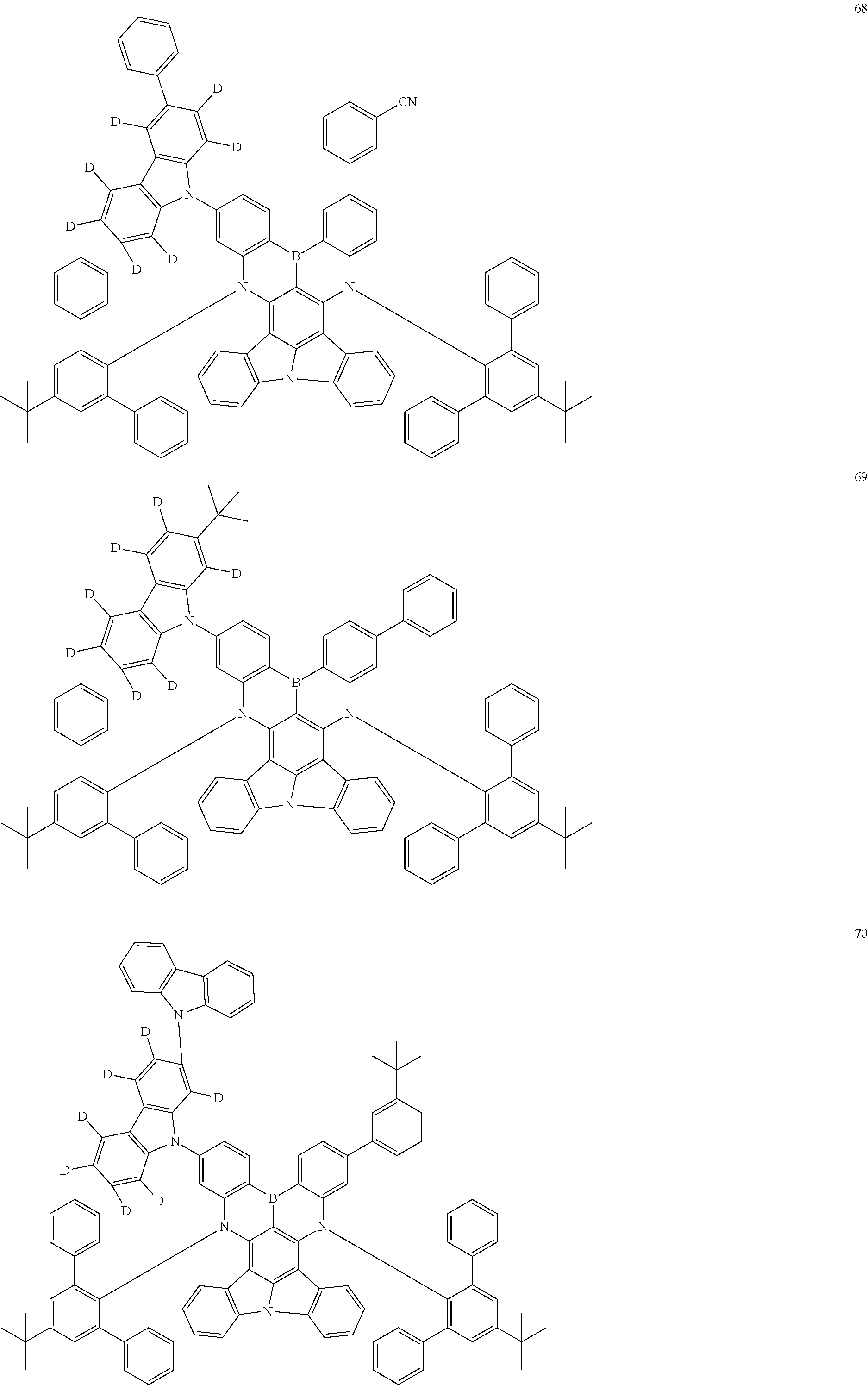

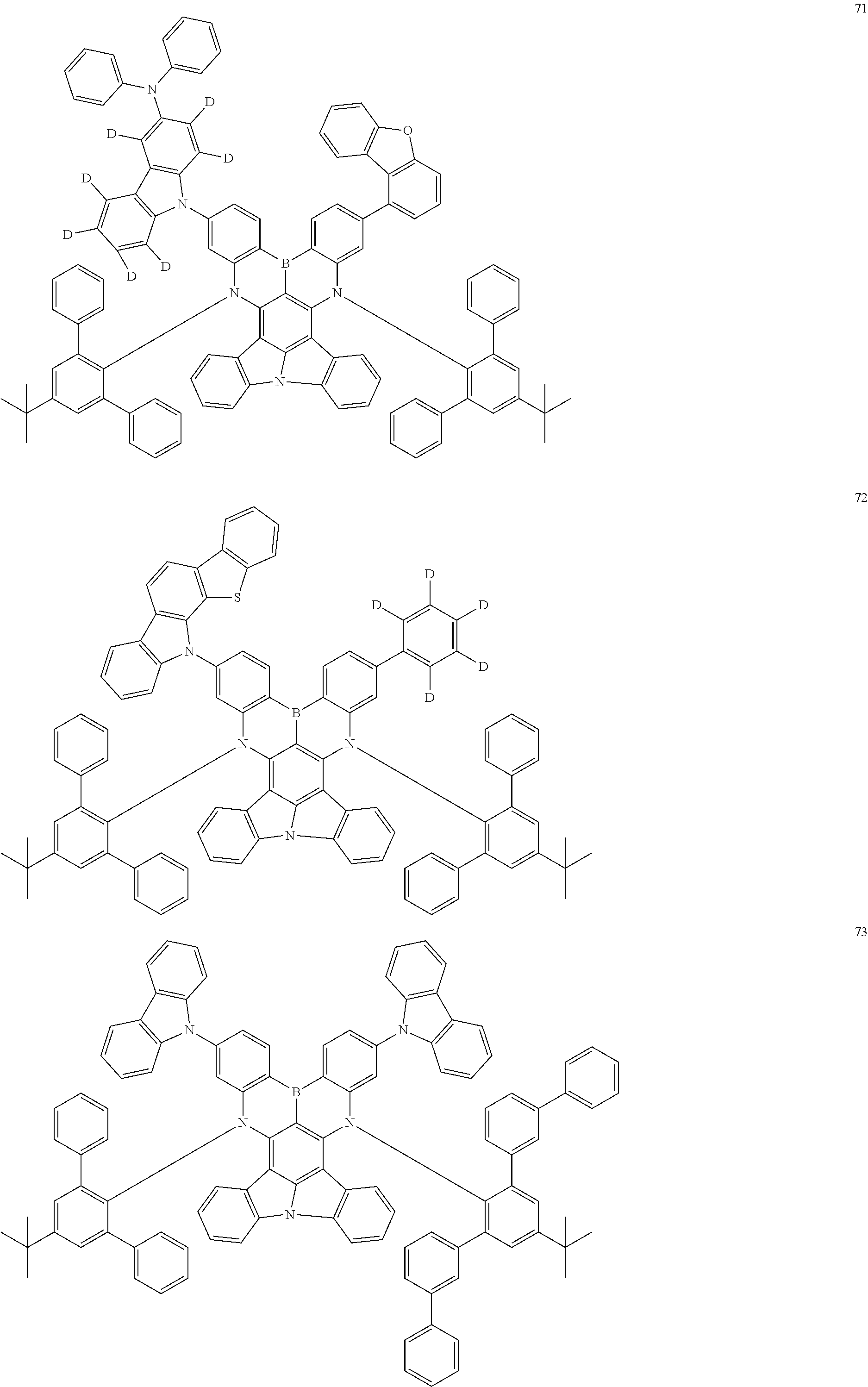

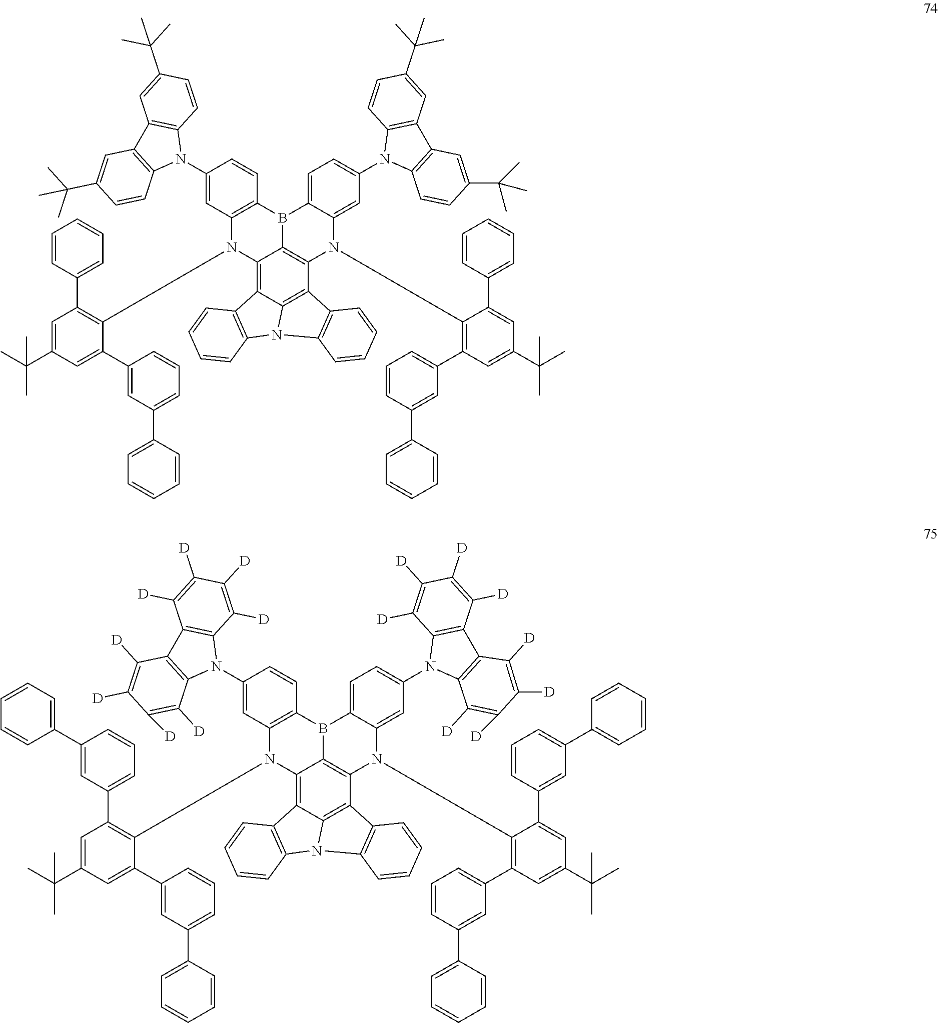

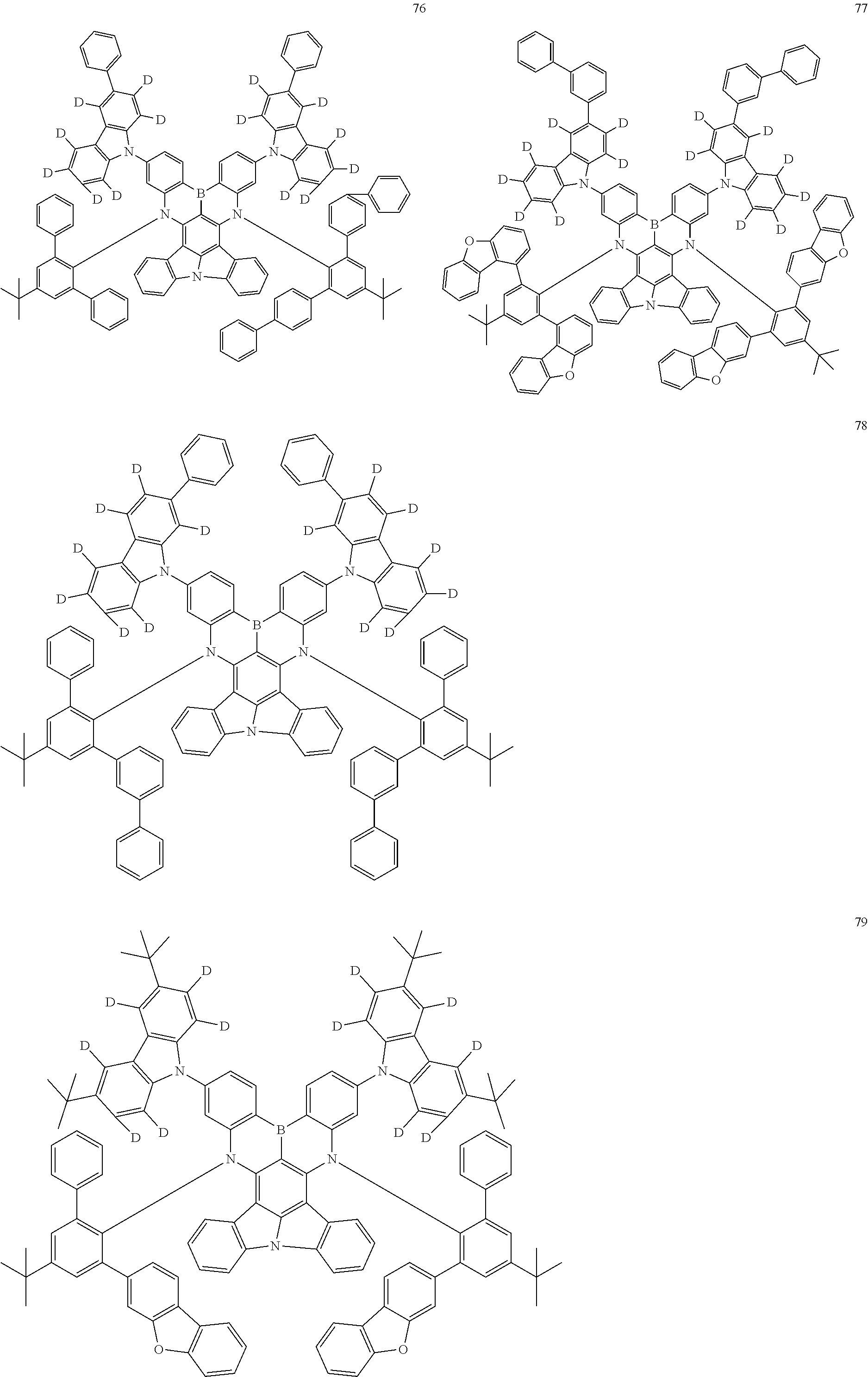

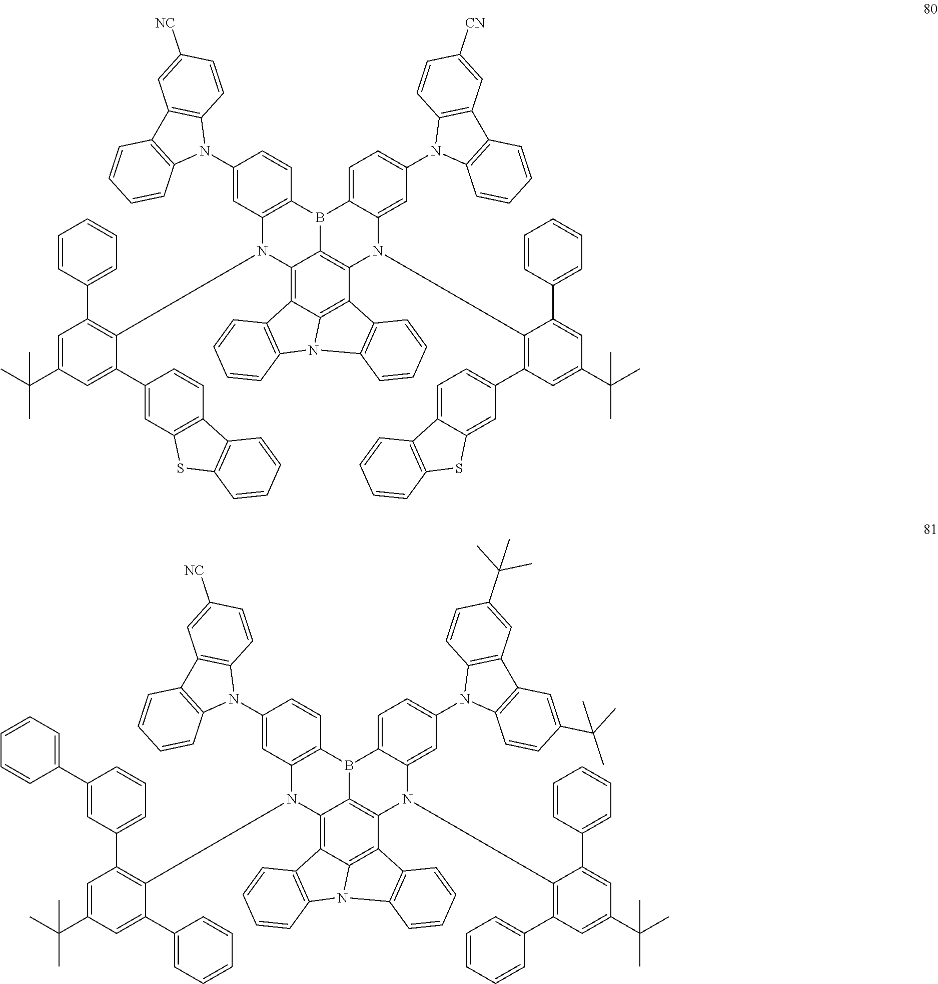 [SMILES: CC(C)(C)c1cc(-c2ccccc2)c(N2c3cc(-n4c5ccccc5c5cc(C#N)ccc54)ccc3B3c4ccc(-n5c6ccccc6c6cc(C#N)ccc65)cc4N(c4c(-c5ccccc5)cc(C(C)(C)C)cc4-c4ccc5c(c4)sc4ccccc45)c4c3c2c2c3ccccc3n3c5ccccc5c4c23)c(-c2ccc3c(c2)sc2ccccc23)c1 ; CC(C)(C)c1cc(-c2ccccc2)c(N2c3cc(-n4c5ccccc5c5cc(C#N)ccc54)ccc3B3c4ccc(-n5c6ccc(C(C)(C)C)cc6c6cc(C(C)(C)C)ccc65)cc4N(c4c(-c5ccccc5)cc(C(C)(C)C)cc4-c4ccccc4)c4c3c2c2c3ccccc3n3c5ccccc5c4c23)c(-c2cccc(-c3ccccc3)c2)c1]

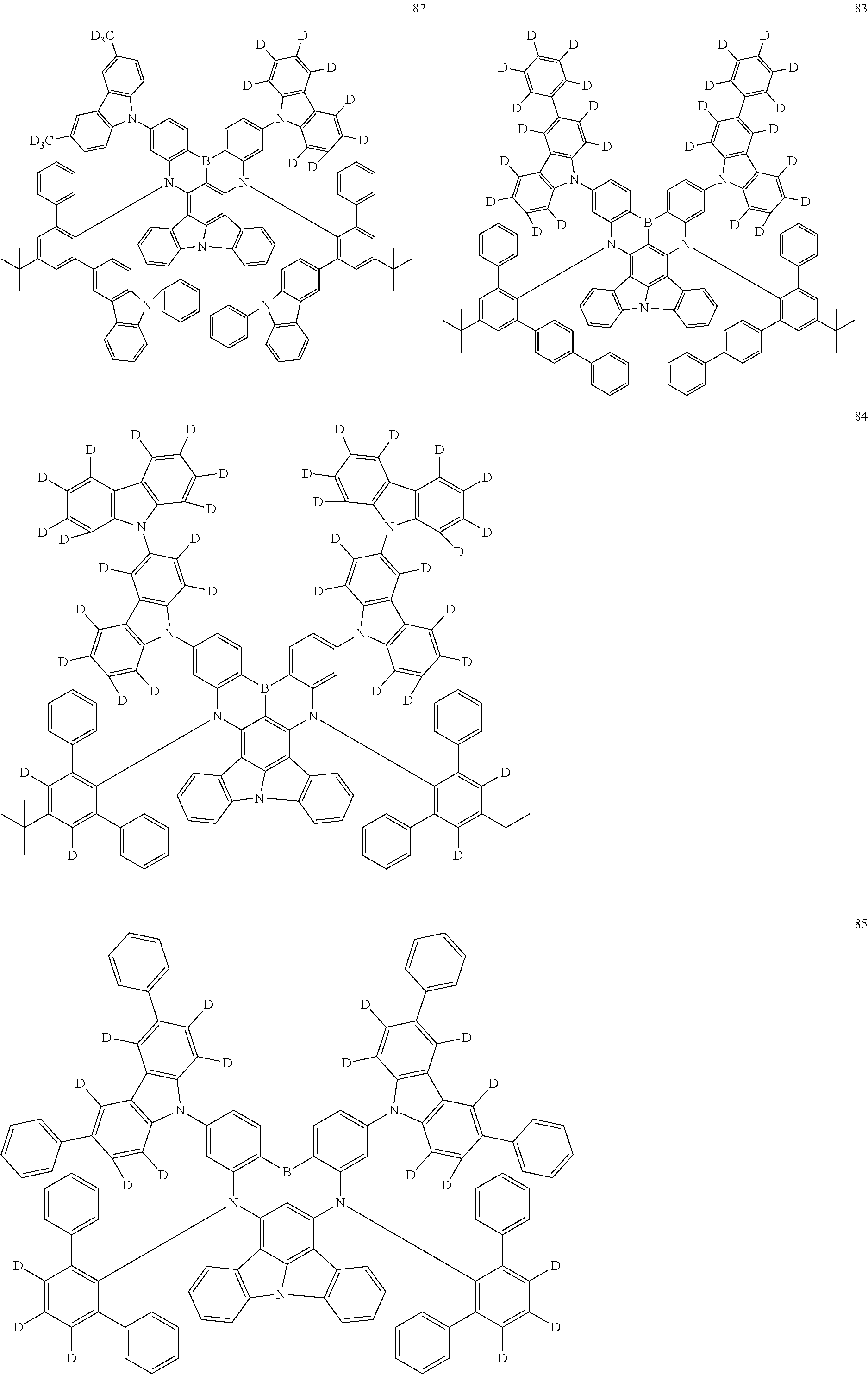

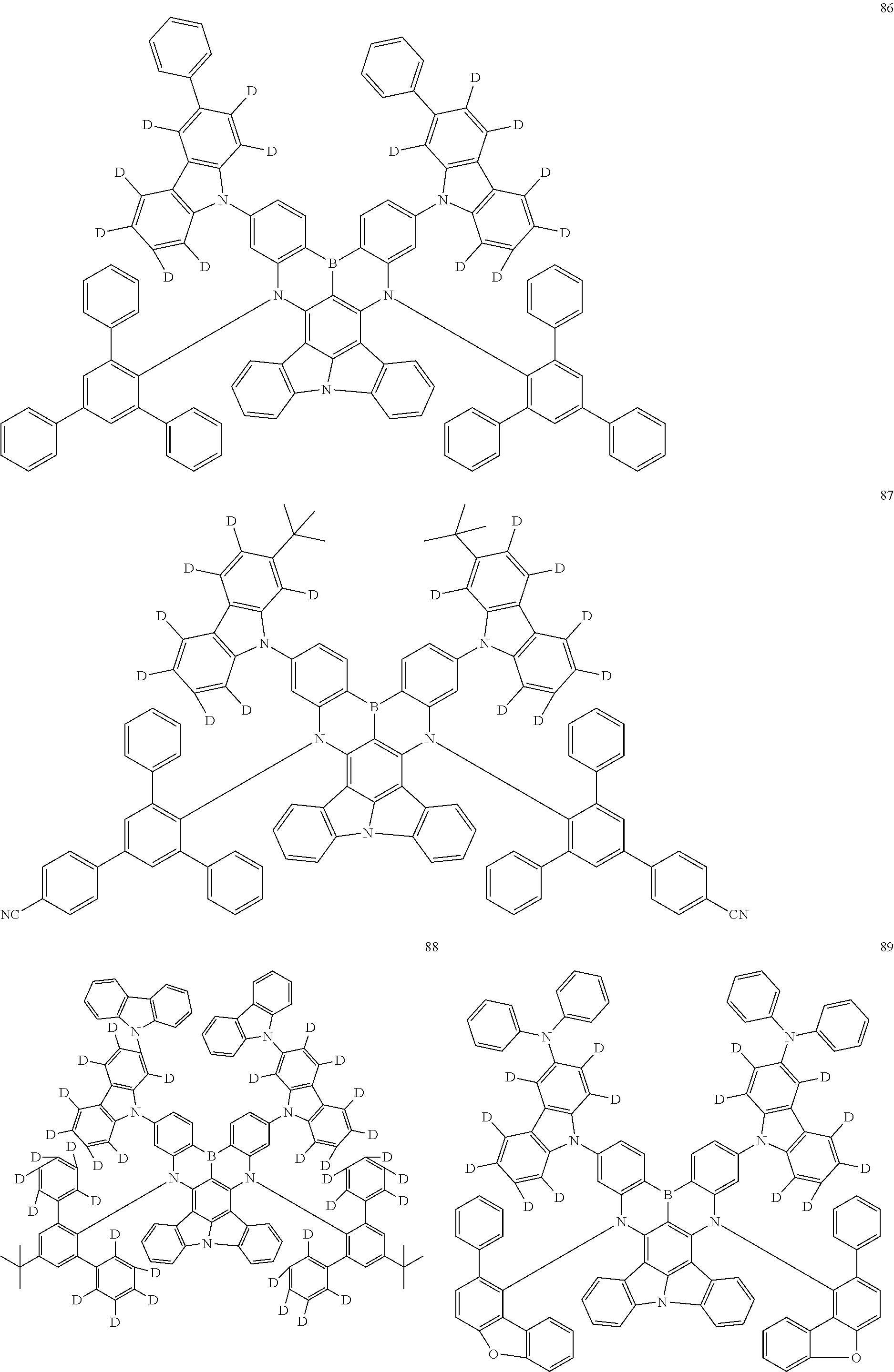

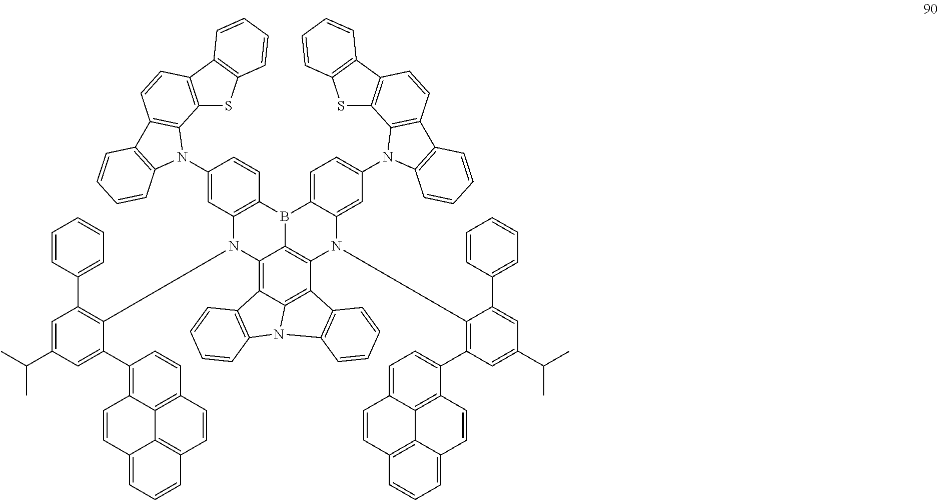 [SMILES: CC(C)c1cc(-c2ccccc2)c(N2c3cc(-n4c5ccccc5c5ccc6c7ccccc7sc6c54)ccc3B3c4ccc(-n5c6ccccc6c6ccc7c8ccccc8sc7c65)cc4N(c4c(-c5ccccc5)cc(C(C)C)cc4-c4ccc5ccc6cccc7ccc4c5c67)c4c3c2c2c3ccccc3n3c5ccccc5c4c23)c(-c2ccc3ccc4cccc5ccc2c3c45)c1]

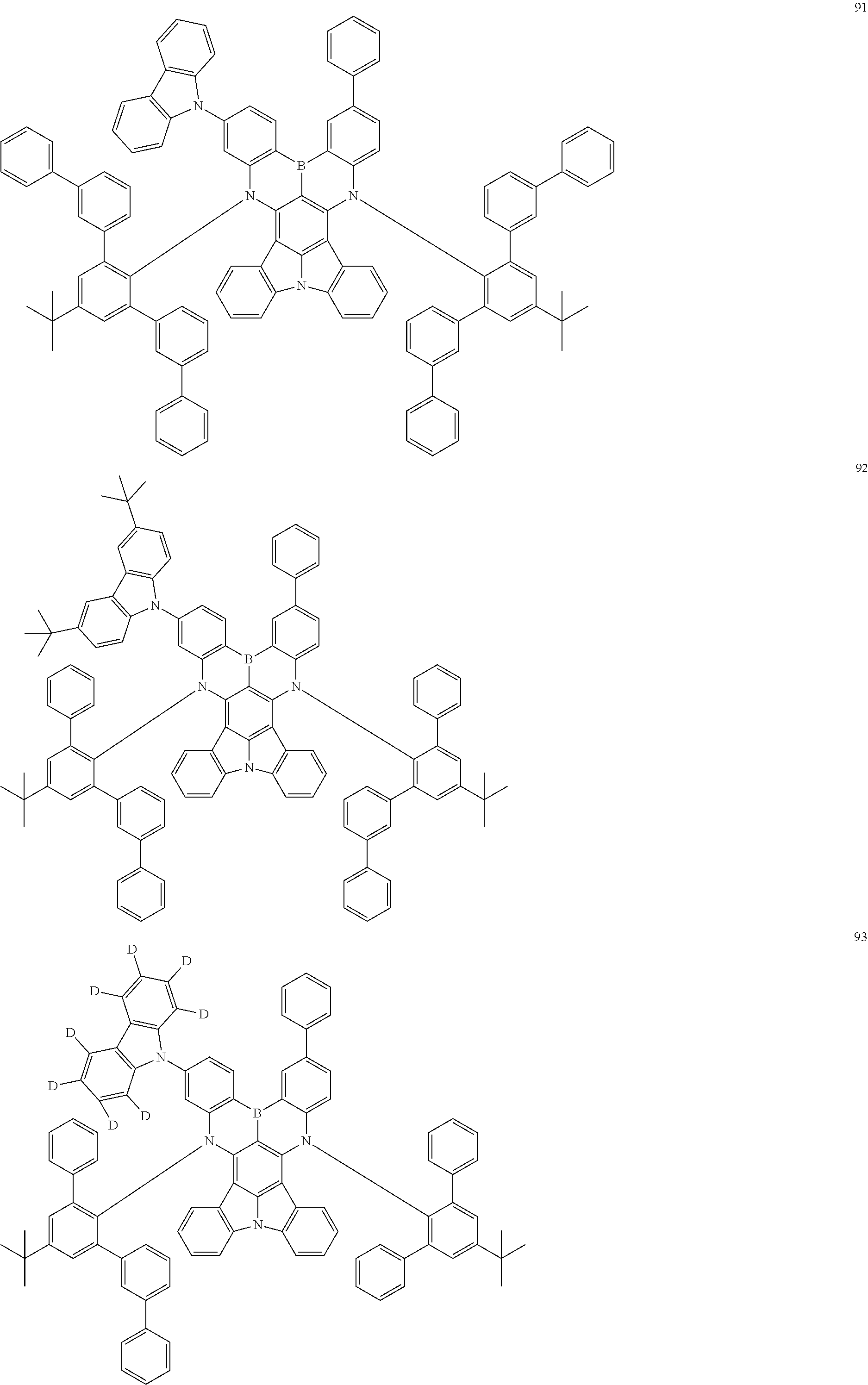

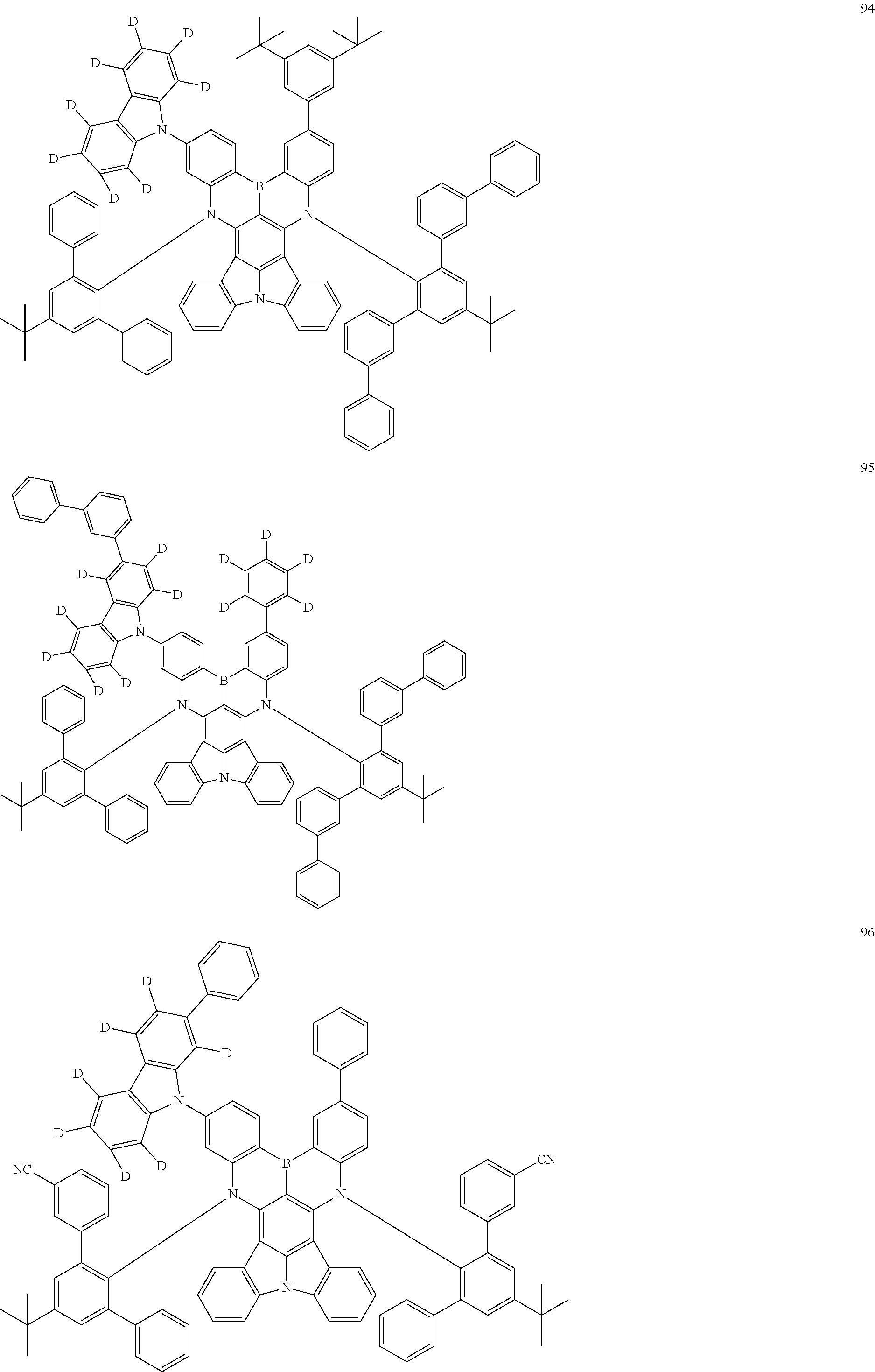

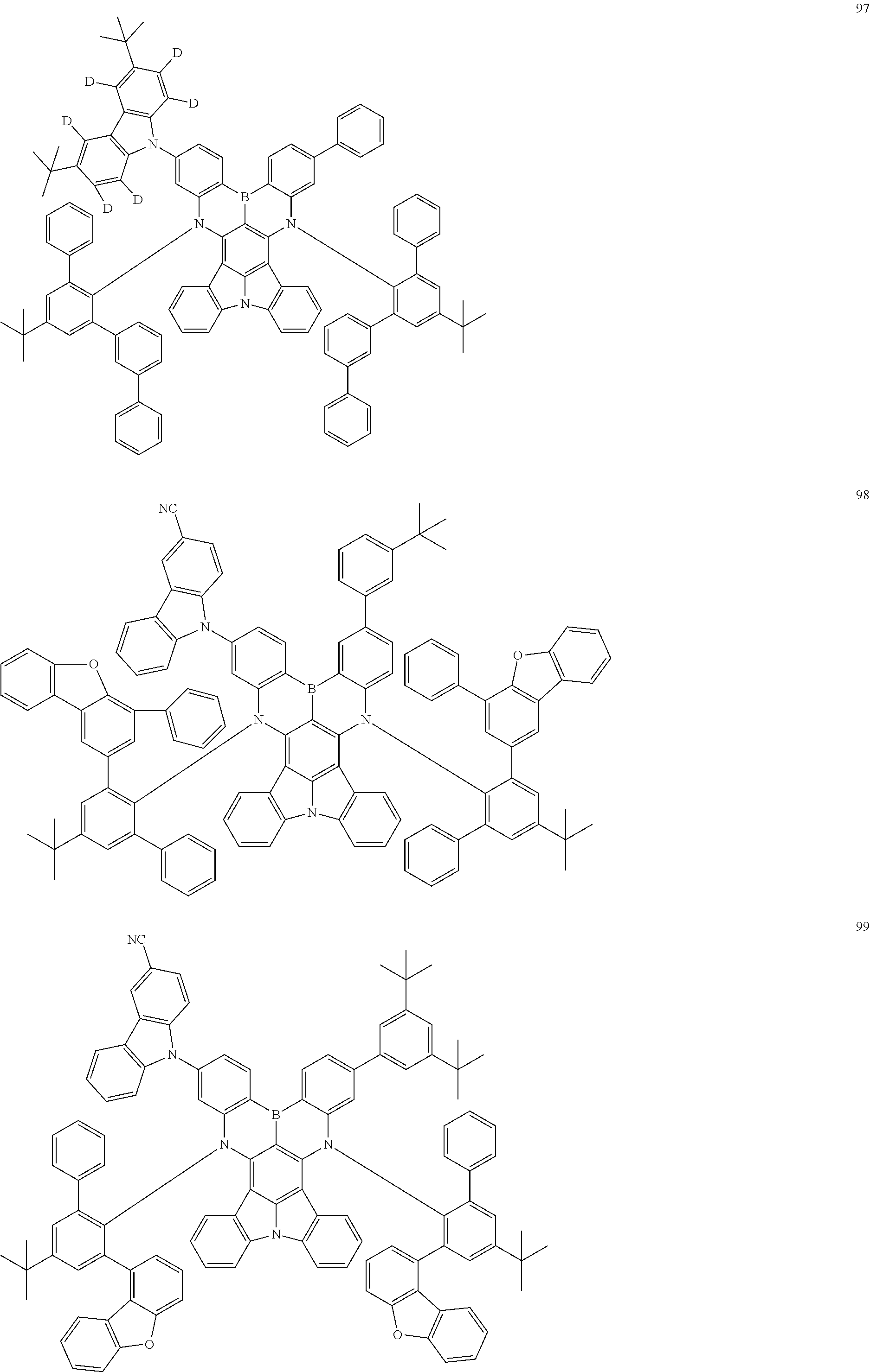

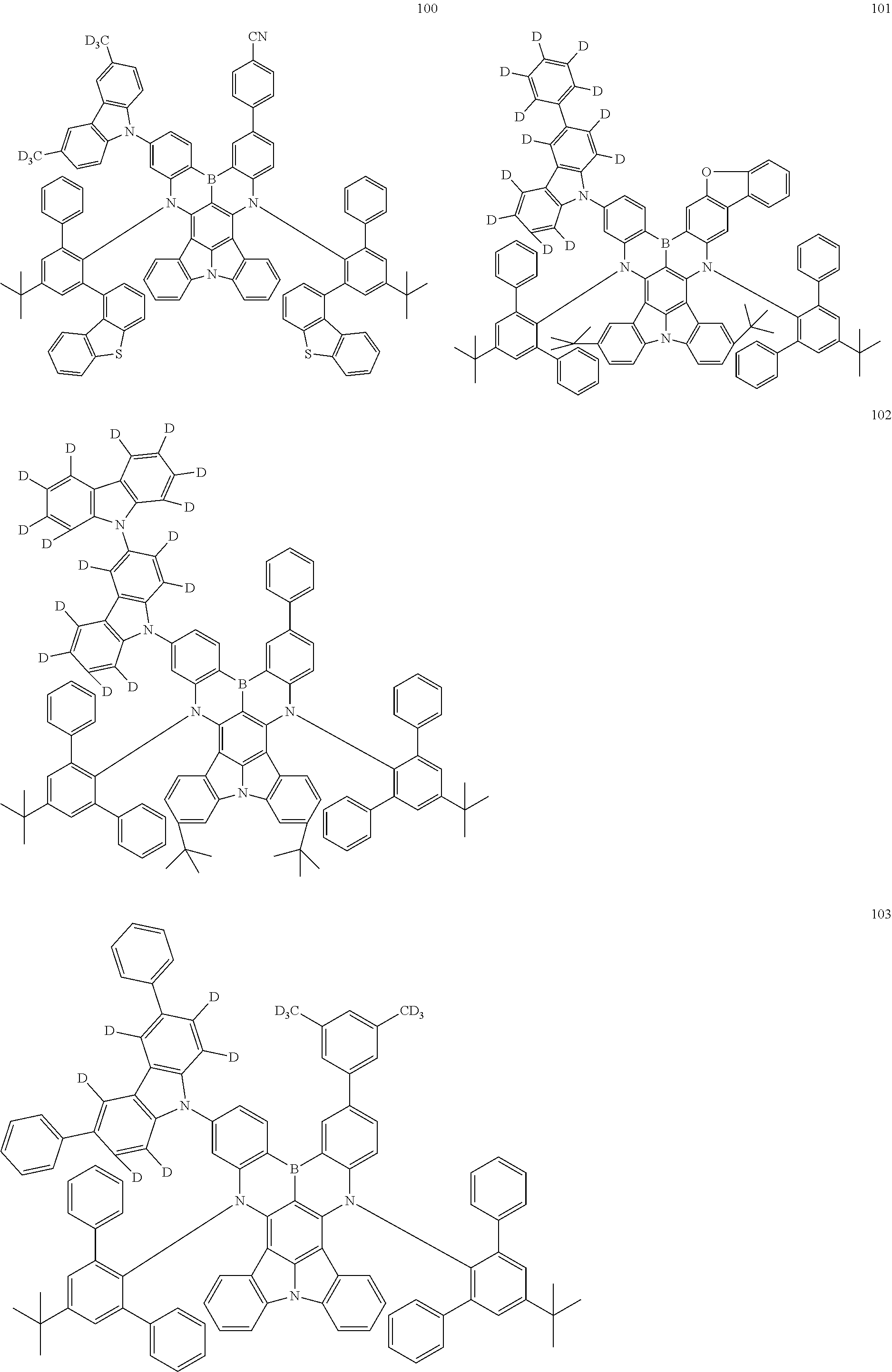

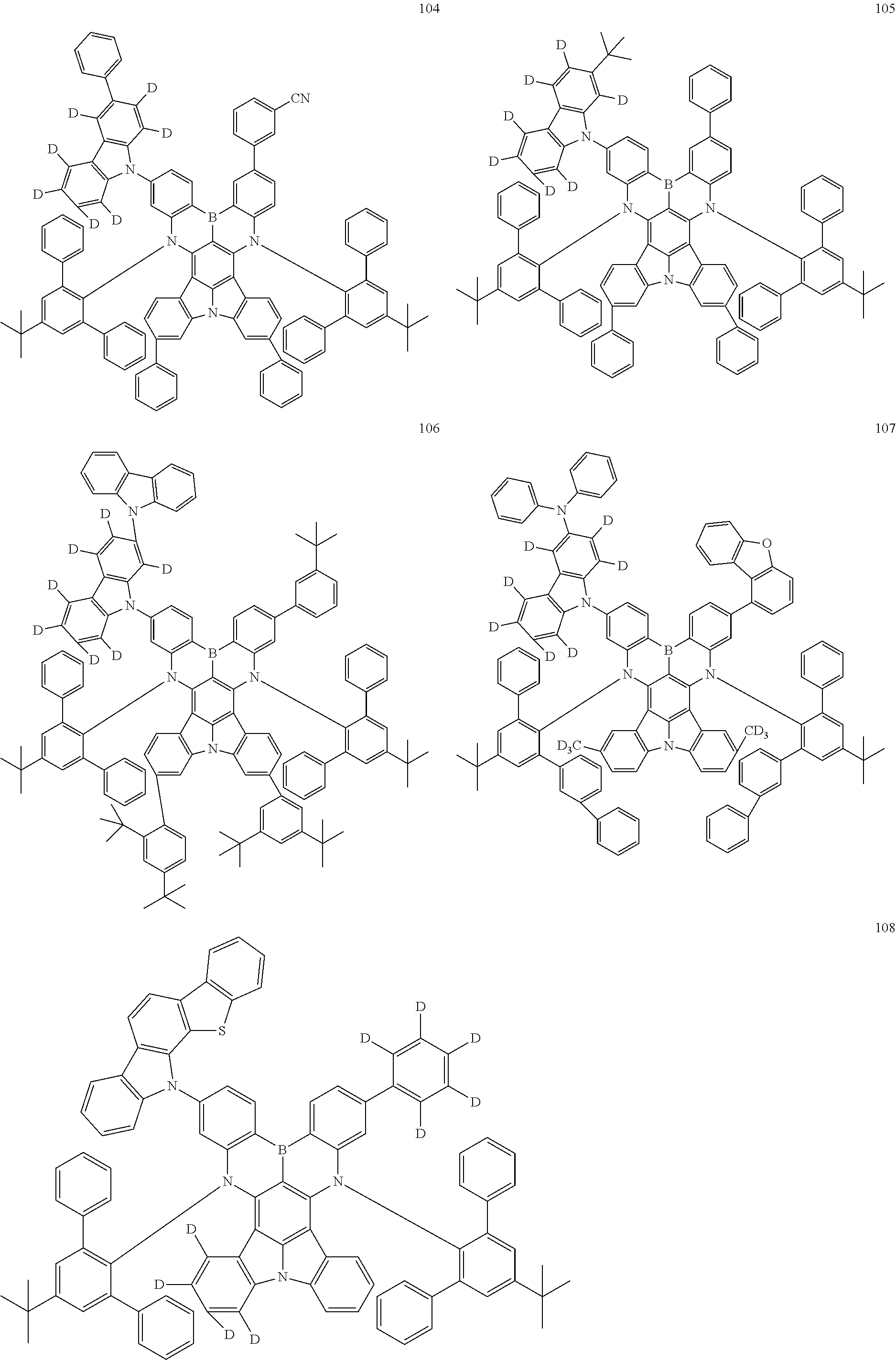

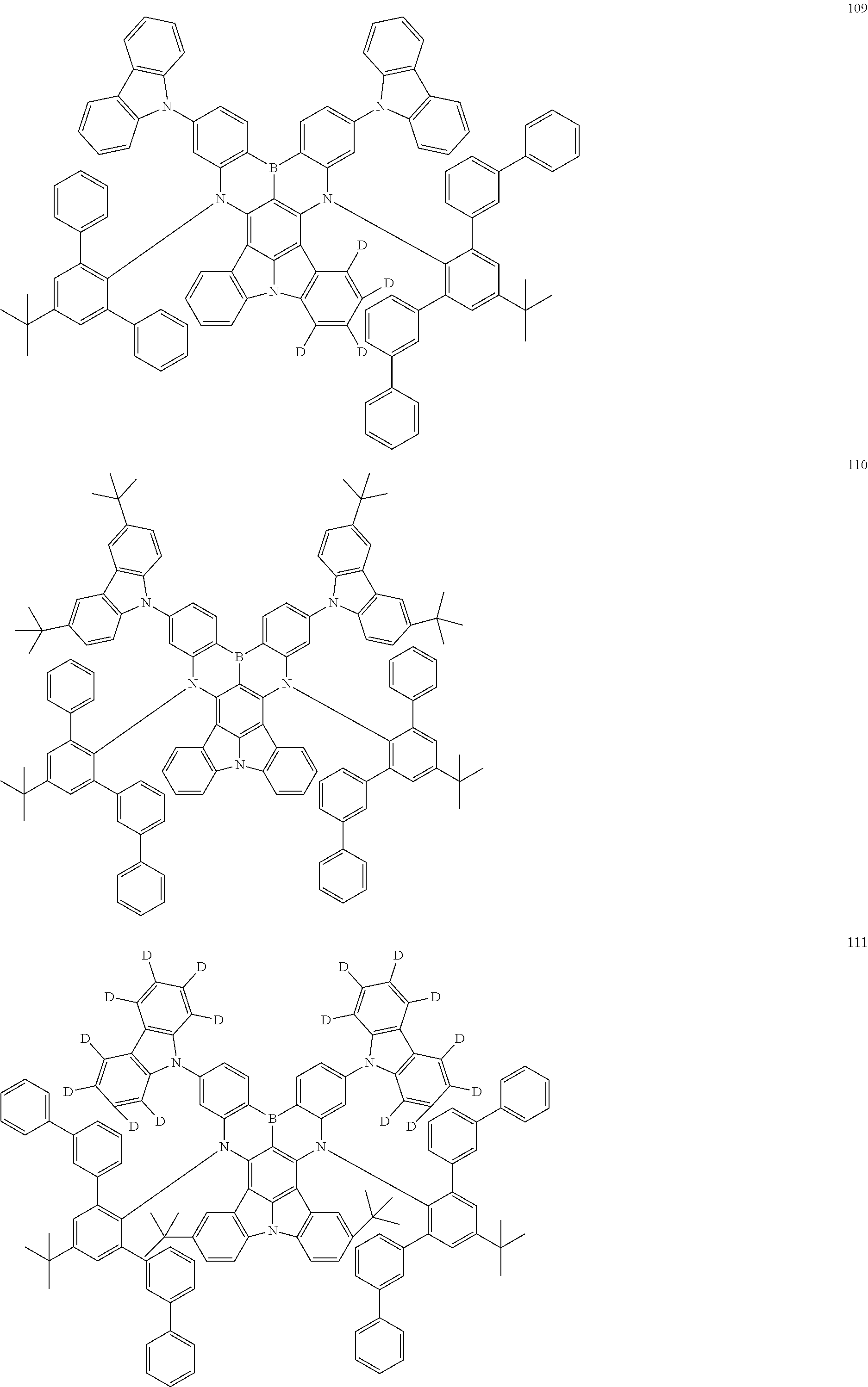

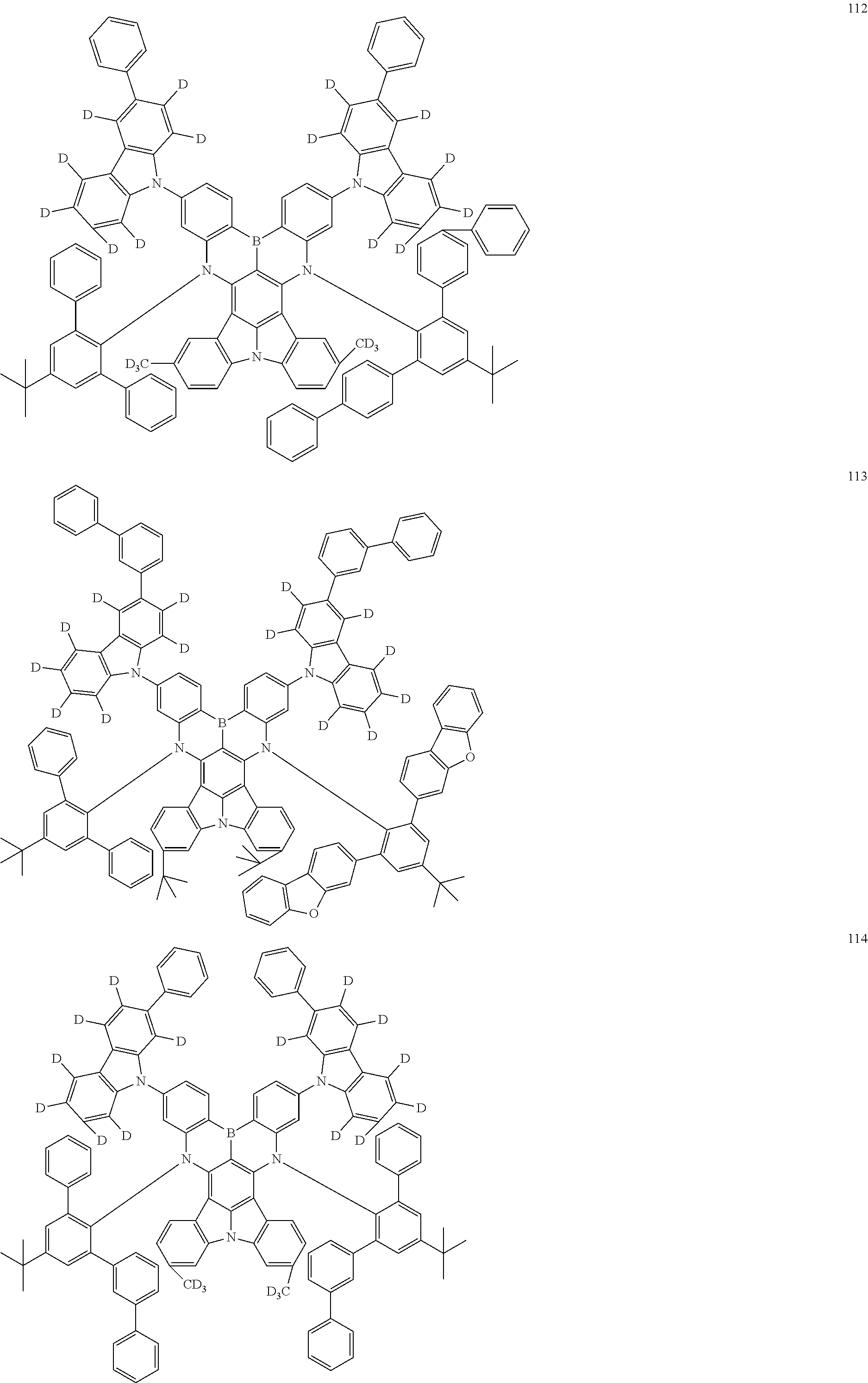

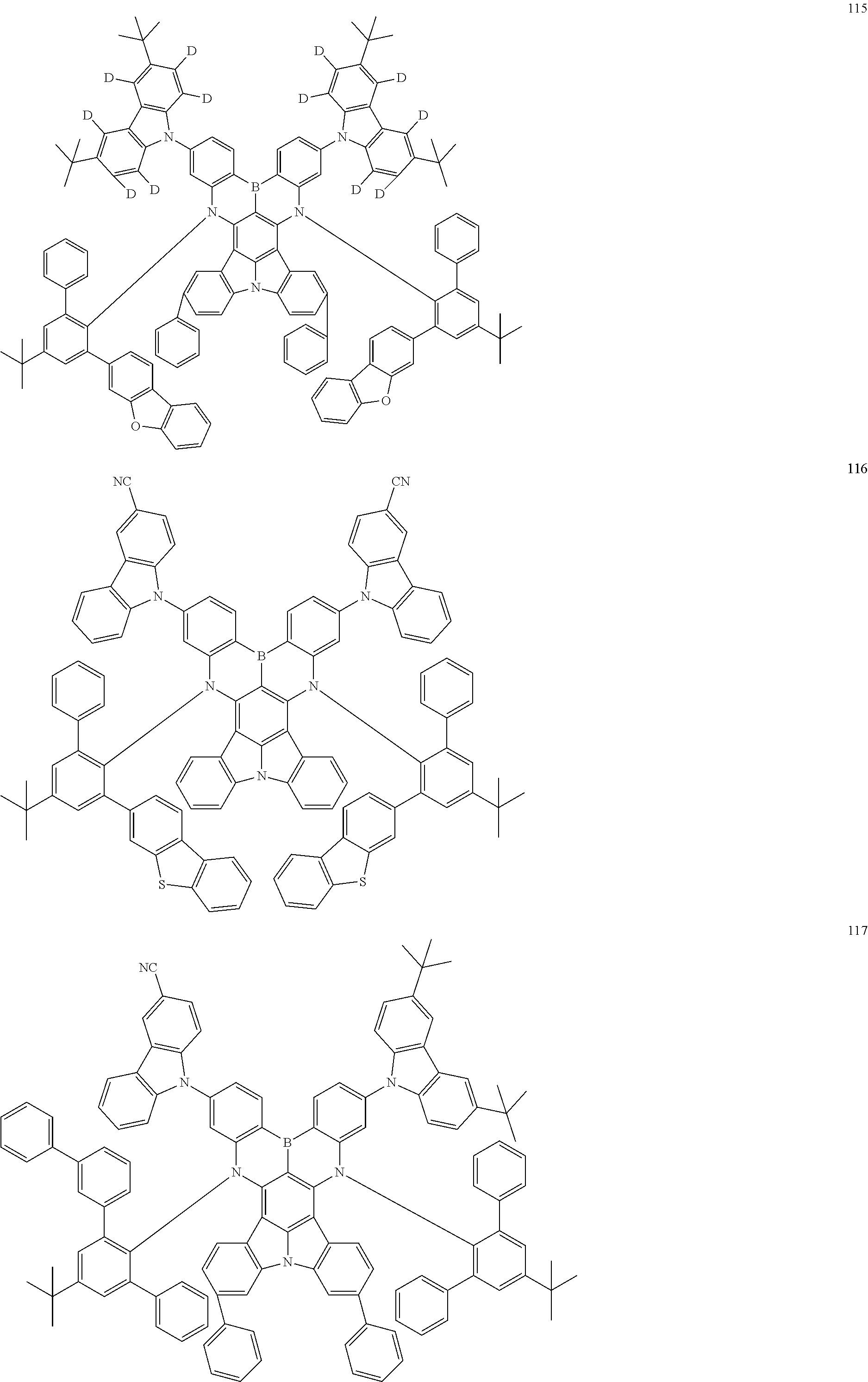

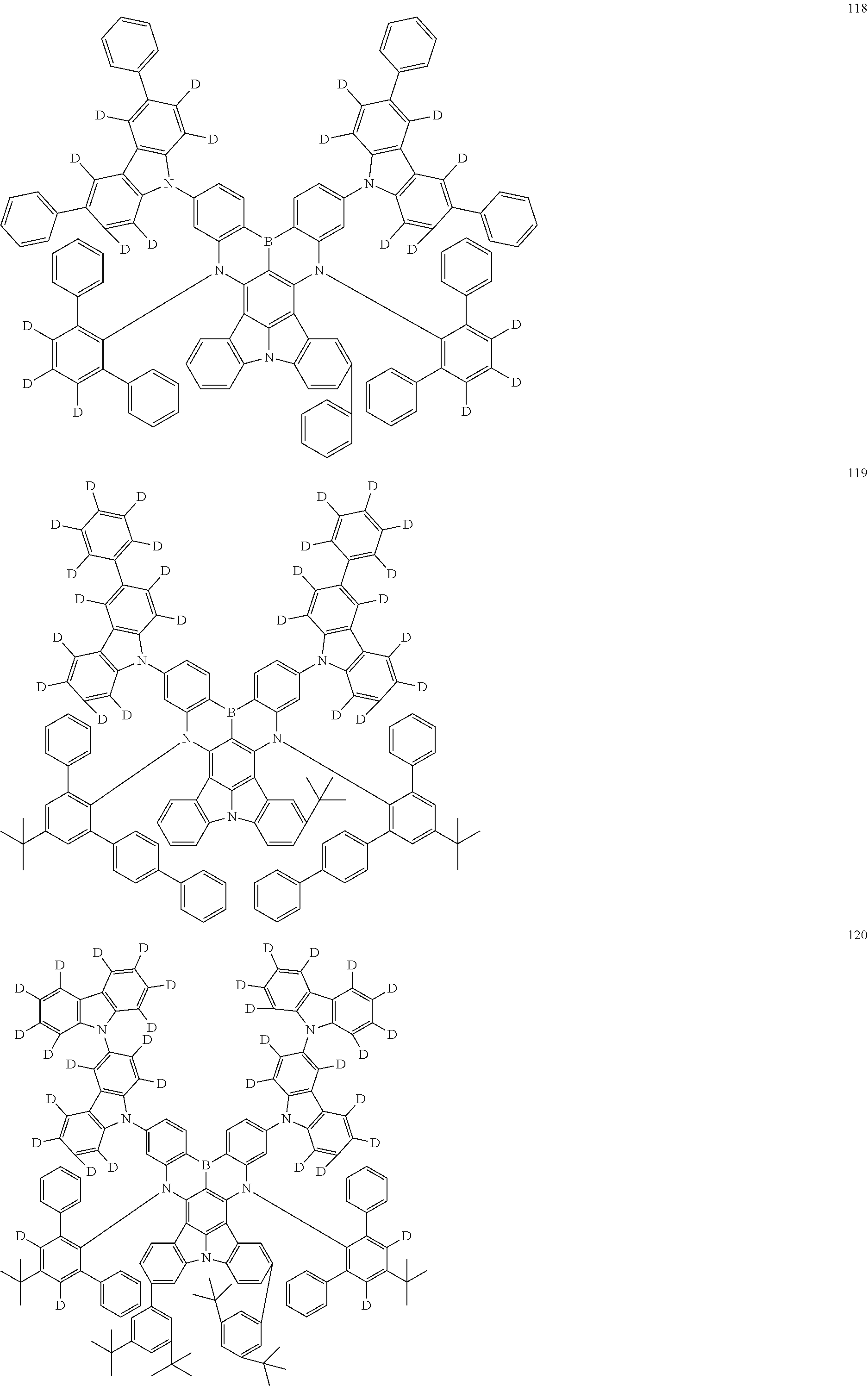

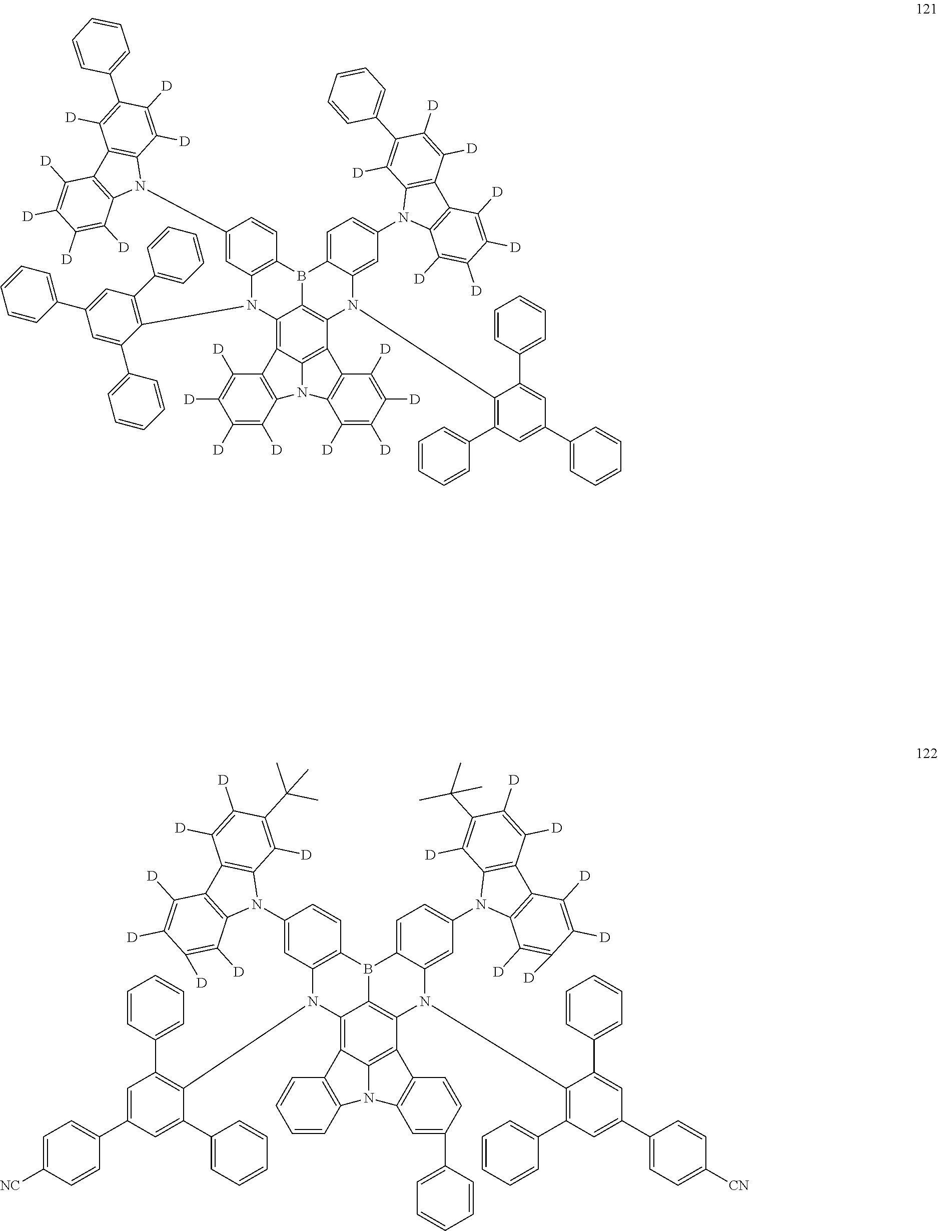

The emission layer EML may include the fused polycyclic compound of an embodiment as a dopant. The fused polycyclic compound of an embodiment may be a thermally activated delayed fluorescence (TADF) material. The fused polycyclic compound of an embodiment may be a thermally activated delayed fluorescence material of a multiple resonance (MR) type or kind. The fused polycyclic compound of an embodiment may be configured to emit light through the transformation of triplet excitons into singlet excitons by a reverse inter system crossing (RISC) mechanism.

The fused polycyclic compound of an embodiment may include a fused ring of nine rings, including three nitrogen atoms and one boron atom as ring-forming atoms, as a central structure. The fused polycyclic compound of an embodiment may include the fused ring of nine rings represented by Formula Z1 as a central structure. The fused ring of nine rings may have a fused structure of an indolocarbazole moiety with a fused ring of five rings represented by Formula Z2.

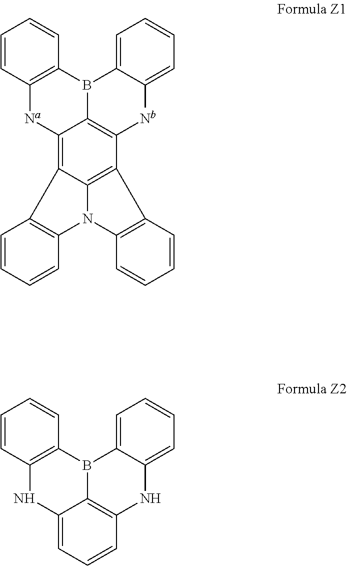

In Formula Z1, N^{a} and N^{b} are nitrogen atoms and are designated together with alphabets (a, b) for the convenience of explanation. In Formula Z1, N^{a} and N^{b} are in para relations with the boron atom and may be nitrogen atoms constituting the fused ring of two rings in the fused ring of nine rings. N^{a} and N^{b} may each independently be combined with a substituted or unsubstituted ortho terphenyl group. The ortho terphenyl group may correspond to the ortho terphenyl group in which Rₐ₁ to Rₐ₆ are combined in Formula 1.

The fused ring of five rings, represented by Formula Z2 may show multiple resonance properties. The fused polycyclic compound of an embodiment, including the fused ring of nine rings (i.e., represented by Formula Z1), in which the indolocarbazole moiety is fused with the fused ring of five rings may have reinforced rigidity and multiple resonance to have small ΔE_{ST}, and may have increased spin-orbit coupling (SOC) constant to have accelerated RISC. The fused polycyclic compound of an embodiment includes a fused indolocarbazole moiety and may have even more reinforced rigidity and multiple resonance. When the multiple resonance is reinforced, the separation degree of the highest occupied molecular orbital (HOMO) and the lowest unoccupied molecular orbital (LUMO) among atoms may increase, ΔE_{ST} may decrease, and RISC may be accelerated. ΔE_{ST} is an absolute value of an energy level difference between a singlet (S1) state and a triplet (T1) state. In some embodiments, the fused polycyclic compound of an embodiment includes an ortho terphenyl group which sterically protects the fused ring of nine rings, and may show excellent or suitable material stability. The ortho terphenyl group corresponds to a bulky substituent and may protect the vacant p orbital of a boron atom. The boron atom may be a ring-forming atom in the fused ring of nine rings. Accordingly, the trigonal bonding structure of the boron atom in the fused ring of nine rings may be effectively maintained.

The ortho terphenyl group may be directly bonded to the nitrogen atom in the fused ring of nine rings to increase intermolecular distance and prevent or reduce intermolecular interaction. Accordingly, in the fused polycyclic compound of an embodiment, dexter energy transfer according to the intermolecular interaction may be suppressed or reduced. The dexter energy transfer is produced in triplet excitons, and when the dexter energy transfer is suppressed or reduced, the increase of the concentration of the triplet excitons in a compound may be prevented or reduced. Because triplet excitons having a high concentration remain in an excited state for a long time, the decomposition of the compound may be induced, hot excitons may be produced through triplet triplet annihilation (TTA) to decay around (e.g., surrounding) compounds, thereby deteriorating the lifetime of a light emitting device.

Intermolecular interaction includes intermolecular aggregation, intermolecular excimer formation, intermolecular exciplex, and/or the like, and these lead to the deterioration of the emission efficiency and lifetime of the light emitting device. When the intermolecular aggregation of the fused polycyclic compound of an embodiment is prevented or reduced, the purification of a compound during synthesizing the fused polycyclic compound may be easy, excellent or suitable stability may be shown in relation to the thermal decomposition in a sublimation purification step during the synthesis. In some embodiments, the fused polycyclic compound of an embodiment may be configured to emit light having high color purity.

The fused polycyclic compound of an embodiment includes a fused ring of nine rings, including three nitrogen atoms and one boron atom as ring-forming atoms, as a central structure, and ortho terphenyl groups may be combined with the two nitrogen atoms in the central structure. Accordingly, the fused polycyclic compound of an embodiment may show excellent or suitable material stability and accelerated RISC. The light emitting device including the fused polycyclic compound of an embodiment may show a low driving voltage, high efficiency and long-life characteristics.

The fused polycyclic compound of an embodiment may be configured to emit blue light and may have a light emitting central wavelength in a wavelength region of about 430 nm to about 490 nm. The light emitting device ED including the fused polycyclic compound of an embodiment may be configured to emit light having a light emitting central wavelength in a wavelength region of about 430 nm to about 490 nm. The light emitting device ED including the fused polycyclic compound of an embodiment may be configured to emit blue light. For example, a third light emitting device ED-3 (FIG. 2) emitting blue light may include the fused polycyclic compound of an embodiment.

In an embodiment, the emission layer EML may include the fused polycyclic compound of an embodiment and may further include at least one selected from among second to fourth compounds. In an embodiment, the emission layer EML may include a second compound represented by Formula HT-1. For example, the second compound may be utilized as the hole transport host material of the emission layer EML.

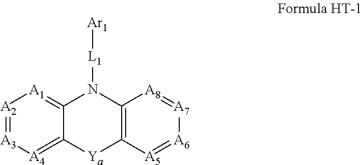

In Formula HT-1, A₁ to A₈ may each independently be N or CR₅₁. For example, all of A₁ to A₈ may be CR₅₁. In some embodiments, any one selected from among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but the embodiment of the present disclosure is not limited thereto.

In Formula HT-1, Yₐ may be a direct linkage, CR₅₂R₅₃, or SiR₅₄R₅₅. For example, it may refer to the two benzene rings being linked to the nitrogen atom in Formula HT-1 are linked via a direct linkage,

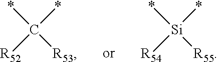

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but the embodiment of the present disclosure is not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₅ may be bonded to an adjacent group to form a ring. For example, R₅₁ to R₅₅ may each independently be a hydrogen atom or a deuterium atom. R₅₁ to R₅₅ may each independently be an unsubstituted methyl group or an unsubstituted phenyl group.

In an embodiment, the second compound represented by Formula HT-1 may be represented by any one selected from among the compounds represented by Compound Group 2. The emission layer EML may include at least one selected from among the compounds represented by Compound Group 2 as a hole transporting host material.

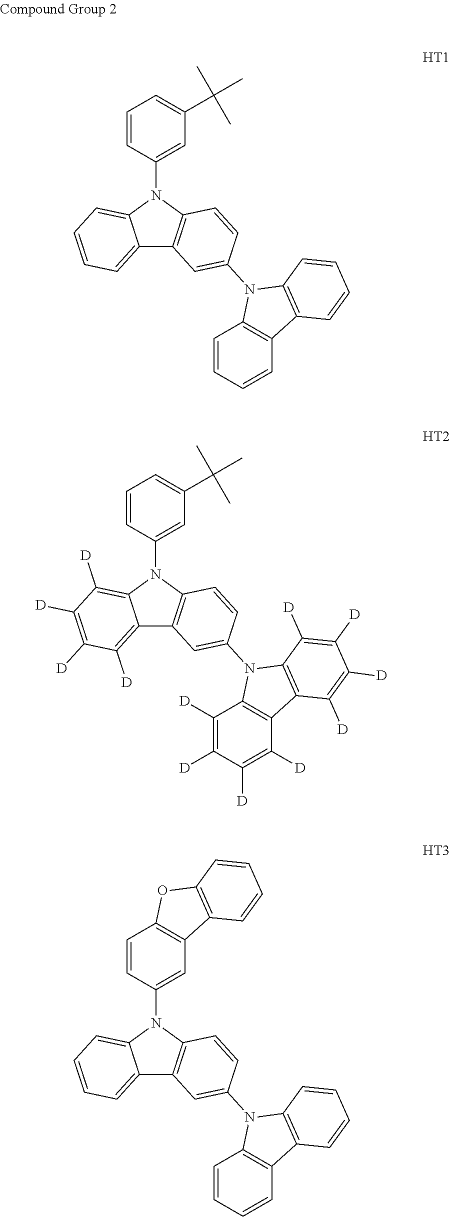 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

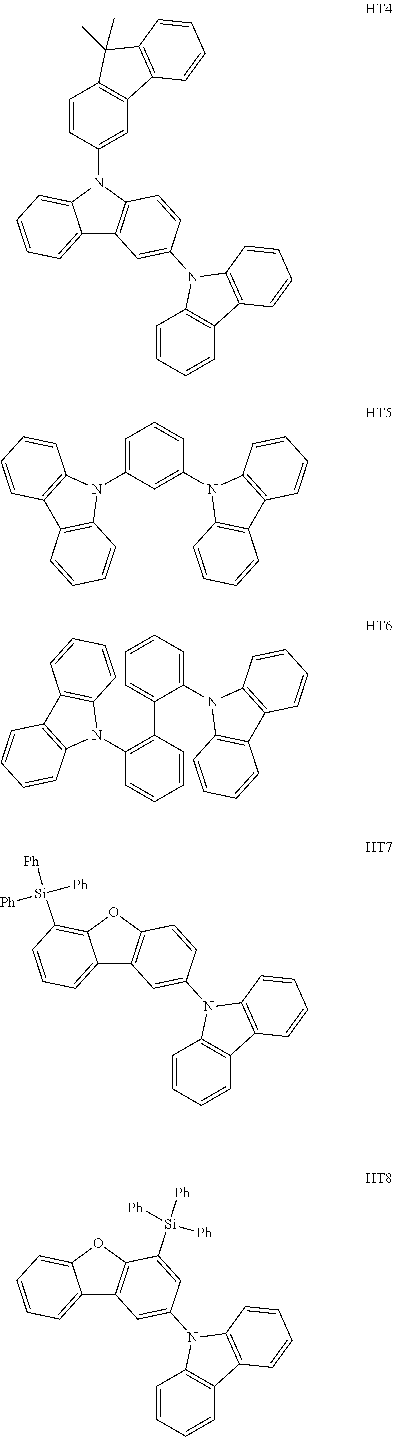 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

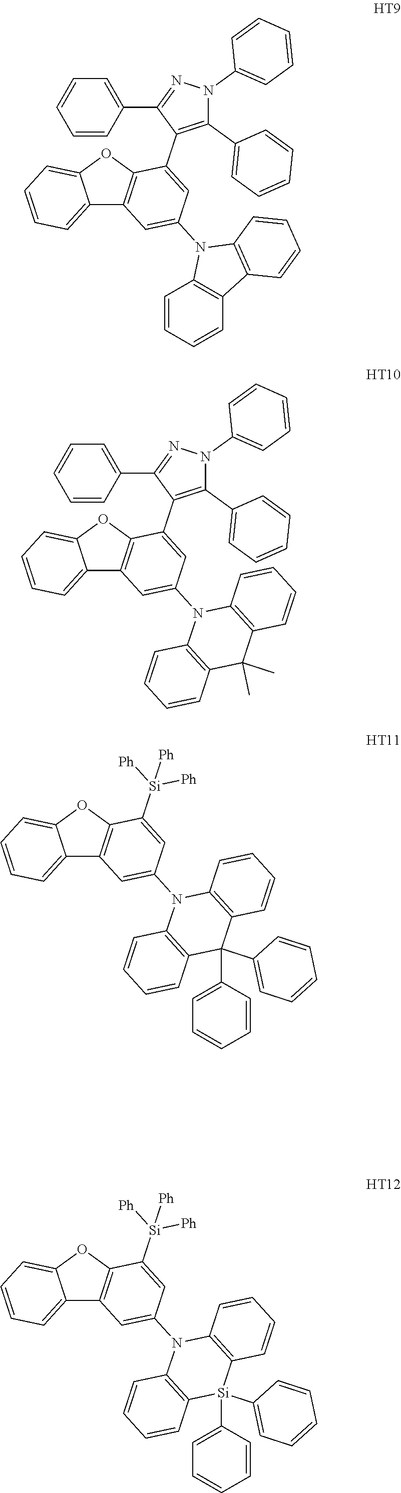

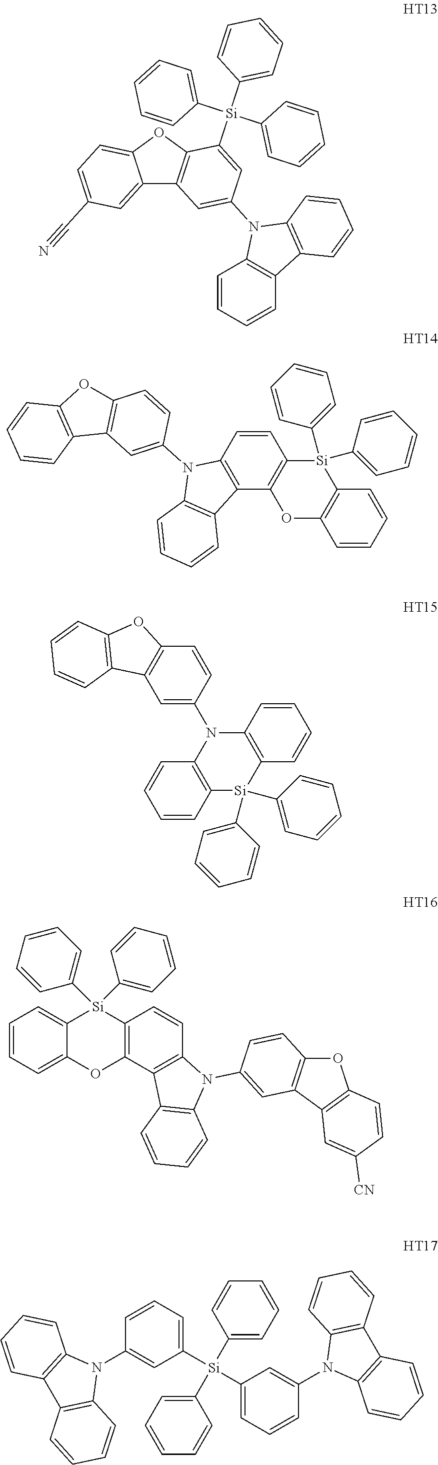 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1 ; c1ccc([Si](c2ccccc2)(c2cccc(-n3c4ccccc4c4ccccc43)c2)c2cccc(-n3c4ccccc4c4ccccc43)c2)cc1]

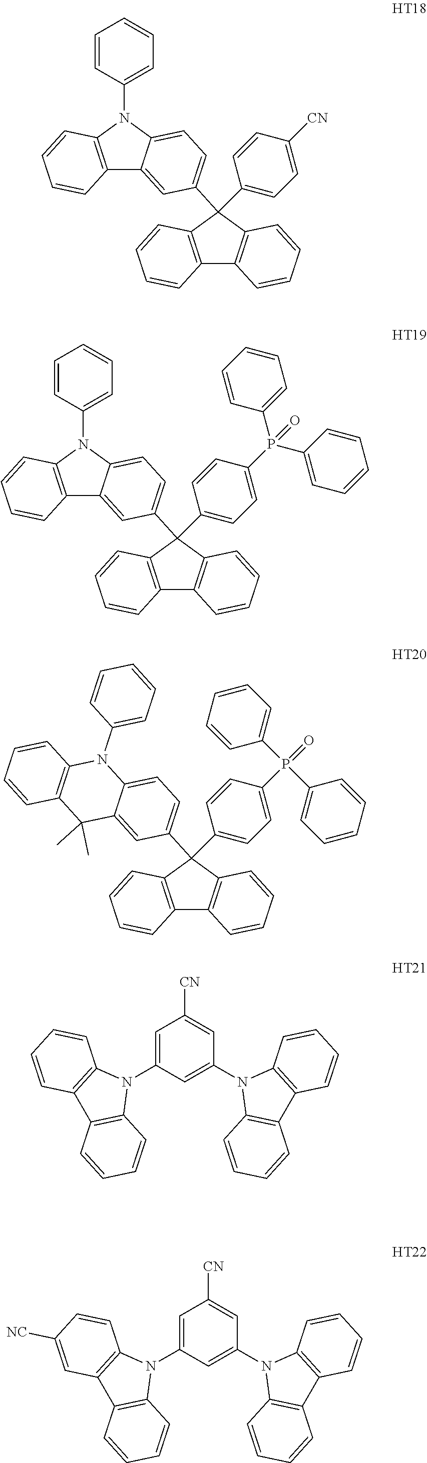 [SMILES: N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1]

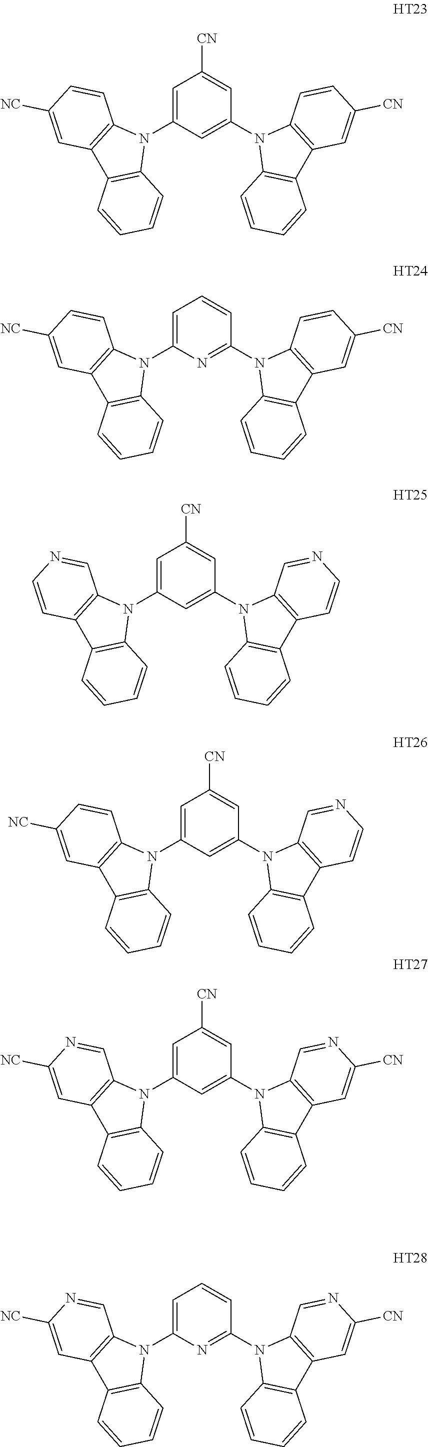 [SMILES: N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

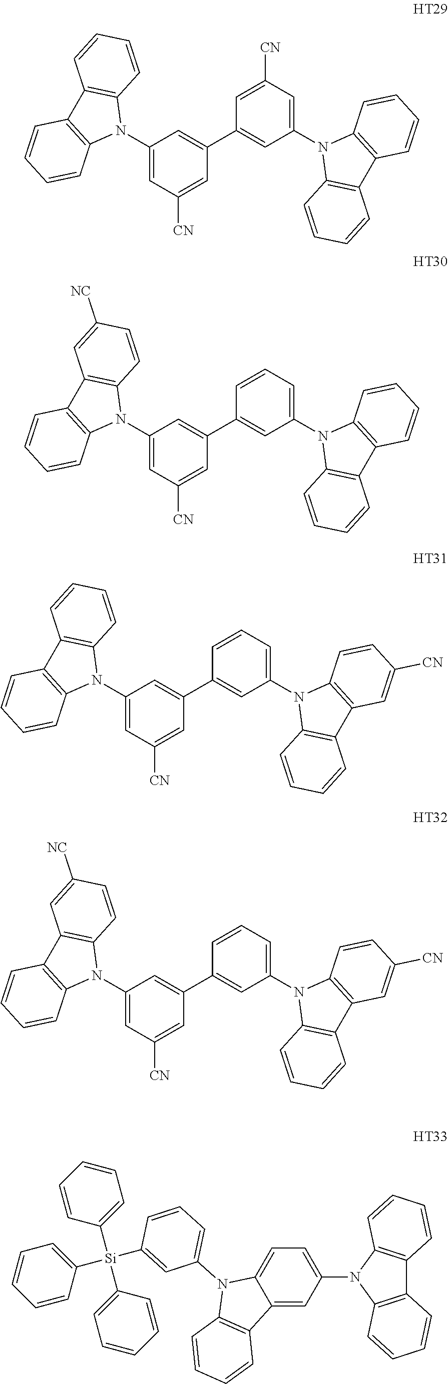 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1]

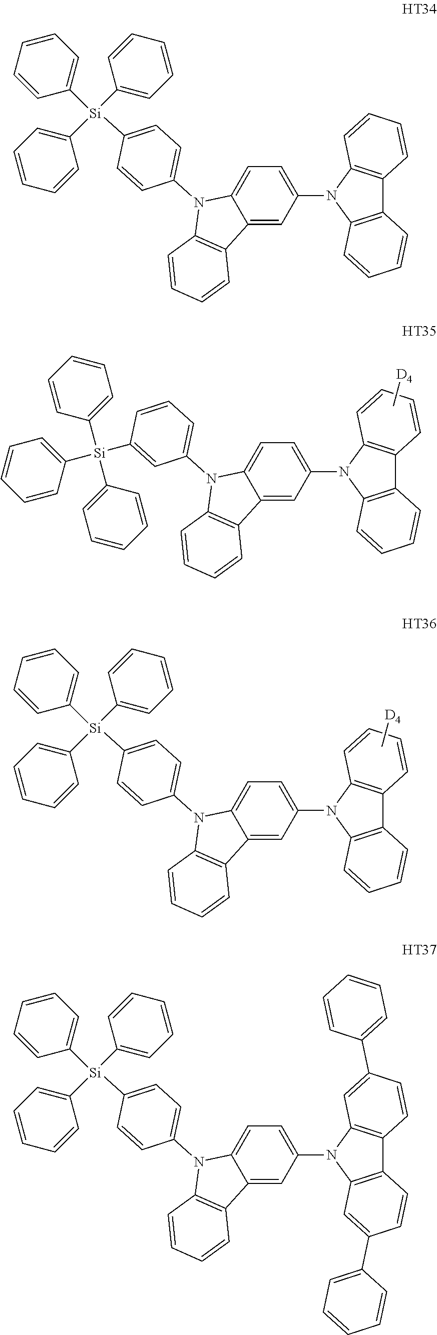

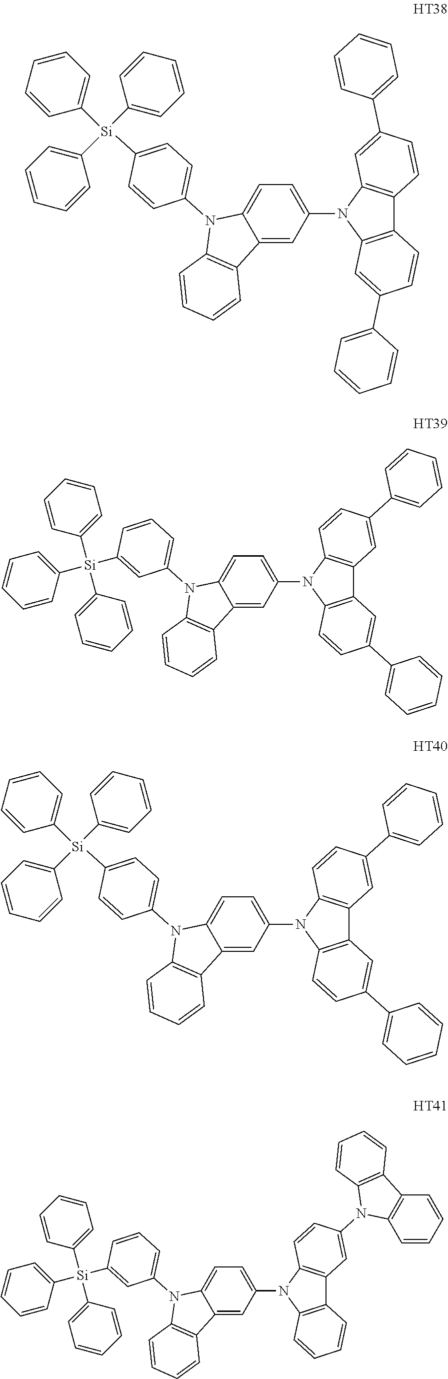 [SMILES: c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1]

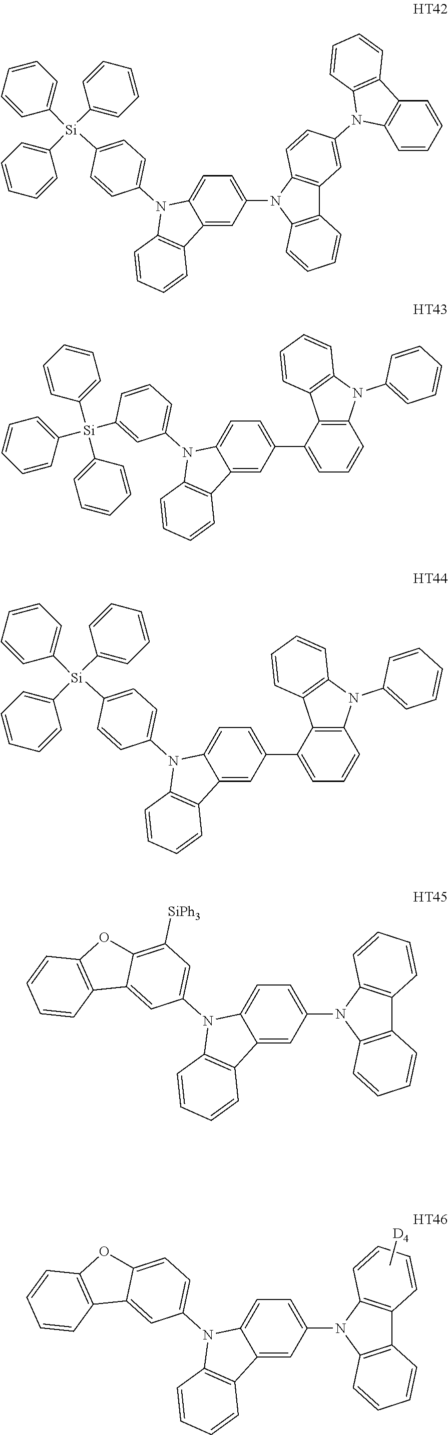

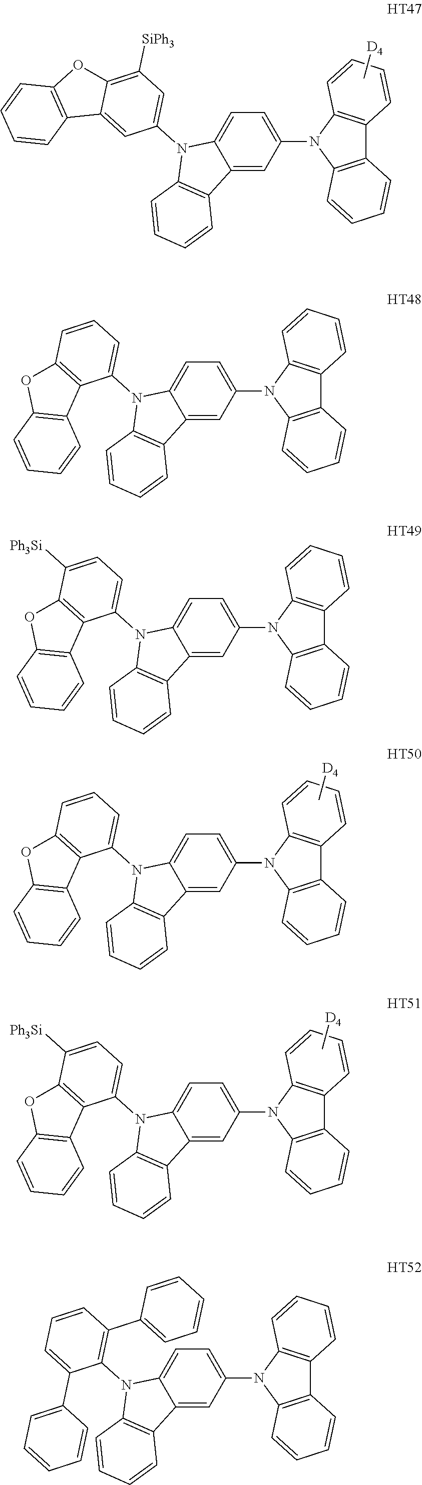

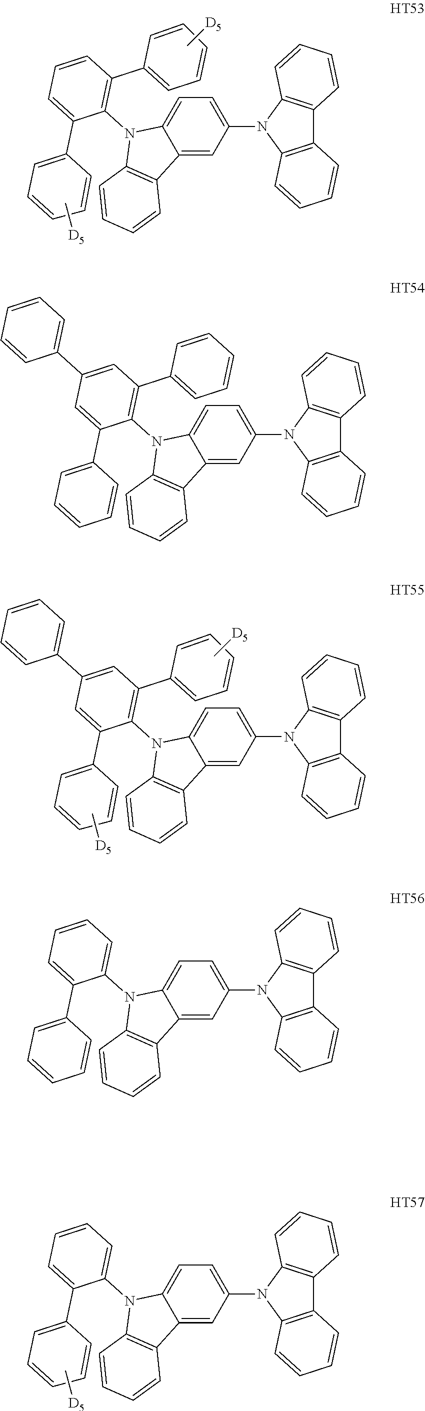

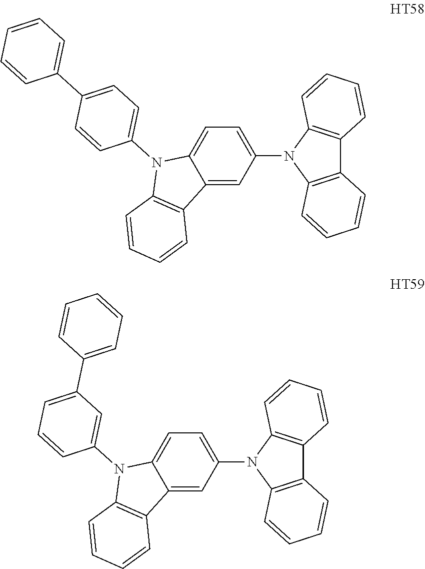 [SMILES: c1ccc(-c2ccc(-n3c4ccccc4c4cc(-n5c6ccccc6c6ccccc65)ccc43)cc2)cc1 ; c1ccc(-c2cccc(-n3c4ccccc4c4cc(-n5c6ccccc6c6ccccc65)ccc43)c2)cc1]

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In an embodiment, the emission layer EML may include the third compound represented by Formula ET-1. For example, the third compound may be utilized as an electron transport host material for the emission layer EML.

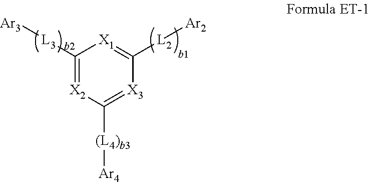

In Formula ET-1, at least one selected from among X₁ to X₃ is N, and the rest are CR₅₆. For example, any one selected from among X₁ to X₃ may be N, and the rest may each independently be CR₅₆. In this case, the third compound represented by Formula ET-1 may include a pyridine moiety. In some embodiments, two among X₁ to X₃ may be N, and the rest may be CR₅₆. In this case, the third compound represented by Formula ET-1 may include a pyrimidine moiety. In some embodiments, X₁ to X₃ may all be N. In this case, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group, or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when b1 to b3 are integers of 2 or greater, L₂ to L₄ may each independently be a substituted or unsubstituted arylene group having 6 to 30 ring-forming carbon atoms, or a substituted or unsubstituted heteroarylene group having 2 to 30 ring-forming carbon atoms.

In an embodiment, the third compound may be represented by any one selected from among compounds in Compound Group 3. The light emitting device ED of an embodiment may include any one selected from among the compounds in Compound Group 3.

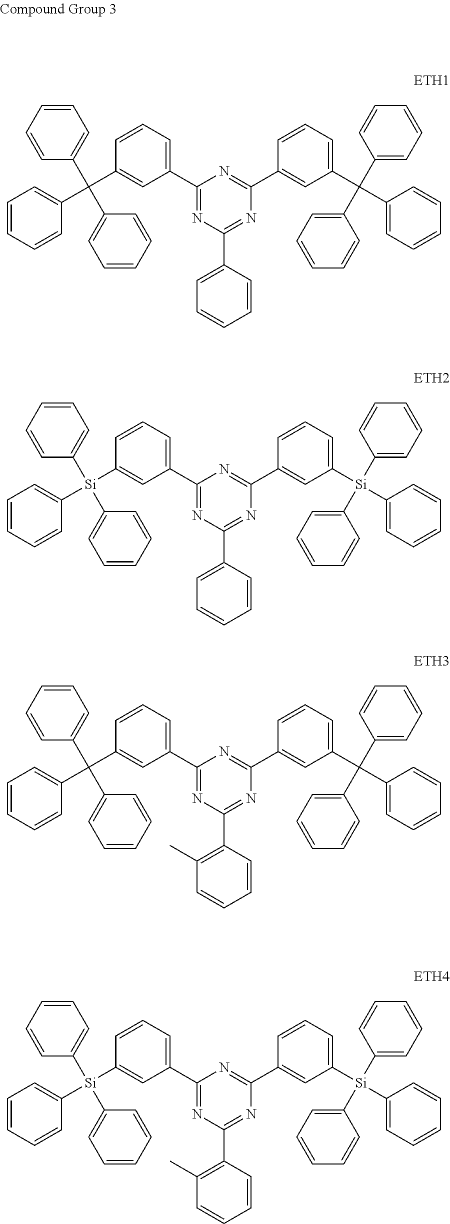 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

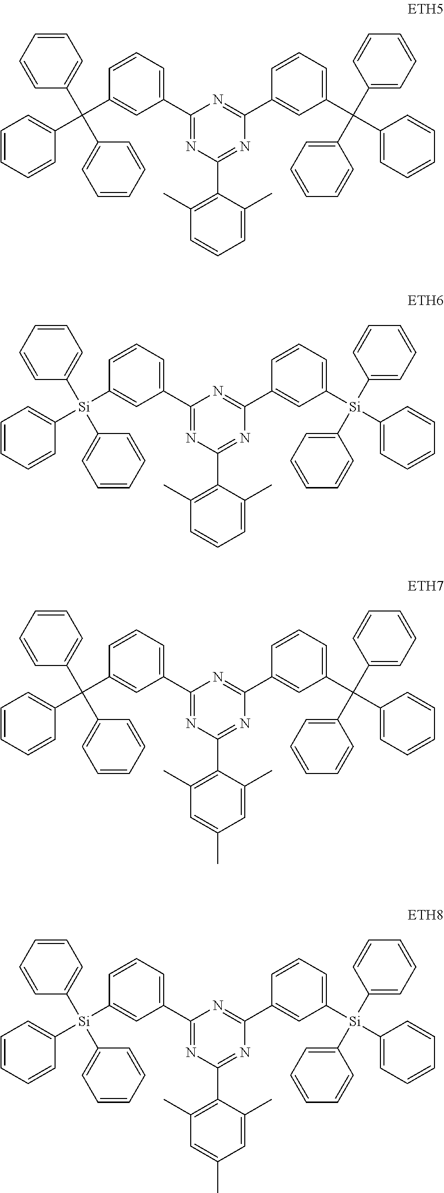 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

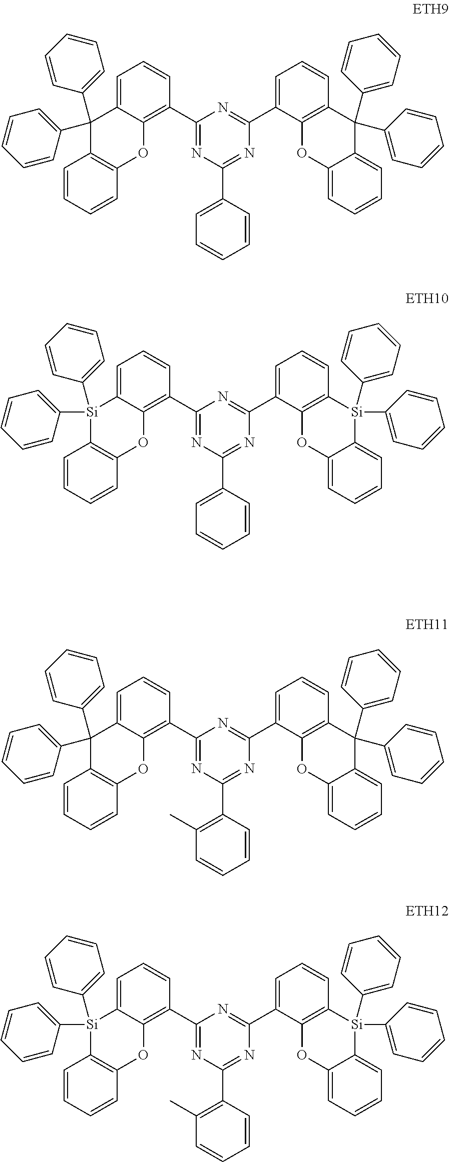 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

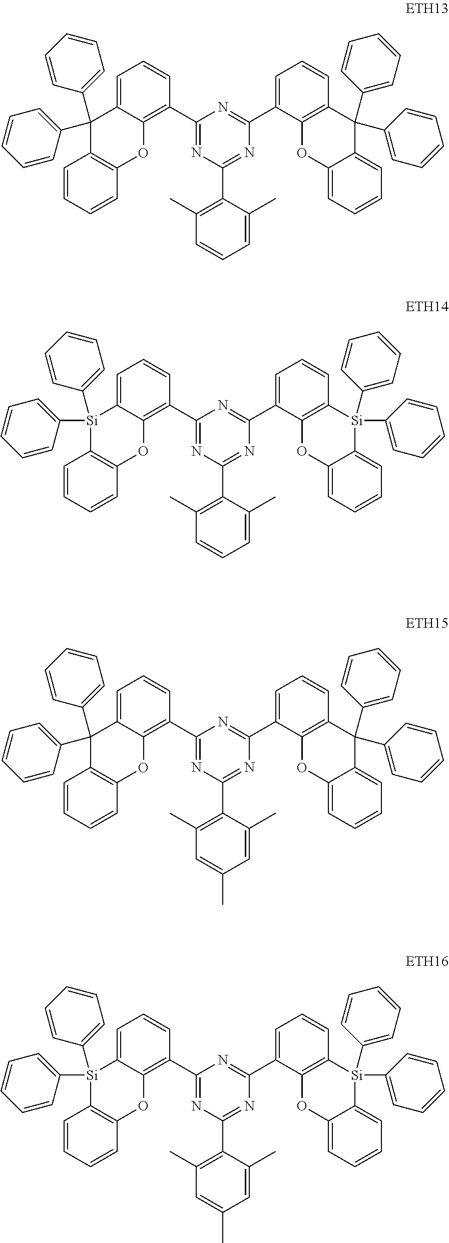 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

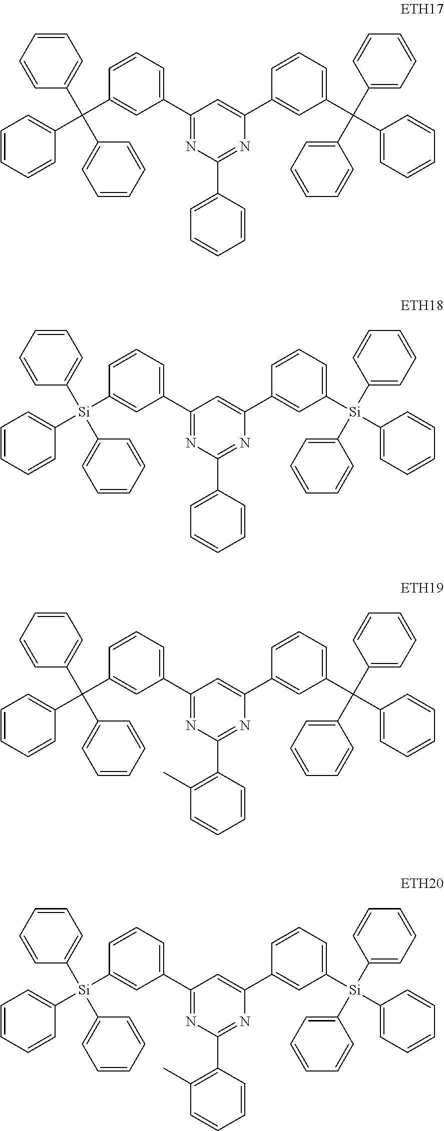 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

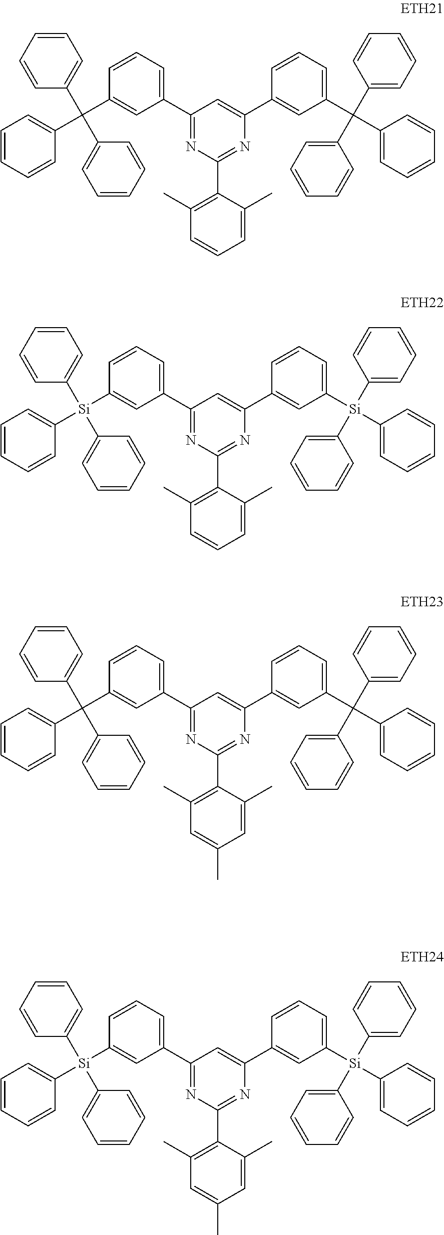 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

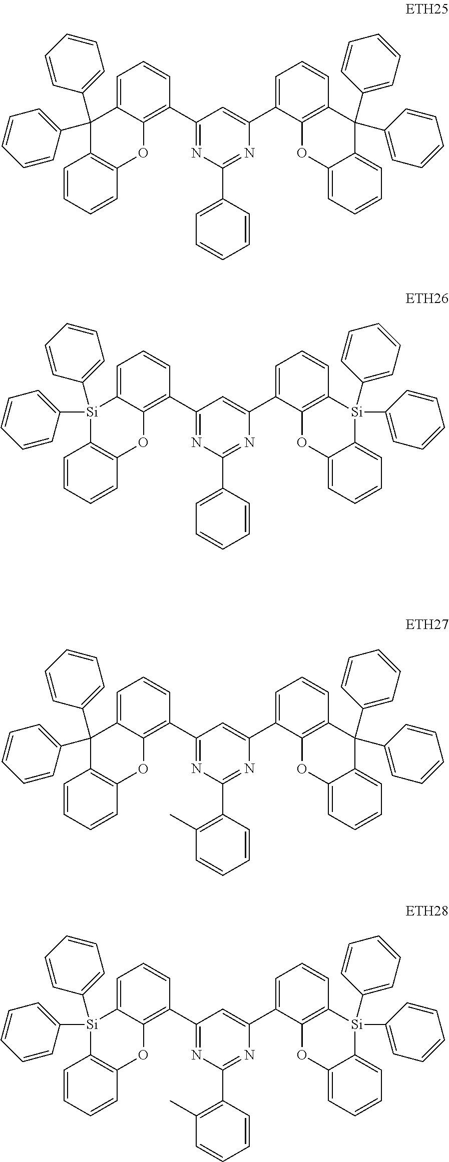 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

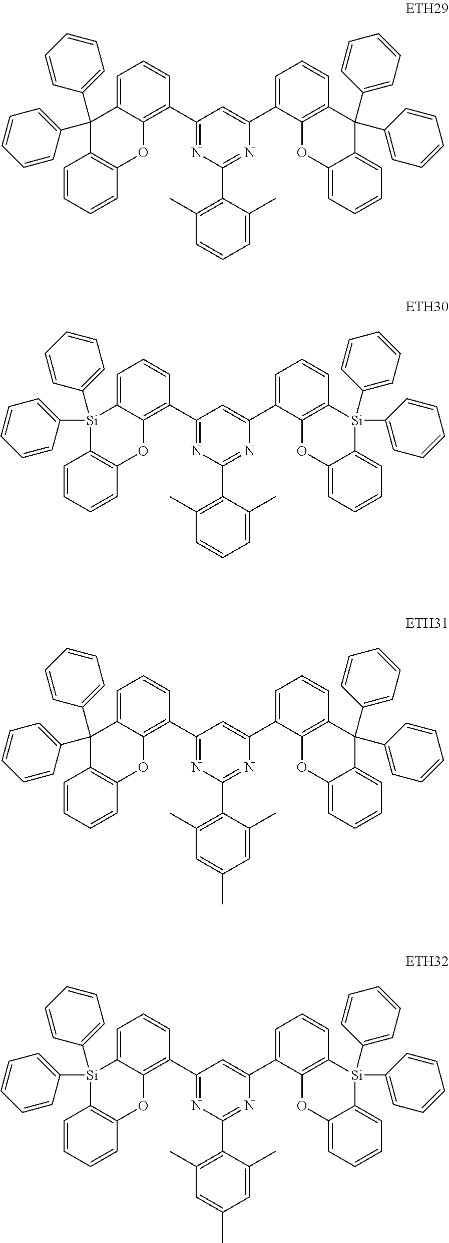 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

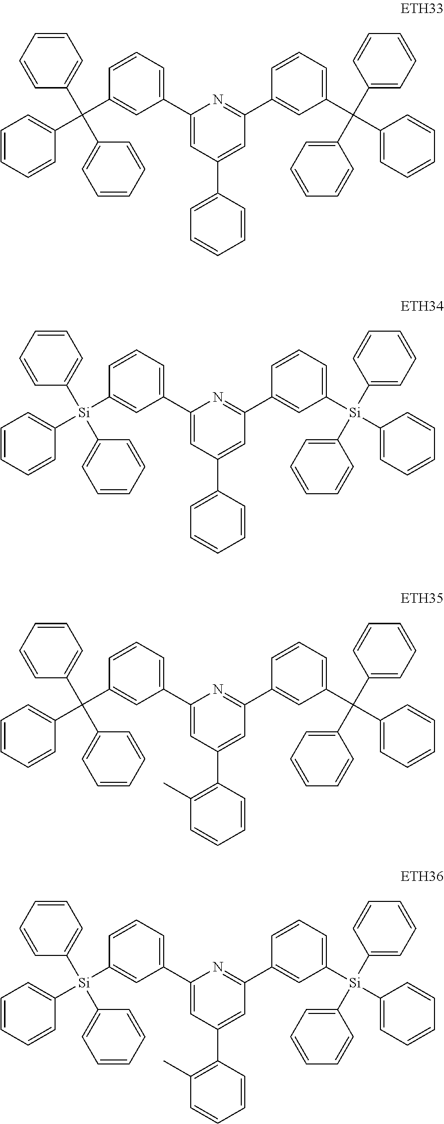 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

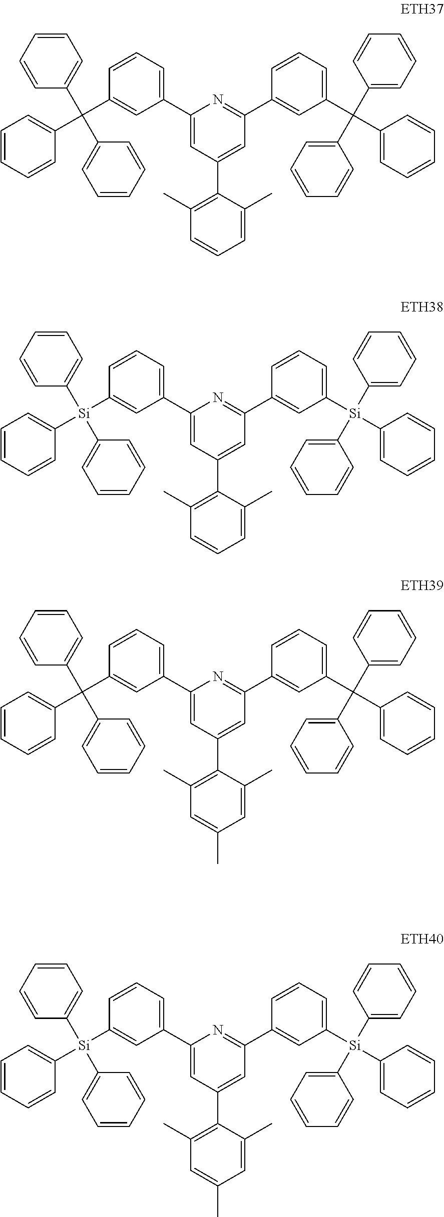 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

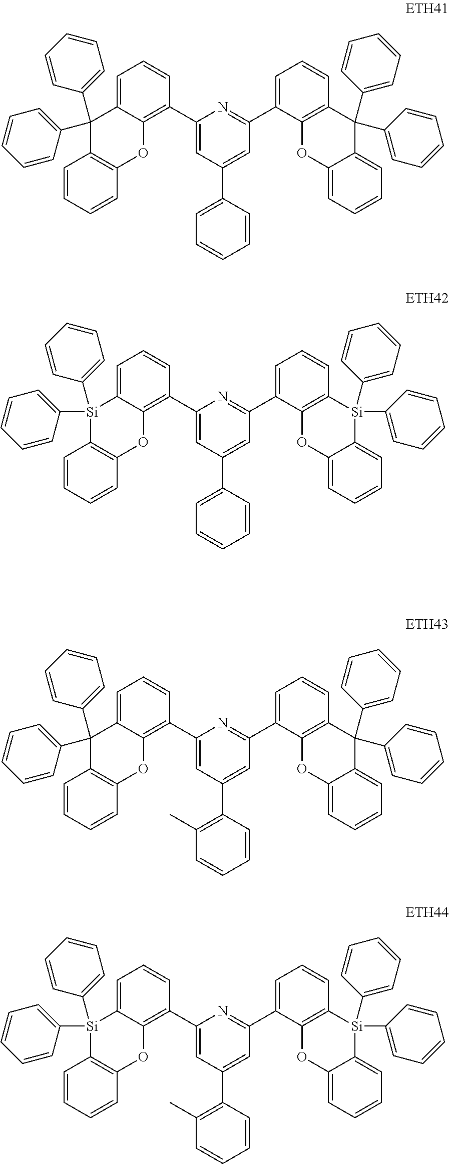 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

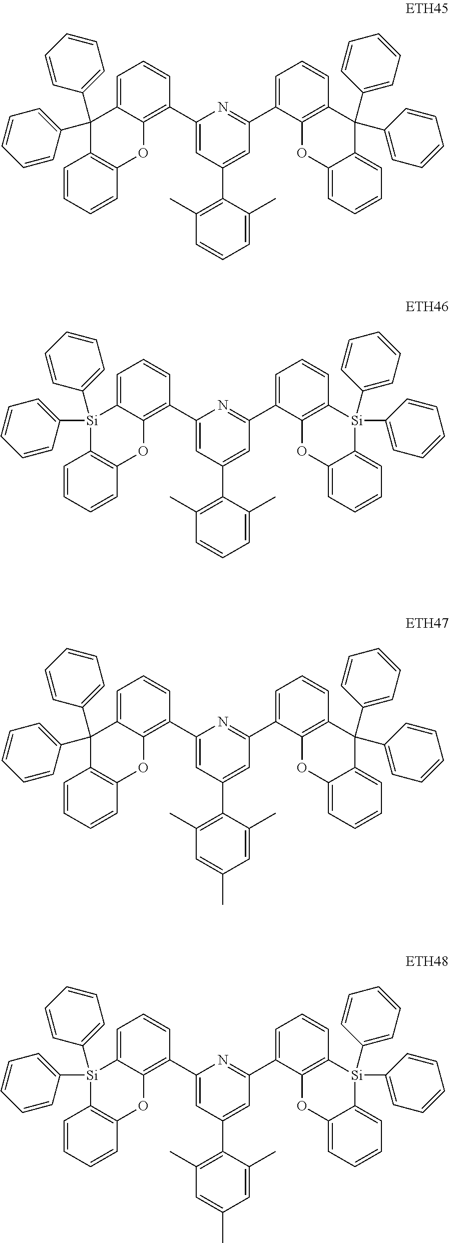 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

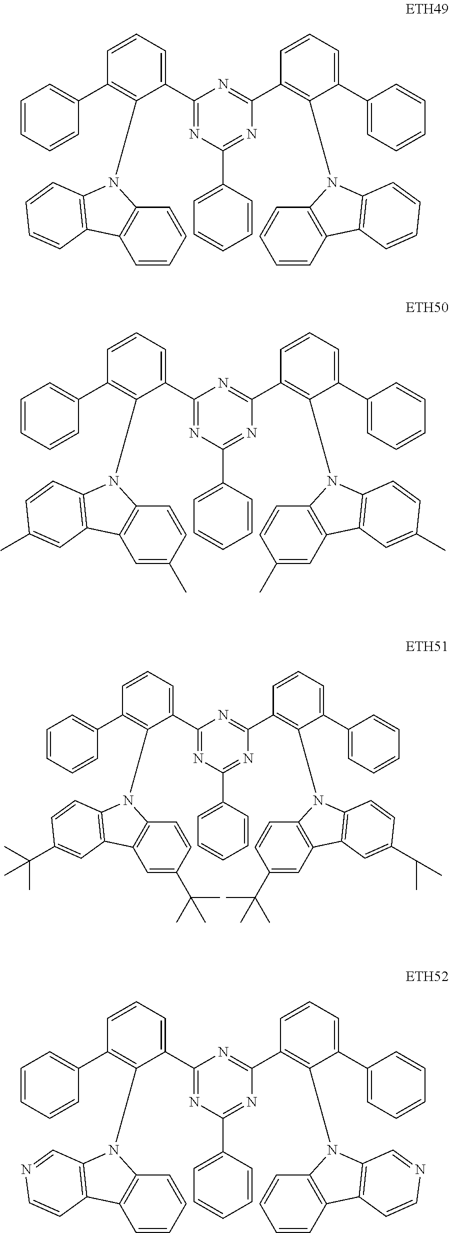

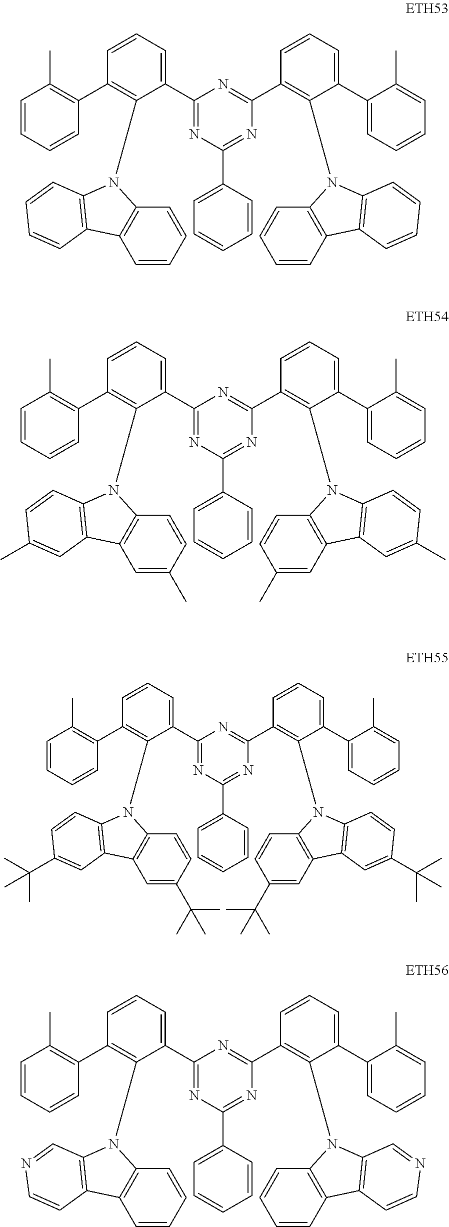

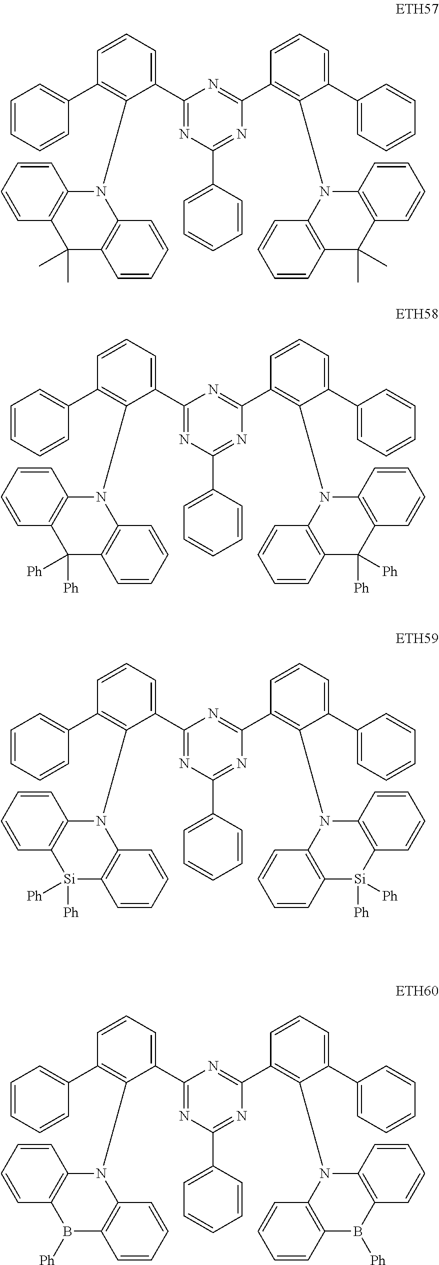

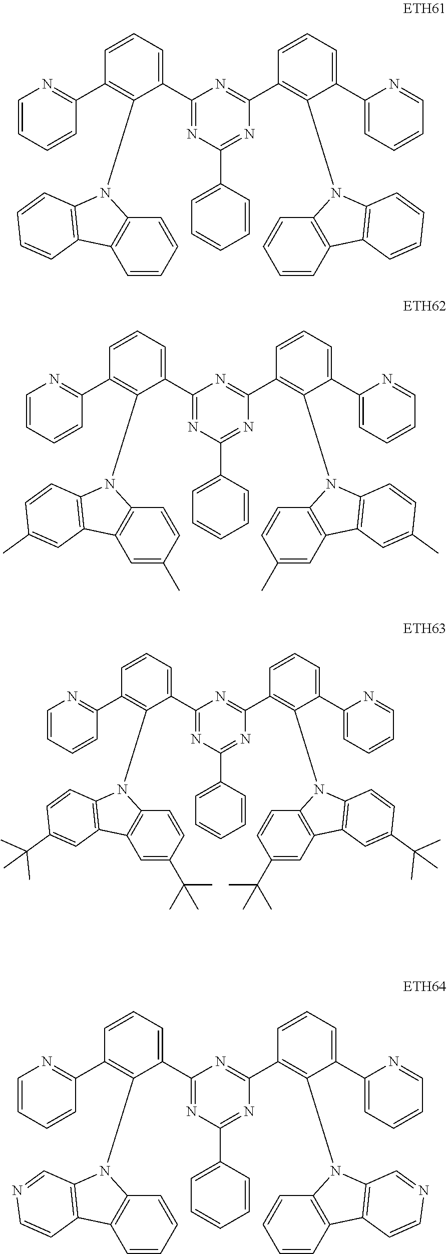

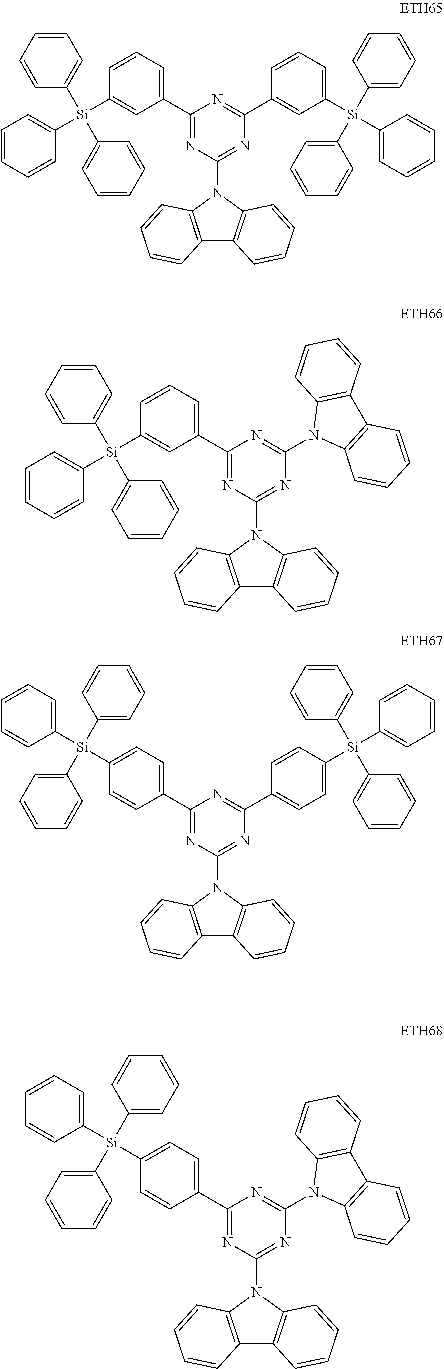 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

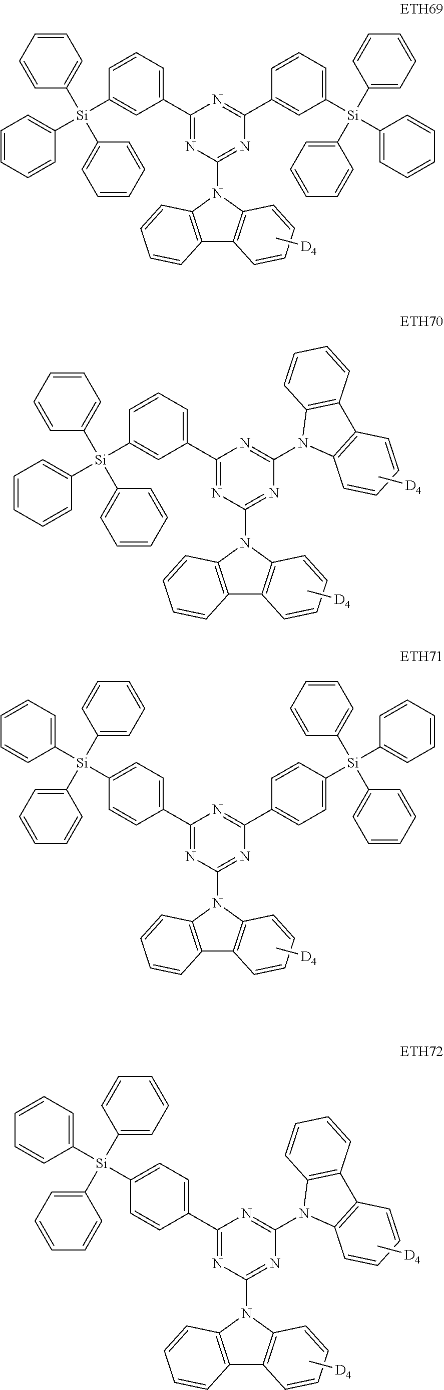

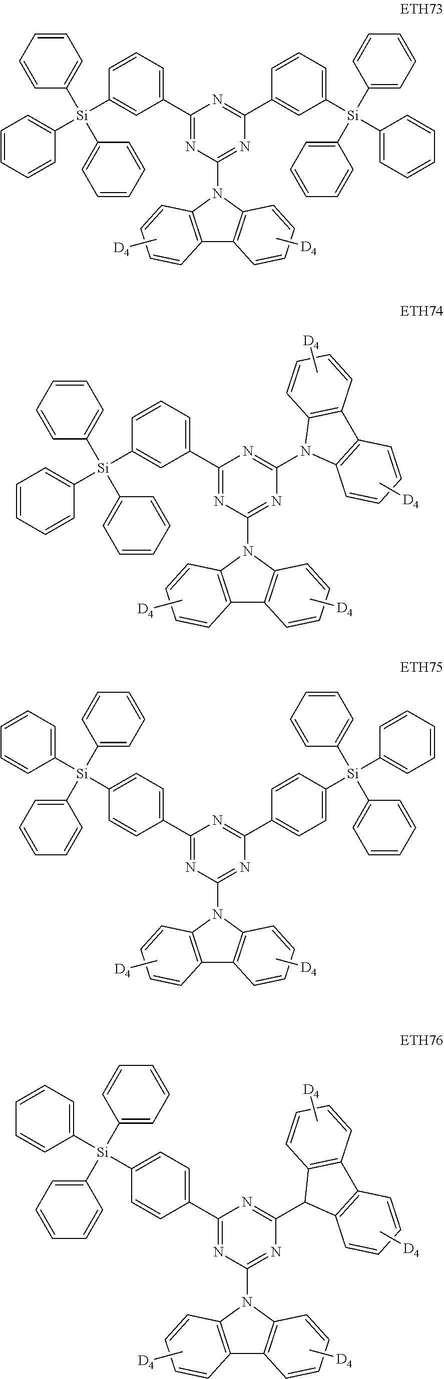

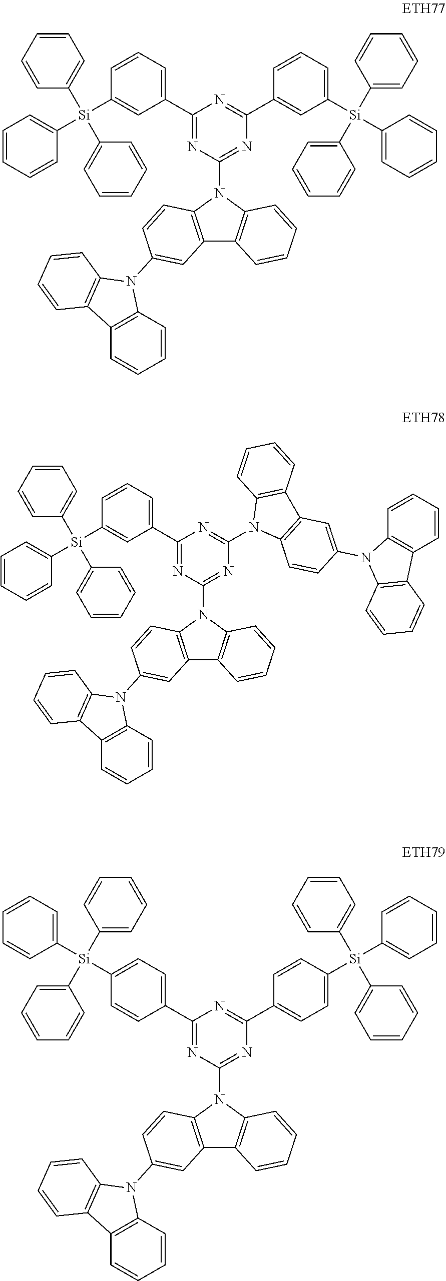

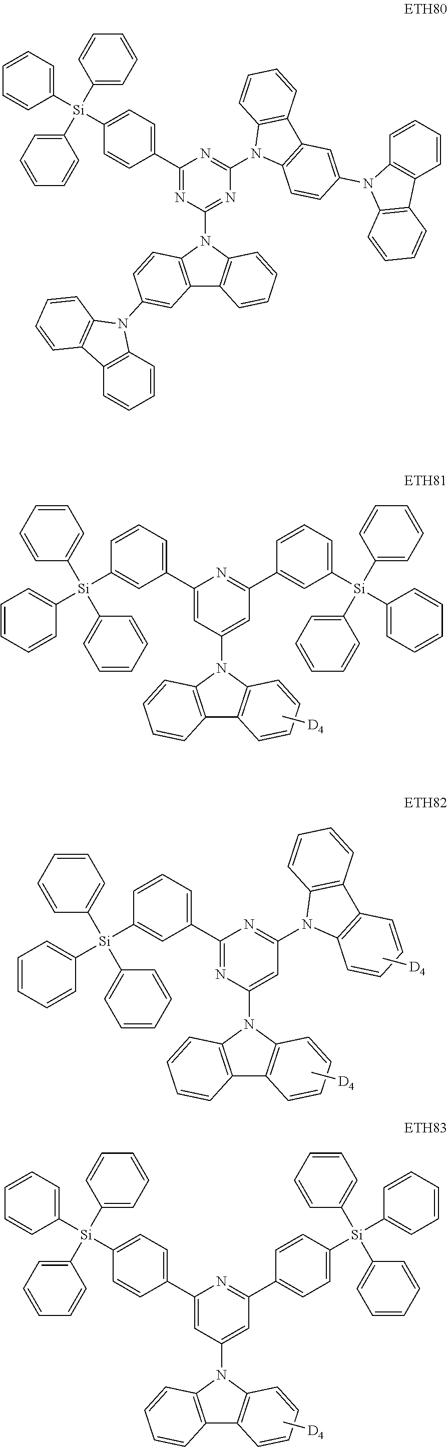

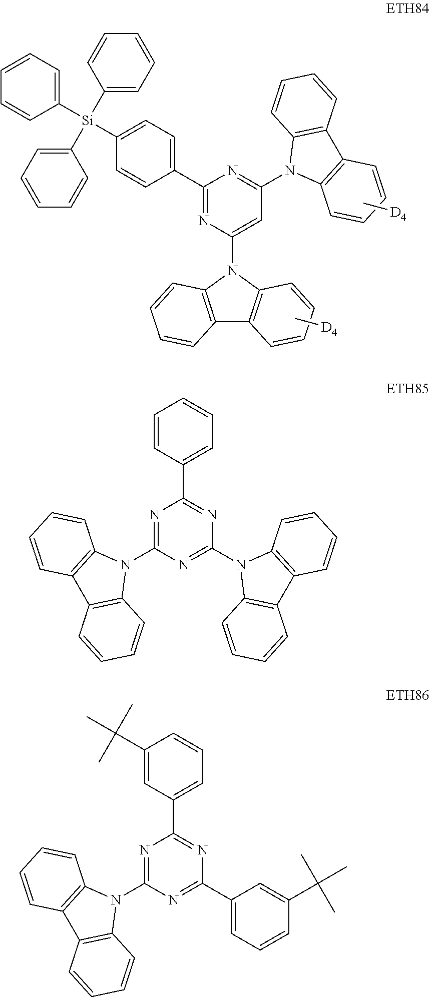

In the embodiment compounds presented in Compound Group 3, “D” refers to a deuterium atom and “Ph” refers to an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In an embodiment, the emission layer EML may include a fourth compound in addition to the first compound to the third compound as described previously. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED of an embodiment may include, as the fourth compound, a compound represented by Formula D-1:

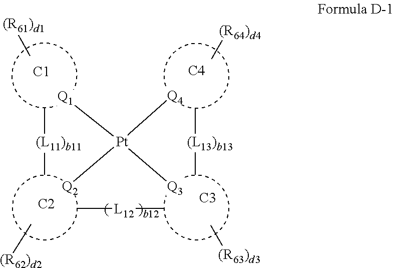

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms.

In Formula D-1, L₁₁ to L₁₃ may each independently be a direct linkage,

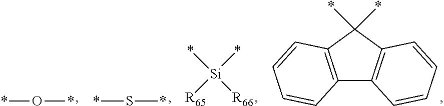

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” refers to a part linked to C1 to C4.

In Formula D-1, b11 to b13 may each independently be 0 or 1. When b11 is 0, C1 and C2 may not be linked to each other. When b12 is 0, C2 and C3 may not be linked to each other. When b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₆₁ to R₆₆ may be bonded to an adjacent group to form a ring. R₆₁ to R₆₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₆₁ to R₆₄. The case where each of d1 to d4 is 4 and R₆₁'s to R₆₄' are each hydrogen atoms may be the same as the case where each of d1 to d4 is 0. When each of d1 to d4 is an integer of 2 or more, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring or a substituted or unsubstituted heterocycle represented by any one selected from among C-1 to C-4:

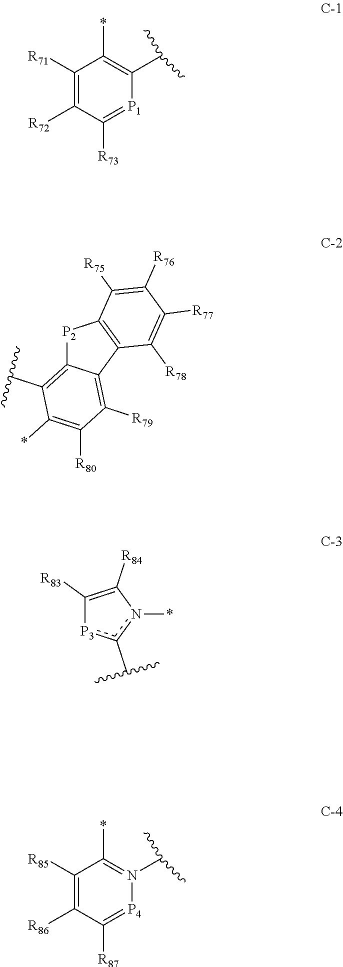

In C-1 to C-4, P₁ may be [symbol] or CR₇₄, P₂ may be [symbol] or NR₈₁, P₃ may be [symbol] or NR₈₂, and P₄ may be [symbol] or CR₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In some embodiments, in C-1 to C-4,“ [symbol] ” corresponds to a part linked to Pt that is a central metal atom, and “ [symbol] ” corresponds to a part linked to a neighboring cyclic group (C1 to C4) or a linker (L₁₁ to L₁₃).

The emission layer EML of an embodiment may include the first compound, which is a fused polycyclic compound, and at least one selected from among the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In an embodiment, the fourth compound may be a sensitizer. The fourth compound included in the emission layer EML in the light emitting device ED of an embodiment may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of an embodiment may improve luminous efficiency. In some embodiments, when the energy delivery to the first compound is increased, an exciton formed in the emission layer EML is not accumulated inside the emission layer EML and emits light rapidly, and thus deterioration of the device may be reduced. Therefore, the service life of the light emitting device ED of an embodiment may increase.

The light emitting device ED of an embodiment may include all of the first compound, the second compound, the third compound, and the fourth compound, and the emission layer EML may include the combination of two host materials and two dopant materials. In the light emitting device ED of an embodiment, the emission layer EML may concurrently (e.g., simultaneously) include the second compound and the third compound, which are two different hosts, the first compound that is configured to emit a delayed fluorescence, and the fourth compound including an organometallic complex, thereby exhibiting excellent or suitable luminous efficiency characteristics.

In an embodiment, the fourth compound represented by Formula D-1 may represented at least one selected from among the compounds represented by Compound Group 4. The emission layer EML may include at least one selected from among the compounds represented by Compound Group 4 as a sensitizer material.

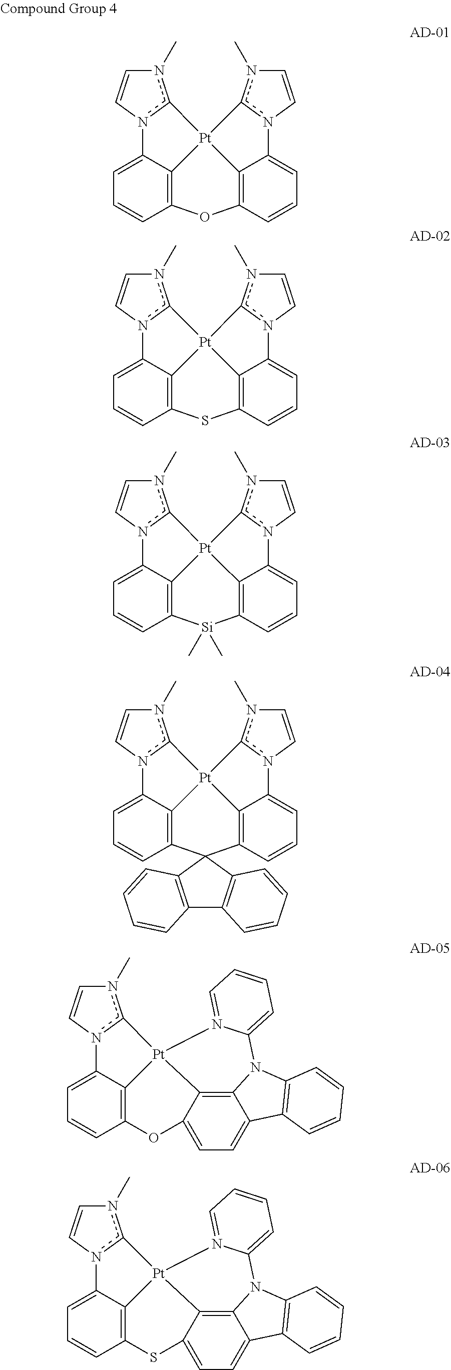

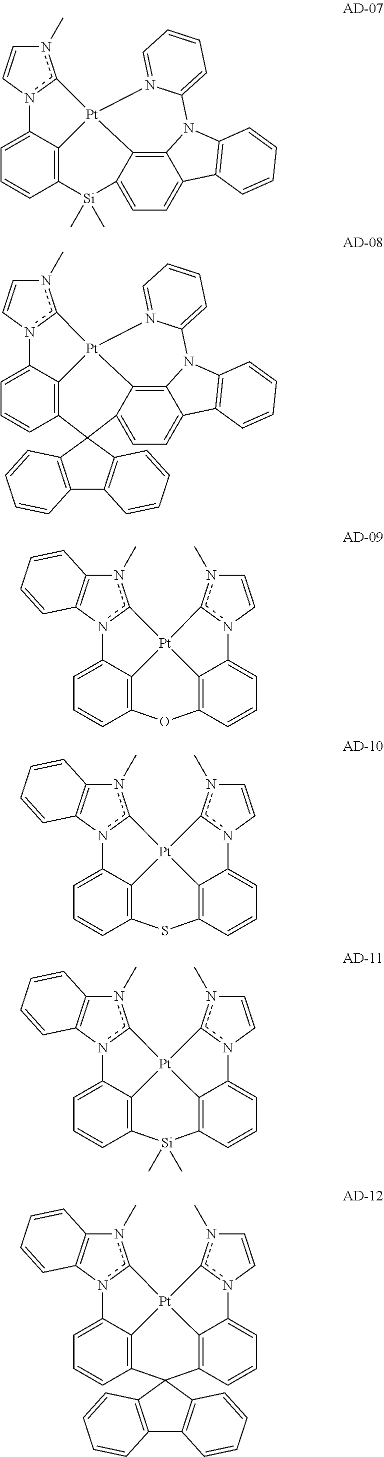

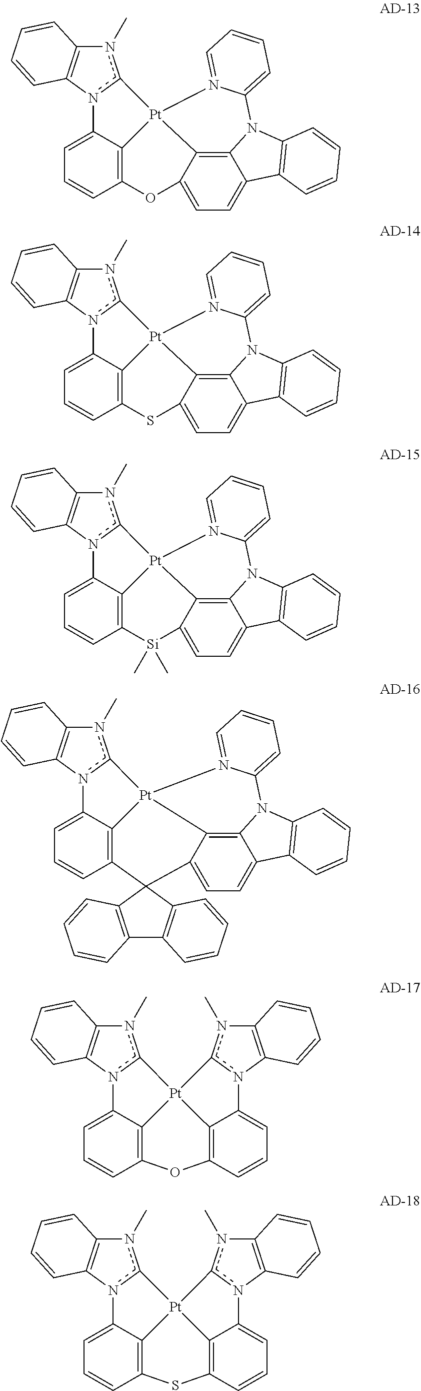

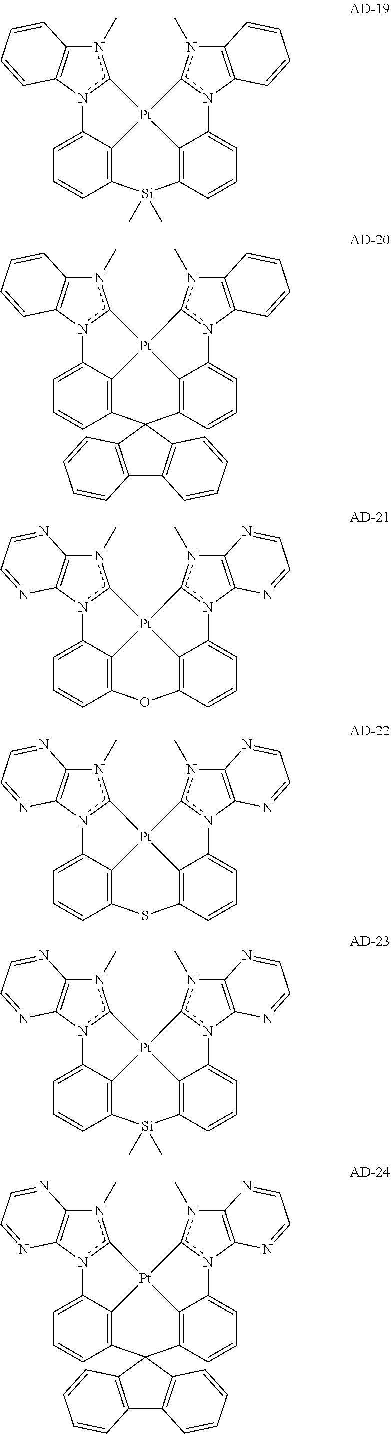

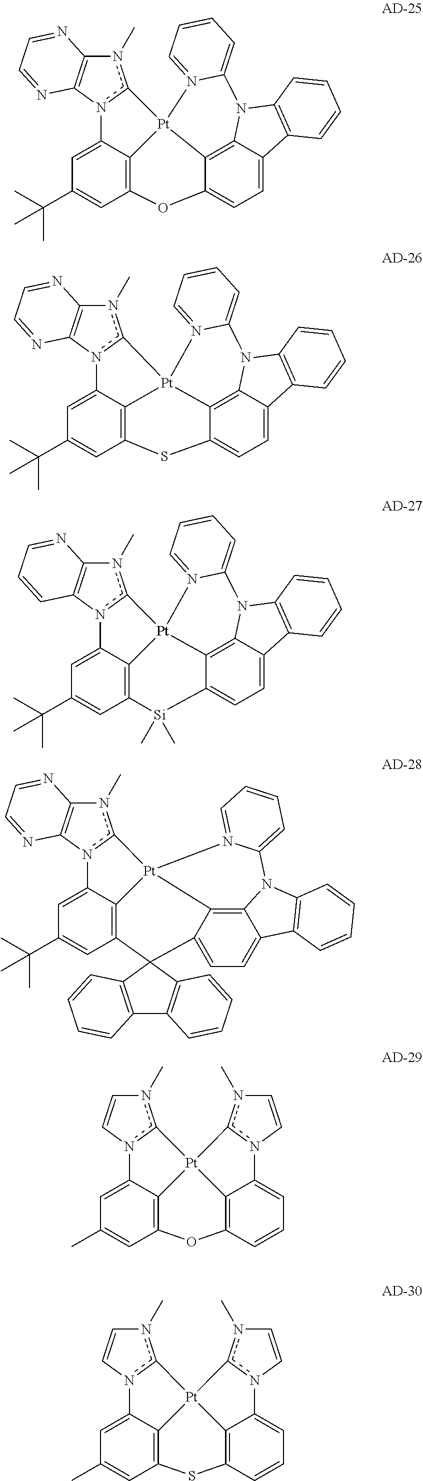

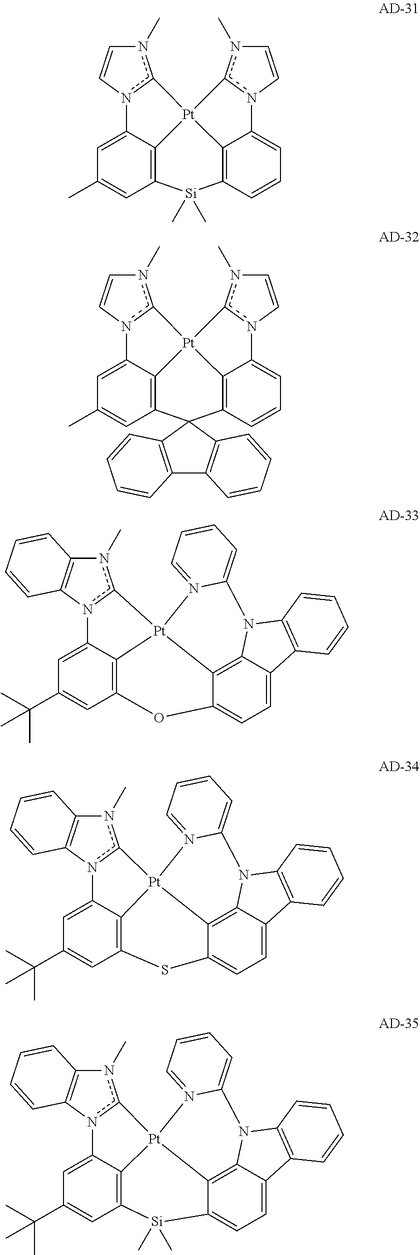

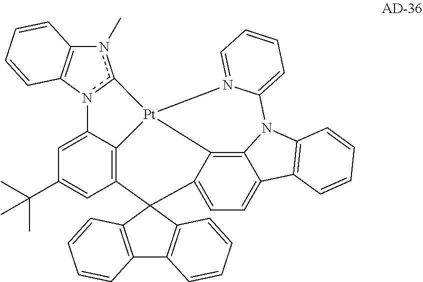

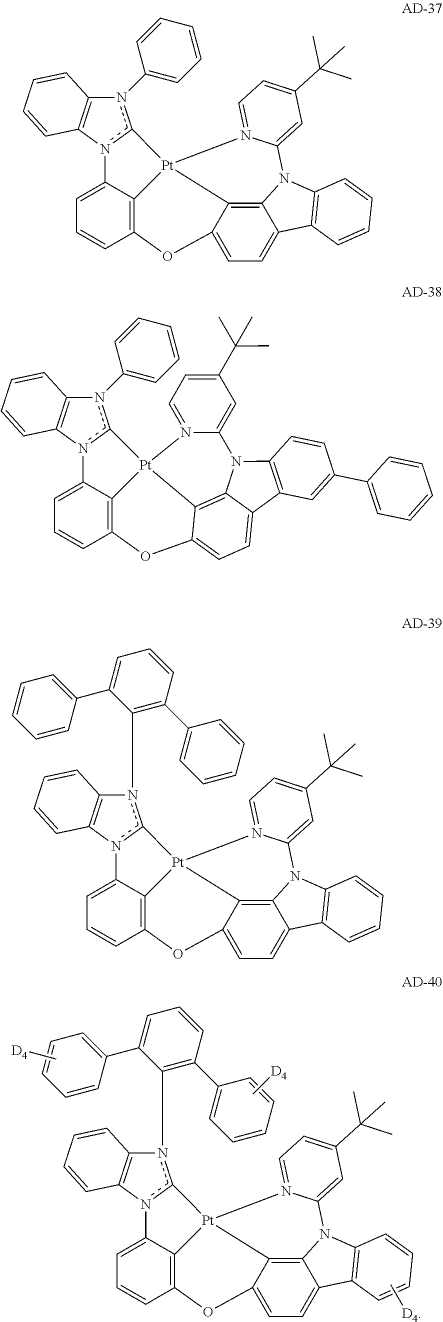

In the embodiment compounds presented in Compound Group 4, “D” refers to a deuterium atom.

When the emission layer EML in the light emitting device ED of an embodiment includes all of the first compound, the second compound, and the third compound, with respect to the total weight of the first compound, the second compound, and the third compound, the content (e.g., amount) of the first compound may be about 0.1 wt % to about 5 wt %. However, the embodiment of the present disclosure is not limited thereto. When the content (e.g., amount) of the first compound satisfy the previously described proportion, the energy transfer from the second compound and the third compound to the first compound may increase, and thus the luminous efficiency and device service life may increase.

The contents of the second compound and the third compound in the emission layer EML may be the rest excluding the weight of the first compound. For example, the contents of the second compound and the third compound in the emission layer EML may be about 65 wt % to about 95 wt % with respect to the total weight of the first compound, the second compound, and the third compound.

In the total weight of the second compound and the third compound, the weight ratio of the second compound and the third compound may be about 3:7 to about 7:3.

When the contents of the second compound and the third compound satisfy the previously described ratio, a charge balance characteristic in the emission layer EML are improved, and thus the luminous efficiency and device service life may increase. When the contents of the second compound and the third compound deviate from the previously described ratio range, a charge balance in the emission layer EML is broken, and thus the luminous efficiency may be reduced and the device may be easily deteriorated.

When the emission layer EML includes the fourth compound, the content (e.g., amount) of the fourth compound in the emission layer EML may be about 10 wt % to about 30 wt % with respect to the total weight of the first compound, the second compound, the third compound, and the fourth compound. However, the embodiment of the present disclosure is not limited thereto. When the content (e.g., amount) of the fourth compound satisfies the previously described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the previously described content (e.g., amount) ratio range, excellent or suitable luminous efficiency and long service life may be achieved.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML may further include compounds described in addition to the first to fourth compounds described previously. In the light emitting device ED of an embodiment, the emission layer EML may include an anthracene derivative, a pyrene derivative, a fluoranthene derivative, a chrysene derivative, a dihydrobenzanthracenederivative, or a triphenylene derivative. For example, the emission layer EML may include the anthracene derivative or the pyrene derivative.

In each light emitting device ED of embodiments illustrated in FIGS. 3 to 7, the emission layer EML may further include a suitable host and dopant besides the previously described host and dopant, and for example the emission layer EML may include a compound represented by Formula E-1. The compound represented by Formula E-1 may be utilized as a fluorescent host material.

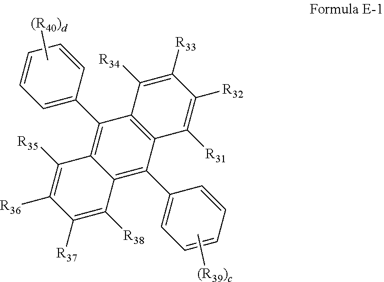

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle. In Formula E-1, c and d may each independently be an integer of 0 to 5.

Formula E-1 may be represented by any one selected from among Compound E1 to Compound E19:

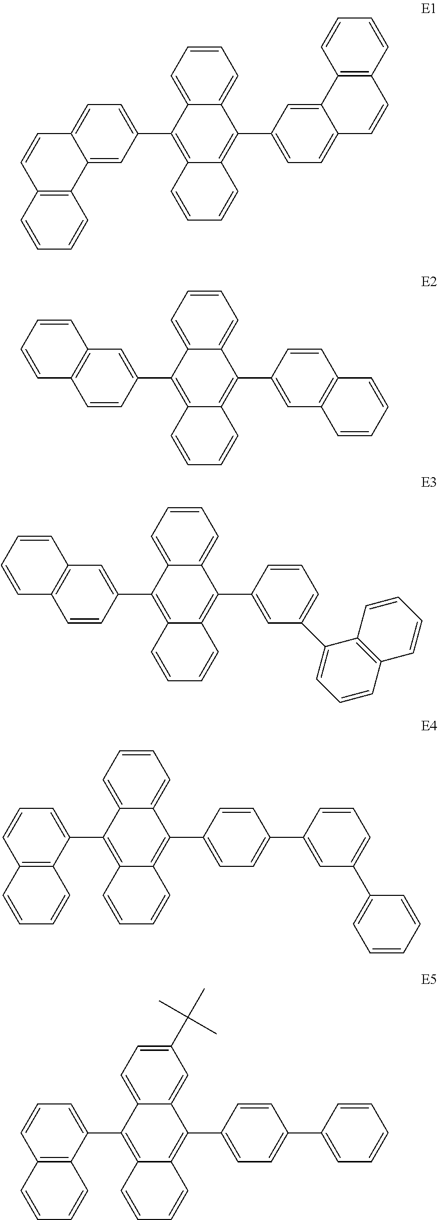

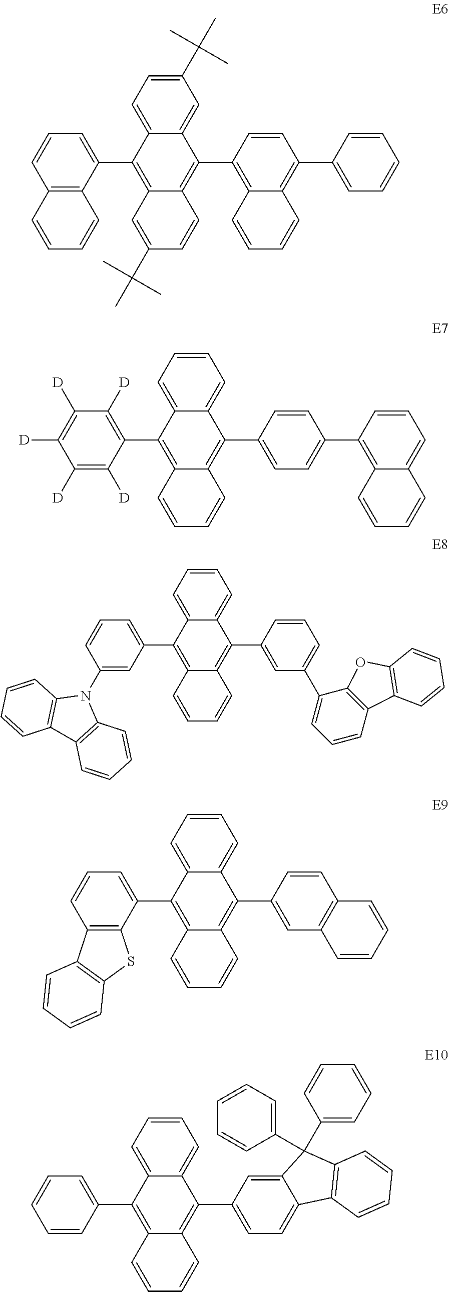

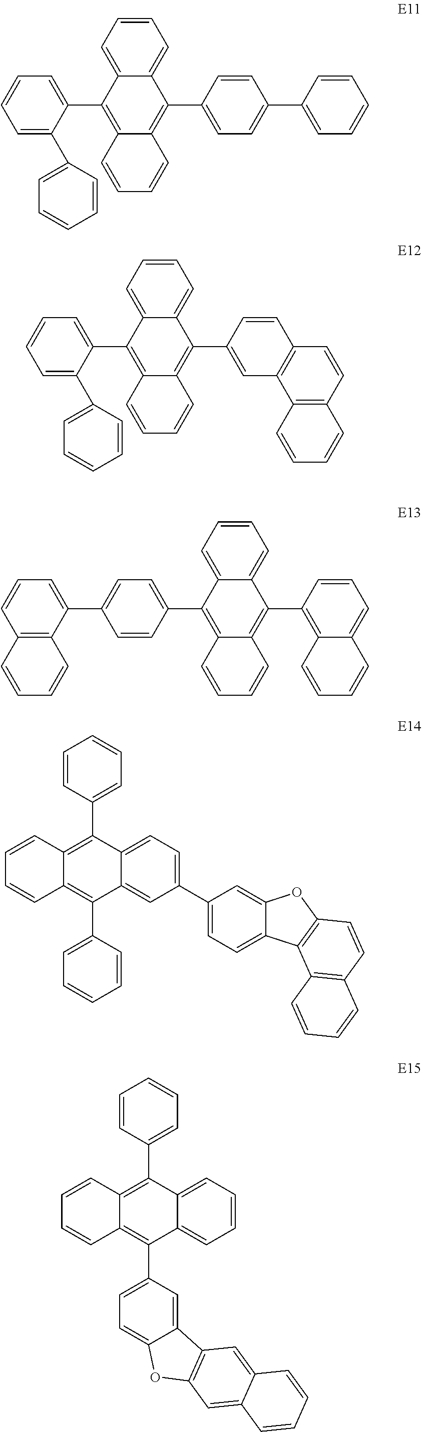

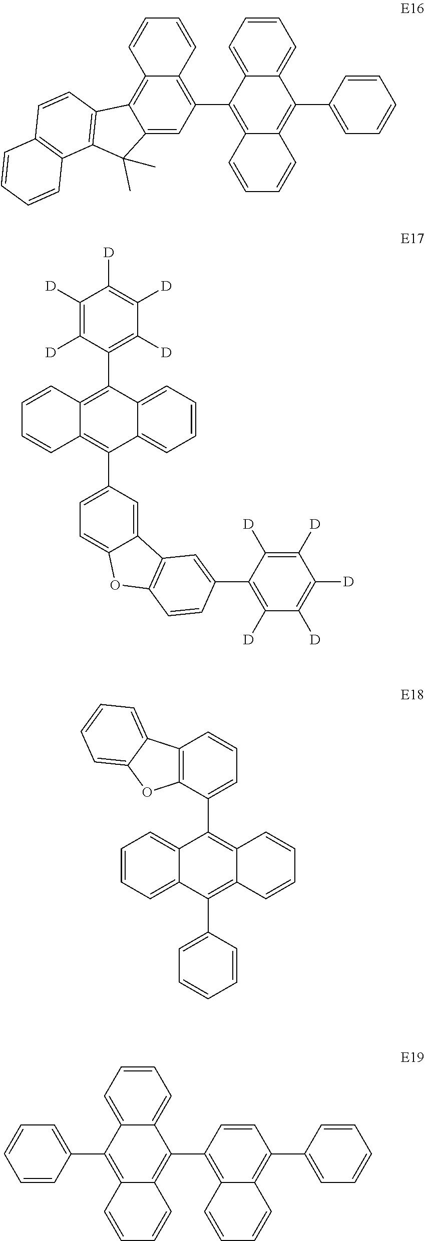

In an embodiment, the emission layer EML may include a compound represented by Formula E-2a or Formula E-2b. The compound represented by Formula E-2a or Formula E-2b may be utilized as a phosphorescent host material.

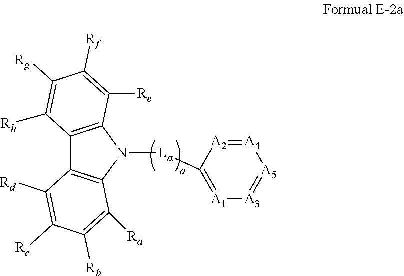

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of La's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₈ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc., as a ring-forming atom.

In some embodiments, in Formula E-2a, two or three selected from among A₁ to A₈ may be N, and the rest may be CRᵢ.

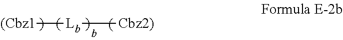

In Formula E-2b, Cbz1 and Cbz2 may each independently be an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are examples, and the compound represented by Formula E-2a or Formula E-2b is not limited to those represented in Compound Group E-2.

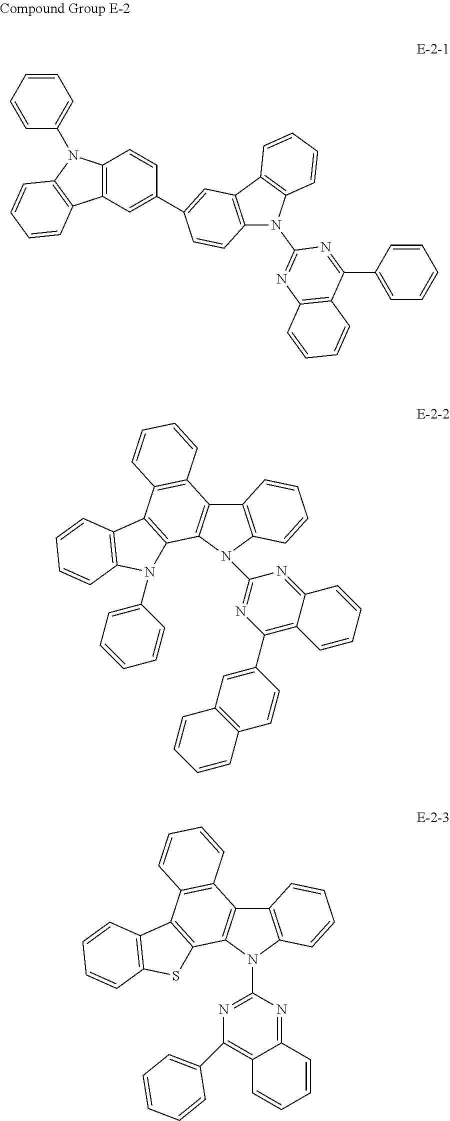 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

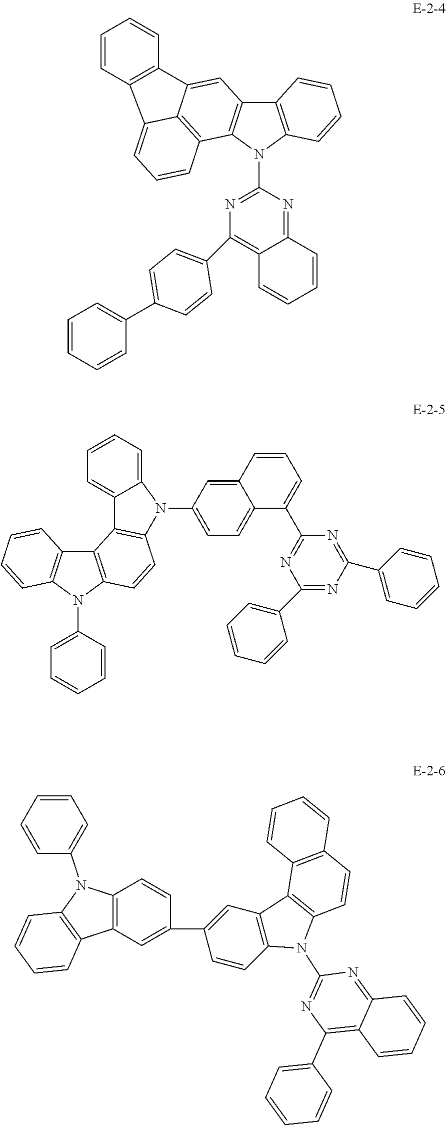 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

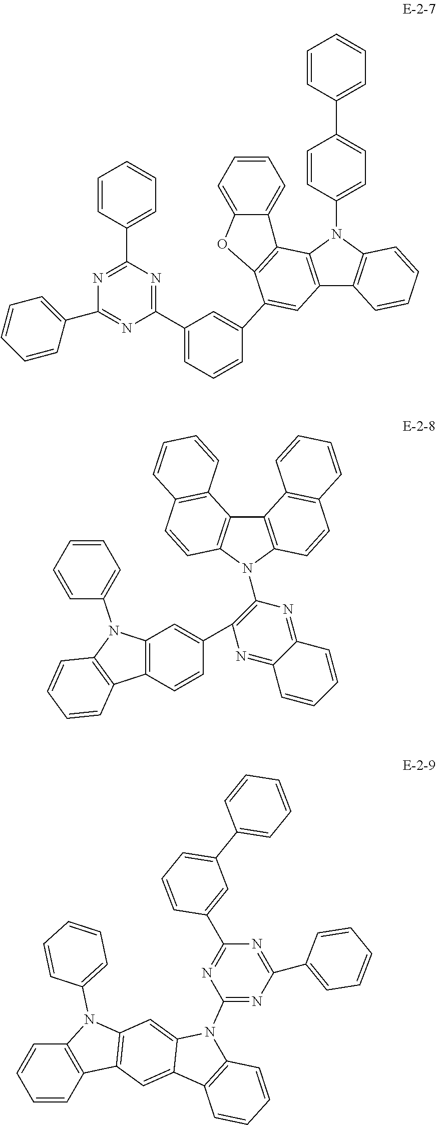 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

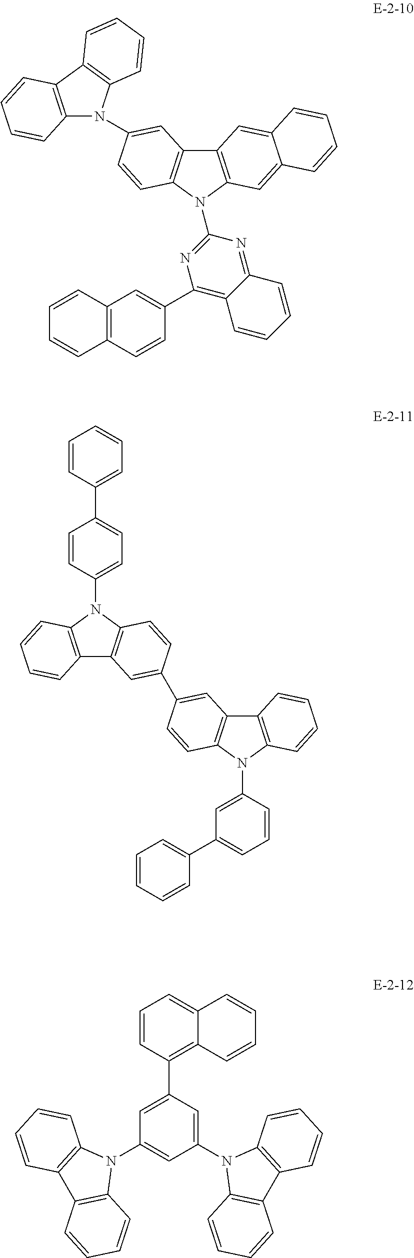 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

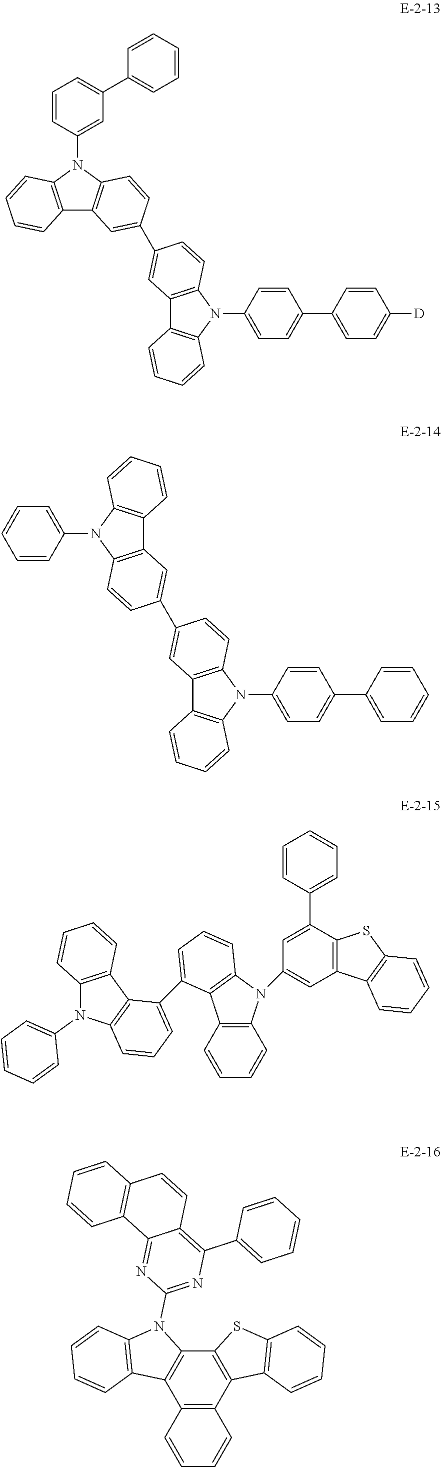 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1 ; c1ccc(-c2nc(-n3c4ccccc4c4c5ccccc5c5c6ccccc6sc5c43)nc3c2ccc2ccccc23)cc1]

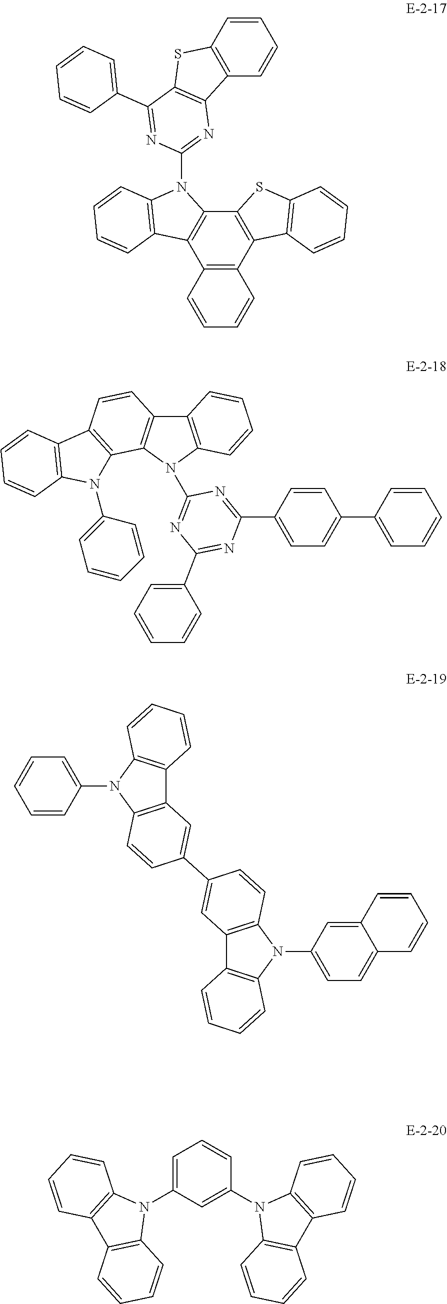 [SMILES: c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1]

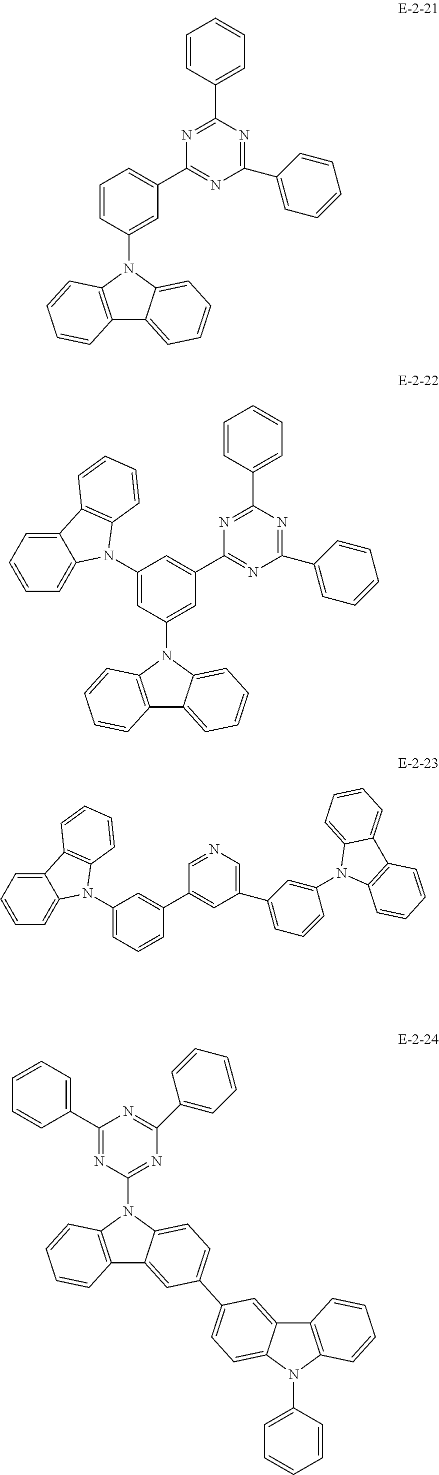 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl] ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

The emission layer EML may include the compound represented by Formula M-a. The compound represented by Formula M-a may be utilized as a phosphorescent dopant material.

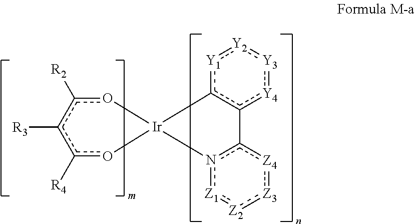

In Formula M-a, Y₁ to Y₄ and Z1 to Z4 may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25.

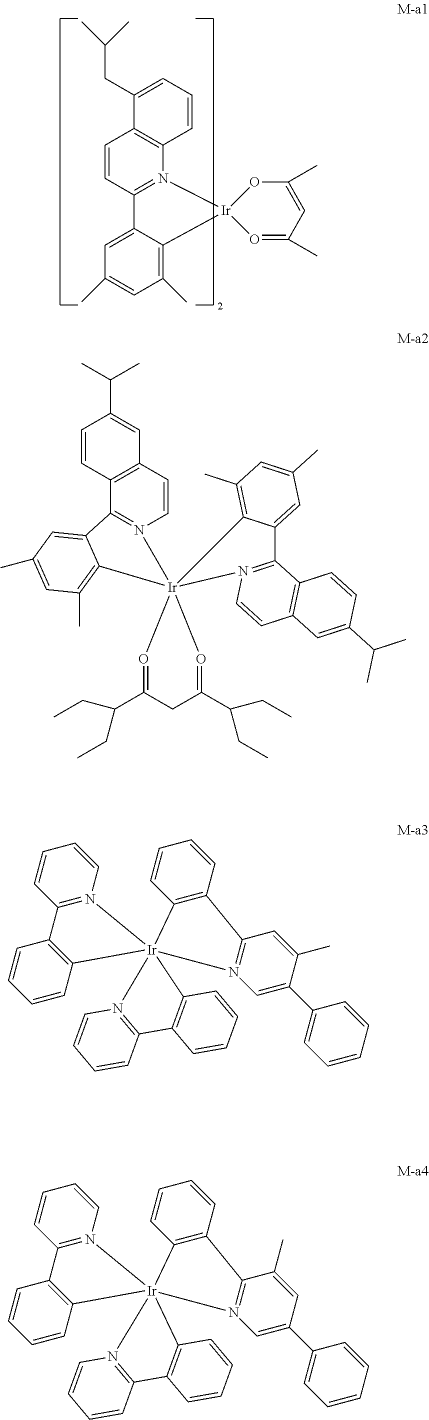

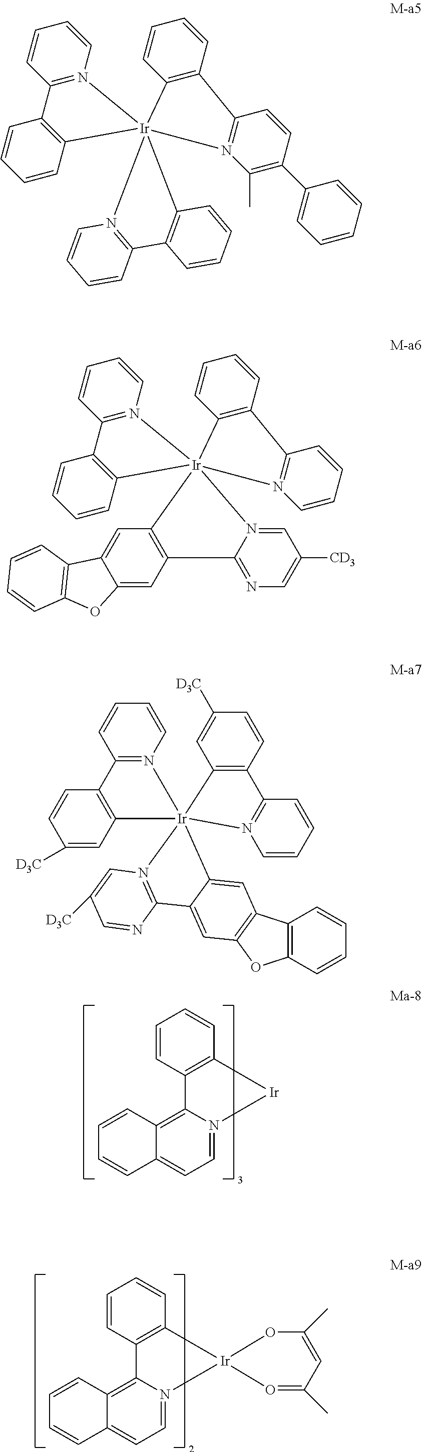

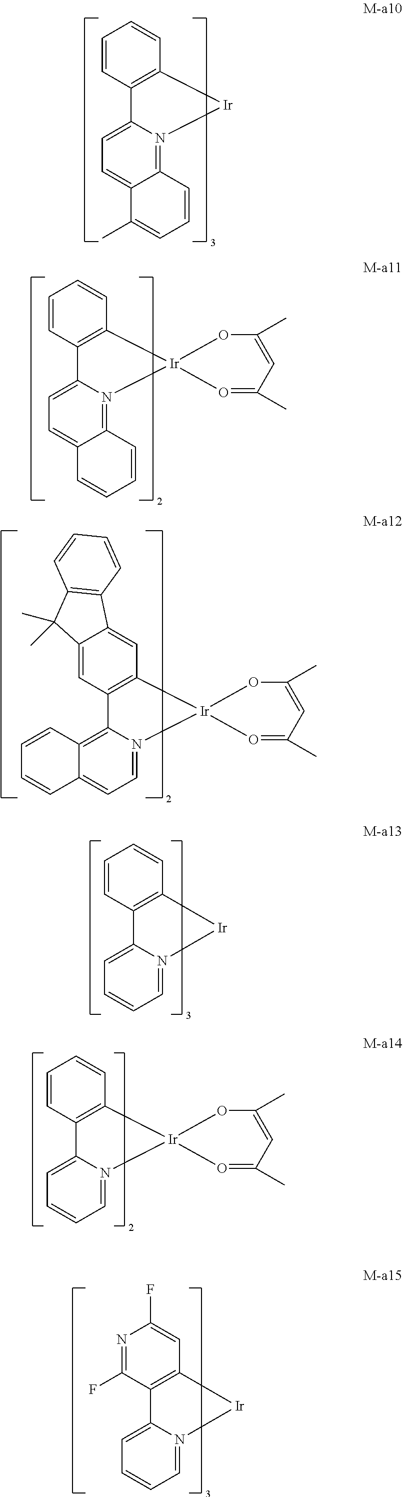

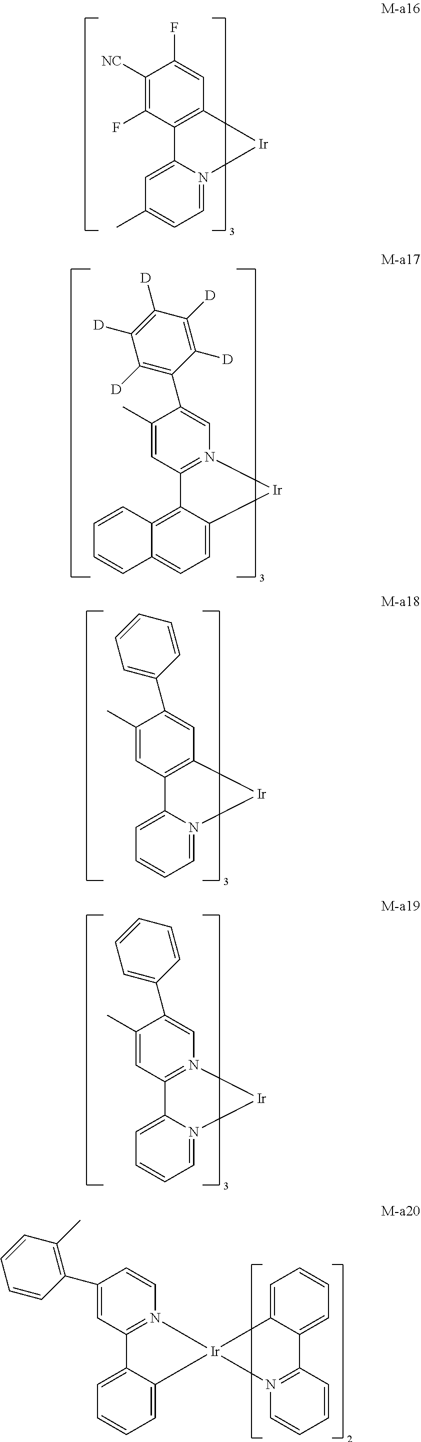

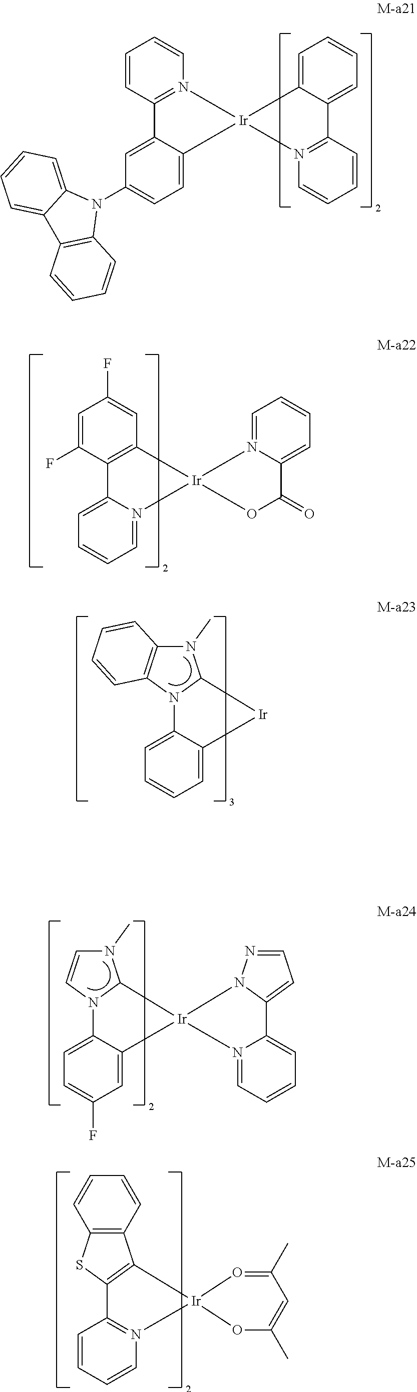

The emission layer EML may include a compound represented by any one selected from among Formula F-a to Formula F-c. The compound represented by Formula F-a to Formula F-c may be utilized as a fluorescence dopant material.

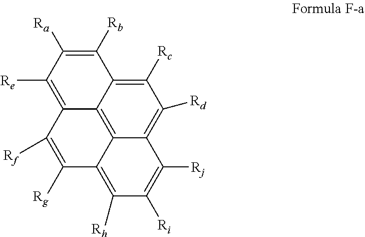

In Formula F-a, two selected from among Rₐ to Rⱼ may each independently be substituted with [symbol] . The others, which are not substituted with [symbol] , among Rₐ to Rᵢ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In [symbol] , Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

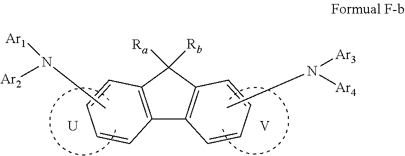

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that when the number of U or V is 1, one ring constitutes a fused ring at a portion indicated by U or V, and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

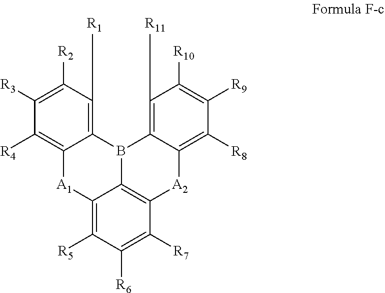

In Formula F-c, A1 and A2 may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a fused ring. For example, when A₁ and A₂ may each independently be NRₘ, A₁ may be bonded to R₄ or R₅ to form a ring. In some embodiments, A₂ may be bonded to R₇ or R₈ to form a ring.

In an embodiment, the emission layer EML may further include, as a suitable dopant material, a styryl derivative (e.g., 1,4-bis[2-(3-N-ethylcarbazolyl)vinyl] benzene (BCzVB), 4-(di-p-tolylamino)-4′-[(di-p-tolylamino)styryl]stilbene (DPAVB), and N-(4-((E)-2-(6-((E)-4-(diphenylamino)styryl) naphthalen-2-yl)vinyl)phenyl)-N-phenylbenzenamine (N-BDAVBi), 4,4′-bis[2-(4-(N,N-diphenylamino)phenyl)vinyl]biphenyl(DPAVBi), perylene and a derivative thereof (e.g., 2,5,8,11-tetra-t-butylperylene (TBP)), pyrene and a derivative thereof (e.g., 1,1-dipyrene, 1,4-dipyrenylbenzene, 1,4-bis(N,N-diphenylamino) pyrene), etc.

The emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be utilized as a phosphorescent dopant. For example, iridium (III) bis(4,6-difluorophenylpyridinato-N,C2′) (FIrpic), bis(2,4-difluorophenylpyridinato)-tetrakis(1-pyrazolyl) borate iridium (III) (Flr6), or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from among II-VI group compounds, I-II-VI group compounds, II-IV-VI group compounds, I-II-IV-VI group compounds, II-IV-V group compounds, III-VI group compounds, I-III-VI group compounds, III-V group compounds, III-II-V group compounds, IV-VI group compounds, IV group elements, IV group compounds, and combinations thereof.

The II-VI group compound may be selected from among the group including: a binary compound selected from among the group including CdSe, CdTe, CdS, ZnS, ZnSe, ZnTe, ZnO, HgS, HgSe, HgTe, MgSe, MgS, and mixtures thereof; a ternary compound selected from among the group including CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from among the group including HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

In some embodiments, the II-VI group compound may further include I group metals and/or IV group elements. The I-II-VI group compound may be selected from among CuSnS and CuZnS, and the II-IV-VI group compound may be ZnSnS, and/or the like. The I-II-IV-VI group compound may be selected from among a quaternary compound selected from among the group including Cu₂ZnSnS₂, CuZnSnS₄, Cu₂ZnSnSe₄, Ag₂ZnSnS₂, and mixtures thereof.

The II-IV-V group compound may be selected from among a ternary compound selected from among the group including ZnSnP, ZnSnP₂, ZnSnAs₂, ZnGeP₂, ZnGeAs₂, CdSnP₂, CdGeP₂, and mixtures thereof.

The III-VI group compound may include a binary compound such as GaS, GazS₃, GaSe, GazSes, GaTe, InTe, InS, InSe, In₂S₃, and In₂Se₃, a ternary compound such as InGaS₃, and InGaSe₃, or optional combinations thereof.

The I-III-VI group compound may be selected from among a ternary compound selected from among the group including AgInS, AgInS₂, CuInS, CuInS₂, AgGaS₂, CuGaS₂, CuGaO₂, AgGaO₂, AgAlO₂ and mixtures thereof, or a quaternary compound such as AgInGaS₂, and CuInGaS₂.

The III-V group compound may be selected from among the group including a binary compound selected from among the group including GaN, GaP, GaAs, GaSb, AlN, AIP, AIAs, AISb, InN, InP, InAs, InSb, and mixtures thereof, a ternary compound selected from among the group including GaNP, GaNAs, GaNSb, GaPAs, GaPSb, AlNP, AlNAs, AlNSb, AIPAS, AIPSb, InGaP, InAIP, InNP, InNAs, InNSb, InPAs, InPSb, and mixtures thereof, and a quaternary compound selected from among the group including GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, and mixtures thereof. In some embodiments, the III-V group compound may further include II group metals. For example, InZnP, etc. may be selected from among a III-II-V group compound.

The IV-VI group compound may be selected from among the group including a binary compound selected from among the group including SnS, SnSe, SnTe, PbS, PbSe, PbTe, and mixtures thereof, a ternary compound selected from among the group including SnSeS, SnSeTe, SnSTe, PbSeS, PbSeTe, PbSTe, SnPbS, SnPbSe, SnPbTe, and mixtures thereof, and a quaternary compound selected from among the group including SnPbSSe, SnPbSeTe, SnPbSTe, and mixtures thereof. The IV group element may be selected from among the group including Si, Ge, and a mixture thereof. The IV group compound may be a binary compound selected from among the group including SiC, SiGe, and a mixture thereof.

Each element included in the polynary compound such as the binary compound, the ternary compound and the quaternary compound may be present at substantially uniform concentration or at substantially non-uniform concentration in a particle. For example, the chemical formulae refer to the types (kinds) of the elements included in the compound, and the atomic ratio in the compound may be different. For example, AgInGaS₂ may refer to AgInₓGa₁₋ₓS₂ (x is a real number between 0-1).

In some embodiments, the quantum dot may have a single structure in which the concentration of each element included in the quantum dot is substantially uniform, or a core-shell double structure. For example, a material included in the core and a material included in the shell may be different from each other.

The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. The interface between the core and the shell may have a concentration gradient in which the concentration of an element present in the shell is decreased toward the center.

In some embodiments, the quantum dot may have the previously described core-shell structure including a core including a nanocrystal and a shell wrapping the core. Examples of the shell of the quantum dot may include a metal or non-metal oxide, a semiconductor compound, and/or combinations thereof.

For example, the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a ternary compound such as MgAl₂O₄, CoFe₂O₄, NiFe₂O₄ and CoMn₂O₄, but an embodiment of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, etc., but an embodiment of the present disclosure is not limited thereto.

Each element included in the polynary compound such as the binary compound and the ternary compound may be present at substantially uniform concentration or substantially non-uniform concentration in a particle. For example, the chemical formulae refer to the types (kinds) of elements included, and the atomic ratio in the compound may be different.

The quantum dot may have a full width of half maximum (FWHM) of emission wavelength spectrum of about 45 nm or less, about 40 nm or less, more, or about 30 nm or less. Within this range, color purity or color reproducibility may be improved. In some embodiments, light emitted via the quantum dot is emitted in all directions, and light viewing angle properties may be improved.

In some embodiments, the shape of the quantum dot may be generally utilized shapes in the art, without specific limitation. In some embodiments, the shape of spherical, pyramidal, multi-arm, or cubic nanoparticle, nanotube, nanowire, nanofiber, nanoplate particle, etc. may be utilized.

By controlling the size of the quantum dot or by controlling the element ratio in the quantum dot compound, an energy band gap may be controlled or selected, and one or more suitable wavelength bands of light may be obtained from a quantum dot emission layer. Accordingly, by utilizing the quantum dot (utilizing quantum dots having different sizes or controlling an element ratio in a quantum dot compound differently), a light emitting device emitting one or more suitable wavelengths of light may be accomplished. For example, the size of the quantum dot or the element ratio in the quantum dot compound may be controlled or selected to emit red, green and/or blue light. In some embodiments, the quantum dots may be provided to combine one or more suitable emission colors to emit white light.

In each of the light emitting devices ED of embodiments illustrated in FIGS. 3 to 7, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but the embodiment of the present disclosure is not limited thereto. The electron transport region ETR may have a thickness, for example, from about 1,000 Å to about 1,500 Å.

The electron transport region ETR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2:

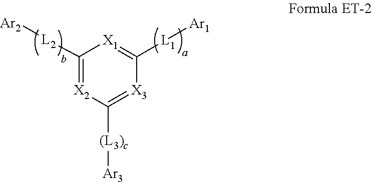

In Formula ET-2, at least one selected from among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to Ls may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c may each independently be an integer of 2 or more, L₁ to Ls may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri [(3-pyridyl)-phen-3-yl] benzene, 2,4,6-tris(3′-(pyridin-3-yl) biphenyl-3-yl)-1,3,5-triazine, 2-(4-(N-phenylbenzoimidazol-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), or a mixture thereof.

The electron transport region ETR may include at least one selected from among Compound ET1 to Compound ET36:

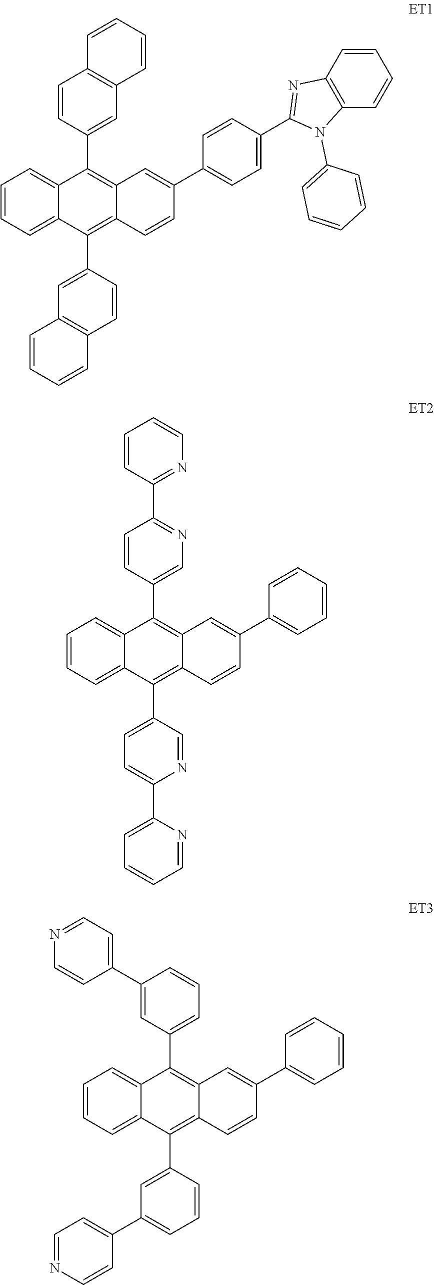 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

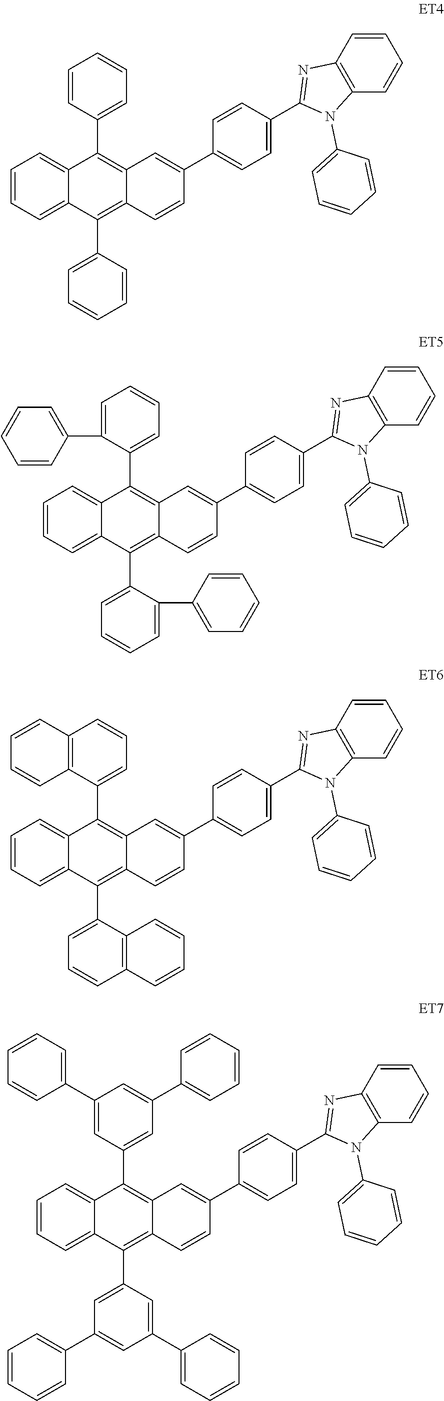 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

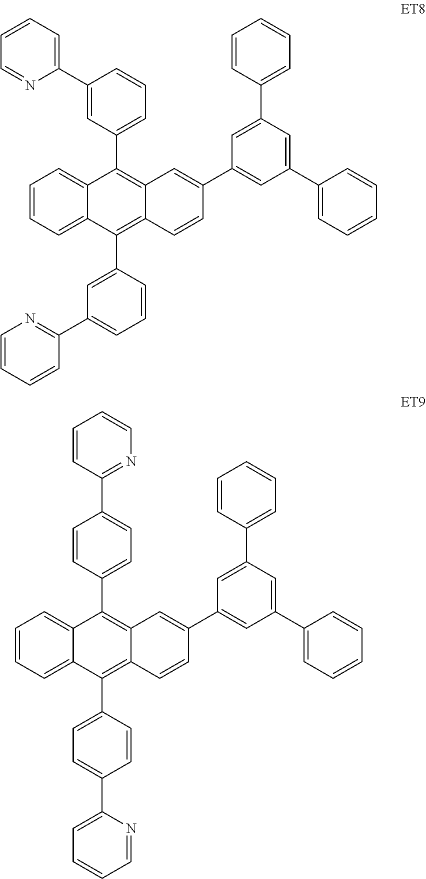 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

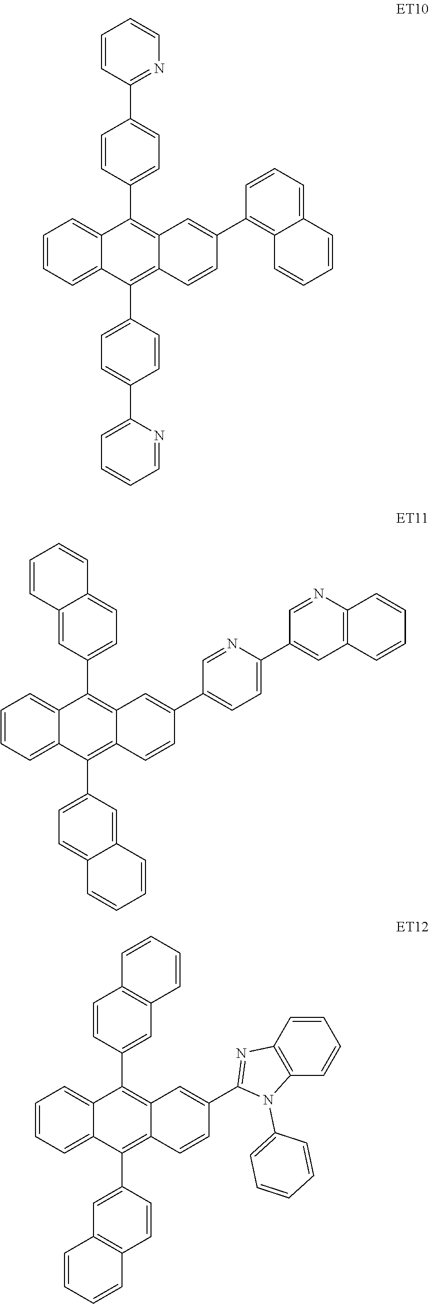

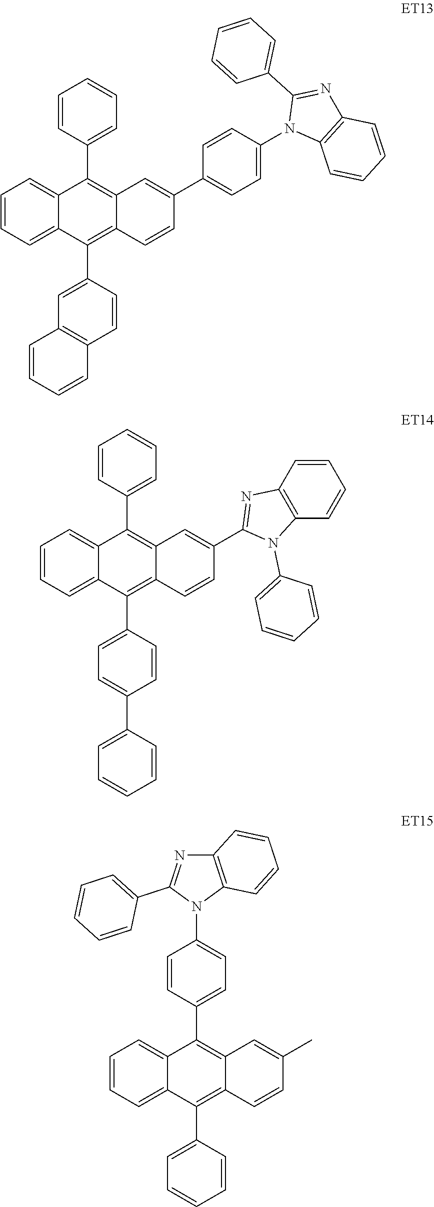 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

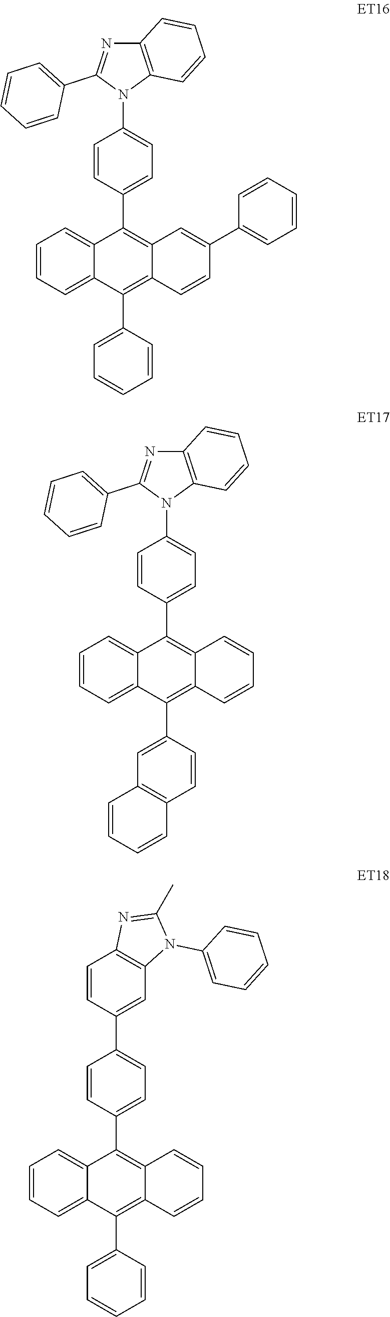 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

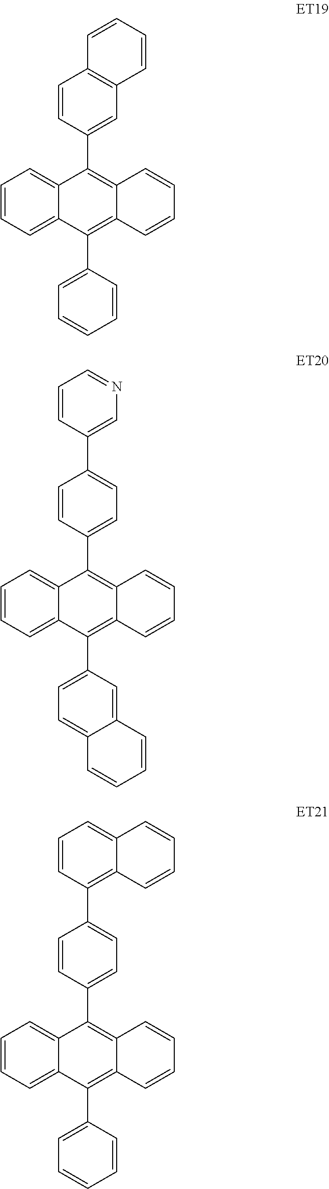

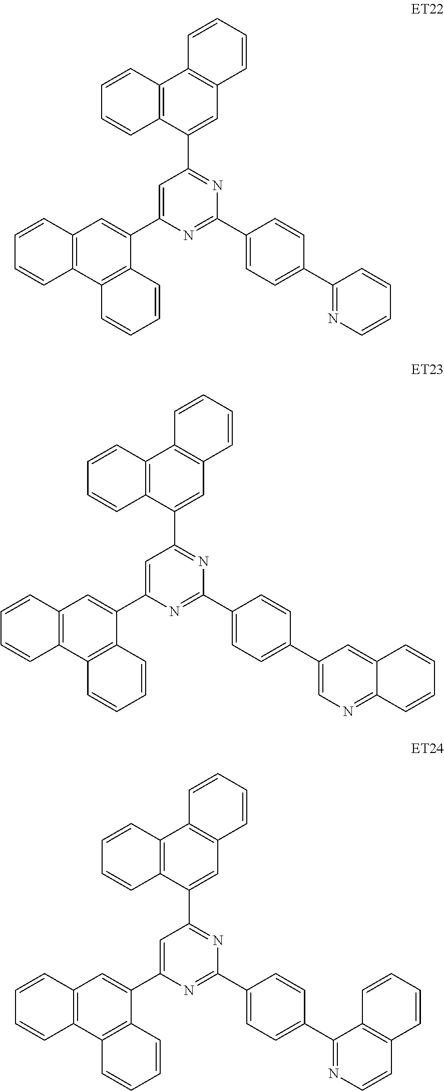 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5cc6ccccc6c6ccccc56)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

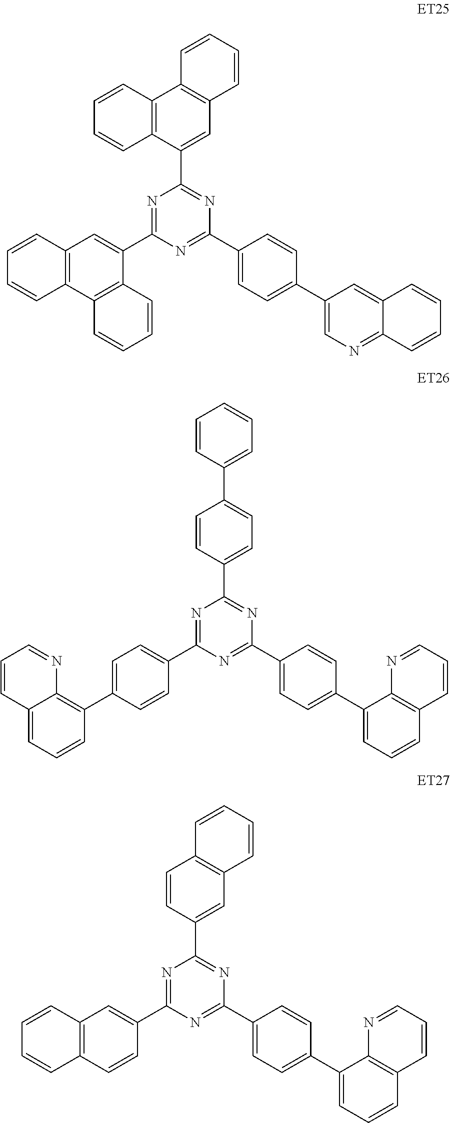 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

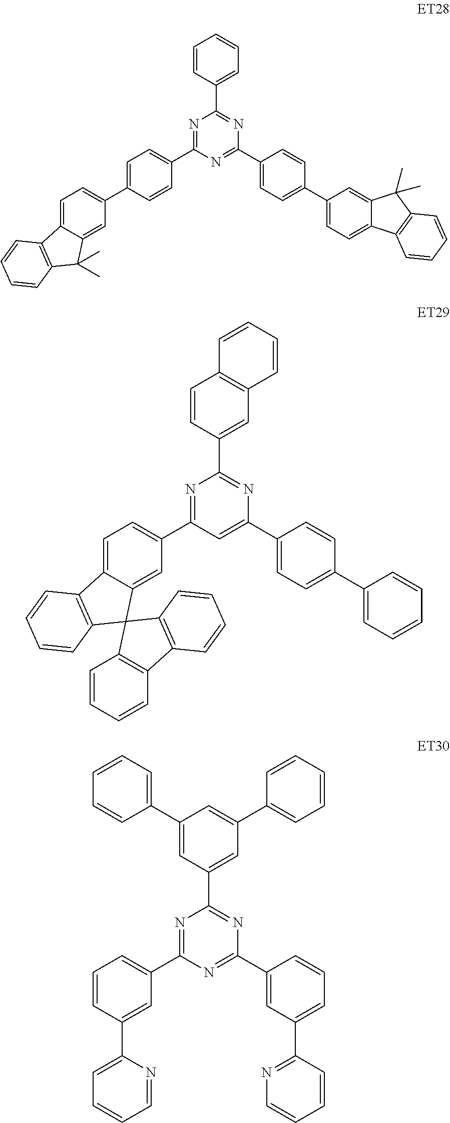

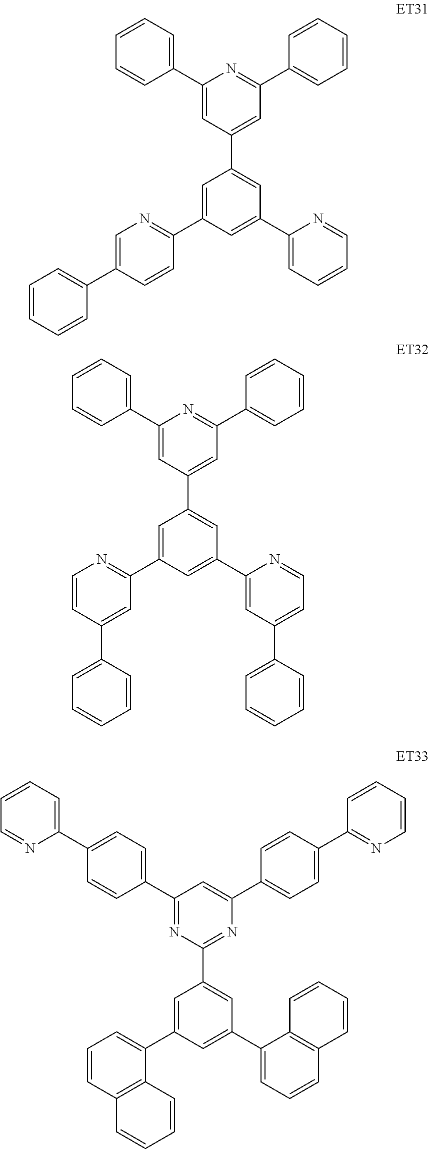

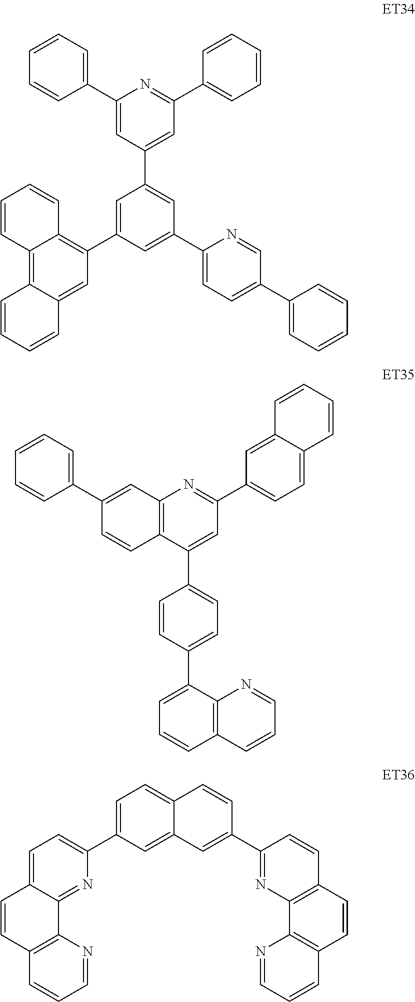

In some embodiments, the electron transport region ETR may include a metal halide such as LiF, NaCl, CsF, RbCI, Rbl, Cul, and KI, a lanthanide metal such as Yb, and a co-deposited material of the metal halide and the lanthanide metal. For example, the electron transport region ETR may include KI: Yb, Rbl: Yb, LiF: Yb, etc., as a co-deposited material. In some embodiments, the electron transport region ETR may be formed utilizing a metal oxide such as Li₂O or BaO, or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the previously described materials, but the embodiment of the present disclosure is not limited thereto.

The electron transport region ETR may include the previously described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned range, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the previously described range, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/AI, Mo, Ti, Yb, W, or a compound or mixture thereof (e.g., AgMg, AgYb, or MgYb). In some embodiments, the second electrode EL2 may have a multilayer structure including a reflective film or a transflective film formed of the previously described materials, and a transparent conductive film formed of ITO, IZO, ZnO, ITZO, etc. For example, the second electrode EL2 may include the previously described metal materials, combinations of at least two metal materials of the previously described metal materials, oxides of the previously described metal materials, and/or the like.

In some embodiments, the second electrode EL2 may be connected with an auxiliary electrode. When the second electrode EL2 is connected with the auxiliary electrode, the resistance of the second electrode EL2 may be decreased.

In some embodiments, a capping layer CPL may further be disposed on the second electrode EL2 of the light emitting device ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiO_{y}, etc.

For example, when the capping layer CPL includes an organic material, the organic material may include a-NPD, NPB, TPD, m-MTDATA, Alq₃, CuPc, N4, N4, N4′, N4′-tetra(biphenyl-4-yl) biphenyl-4,4′-diamine (TPD15), 4,4′,4″-tris(carbazol-9-yl)triphenylamine (TCTA), etc., or an epoxy resin, or acrylate such as methacrylate. However, the embodiment of the present disclosure is not limited thereto, and the capping layer CPL may include at least one selected from among Compounds P1 to P5:

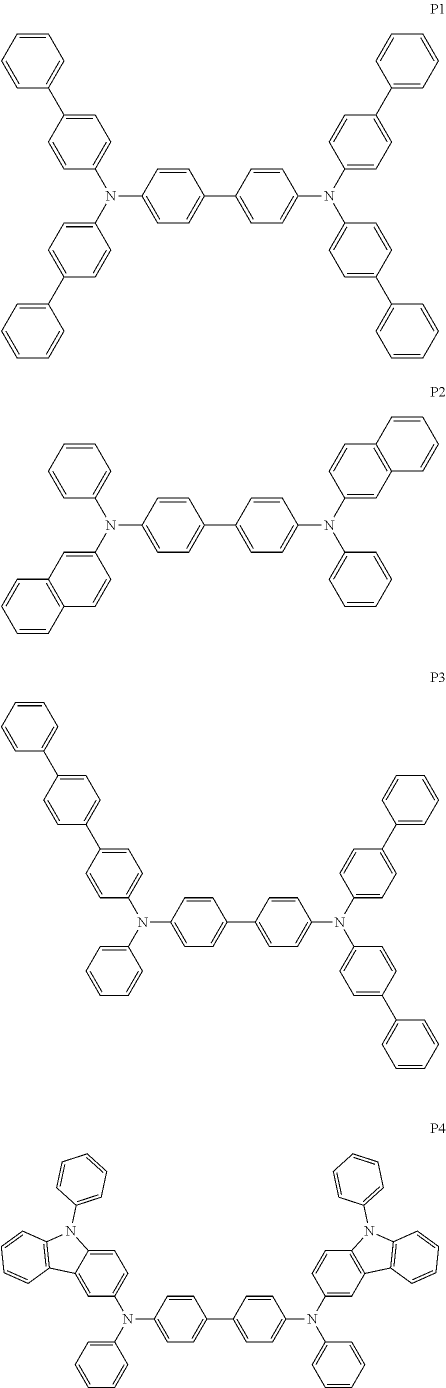 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

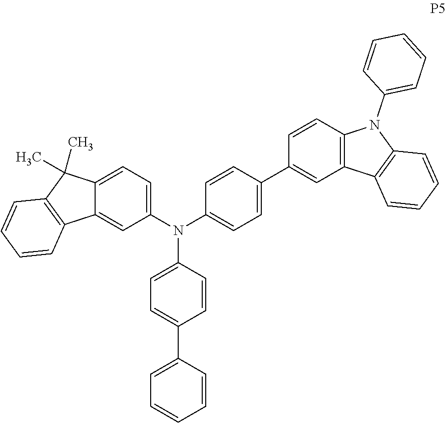 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

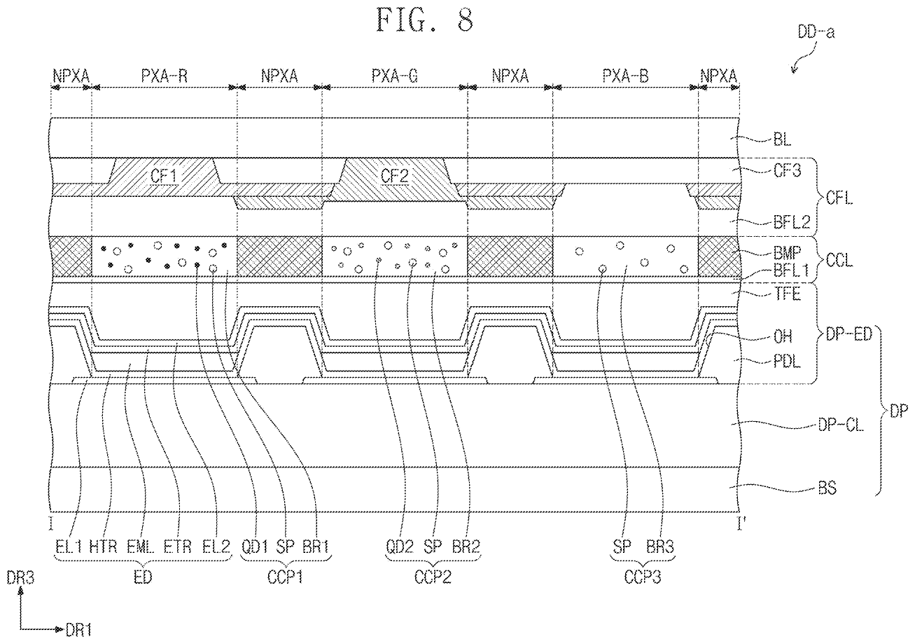

FIG. 8 to FIG. 11 are cross-sectional views of display apparatus according to embodiments. Hereinafter, in the explanation on the display apparatus according to embodiments, referring to FIG. 8 to FIG. 11, the overlapping contents with those explained in FIG. 1 to FIG. 7 will not be explained again, and different points will be explained mainly.

Referring to FIG. 8, the display apparatus DD-a according to an embodiment may include a display panel DP including a display device layer DP-ED, a light control layer CCL disposed on the display panel DP and a color filter layer CFL. In an embodiment shown in FIG. 8, the display panel DP may include a base layer BS, a circuit layer DP-CL provided on the base layer BS and a display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the same structure as the light emitting devices of FIG. 3 to FIG. 7 may be applied to the structure of the light emitting device ED, shown in FIG. 8. The light emitting device ED shown in FIG. 8 includes the fused polycyclic compound of an embodiment and may show a low driving voltage, high efficiency and long-life characteristics.

Referring to FIG. 8, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may be configured to emit light in substantially the same wavelength range. In the display apparatus DD-a of an embodiment, the emission layer EML may be configured to emit blue light. In some embodiments, unlike the configuration illustrated, in an embodiment, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may be configured to emit provided light by converting the wavelength thereof. For example, the light control layer CCL may be a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 8, divided patterns BMP may be disposed between the light control parts CCP1, CCP2 and CCP3 which are spaced apart from each other, but the embodiment of the present disclosure is not limited thereto. FIG. 8 illustrates that the divided patterns BMP do not overlap the light control parts CCP1, CCP2 and CCP3, but at least a portion of the edges of the light control parts CCP1, CCP2 and CCP3 may overlap the divided patterns BMP.

The light control layer CCL may include a first light control part CCP1 containing a first quantum dot QD1 which converts first color light provided from the light emitting device ED into second color light, a second light control part CCP2 containing a second quantum dot QD2 which converts the first color light into third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described previously may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block or reduce the light control parts CCP1, CCP2 and CCP3 from being exposed to moisture/oxygen. In some embodiments, the barrier layer BFL1 may cover the light control parts CCP1, CCP2, and CCP3. In some embodiments, the barrier layer BFL2 may be provided between the light control parts CCP1, CCP2, and CCP3 and the color filter layer CFL.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display apparatus DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment or dye. The first filter CF1 may include a red pigment or dye, the second filter CF2 may include a green pigment or dye, and the third filter CF3 may include a blue pigment or dye.

In some embodiments, the embodiment of the present disclosure is not limited thereto, and the third filter CF3 may not include (e.g., may exclude) a pigment or dye. The third filter CF3 may include a polymeric photosensitive resin and may not include (e.g., may exclude) a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but may be provided as one filter.

Although not illustrated, the color filter layer CFL may further include a light shielding part. The light shielding part may be a black matrix. The light shielding part may include an organic light shielding material or an inorganic light shielding material containing a black pigment or dye. The light shielding part may prevent or reduce light leakage, and may separate boundaries between the adjacent filters CF1, CF2, and CF3. Furthermore, in an embodiment, the light shielding part may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, in an embodiment, the base substrate BL may not be provided.

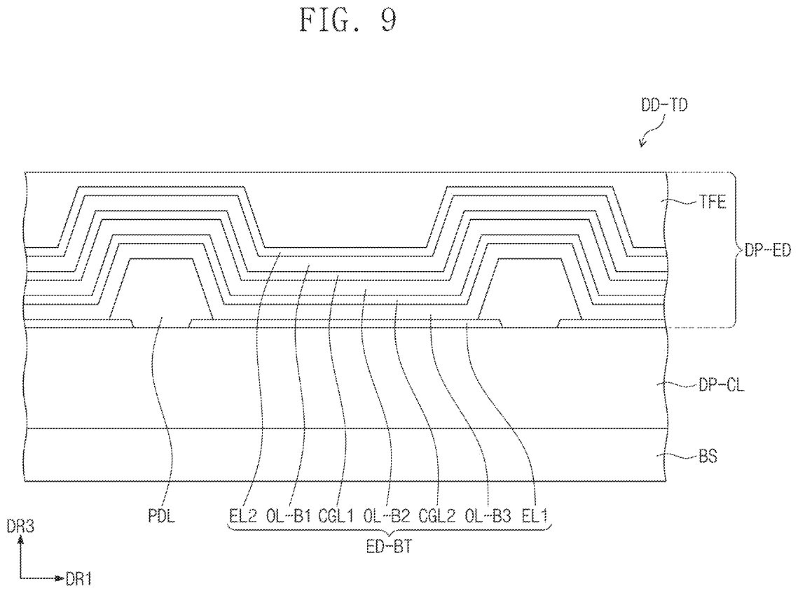

FIG. 9 is a cross-sectional view showing a portion of a display apparatus according to an embodiment. In the display apparatus DD-TD of an embodiment, a light emitting device ED-BT may include multiple light emitting structures OL-B1, OL-B2 and OL-B3. At least one selected from among the multiple light emitting structures OL-B1, OL-B2 and OL-B3 may include the fused polycyclic compound of an embodiment. Accordingly, the light emitting device ED-BT may show a low driving voltage, high efficiency and long-life characteristics.

The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 8) and a hole transport region HTR and an electron transport region ETR disposed with the emission layer EML (FIG. 8) located therebetween.

For example, the light emitting device ED-BT included in the display apparatus DD-TD of an embodiment may be a light emitting device having a tandem structure and including a plurality of emission layers.

In an embodiment illustrated in FIG. 9, all light beams respectively emitted from the light emitting structures OL-B1, OL-B2, and OL-B3 may be blue light. However, the embodiment of the present disclosure is not limited thereto, and the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may be configured to emit white light (e.g., combined white light).

Charge generation layers CGL1 and CGL2 may be respectively disposed between two of the neighboring light emitting structures OL-B1, OL-B2, and OL-B3. The charge generation layers CGL1 and CGL2 may include a p-type or kind charge generation layer and/or an n-type or kind charge generation layer.

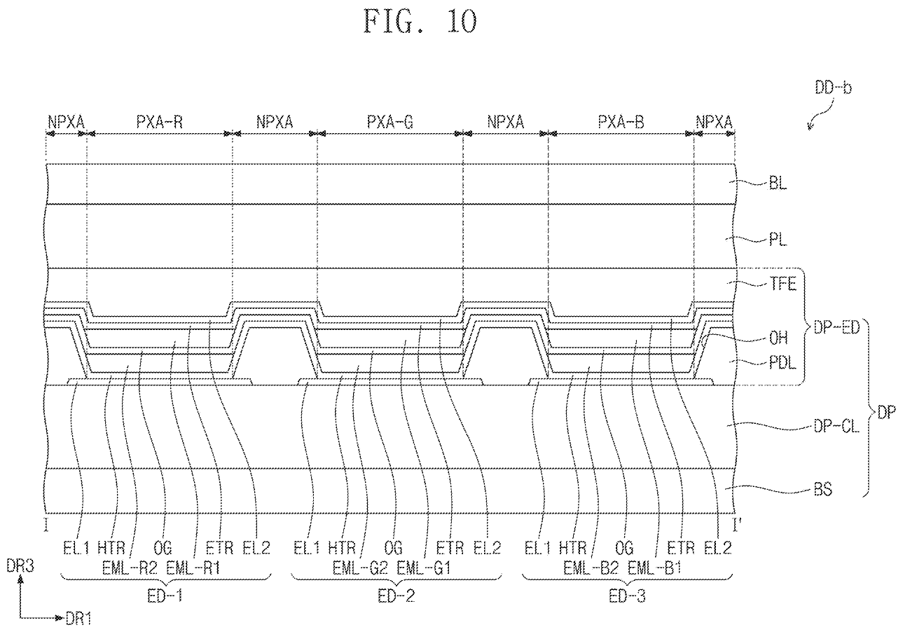

Referring to FIG. 10, the display apparatus DD-b according to an embodiment may include light emitting devices ED-1, ED-2 and ED-3, in which two emission layers are stacked. At least one selected from among the light emitting devices ED-1, ED-2 and ED-3 may include the fused polycyclic compound of an embodiment. Accordingly, at least one selected from among the light emitting devices ED-1, ED-2 and ED-3 may show a low driving voltage, high efficiency and long-life characteristics.

Compared with the display apparatus DD of an embodiment illustrated in FIG. 2, an embodiment illustrated in FIG. 10 has a difference in that the first to third light emitting devices ED-1, ED-2, and ED-3 each include two emission layers stacked in the thickness direction. In each of the first to third light emitting devices ED-1, ED-2, and ED-3, the two emission layers may be configured to emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. More specifically, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the emission auxiliary part OG and the electron transport region ETR. The second red emission layer EML-R2, the second green emission layer EML-G2, and the second blue emission layer EML-B2 may be disposed between the hole transport region HTR and the emission auxiliary part OG.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be disposed on the display device layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display apparatus according to an embodiment may not be provided.

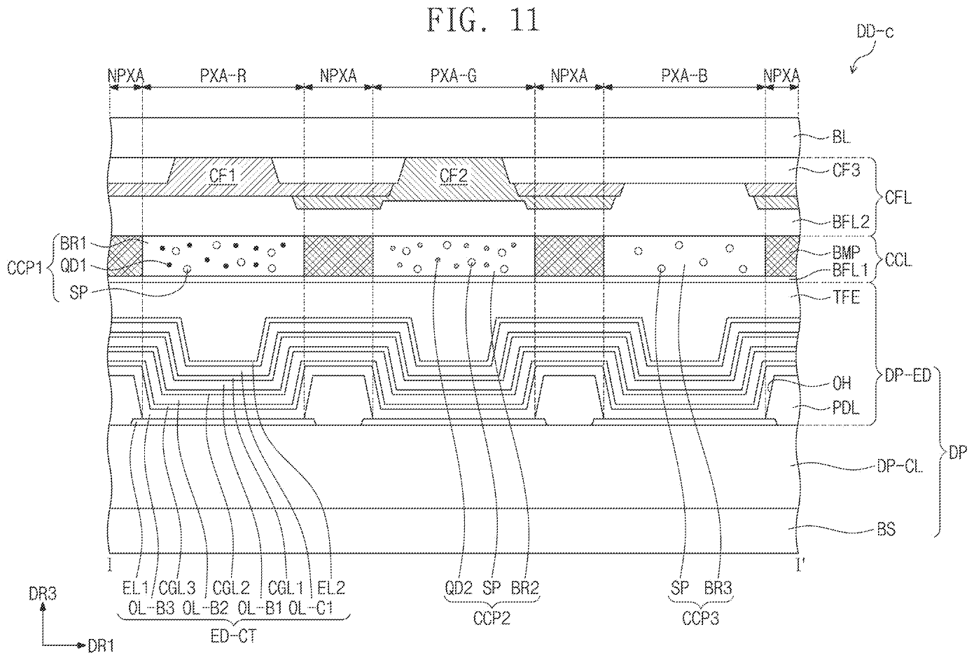

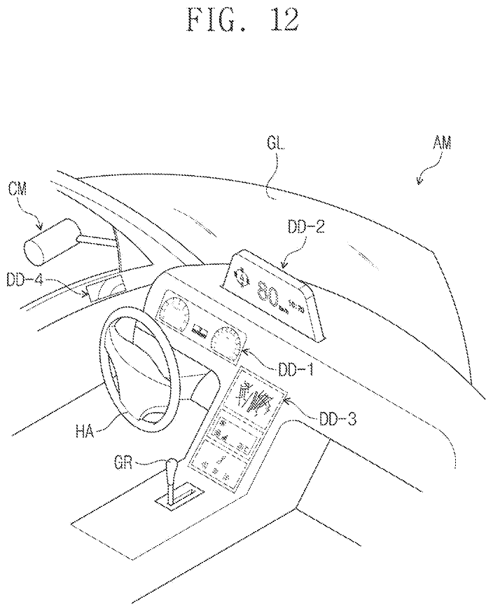

Different from FIG. 9 and FIG. 10, the display apparatus DD-c of FIG. 11 is shown to include four light emitting structures OL-B1, OL-B2, OL-B3 and OL-C1. The light emitting device ED-CT may include oppositely disposed first electrode EL1 and second electrode EL2, and first to fourth light emitting structures OL-B1, OL-B2, OL-B3 and OL-C1 stacked in order in a thickness direction between the first electrode EL1 and the second electrode EL2. At least one selected from among the first to fourth light emitting structures OL-B1, OL-B2, OL-B3 and OL-C1 may include the fused polycyclic compound of an embodiment. Accordingly, the light emitting device ED-CT may show a low driving voltage, high efficiency and long-life characteristics.

Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may be configured to emit blue light, and the fourth light emitting structure OL-C1 may be configured to emit green light. However, the embodiment of the present disclosure is not limited thereto, and the first to fourth light emitting structures OL-B1, OL-B2, OL-B3, and OL-C1 may be configured to emit light beams in different wavelength regions.

The charge generation layers CGL1, CGL2, and CGL3 disposed between adjacent light emitting structures OL-B1, OL-B2, OL-B3, and OL-C1 may include a p-type or kind charge generation layer and/or an n-type or kind charge generation layer.

In an embodiment, the electronic apparatus may include a display apparatus including a plurality of light emitting devices, and a control part which controls the display apparatus. The electronic apparatus of an embodiment may be a device that is activated according to an electrical signal. The electronic apparatus may include display apparatuses of one or more suitable embodiments. For example, the electronic apparatus may include not only large-sized electronic apparatuses such as a television set, a monitor, or an outdoor billboard but also include small- and medium-sized electronic apparatuses such as a personal computer, a laptop computer, a personal digital terminal, a display apparatus for a vehicle, a game console, a portable electronic device, or a camera.

FIG. 12 is a view illustrating a vehicle AM in which first to fourth display apparatuses DD-1, DD-2, DD-3, and DD-4 are disposed. At least one selected from among the first to fourth display apparatuses DD-1, DD-2, DD-3, and DD-4 may include the same configuration as the display apparatuses DD, DD-TD, DD-a, DD-b, and DD-c as described with reference to FIGS. 1, and 2, and 8 to 11.

FIG. 12 illustrates a vehicle AM, but this is an example, and the first to fourth display apparatuses DD-1, DD-2, DD-3, and DD-4 may be disposed in another transportation means such as bicycles, motorcycles, trains, ships, and airplanes. In some embodiments, at least one selected from among the first to fourth display apparatuses DD-1, DD-2, DD-3, and DD-4 including the same configuration as the display apparatuses DD, DD-TD, DD-a, DD-b, and DD-c of an embodiment may be employed in a personal computer, a laptop computer, a personal digital terminal, a game console, a portable electronic device, a television, a monitor, an outdoor billboard, and/or the like. In some embodiments, these are merely provided as embodiments, and thus may be employed in other electronic apparatuses unless departing from the present disclosure.

At least one selected from among first to fourth display apparatus DD-1, DD-2, DD-3 and DD-4 may include one of the light emitting devices ED explained referring to FIG. 3 to FIG. 7. At least one selected from among the first to fourth display apparatus DD-1, DD-2, DD-3 and DD-4 may include the fused polycyclic compound of an embodiment. The first to fourth display apparatus DD-1, DD-2, DD-3 and DD-4, including the fused polycyclic compound of an embodiment may show improved display efficiency and display lifetime.

Referring to FIG. 12, the vehicle AM may include a steering wheel HA and a gear GR for driving the vehicle AM. In some embodiments, the vehicle AM may include a front window GL disposed so as to face the driver.

The first display apparatus DD-1 may be disposed in a first region overlapping the steering wheel HA. For example, the first display apparatus DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, etc. A first scale and a second scale may be indicated as a digital image.

The second display apparatus DD-2 may be disposed in a second region facing the driver's seat and overlapping the front window GL. The driver's seat may be a seat in which the steering wheel HA is disposed. For example, the second display apparatus DD-2 may be a head up display (HUD) which displays second information of the vehicle AM. The second display apparatus DD-2 may be optically transparent. The second information may include digital numbers which indicate a driving speed, and may further include information such as the current time. Unlike the configuration illustrated, the second information of the second display apparatus DD-2 may be projected to the front window GL to be displayed.

The third display apparatus DD-3 may be disposed in a third region adjacent to the gear GR. For example, the third display apparatus DD-3 may be disposed between the driver's seat and the passenger seat and may be a center information display (CID) for a vehicle for displaying third information. The passenger seat may be a seat spaced apart from the driver's seat with the gear GR disposed therebetween. The third information may include information about traffic (e.g., navigation information), playing music or radio or a video (or an image), temperatures inside the vehicle AM, etc.

The fourth display apparatus DD-4 may be spaced apart from the steering wheel HA and the gear GR, and may be disposed in a fourth region adjacent to the side of the vehicle AM. For example, the fourth display apparatus DD-4 may be a digital side-view mirror which displays fourth information. The fourth display apparatus DD-4 may display an image outside the vehicle AM taken by a camera module CM disposed outside the vehicle AM. The fourth information may include an image outside the vehicle AM.

The previously described first to fourth information may be examples, and the first to fourth display apparatuses DD-1, DD-2, DD-3, and DD-4 may further display information about the inside and outside of the vehicle AM. The first to fourth information may include different information. However, the embodiment of the present disclosure is not limited thereto, and a part of the first to fourth information may include the same information as one another.

Hereinafter, referring to embodiments and comparative embodiments, the fused polycyclic compound according to the embodiments of the present disclosure and the light emitting device of an embodiment will be explained in particular. In some embodiments, the embodiments are illustrations to assist the understanding of the present disclosure, but the scope of the present disclosure is not limited thereto.

### EXAMPLES

### 1. Synthesis of Fused Polycyclic Compounds of Embodiments

The synthetic method of the compound according to an embodiment will be explained in particular illustrating the synthetic methods of Compounds 12, 47, 58, 69, 80, and 110. In some embodiments, the synthetic methods of the fused polycyclic compound explained hereinafter are embodiments, and the synthetic method of the fused polycyclic compound according to an embodiment of the present disclosure is not limited to the embodiments described herein.

### 1 Synthesis of Fused Polycyclic Compound 12

Fused Polycyclic Compound 12 according to an embodiment may be synthesized by, for example, the steps (e.g., acts or tasks) of Reaction 1.

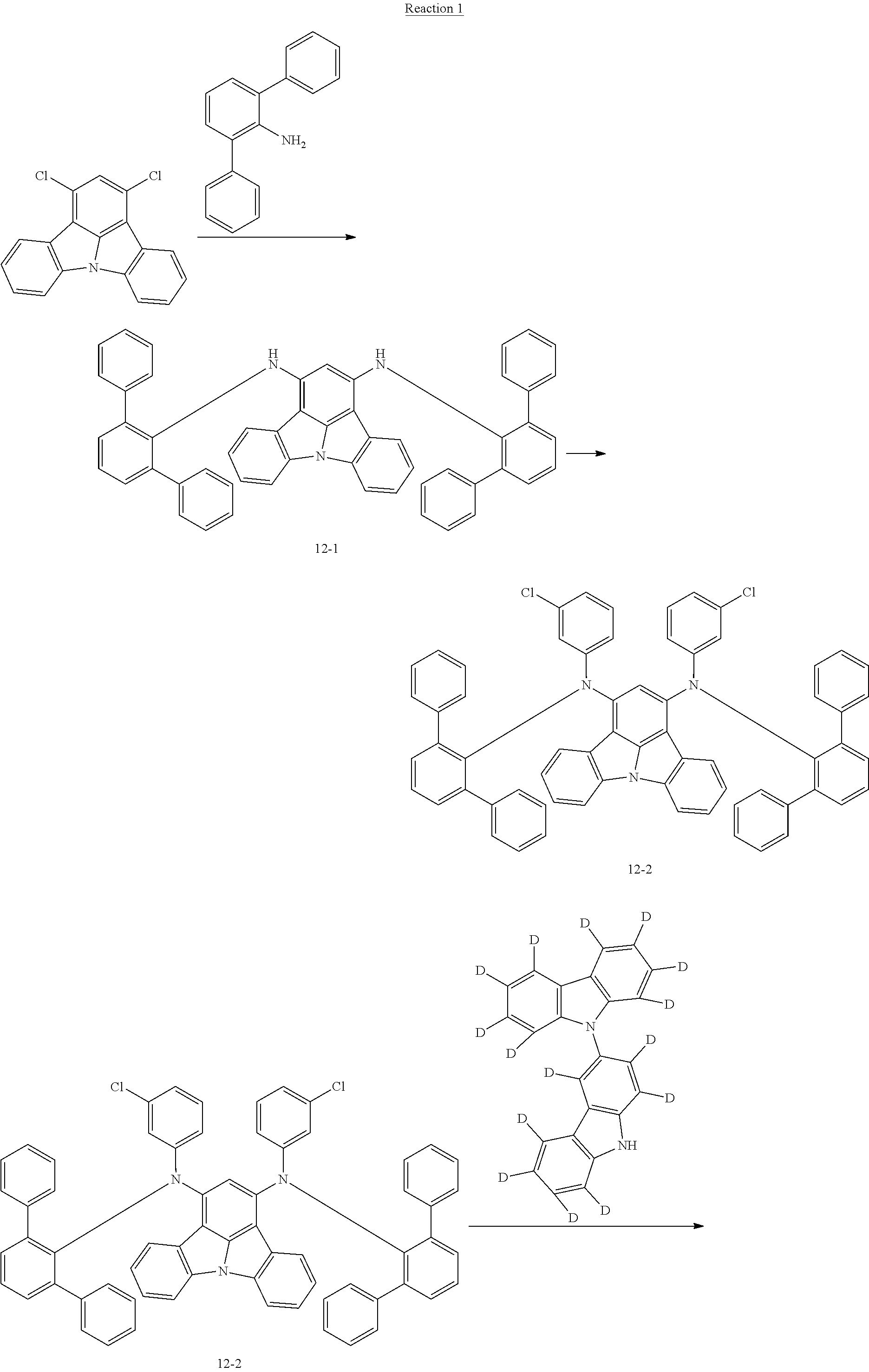

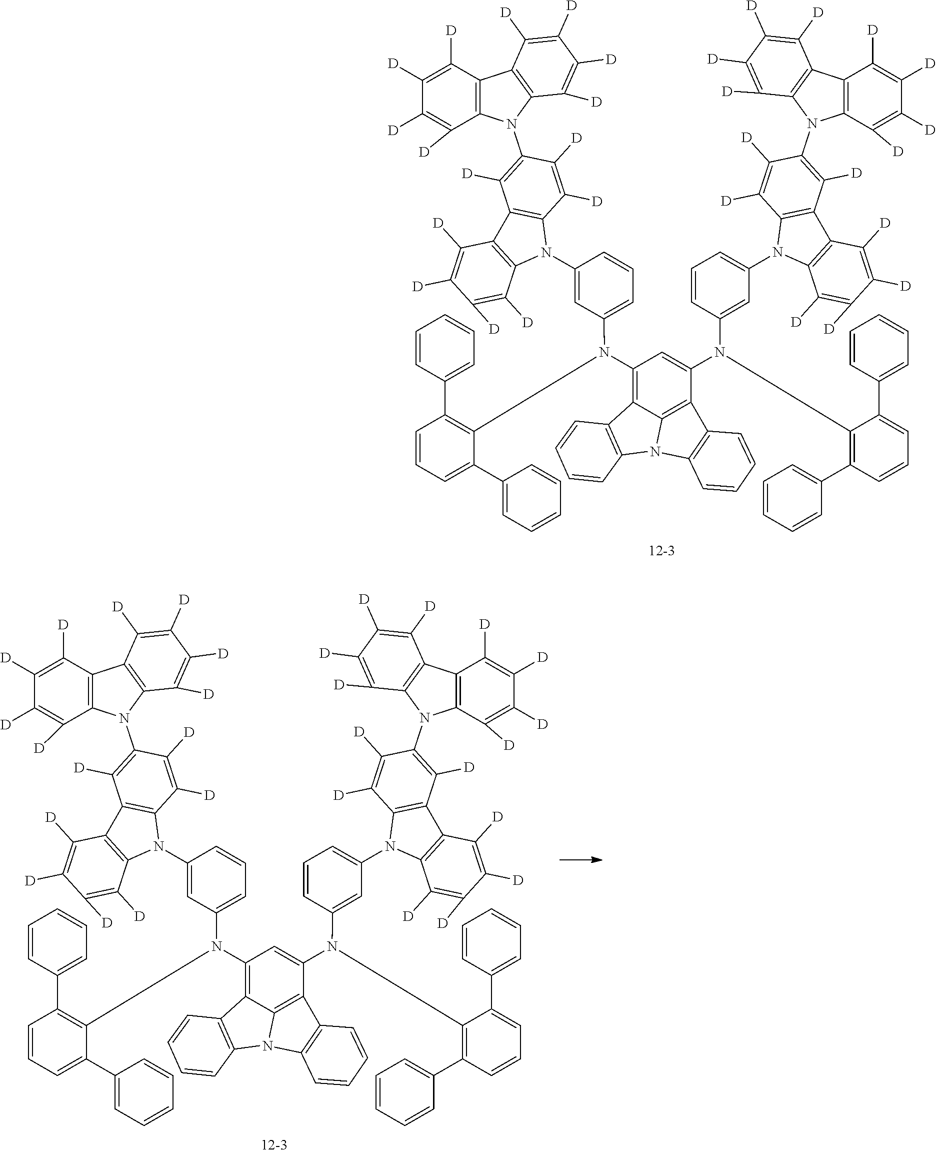

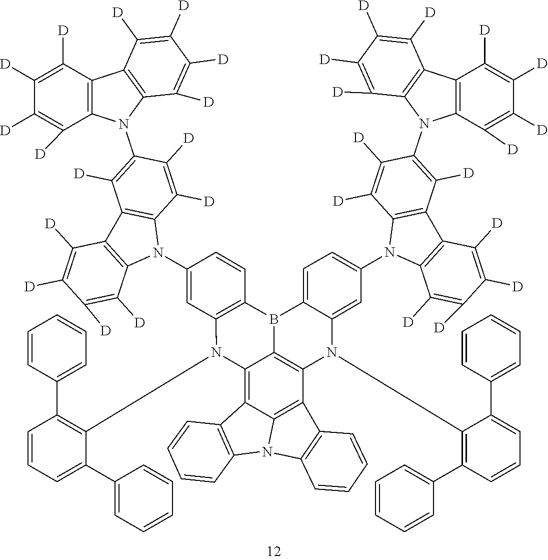 [SMILES: [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1ccc2c(c1)N(c1c(-c3ccccc3)cccc1-c1ccccc1)c1c3c(c4c5ccccc5n5c6ccccc6c1c45)N(c1c(-c4ccccc4)cccc1-c1ccccc1)c1cc(-n4c5c([2H])c([2H])c([2H])c([2H])c5c5c([2H])c(-n6c7c([2H])c([2H])c([2H])c([2H])c7c7c([2H])c([2H])c([2H])c([2H])c76)c([2H])c([2H])c54)ccc1B23]

### Synthesis of Intermediate 12-1

[1,1′: 3′,1″-Terphenyl]-2′-amine (2 eq), 1,3-dichloroindolo [3,2,1-jk] carbazole (1 eq), tris(dibenzylideneacetone) dipalladium (0) (0.05 eq), tri-tert-butylphosphine (0.1 eq), and sodium tert-butoxide (2 eq) were dissolved in o-xylene and stirred at about 140 degrees centigrade for about 10 hours. After cooling, the reaction product was washed with ethyl acetate and water three times (e.g., diluted with ethyl acetate and then washed three times with water or washed three times with ethyl acetate and water), and layer separation was performed to obtain an organic layer. The organic layer thus obtained was dried over MgSO₄ and dried under a reduced pressure. The crude product was purified by column chromatography utilizing methylene chloride (MC) and n-hexane to obtain Intermediate 12-1 (yield: 75%).

### Synthesis of Intermediate 12-2

1-Bromo-3-chlorobenzene (4 eq), Intermediate 12-1 (1 eq), tris(dibenzylideneacetone) dipalladium (0) (0.1 eq), tri-tert-butylphosphine (0.2 eq), and sodium tert-butoxide (3 eq) were dissolved in o-xylene and stirred at about 160 degrees centigrade for about 36 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 12-2 (yield: 83%).

### Synthesis of Intermediate 12-3

9H-3,9′-Bicarbazole-1,1′,2,2′,3′,4,4′,5,5′,6,6′,7,7′,8,8′-d15 (2.1 eq), Intermediate 12-2 (1 eq), tris(dibenzylideneacetone) dipalladium (0) (0.05 eq), tri-tert-butylphosphine (0.1 eq), and sodium tert-butoxide (3 eq) were dissolved in o-xylene and stirred at about 140 degrees centigrade for about 12 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 12-3 (yield: 80%).

### Synthesis of Compound 12

Intermediate 12-3 (1 eq) was dissolved in o-dichlorobenzene and cooled to about 0 degrees centigrade, and in a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwisely to a flask containing the reaction product to finish the reaction, and ethyl alcohol was added to the reaction product to precipitate. The precipitate was filtered to obtain a crude product. The solid thus obtained was purified by column chromatography utilizing MC and n-hexane to obtain Compound 12 (yield: 6%).

### 2 Synthesis of Fused Polycyclic Compound 47

Fused Polycyclic Compound 47 according to an embodiment may be synthesized by, for example, the steps of Reaction 2.

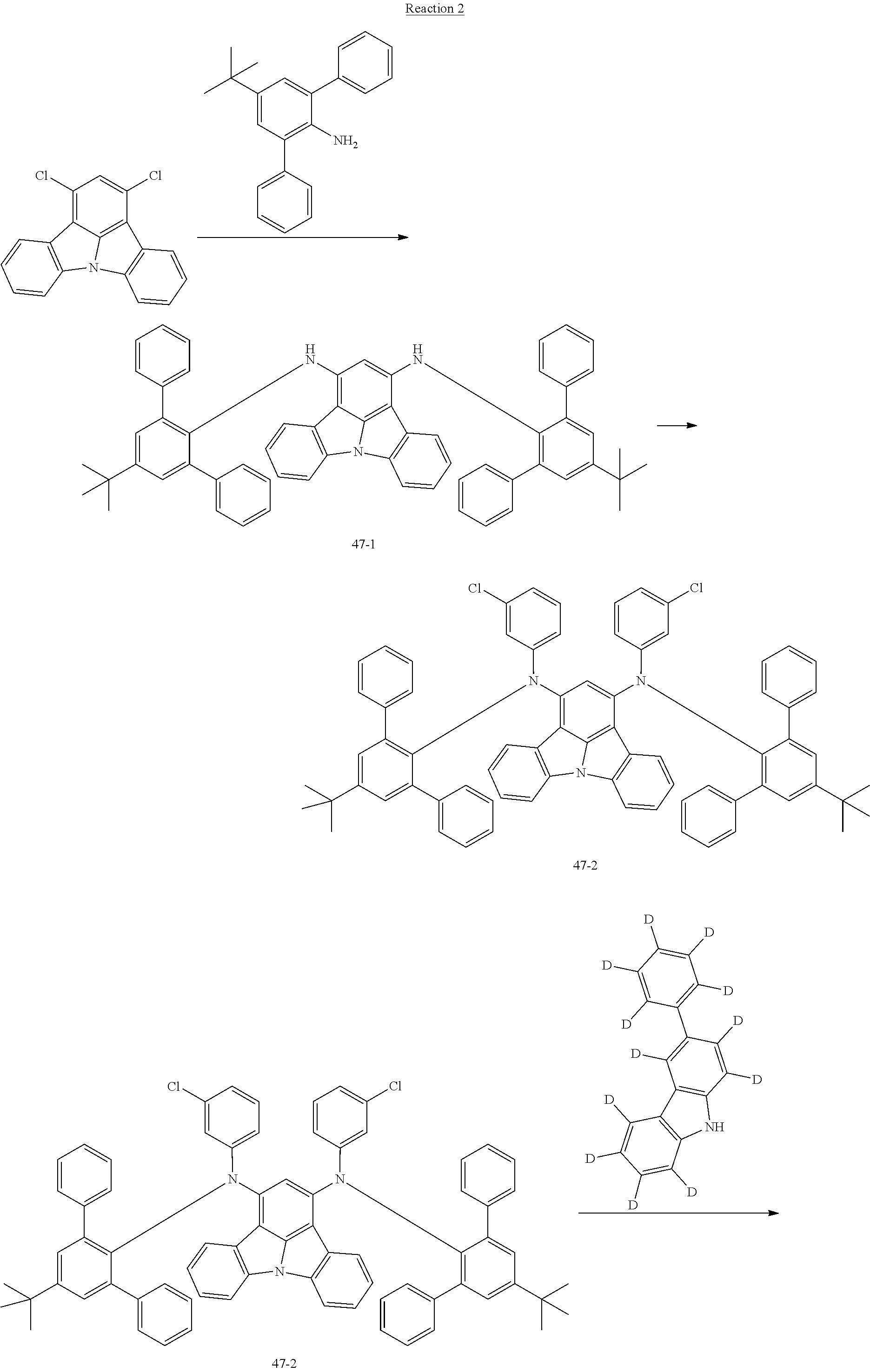

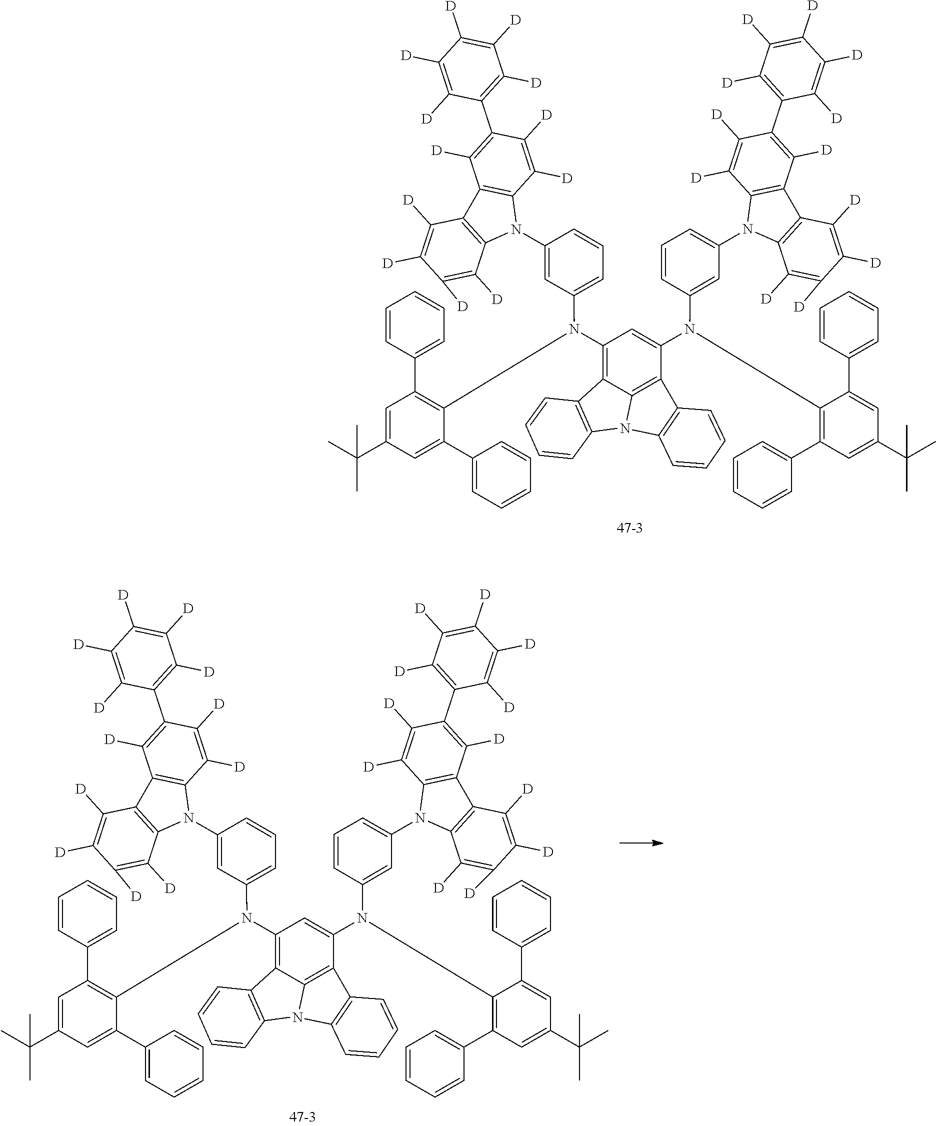

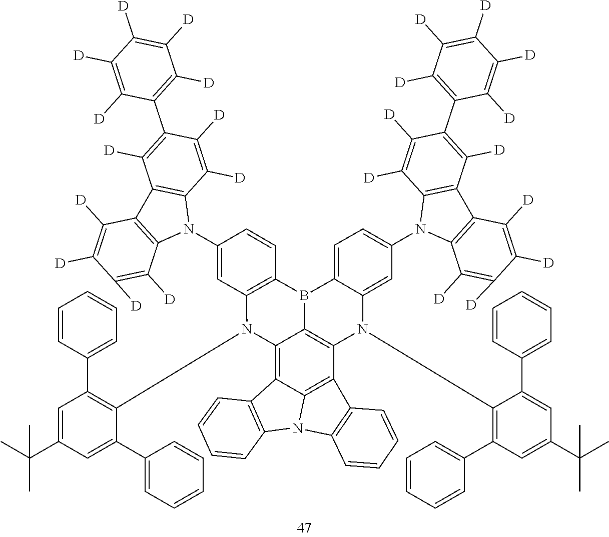 [SMILES: [2H]c1c([2H])c([2H])c(-c2c([2H])c([2H])c3c(c2[2H])c2c([2H])c([2H])c([2H])c([2H])c2n3-c2ccc3c(c2)N(c2c(-c4ccccc4)cc(C(C)(C)C)cc2-c2ccccc2)c2c4c(c5c6ccccc6n6c7ccccc7c2c56)N(c2c(-c5ccccc5)cc(C(C)(C)C)cc2-c2ccccc2)c2cc(-n5c6c([2H])c([2H])c([2H])c([2H])c6c6c([2H])c(-c7c([2H])c([2H])c([2H])c([2H])c7[2H])c([2H])c([2H])c65)ccc2B34)c([2H])c1[2H]]

### Synthesis of Intermediate 47-1

5′-(Tert-butyl)-[1,1′: 3′,1″-terphenyl]-2′-amine (2 eq), 1,3-dichloroindolo [3,2,1-jk] carbazole (1 eq), tris(dibenzylideneacetone) dipalladium (0) (0.05 eq), tri-tert-butylphosphine (0.1 eq), and sodium tert-butoxide (2 eq) were dissolved in o-xylene and stirred at about 140 degrees centigrade for about 10 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 47-1 (yield: 81%).

### Synthesis of Intermediate 47-2

1-Bromo-3-chlorobenzene (4 eq), Intermediate 47-1 (1 eq), tris(dibenzylideneacetone) dipalladium (0) (0.1 eq), tri-tert-butylphosphine (0.2 eq), and sodium tert-butoxide (3 eq) were dissolved in o-xylene and stirred at about 160 degrees centigrade for about 36 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 47-2 (yield: 78%).

### Synthesis of Intermediate 47-3

3-(Phenyl-d5)-9H-carbazole-1,2,4,5,6,7,8-d7 (2 eq), Intermediate 47-2 (1 eq), tris(dibenzylideneacetone) dipalladium (0) (0.05 eq), tri-tert-butylphosphine (0.1 eq), and sodium tert-butoxide (3 eq) were dissolved in o-xylene and stirred at about 140 degrees centigrade for about 12 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 47-3 (yield: 78%).

### Synthesis of Compound 47

Intermediate 47-3 (1 eq) was dissolved in o-dichlorobenzene and cooled to about 0 degrees centigrade, and in a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwisely to a flask containing the reaction product to finish the reaction, and ethyl alcohol was added to the reaction product to precipitate. The precipitate was filtered to obtain a crude product. The solid thus obtained was purified by column chromatography utilizing MC and n-hexane to obtain Compound 47 (yield: 5%).

### 3 Synthesis of Fused Polycyclic Compound 58

Fused Polycyclic Compound 58 according to an embodiment may be synthesized by, for example, the steps of Reaction 3.

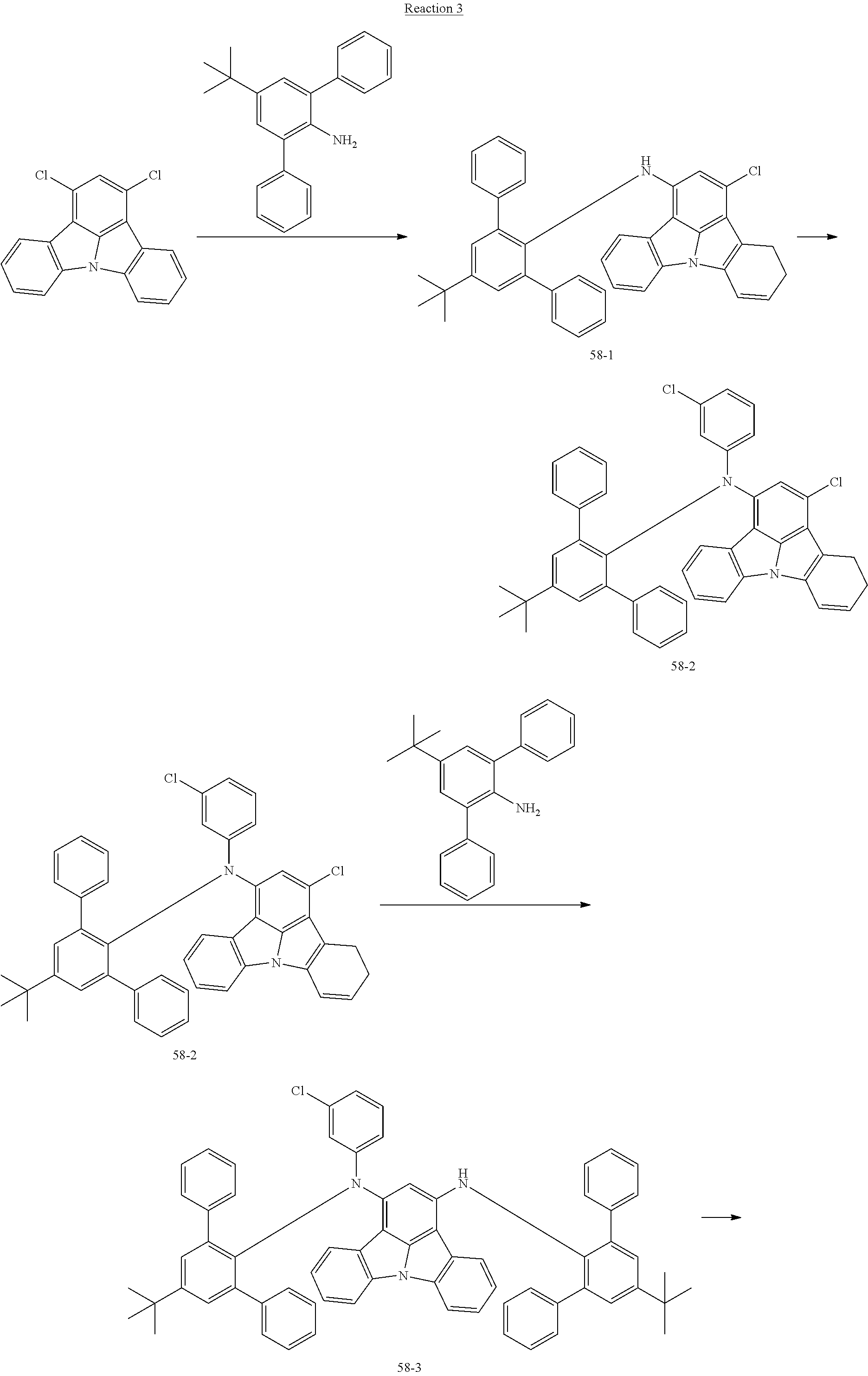

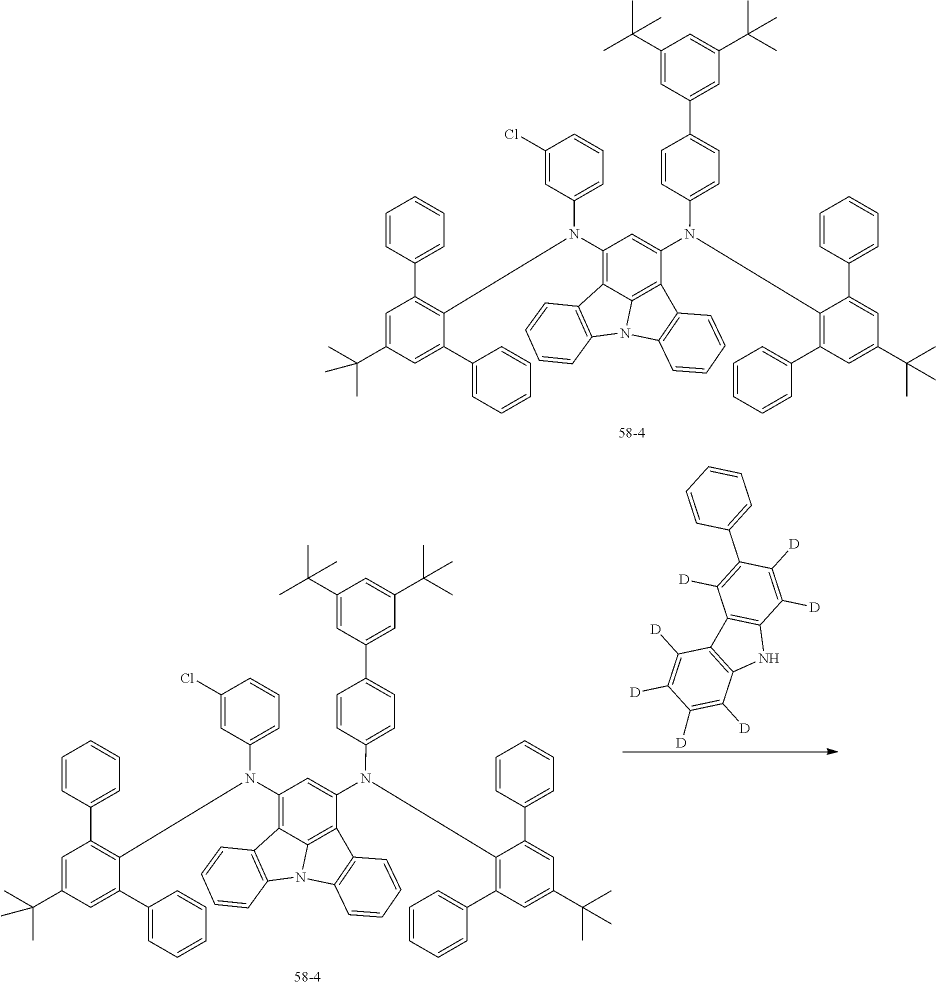

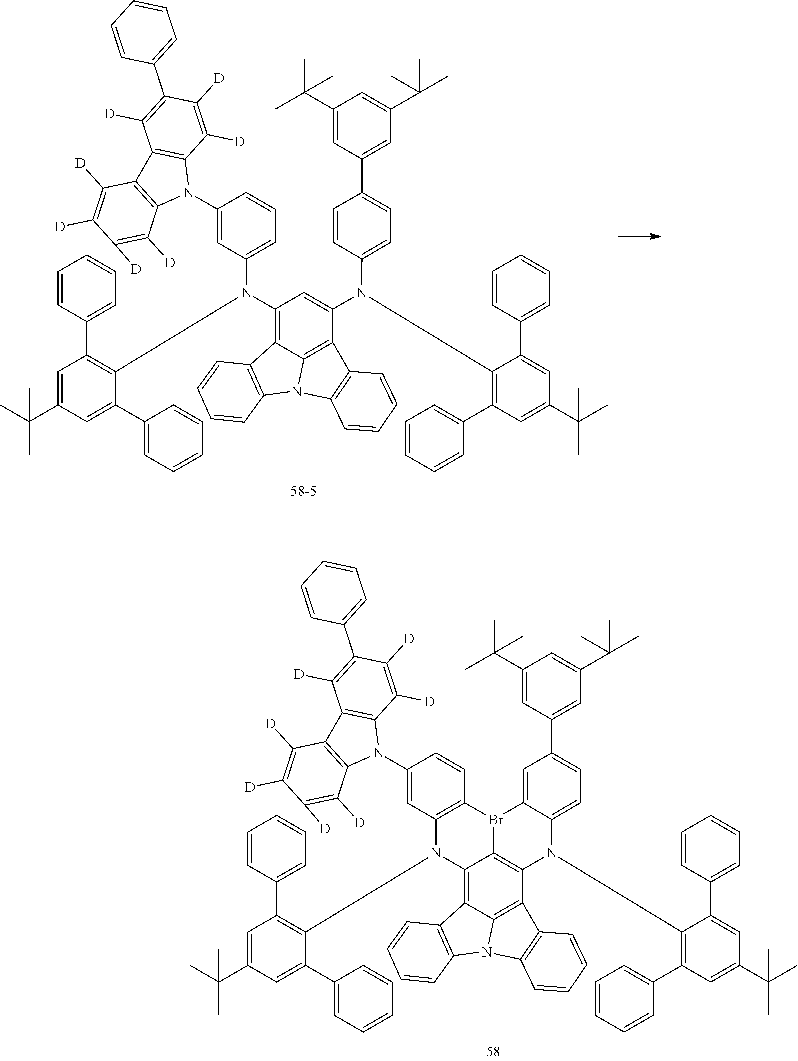

### Synthesis of Intermediate 58-1

5′-(Tert-butyl)-[1,1′: 3′,1″-terphenyl]-2′-amine (1 eq), 1,3-dichloroindolo [3,2,1-jk] carbazole (1 eq), tris(dibenzylideneacetone) dipalladium (0) (0.05 eq), 2,2′-bis(diphenylphosphino)-1,1′-binaphthyl(BINAP, 0.1 eq), and sodium tert-butoxide (2 eq) were dissolved in o-xylene and stirred at about 140 degrees centigrade for about 10 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 58-1 (yield: 73%).

### Synthesis of Intermediate 58-2

1-Bromo-3-chlorobenzene (3 eq), Intermediate 58-1 (1 eq), tris(dibenzylideneacetone) dipalladium (0) (0.1 eq), tri-tert-butylphosphine (0.2 eq), and sodium tert-butoxide (3 eq) were dissolved in o-xylene and stirred at about 160 degrees centigrade for about 36 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 58-2 (yield: 77%).

### Synthesis of Intermediate 58-3

5′-(Tert-butyl)-[1,1′: 3′,1″-terphenyl]-2′-amine (1 eq), Intermediate 58-2 (1 eq), tris(dibenzylideneacetone) dipalladium (0) (0.05 eq), tri-tert-butylphosphine (0.1 eq), and sodium tert-butoxide (2 eq) were dissolved in o-xylene and stirred at about 140 degrees centigrade for about 10 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 58-3 (yield: 84%).

### Synthesis of Intermediate 58-4

3,5-Di-tert-butyl-4′-iodo-1,1′-biphenyl (4 eq), Intermediate 58-3 (1 eq), tris(dibenzylideneacetone) dipalladium (0) (0.1 eq), tri-tert-butylphosphine (0.2 eq), and sodium tert-butoxide (3 eq) were dissolved in o-xylene and stirred at about 160 degrees centigrade for about 36 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 58-4 (yield: 79%).

### Synthesis of Intermediate 58-5

3-Phenyl-9H-carbazole-1,2,4,5,6,7,8-d7 (1 eq), Intermediate 58-4 (1 eq), tris(dibenzylideneacetone) dipalladium (0) (0.05 eq), tri-tert-butylphosphine (0.1 eq), and sodium tert-butoxide (2 eq) were dissolved in o-xylene and stirred at about 140 degrees centigrade for about 10 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 58-5 (yield: 83%).

### Synthesis of Compound 58

Intermediate 58-5 (1 eq) was dissolved in o-dichlorobenzene and cooled to about 0 degrees centigrade, and in a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwisely to a flask containing the reaction product to finish the reaction, and ethyl alcohol was added to the reaction product to precipitate. The precipitate was filtered to obtain a crude product. The solid thus obtained was purified by column chromatography utilizing MC and n-hexane to obtain Compound 58 (yield: 5%).

### 4 Synthesis of Fused Polycyclic Compound 69

Fused Polycyclic Compound 69 according to an embodiment may be synthesized by, for example, the steps of Reaction 4.

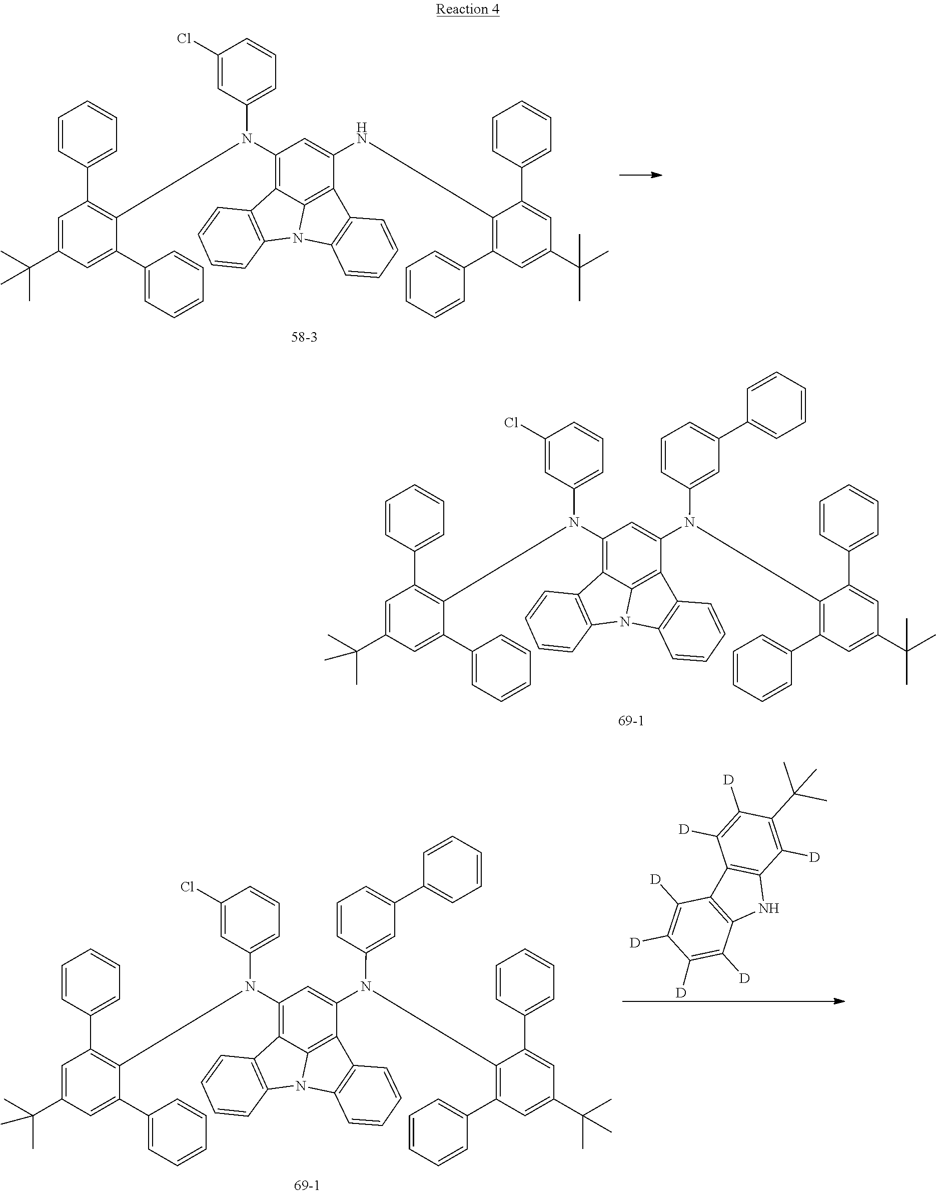

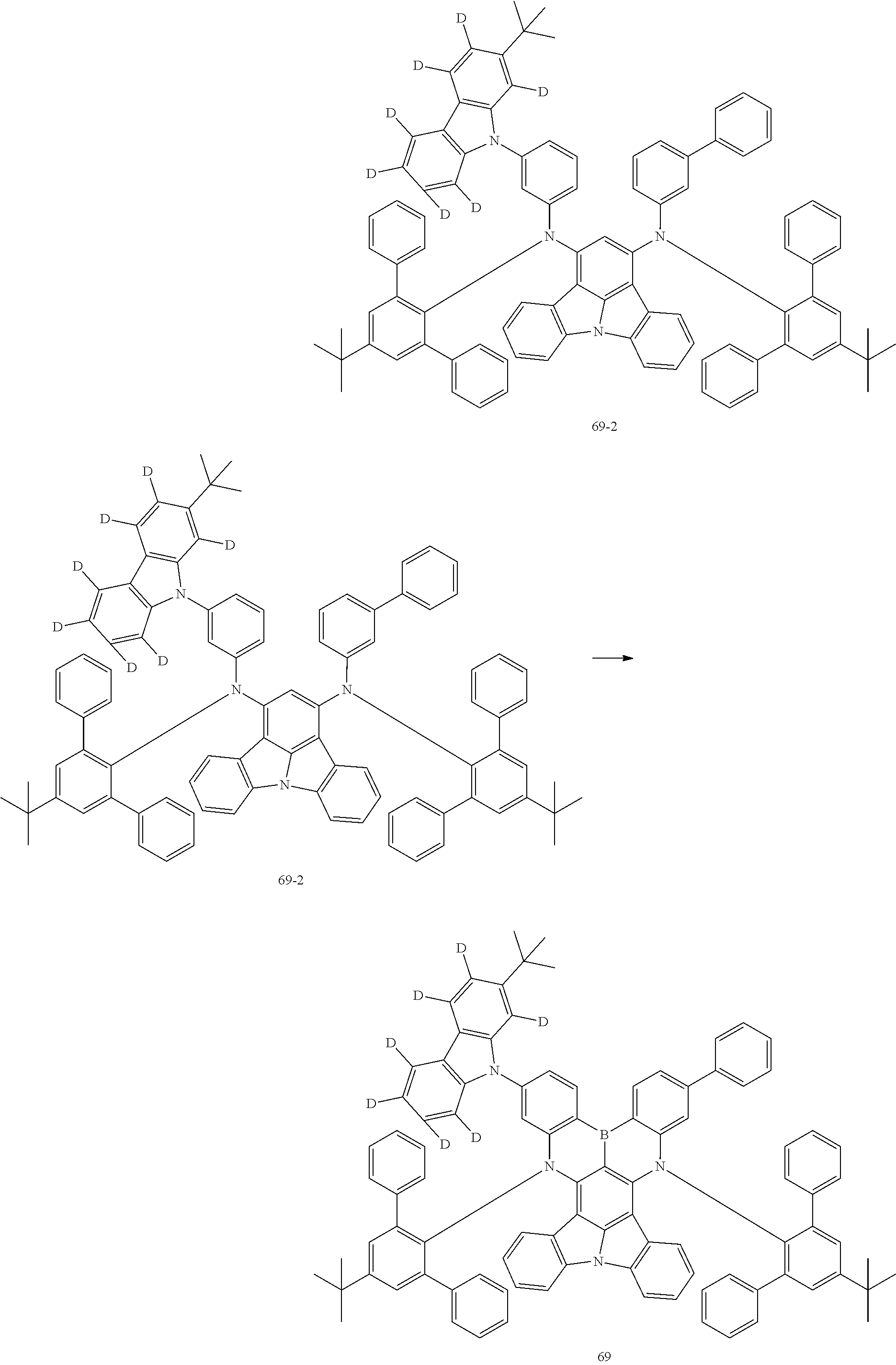

### Synthesis of Intermediate 69-1

3-lodo-1,1′-biphenyl (4 eq), Intermediate 58-3 (1 eq), tris(dibenzylideneacetone) dipalladium (0) (0.1 eq), tri-tert-butylphosphine (0.2 eq), and sodium tert-butoxide (3 eq) were dissolved in o-xylene and stirred at about 160 degrees centigrade for about 36 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 69-1 (yield: 82%).

### Synthesis of Intermediate 69-2

2-(Tert-butyl)-9H-carbazole-1,3,4,5,6,7,8-d7 (1 eq), Intermediate 69-1 (1 eq), tris(dibenzylideneacetone) dipalladium (0) (0.05 eq), tri-tert-butylphosphine (0.1 eq), and sodium tert-butoxide (2 eq) were dissolved in o-xylene and stirred at about 140 degrees centigrade for about 10 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 69-2 (yield: 81%).

### Synthesis of Compound 69

Intermediate 69-2 (1 eq) was dissolved in o-dichlorobenzene and cooled to about 0 degrees centigrade, and in a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwisely to a flask containing the reaction product to finish the reaction, and ethyl alcohol was added to the reaction product to precipitate. The precipitate was filtered to obtain a crude product. The solid thus obtained was purified by column chromatography utilizing MC and n-hexane to obtain Compound 69 (yield: 6%).

### 5 Synthesis of Fused Polycyclic Compound 80

Fused Polycyclic Compound 80 according to an embodiment may be synthesized by, for example, the steps of Reaction 5.

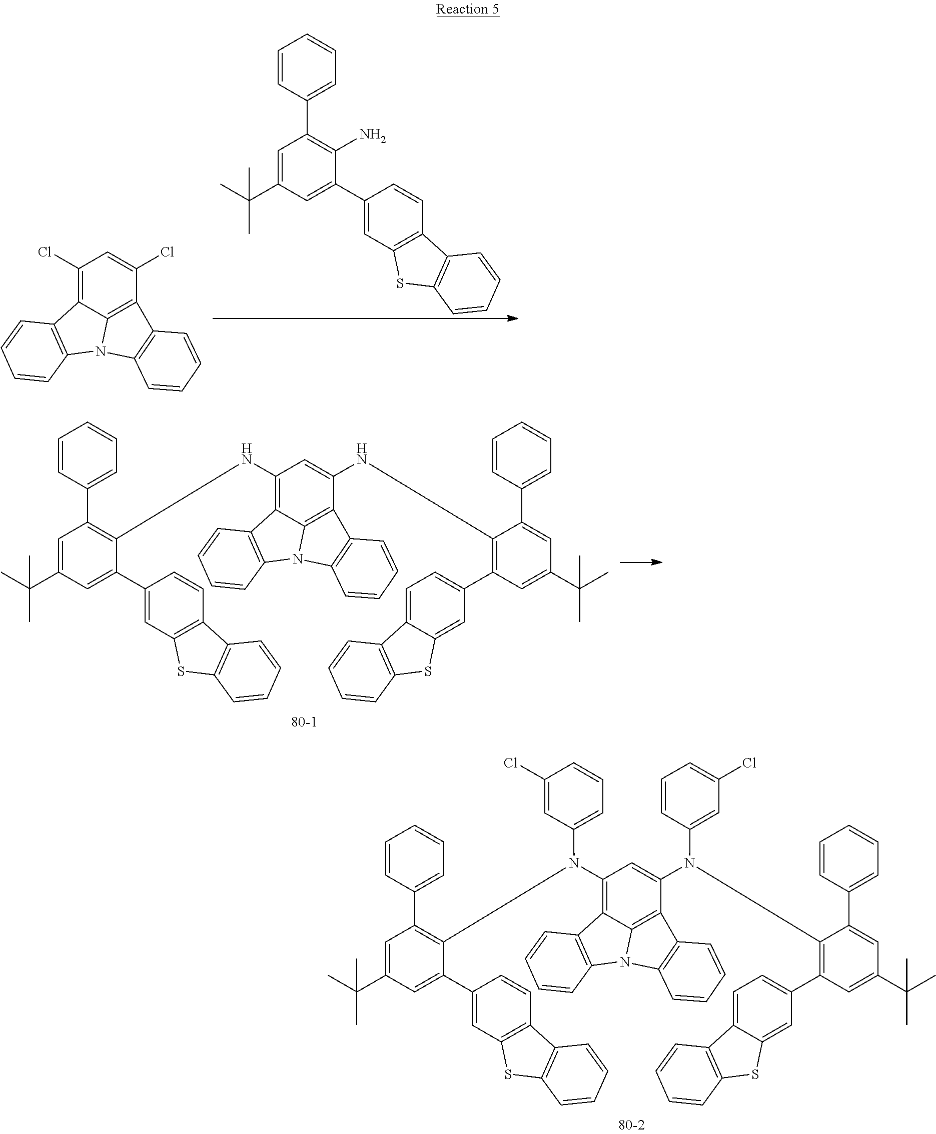

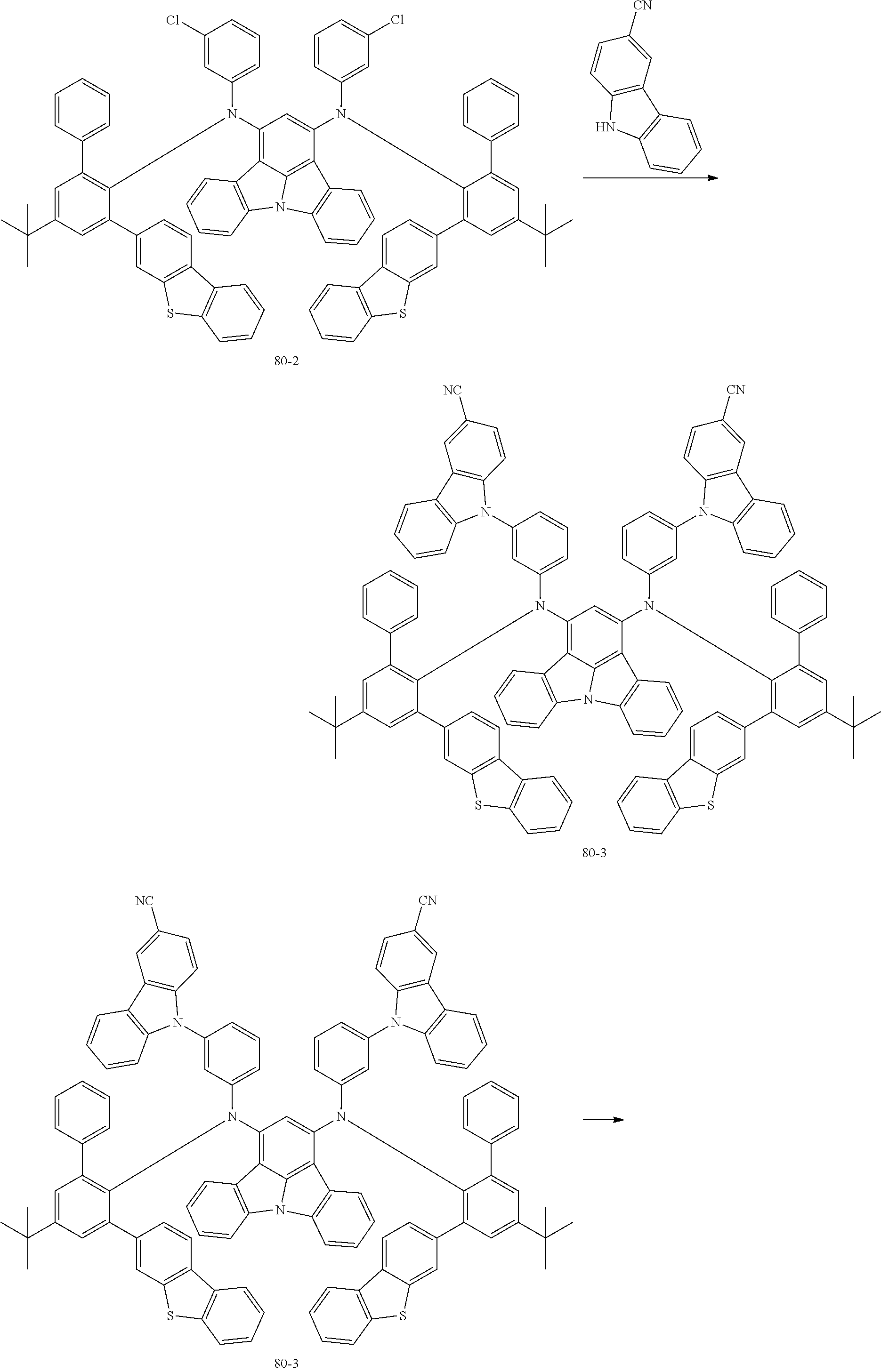

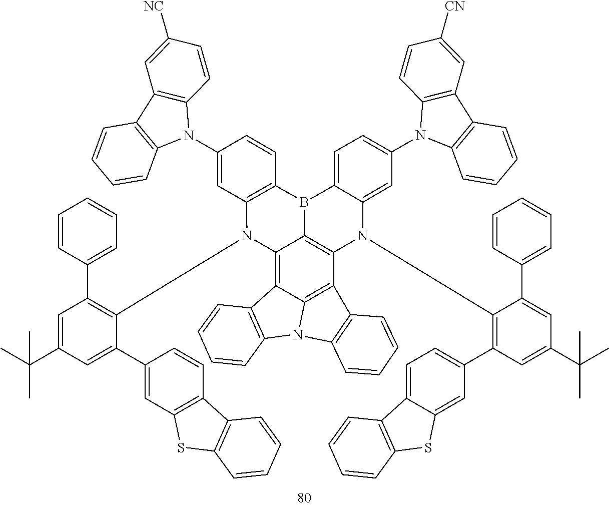 [SMILES: CC(C)(C)c1cc(-c2ccccc2)c(N2c3cc(-n4c5ccccc5c5cc(C#N)ccc54)ccc3B3c4ccc(-n5c6ccccc6c6cc(C#N)ccc65)cc4N(c4c(-c5ccccc5)cc(C(C)(C)C)cc4-c4ccc5c(c4)sc4ccccc45)c4c3c2c2c3ccccc3n3c5ccccc5c4c23)c(-c2ccc3c(c2)sc2ccccc23)c1]

### Synthesis of Intermediate 80-1

5-(Tert-butyl)-3-(dibenzo[b,d] thiophen-3-yl)-[1,1′-biphenyl]-2-amine (2 eq), 1,3-dichloroindolo [3,2,1-jk] carbazole (1 eq), tris(dibenzylideneacetone) dipalladium (0) (0.05 eq), tri-tert-butylphosphine (0.1 eq), and sodium tert-butoxide (2 eq) were dissolved in o-xylene and stirred at about 140 degrees centigrade for about 10 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 80-1 (yield: 73%).

### Synthesis of Intermediate 80-2

1-Bromo-3-chlorobenzene (4 eq), Intermediate 80-1 (1 eq), tris(dibenzylideneacetone) dipalladium (0) (0.1 eq), tri-tert-butylphosphine (0.2 eq), and sodium tert-butoxide (3 eq) were dissolved in o-xylene and stirred at about 160 degrees centigrade for about 36 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 80-2 (yield: 79%).

### Synthesis of Intermediate 80-3

9H-Carbazole-3-carbonitrile (2.1 eq), Intermediate 80-2 (1 eq), tris(dibenzylideneacetone) dipalladium (0) (0.05 eq), tri-tert-butylphosphine (0.1 eq), and sodium tert-butoxide (3 eq) were dissolved in o-xylene and stirred at about 140 degrees centigrade for about 12 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 80-3 (yield: 82%).

### Synthesis of Compound 80

Intermediate 80-3 (1 eq) was dissolved in o-dichlorobenzene and cooled to about 0 degrees centigrade, and in a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwisely to a flask containing the reaction product to finish the reaction, and ethyl alcohol was added to the reaction product to precipitate. The precipitate was filtered to obtain a crude product. The solid thus obtained was purified by column chromatography utilizing MC and n-hexane to obtain Compound 80 (yield: 4%).

### 6 Synthesis of Fused Polycyclic Compound 110

Fused Polycyclic Compound 110 according to an embodiment may be synthesized by, for example, the steps of Reaction 6.

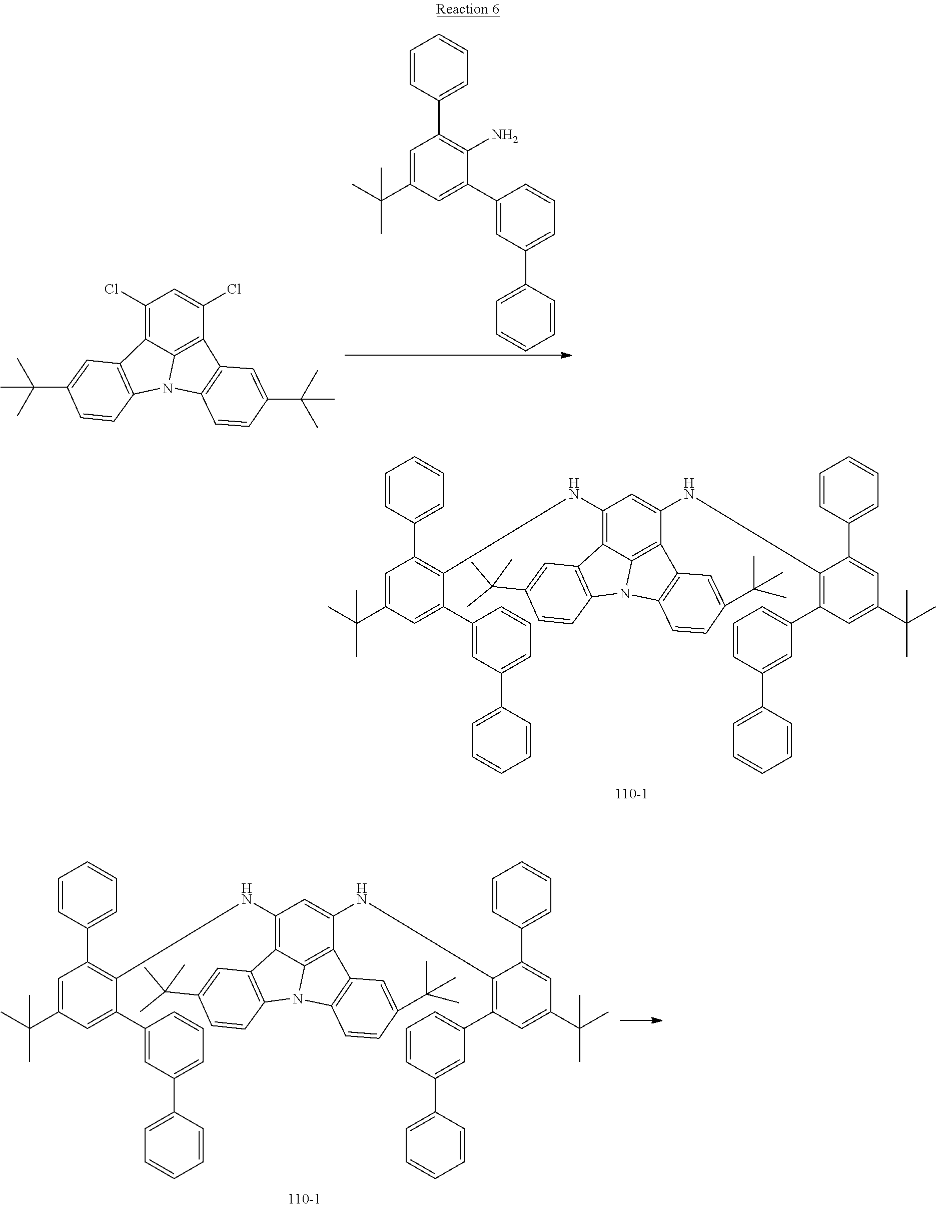

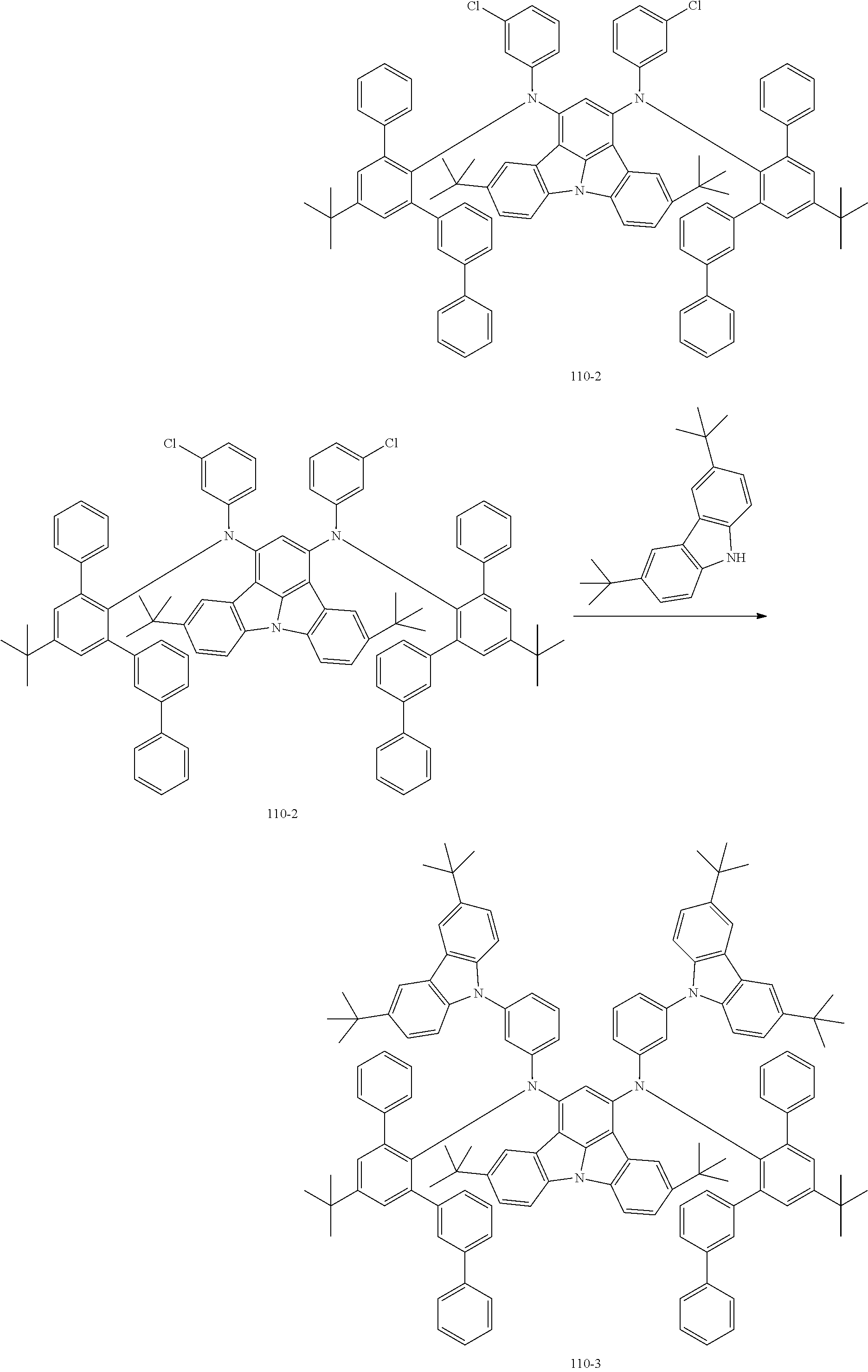

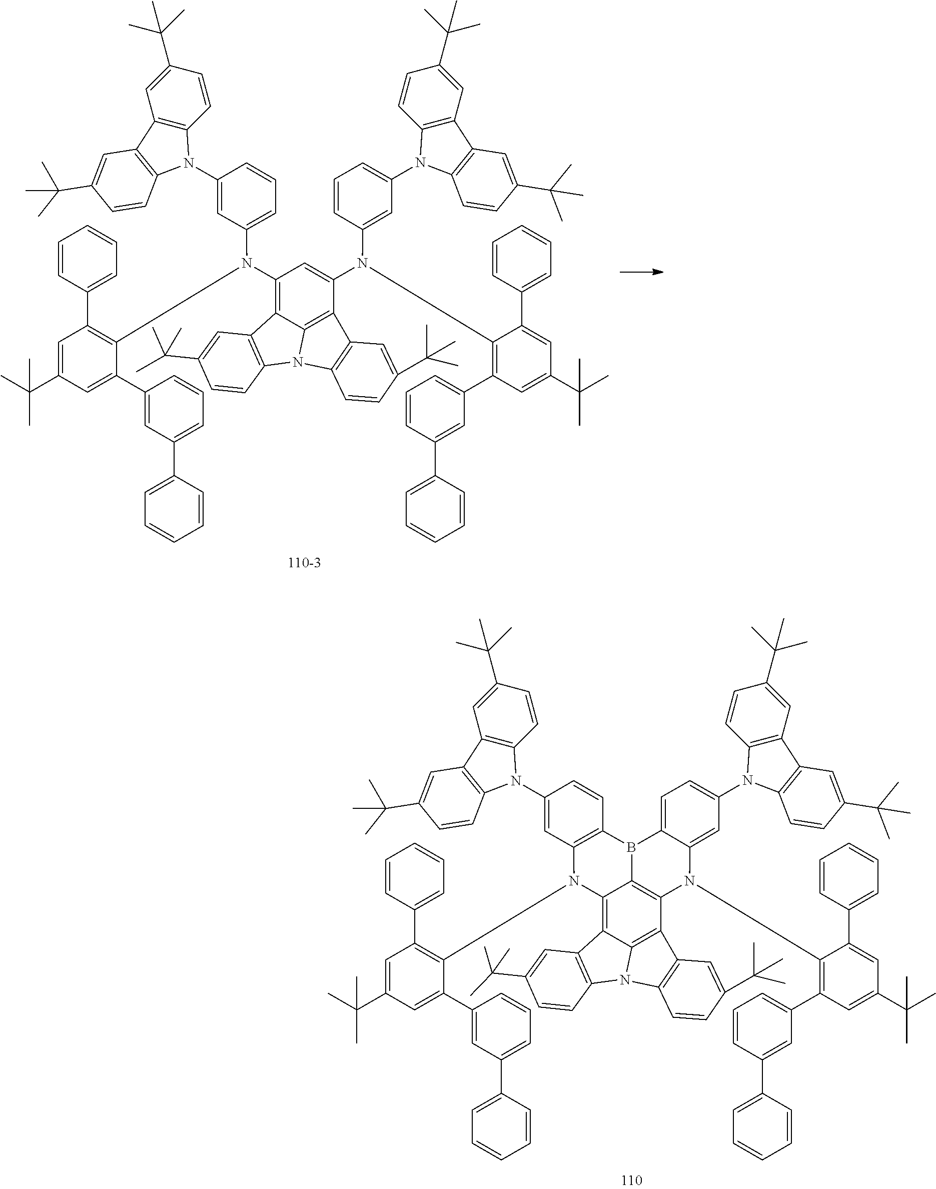

### Synthesis of Intermediate 110-1

5′-(Tert-butyl)-[1,1′: 3′,1″: 3″,1′″-quaterphenyl]-2′-amine (2 eq), 5,11-di-tert-butyl-1,3-dichloroindolo [3,2,1-jk] carbazole (1 eq), tris(dibenzylideneacetone) dipalladium (0) (0.05 eq), tri-tert-butylphosphine (0.1 eq), and sodium tert-butoxide (2 eq) were dissolved in o-xylene and stirred at about 140 degrees centigrade for about 10 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 110-1 (yield: 78%).

### Synthesis of Intermediate 110-2

1-Bromo-3-chlorobenzene (4 eq), Intermediate 110-1 (1 eq), tris(dibenzylideneacetone) dipalladium (0) (0.1 eq), tri-tert-butylphosphine (0.2 eq), and sodium tert-butoxide (3 eq) were dissolved in o-xylene and stirred at about 160 degrees centigrade for about 36 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 110-2 (yield: 81%).

### Synthesis of Intermediate 110-3

3,6-Di-tert-butyl-9H-carbazole (2.1 eq), Intermediate 110-2 (1 eq), tris(dibenzylideneacetone) dipalladium (0) (0.05 eq), tri-tert-butylphosphine (0.1 eq), and sodium tert-butoxide (3 eq) were dissolved in o-xylene and stirred at about 140 degrees centigrade for about 12 hours. After cooling, the reaction product was washed with ethyl acetate and water three times, and layer separation was performed to obtain an organic layer. The organic layer thus obtained was dried over MgSO₄ and dried under a reduced pressure. The crude product was purified by column chromatography utilizing MC and n-hexane to obtain Intermediate 110-3 (yield: 84%).

### 1 Synthesis of Compound 110

Intermediate 110-3 (1 eq) was dissolved in o-dichlorobenzene and cooled to about 0 degrees centigrade, and in a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwisely to a flask containing the reaction product to finish the reaction, and ethyl alcohol was added to the reaction product to precipitate. The precipitate was filtered to obtain a crude product. The solid thus obtained was purified by column chromatography utilizing MC and n-hexane to obtain Compound 110 (yield: 4%).

### 2. Manufacture and Evaluation of Light Emitting Devices

### 1 Manufacture of Light Emitting Devices

Light emitting devices of embodiments including the fused polycyclic compounds of embodiments or Comparative Compounds in emission layers were manufactured by a method. The light emitting devices of Examples 1 to 12 were manufactured utilizing Example Compounds 12, 47, 58, 69, 80 and 110, which are fused polycyclic compounds of embodiments, as the dopant materials of emission layers. The light emitting devices of Comparative Examples 1 to 4 were manufactured utilizing Comparative Compounds CX1 to CX4 as the dopant materials of emission layers.

As a first electrode, a glass substrate on which an ITO electrode of about 15 Ω/cm² (1200 Å) was formed (product of Corning Co.) was cut into a size of 50 mm×50 mm×0.7 mm, washed by ultrasonic waves utilizing isopropyl alcohol and distilled water for about 5 minutes each, and cleaned by irradiating ultraviolet rays for about 30 minutes and ozone. After that, the glass substrate was installed in a vacuum deposition apparatus.

On the first electrode, a hole injection layer with a thickness of about 300 Å was formed by depositing NPD, and on the hole injection layer, a hole transport layer with a thickness of about 200 Å was formed by depositing H-1-1. On the hole transport layer, an emission auxiliary layer with a thickness of about 100 Å was formed by depositing CzSi.

On the emission auxiliary layer, a host mixture of a first host (HT) and a second host (ET) in a weight ratio of about 5:5, a sensitizer, and a dopant were co-deposited in a weight ratio of about 85:14: 1 to form an emission layer with a thickness of about 200 Å. The dopant utilized the Example Compounds or Comparative Compounds.

On the emission layer, a hole blocking layer with a thickness of about 200 Å was formed by depositing TSPO1. Then, on the hole blocking layer, an electron transport layer with a thickness of about 300 Å was formed by depositing TPBi. On the electron transport layer, an electron injection layer with a thickness of about 10 Å was formed by depositing LiF, and on the electron injection layer, Al was deposited to form a second electrode with a thickness of about 3000 Å, to form a light emitting device.

### Materials Used for the Manufacture of Light Emitting Devices

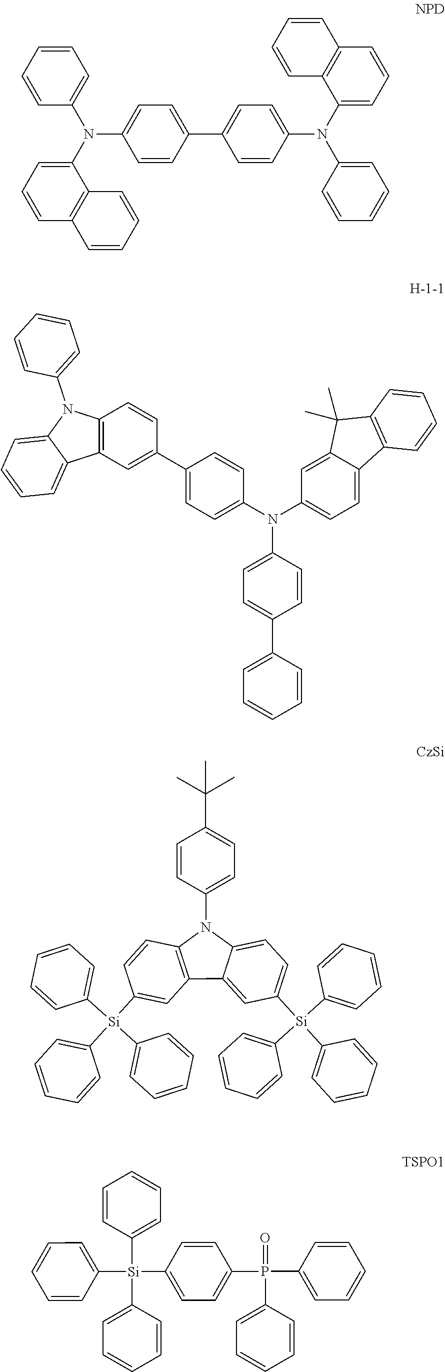 [SMILES: c1ccc(N(c2ccc(-c3ccc(N(c4ccccc4)c4cccc5ccccc45)cc3)cc2)c2cccc3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC(C)(C)c1ccc(-n2c3ccc([Si](c4ccccc4)(c4ccccc4)c4ccccc4)cc3c3cc([Si](c4ccccc4)(c4ccccc4)c4ccccc4)ccc32)cc1 ; O=P(c1ccccc1)(c1ccccc1)c1ccc([Si](c2ccccc2)(c2ccccc2)c2ccccc2)cc1]

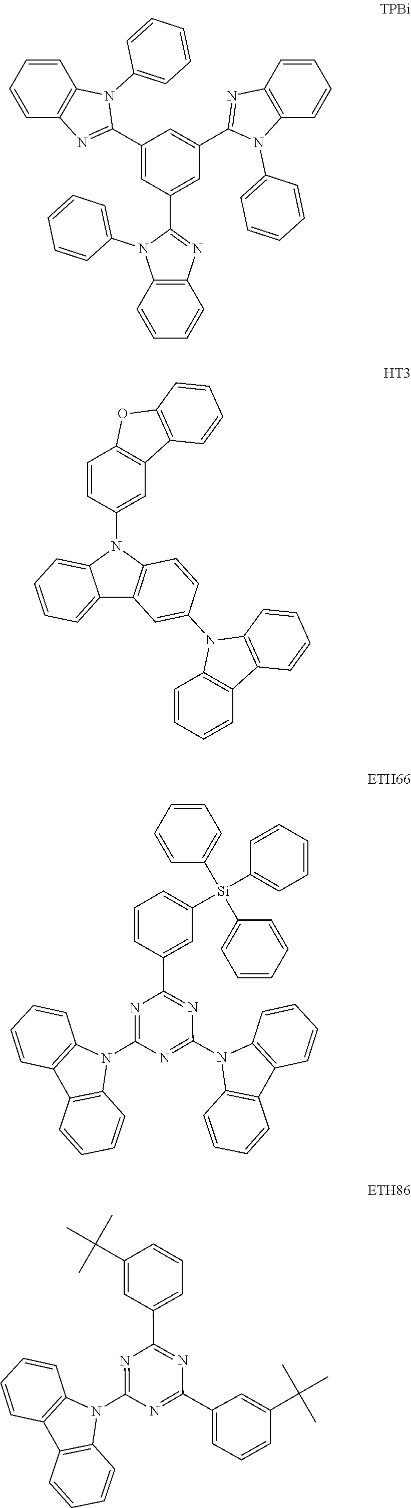

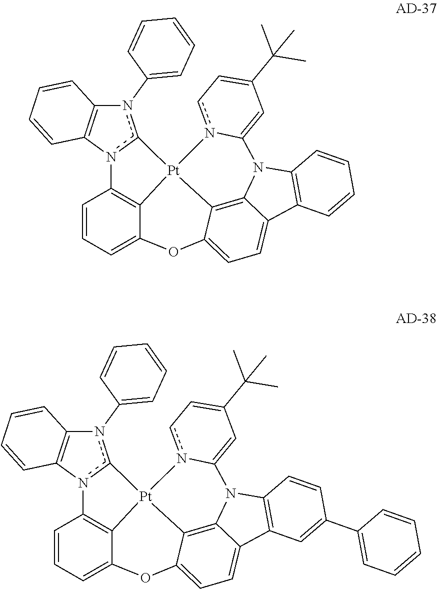

### Example Compounds

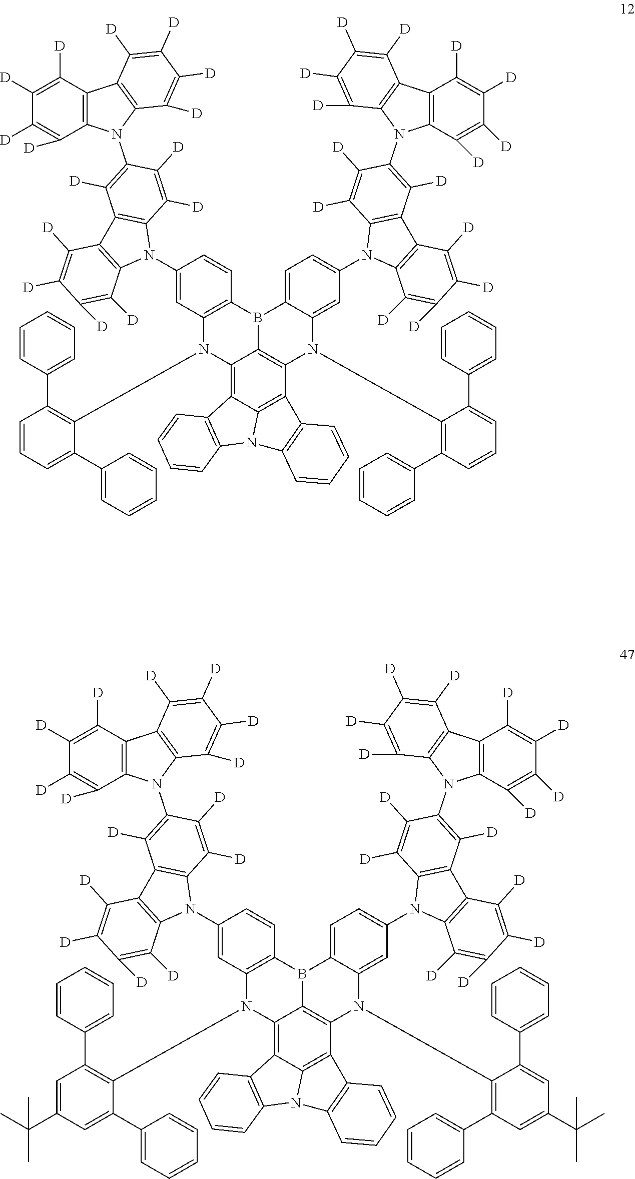

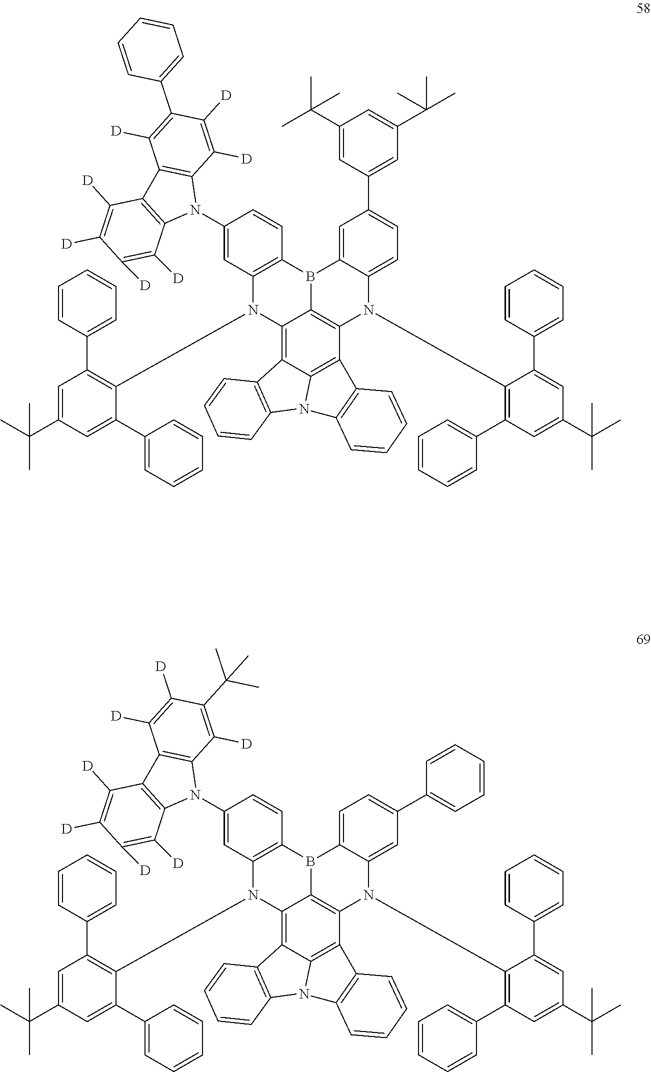

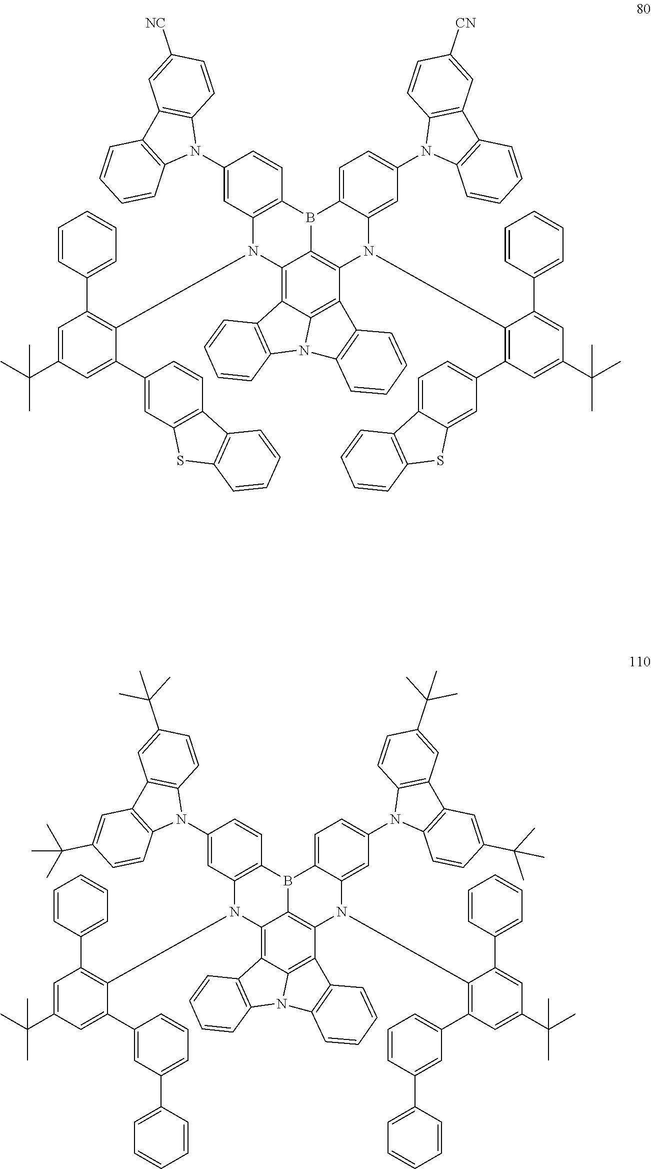

### Comparative Compounds

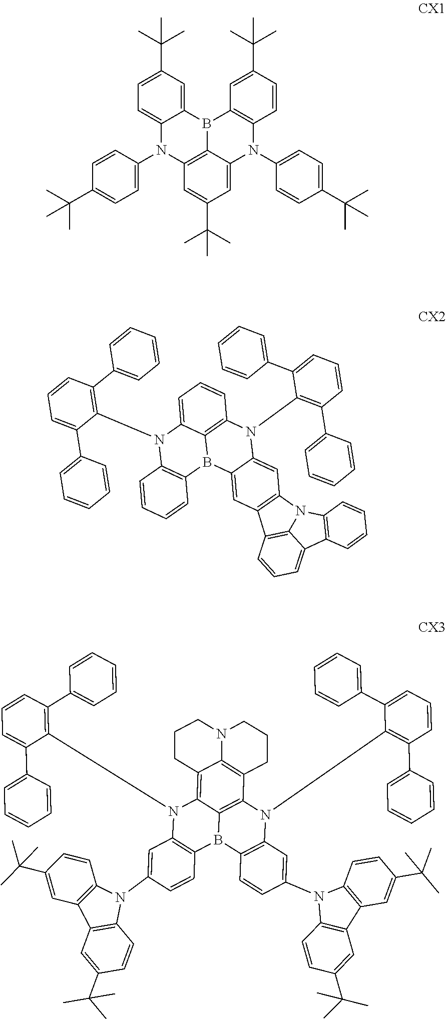

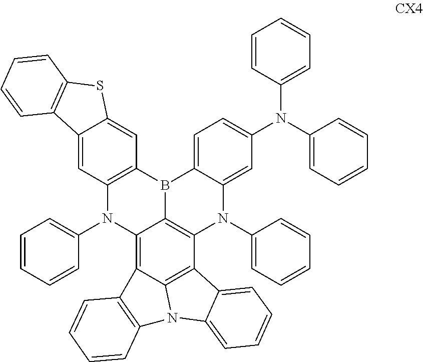 [SMILES: c1ccc(N(c2ccccc2)c2ccc3c(c2)N(c2ccccc2)c2c4c(c5c6ccccc6n6c7ccccc7c2c56)N(c2ccccc2)c2cc5c(cc2B34)sc2ccccc25)cc1]

### 2 Evaluation of Light Emitting Devices

In Table 1, the light emitting devices of the Comparative Examples and the Examples are evaluated and shown. A driving voltage at a current density of about 10 mA/cm², emission efficiency, emission wavelength, and lifetime were measured utilizing Keithley MU 236 and a luminance meter PR650 and shown in Table 1. The lifetime (T950) was obtained by measuring time taken for reducing an initial luminance of 100% to 95%, and calculating relative lifetime based on Comparative Example 1.

TABLE 1

| Element | Host | | | Driving | Emission | Emission | |
|---|---|---|---|---|---|---|---|
| manufacturing | (HT:ET = | | | voltage | efficiency | wavelength | Lifetime |
| example | 5:5) | Sensitizer | Dopant | (V) | (cd/A) | (nm) | (T95) |
| Example 1 | HT3/ETH66 | AD-38 | Compound 12 | 4.5 | 25.8 | 459 | 5.3 |
| Example 2 | HT3/ETH66 | AD-38 | Compound 47 | 4.4 | 25.4 | 459 | 5.5 |
| Example 3 | HT3/ETH66 | AD-38 | Compound 58 | 4.4 | 24.7 | 460 | 4.7 |
| Example 4 | HT3/ETH66 | AD-38 | Compound 69 | 4.5 | 25.1 | 460 | 4.8 |
| Example 5 | HT3/ETH66 | AD-38 | Compound 80 | 4.5 | 25.1 | 459 | 5.0 |
| Example 6 | HT3/ETH66 | AD-38 | Compound 110 | 4.4 | 25.3 | 458 | 5.2 |
| Example 7 | HT3/ETH86 | AD-37 | Compound 12 | 4.4 | 25.3 | 459 | 5.2 |
| Example 8 | HT3/ETH86 | AD-37 | Compound 47 | 4.4 | 25.1 | 459 | 5.3 |
| Example 9 | HT3/ETH86 | AD-37 | Compound 58 | 4.4 | 24.5 | 459 | 4.9 |
| Example 10 | HT3/ETH86 | AD-37 | Compound 69 | 4.5 | 24.8 | 460 | 4.8 |
| Example 11 | HT3/ETH86 | AD-37 | Compound 80 | 4.5 | 25.2 | 460 | 5.0 |
| Example 12 | HT3/ETH86 | AD-37 | Compound 110 | 4.4 | 25.3 | 459 | 5.1 |
| Comparative | HT3/ETH86 | AD-38 | Comparative | 5.4 | 17.5 | 462 | 1.0 |
| Example 1 | | | Compound CX1 | | | | |
| Comparative | HT3/ETH86 | AD-38 | Comparative | 5.3 | 19.7 | 463 | 1.1 |
| Example 2 | | | Compound CX2 | | | | |
| Comparative | HT3/ETH86 | AD-38 | Comparative | 5.6 | 17.3 | 467 | 0.7 |
| Example 3 | | | Compound CX3 | | | | |
| Comparative | HT3/ETH86 | AD-38 | Comparative | 5.1 | 18.8 | 464 | 0.8 |
| Example 4 | | | Compound CX4 | | | | |

Referring to Table 1, it can be found that the light emitting devices of Examples 1 to 12 and Comparative Examples 1 to 4 emit blue light in a wavelength region of about 450 nm to about 470 nm. Compared to the light emitting devices of Comparative Examples 1 to 4, it can be found that the light emitting devices of Examples 1 to 12 have reduced driving voltages, high emission efficiency and long lifetime. The light emitting devices of Examples 1 to 12 include Compounds 12, 47, 58, 69, 80 and 110, and Compounds 12, 47, 58, 69, 80 and 110 are the fused polycyclic compounds of embodiments.

Compounds 12, 47, 58, 69, 80 and 110 include the fused ring of nine rings, in which an indolocarbazole moiety is fused, as a central structure, and to the fused ring of nine rings, an ortho terphenyl group is bonded. Accordingly, it can be found that the stability of the materials of Compounds 12, 47, 58, 69, 80 and 110 is improved, RISC is accelerated, and the efficiency and lifetime of light emitting devices are improved. Accordingly, the light emitting device including the fused polycyclic compound of an embodiment may show a low driving voltage, high efficiency, and long-life characteristics.

The light emitting device of Comparative Example 1 includes Comparative Compound CX1, and Comparative Compound CX1 includes a fused ring of five rings. Comparative Compound CX1 does not include the fused ring of nine rings fused in which an indolocarbazole moiety is fused, and an ortho terphenyl group, and is different from the fused polycyclic compound of an embodiment. Accordingly, the light emitting device of Comparative Example 1, including Comparative Compound CX1 showed a relatively high driving voltage, low efficiency and short lifetime.

The light emitting device of Comparative Example 2 includes Comparative Compound CX2. Comparative Compound CX2 includes a fused ring of nine rings fused in which an indolocarbazole moiety is fused, but the fused position of the indolocarbazole moiety is different from that of the fused polycyclic compound of an embodiment. Accordingly, the light emitting device of Comparative Example 2, including Comparative Compound CX2 showed a relatively high driving voltage, low efficiency and short lifetime.

The light emitting device of Comparative Example 3 includes Comparative Compound CX3. Comparative Compound CX3 does not include a fused ring of nine rings in which an indolocarbazole moiety is fused and is different from the fused polycyclic compound of an embodiment. Accordingly, the light emitting device of Comparative Example 3, including Comparative Compound CX3 showed a relatively high driving voltage, low efficiency and short lifetime.

The light emitting device of Comparative Example 4 includes Comparative Compound CX4. Comparative Compound CX4 includes a fused ring of nine rings in which an indolocarbazole moiety is fused, but does not include an ortho terphenyl group, and is different from the fused polycyclic compound of an embodiment. Accordingly, the light emitting device of Comparative Example 4, including Comparative Compound CX4 showed a relatively high driving voltage, low efficiency and short lifetime.

The light emitting device of an embodiment may include an emission layer disposed between a first electrode and a second electrode. The emission layer may include the fused polycyclic compound of an embodiment. The fused polycyclic compound of an embodiment may include a fused ring of nine rings, including three nitrogen atoms and one boron atom as ring-forming atoms, as a central structure, and ortho terphenyl groups may be bonded to the two nitrogen atoms in the central structure. Accordingly, in the fused polycyclic compound of an embodiment, dexter energy transfer may be suppressed or reduced, excellent or suitable material stability may be shown, and RISC may be accelerated. The light emitting device including the fused polycyclic compound of an embodiment may show a low driving voltage, high efficiency and long lifetime.

The light emitting device of an embodiment and a display apparatus including the same includes the fused polycyclic compound of an embodiment and may show high efficiency and long-life characteristics.

The fused polycyclic compound of an embodiment may contribute to the improvement of the efficiency and the lifetime of the light emitting device.

In the present disclosure, singular expressions may include plural expressions unless the context clearly indicates otherwise. It will be further understood that the terms “comprise(s),” “include(s),” or “have/has” when utilized in the present disclosure, specify the presence of stated features, integers, steps, operations, elements, and/or components, but do not preclude the presence or addition of one or more other features, integers, steps, operations, elements, components, and/or groups thereof. The “/” utilized herein may be interpreted as “and” or as “or” depending on the situation.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, when particles (e.g., nanoparticles) are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In present disclosure, “not include a or any ‘component’” “exclude a or any ‘component”, “component’-free”, and/or the like refers to that the “component” not being added, selected, or utilized as a component in a compound/composition, but the “component” of less than a suitable amount may still be included due to other impurities and/or external factors in a composition.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein.

The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the embodiments of the present disclosure have been described, it is understood that the present disclosure should not be limited to these embodiments, but one or more suitable changes and modifications can be made by one ordinary skilled in the art within the spirit and scope of the present disclosure as hereinafter claimed.

What is claimed is:

1. A light emitting device comprising:
a first electrode;
a second electrode on the first electrode; and
an emission layer between the first electrode and the second electrode, and comprising a first compound represented by Formula 1: 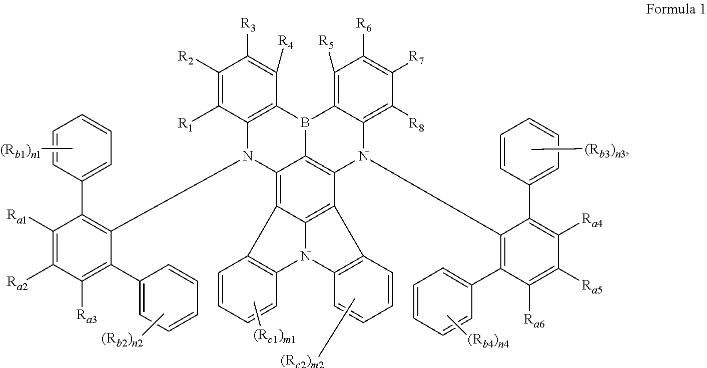
wherein, in Formula 1,
R₁ to R₈ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
n1 to n4 are each independently an integer of 0 to 5,
Rₐ₁ to Rₐ₆ and R_{b1} to R_{b4} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
m1 and m2 are each independently an integer of 0 to 4, and
R_{c1} and R_{c2} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms.

2. The light emitting device of claim 1, wherein the emission layer further comprises at least one selected from among a second compound represented by Formula HT-1, a third compound represented by Formula ET-1, and a fourth compound represented by Formula D-1: 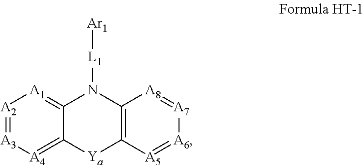
wherein, in Formula HT-1,
A₁ to A₈ are each independently N or CR₅₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₅₂R₅₃, or SiR₅₄R₅₅,
Ar₁ is a substituted or unsubstituted aryl group of 6 to 30 ring-forming carbon atoms, or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group or 2 to 60 ring-forming carbon atoms, and/or combined with an adjacent group to form a ring, 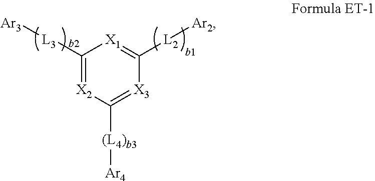
wherein, in Formula ET-1,
at least one selected from among X₁ to X₃ is N, and the remainder are CR₅₆,
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group or 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group or 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group or 2 to 30 ring-forming carbon atoms, and 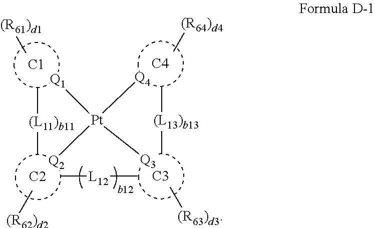
wherein, in Formula D-1,
Q₁ to Q₄ are each independently C or N,
C1 to C4 are each independently a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms,
L₁₁ to L₁₃ are each independently a direct linkage, 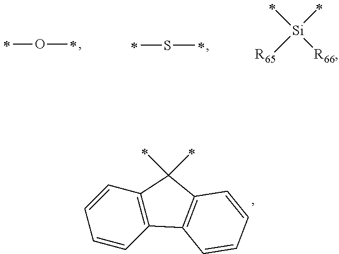
a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and
d1 to d4 are each independently an integer of 0 to 4.

3. The light emitting device of claim 1, wherein Formula 1 is represented by Formula 1-A: 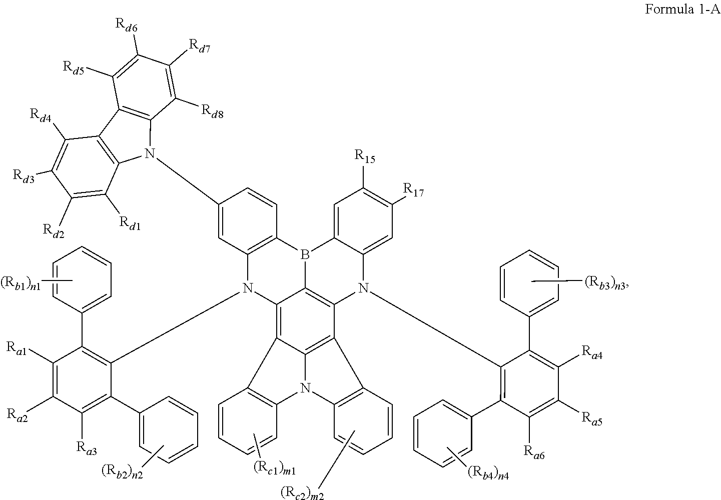
wherein, in Formula 1-A,
R₁₆ and R₁₇ are each independently a hydrogen atom, a deuterium atom, a halogen atom, a substituted or unsubstituted oxy group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms,
R_{d1} to R_{d8} are each independently a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
n1 to n4, Rₐ₁ to Rₐ₆, R_{b1} to R_{b4}, m1, m2, R_{c1}, and R_{c2} are the same as defined in Formula 1.

4. The light emitting device of claim 3, wherein Formula 1-A is represented by Formula 1-A1: 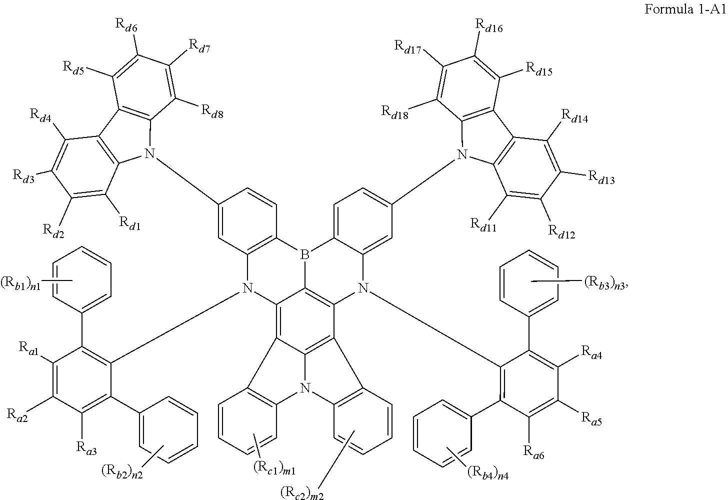
wherein, in Formula 1-A1,
R_{d11} to R_{d18} are each independently a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
n1 to n4, Rₐ₁ to Rₐ₆, R_{b1} to R_{b4}, m1, m2, R_{c1}, R_{c2}, R₁₆, R₁₇, and Rₐ₁ to R_{d8} are the same as defined in Formula 1-A.

5. The light emitting device of claim 1, wherein, in Formula 1, R₁ to R₈ are each independently a hydrogen atom, a deuterium atom, or are each represented by one selected from among R-1 to R-26: 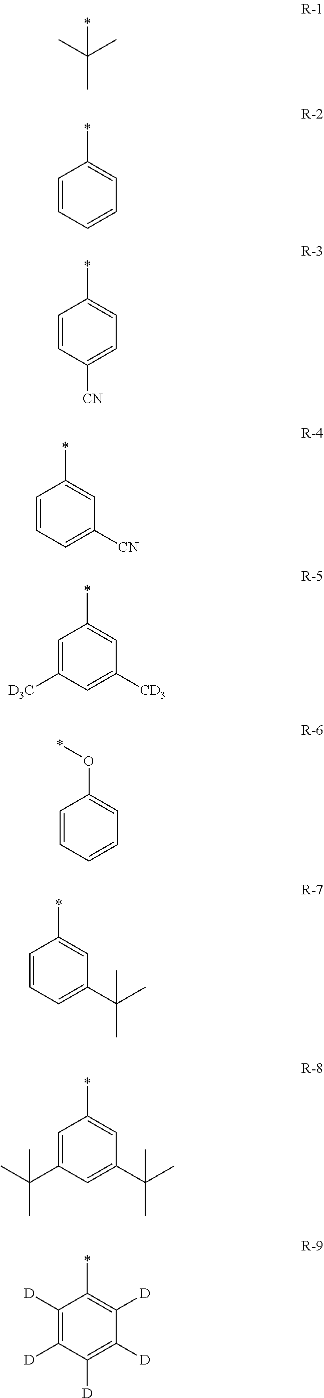 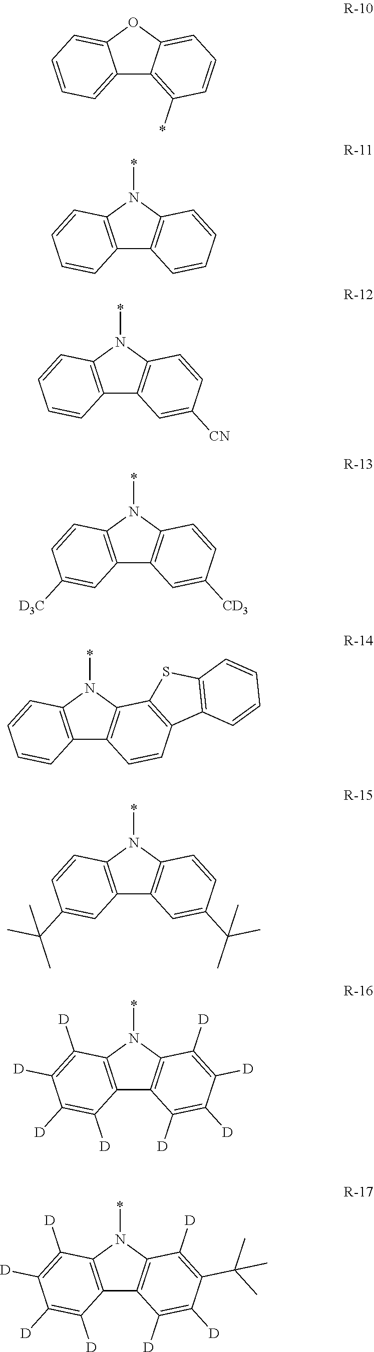 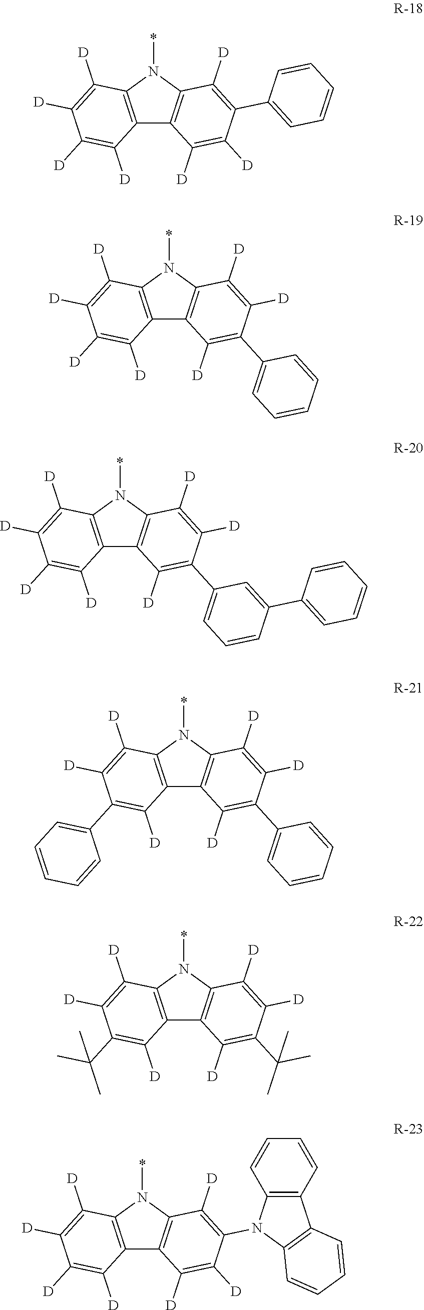 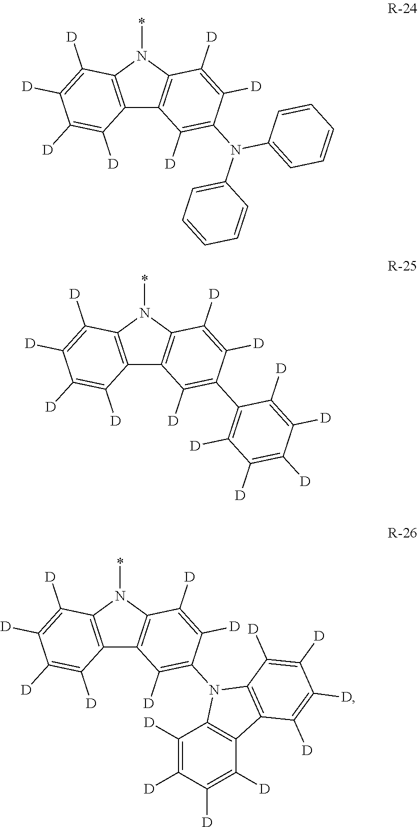
wherein, in R-5, R-9, R-13, and R-16 to R-26, D is a deuterium atom.

6. The light emitting device of claim 1, wherein, in Formula 1, R₁ to R₈ are each independently a hydrogen atom, a deuterium atom, a substituted or unsubstituted t-butyl group, a substituted or unsubstituted aryl oxy group, a substituted or unsubstituted phenyl group, a substituted or unsubstituted carbazole group, a substituted or unsubstituted dibenzofuran group, or a substituted or unsubstituted benzo thieno carbazole group.

7. The light emitting device of claim 1, wherein Formula 1 is represented by one selected from among Formula 1-B1 to Formula 1-B3: 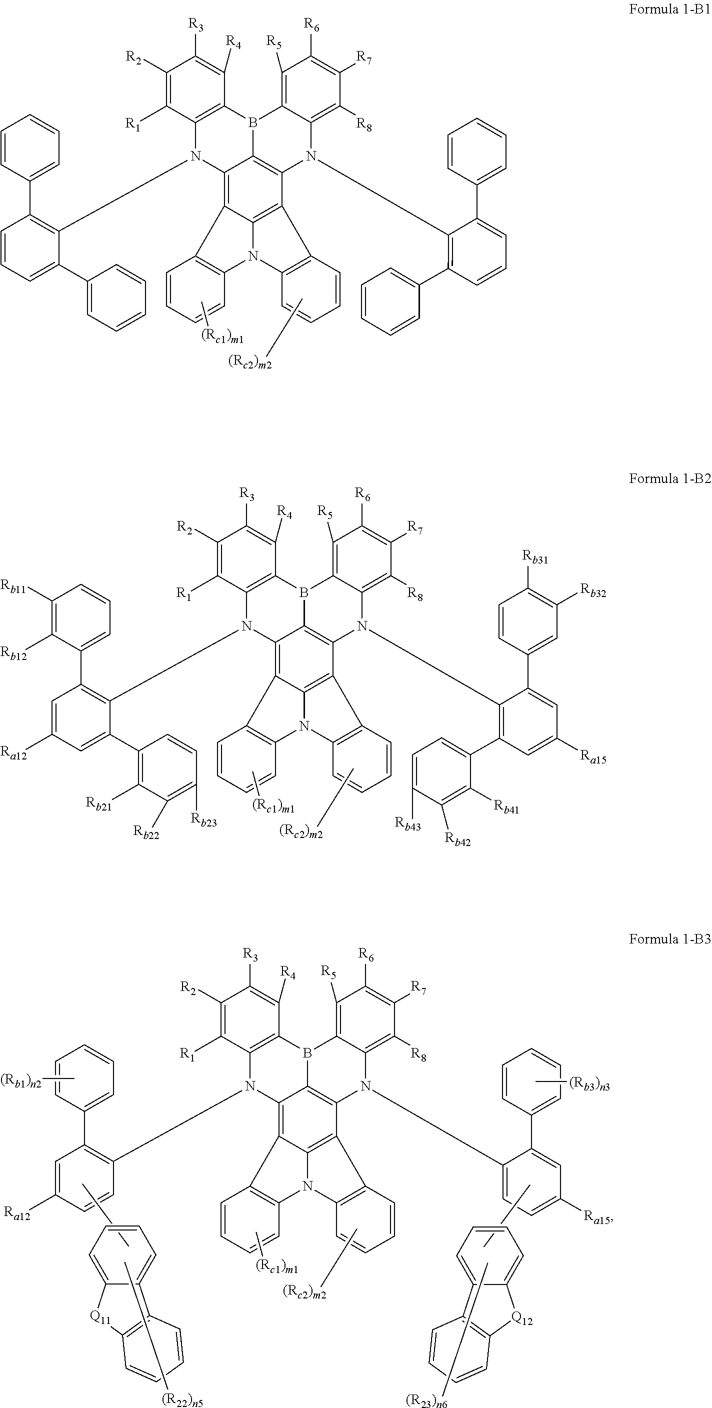
wherein, in Formula 1-B2,
R_{b11}, R_{b12}, R_{b21} to R_{b23}, R_{b31}, R_{b32}, and R_{b41} to R_{b43} are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 30 carbon atoms, a substituted or unsubstituted alkenyl group of 2 to 30 carbon atoms, or a substituted or unsubstituted aryl group of 6 to 30 ring-forming carbon atoms, and/or combined with an adjacent group to form a ring,
wherein, in Formula 1-B3,
Q₁₁ and Q₁₂ are each independently NR₂₁, O, or S,
n5 and n6 are each independently an integer of 0 to 7, and
R₂₁ to R₂₃ are each independently a hydrogen atom, a deuterium atom, or a substituted or unsubstituted aryl group of 6 to 30 ring-forming carbon atoms,
wherein, in Formula 1-B2 and Formula 1-B3,
Rₐ₁₂ and Rₐ₁₅ are each independently a hydrogen atom, a deuterium atom, a cyano group, a substituted or unsubstituted alkyl group of 1 to 30 carbon atoms, or a substituted or unsubstituted aryl group of 6 to 30 ring-forming carbon atoms, and
wherein, in Formula 1-B1 to Formula 1-B3,
R₁ to R₈, n1, n3, R_{b1}, R_{b3}, m1, m2, R_{c1}, and R_{c2} are the same as defined in Formula 1.

8. The light emitting device of claim 1, wherein, in Formula 1, R_{c1} and R_{c2} are each independently a hydrogen atom, a deuterium atom, a substituted or unsubstituted methyl group, a substituted or unsubstituted t-butyl group, or a substituted or unsubstituted phenyl group.

9. The light emitting device of claim 1, wherein, in Formula 1, R_{c1} and R_{c2} are each independently a hydrogen atom, a deuterium atom, or represented by one selected from among RC-1 to RC-4: 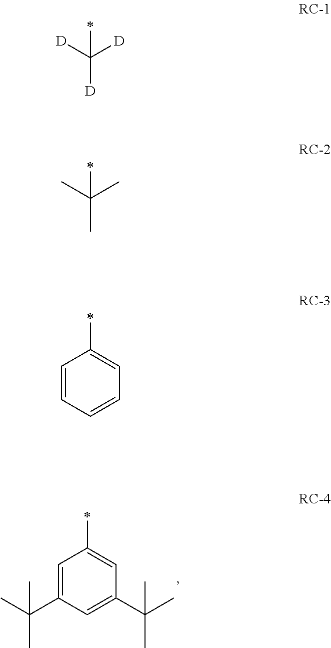
wherein, in RC-1, D is a deuterium atom.

10. The light emitting device of claim 1, wherein the first compound comprises a deuterium atom, or a substituent comprising a deuterium atom.

11. The light emitting device of claim 1, wherein the first compound is represented by one selected from among the compounds in Compound Group 1: 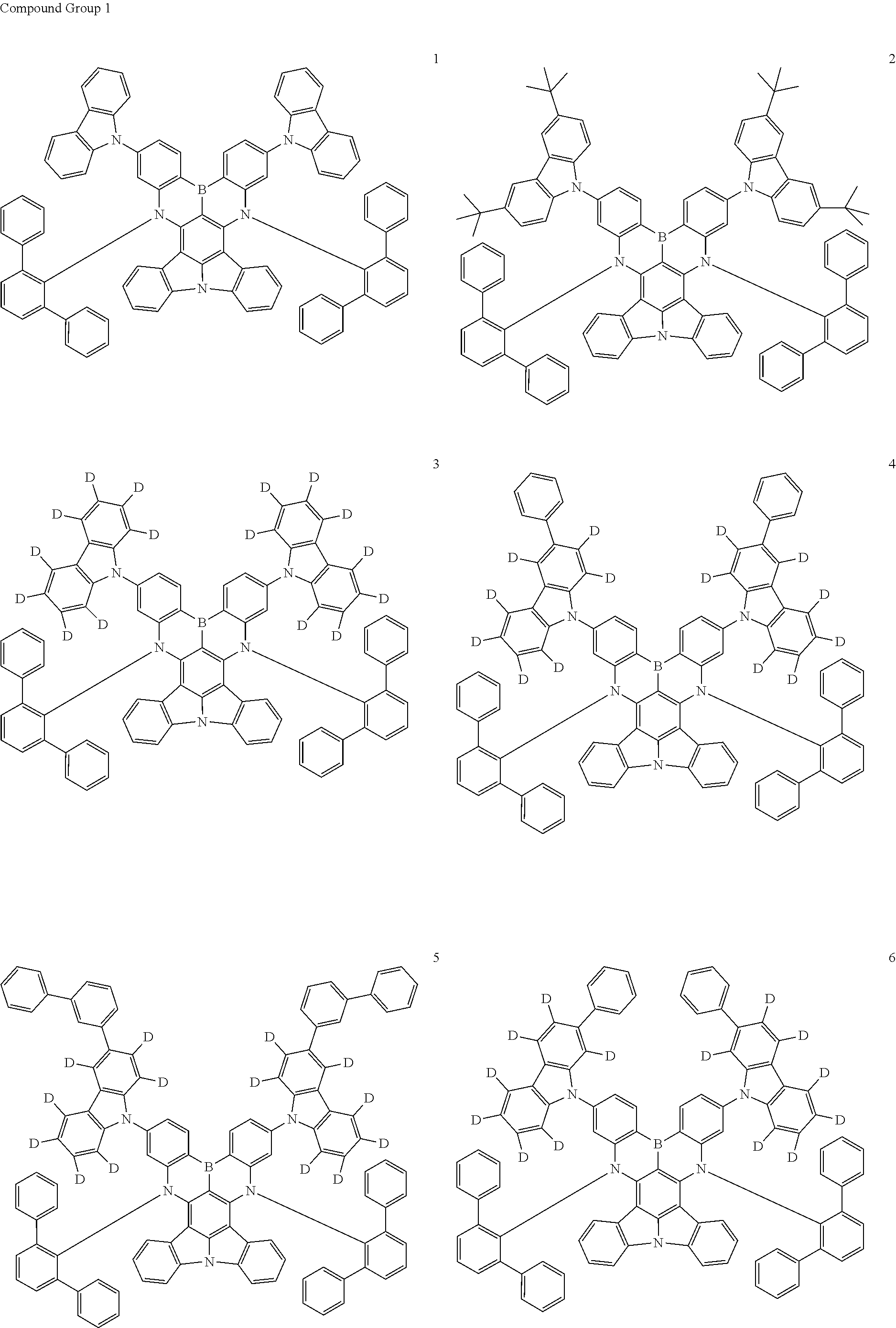 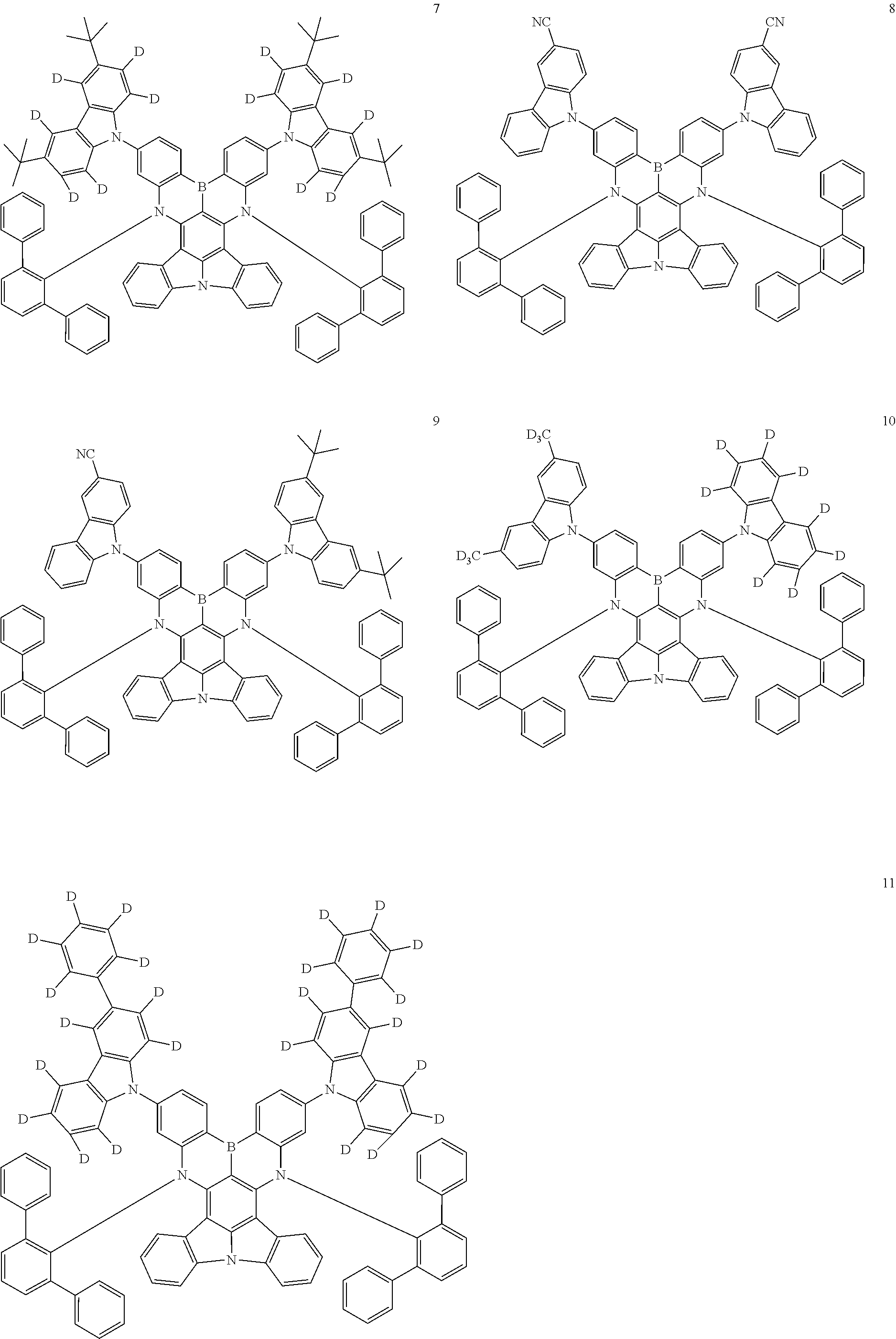 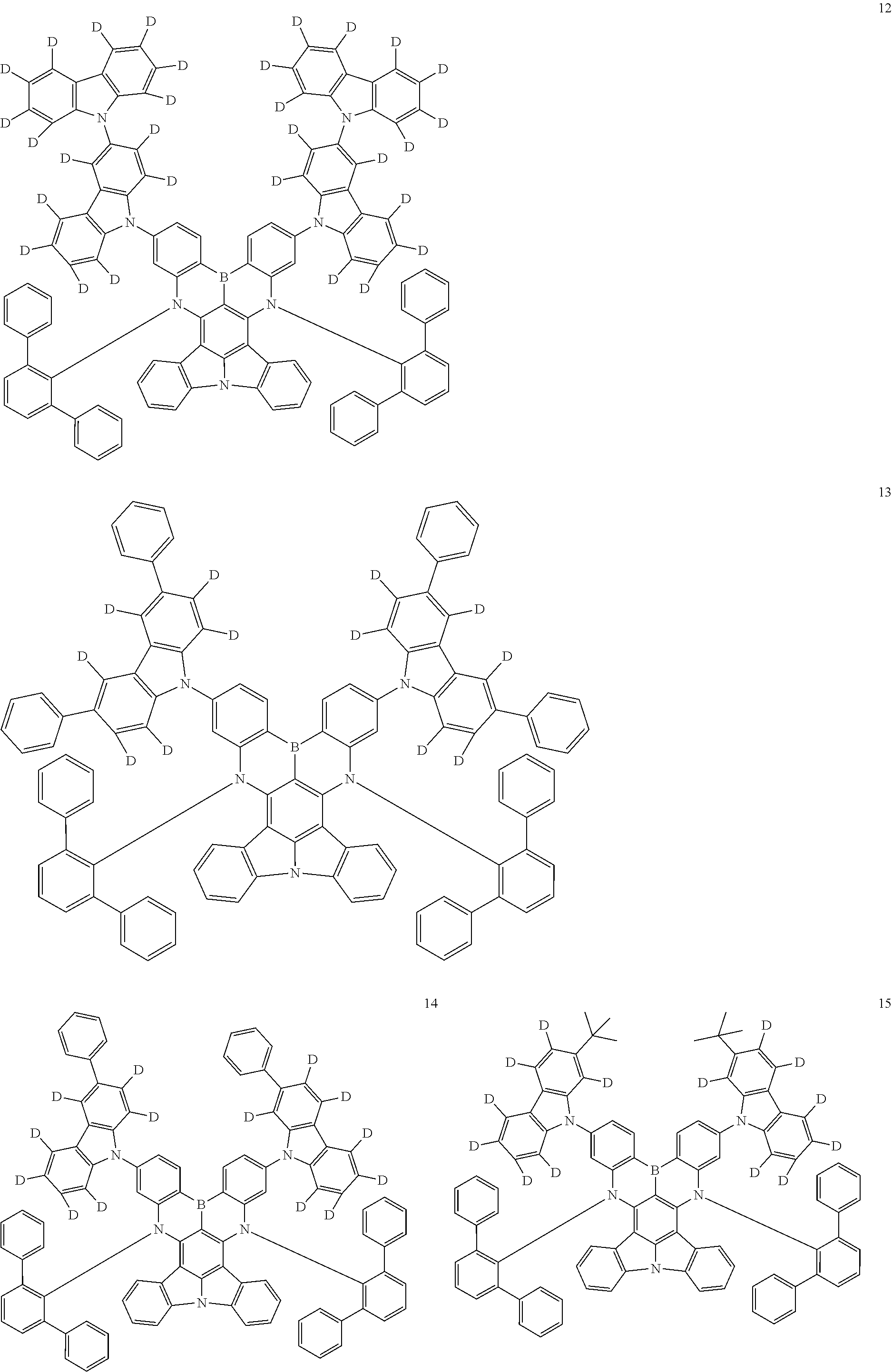 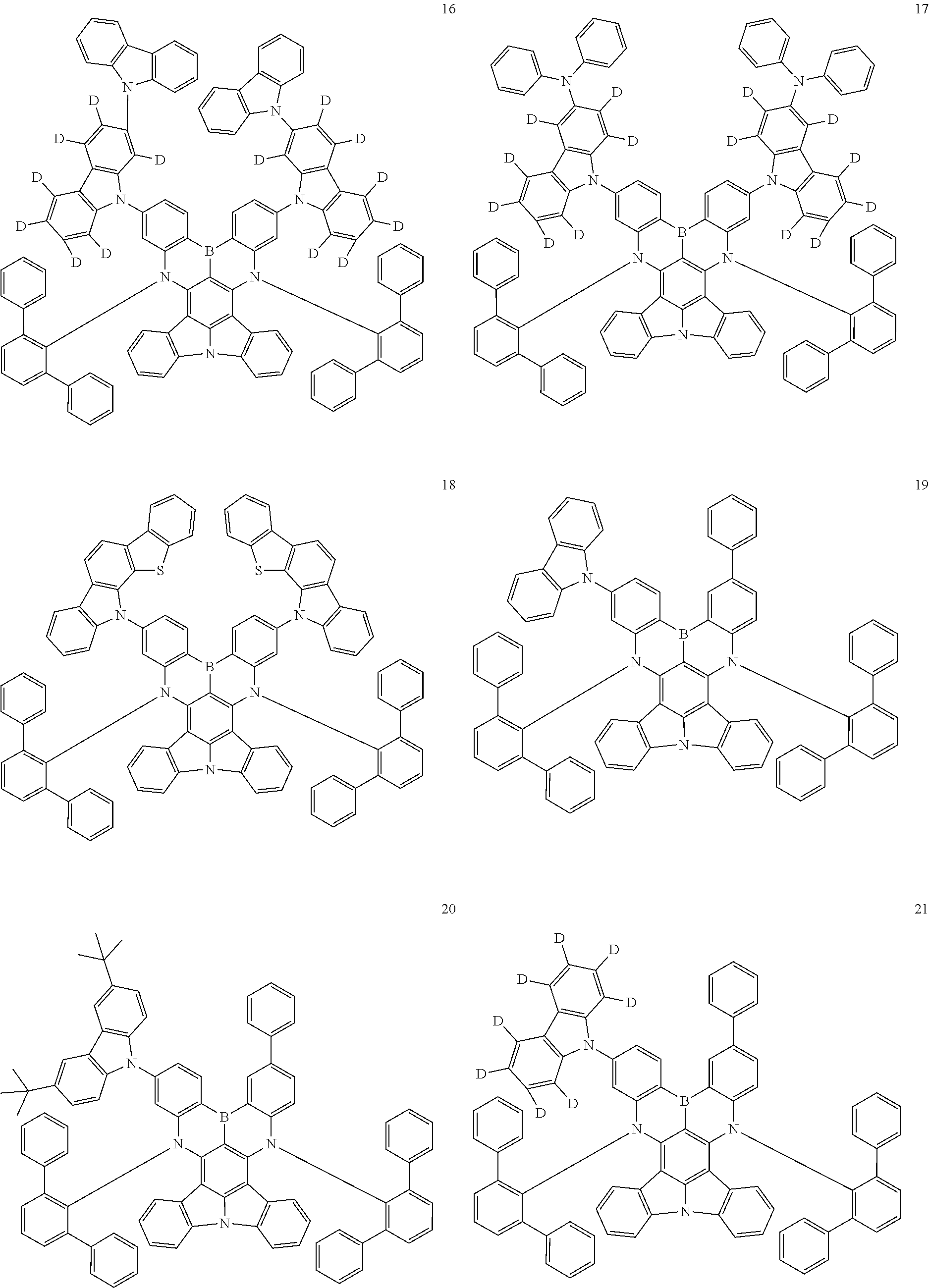 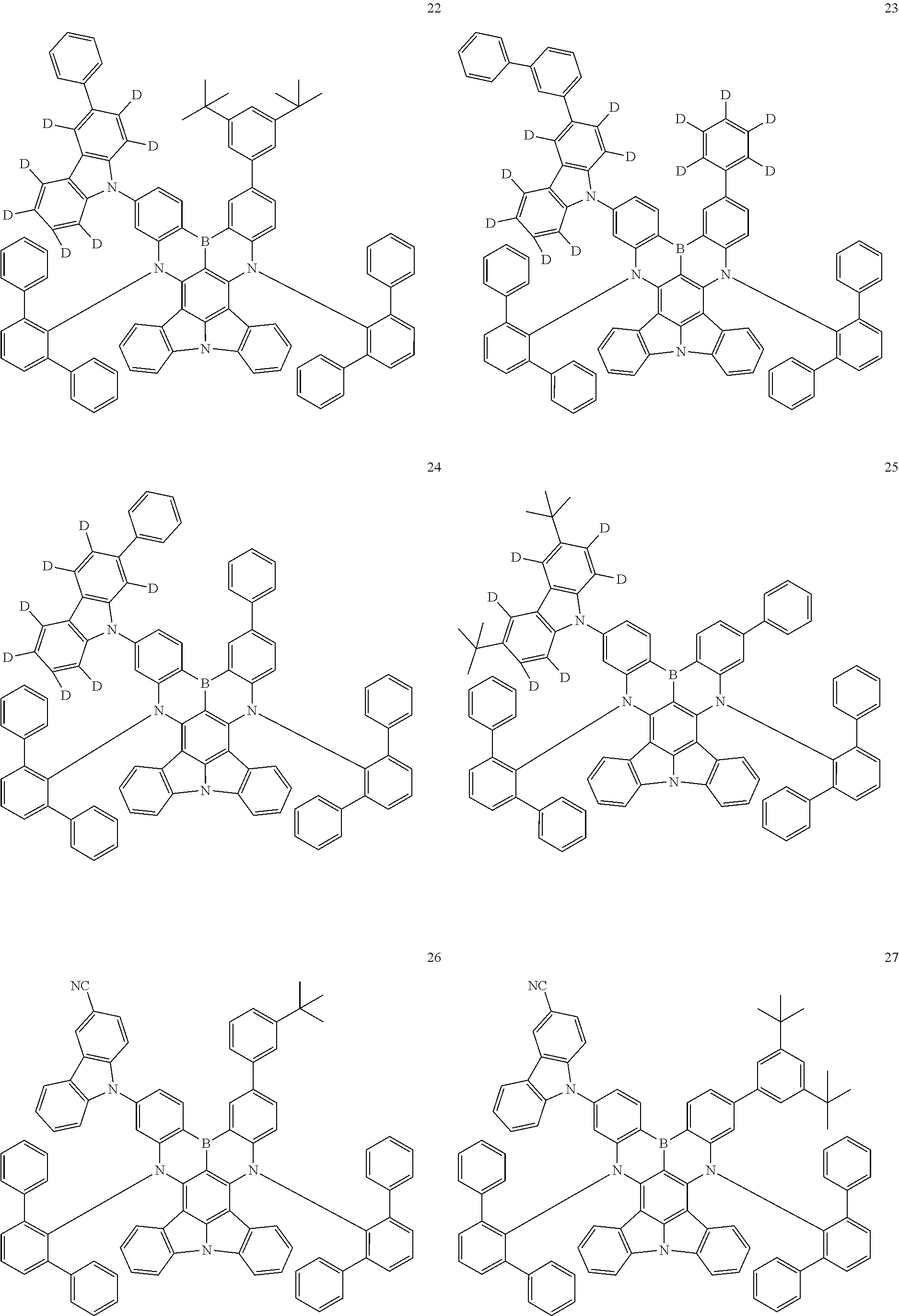 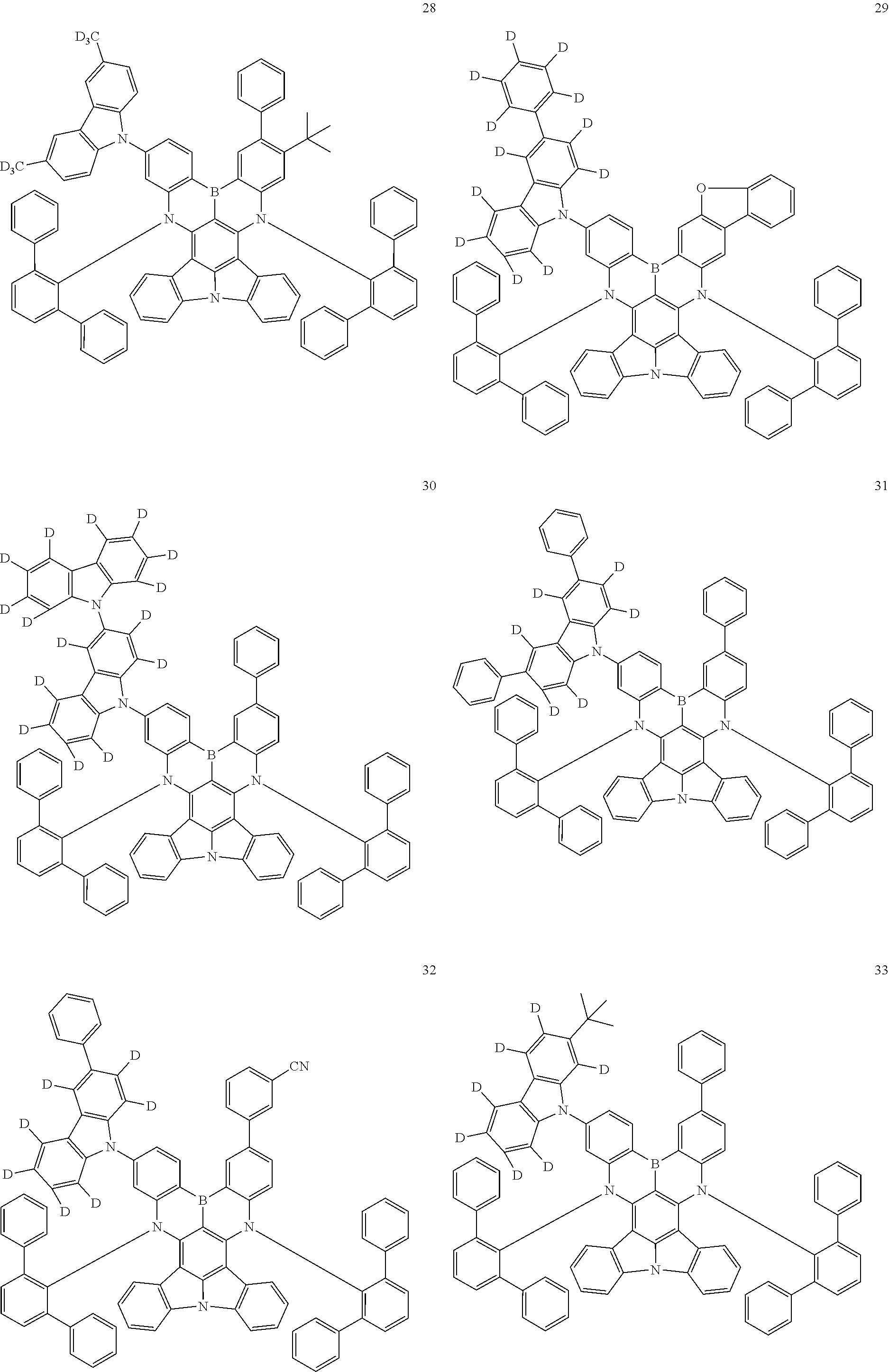 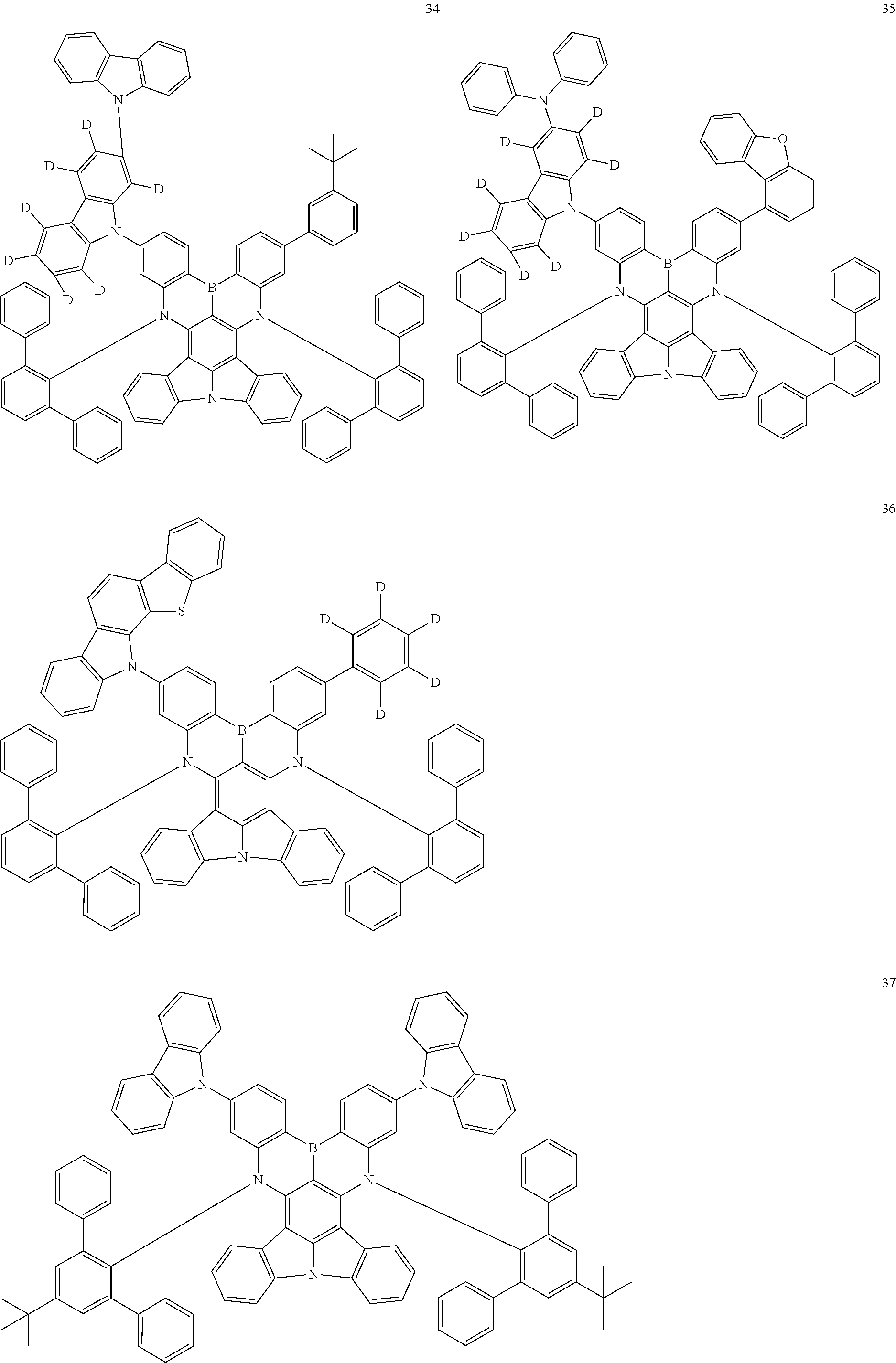 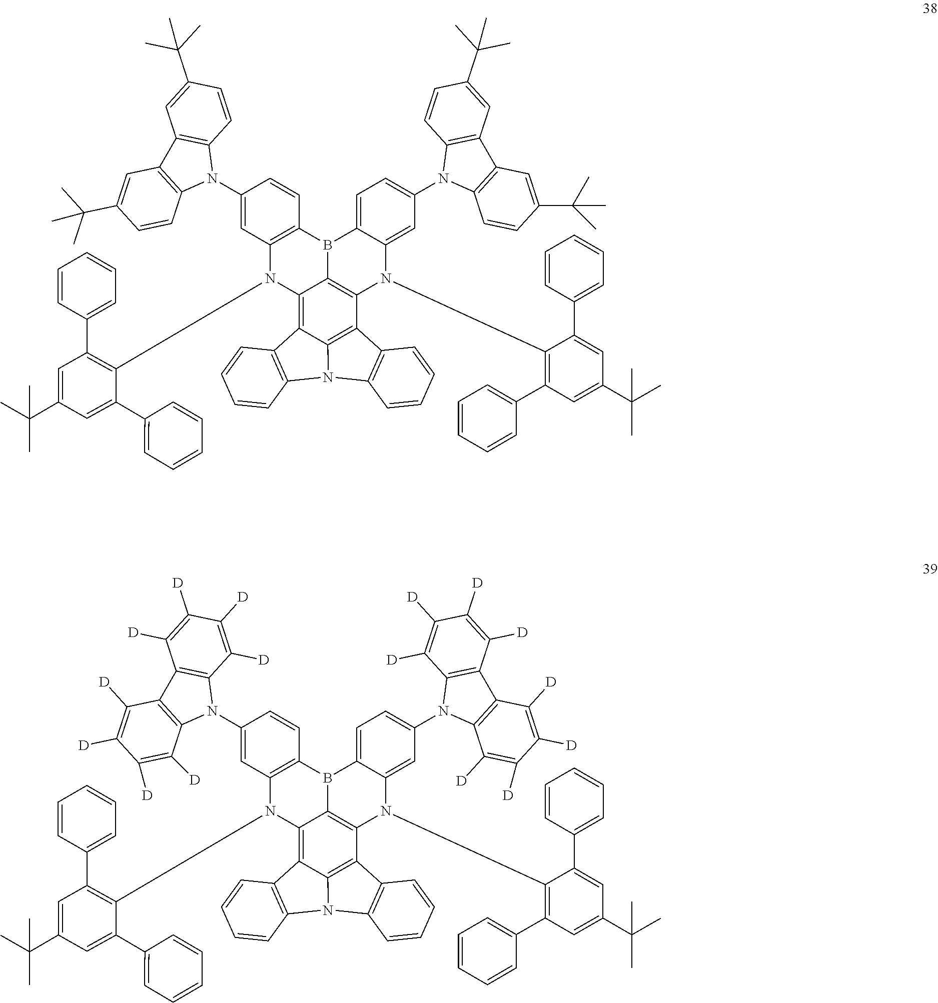 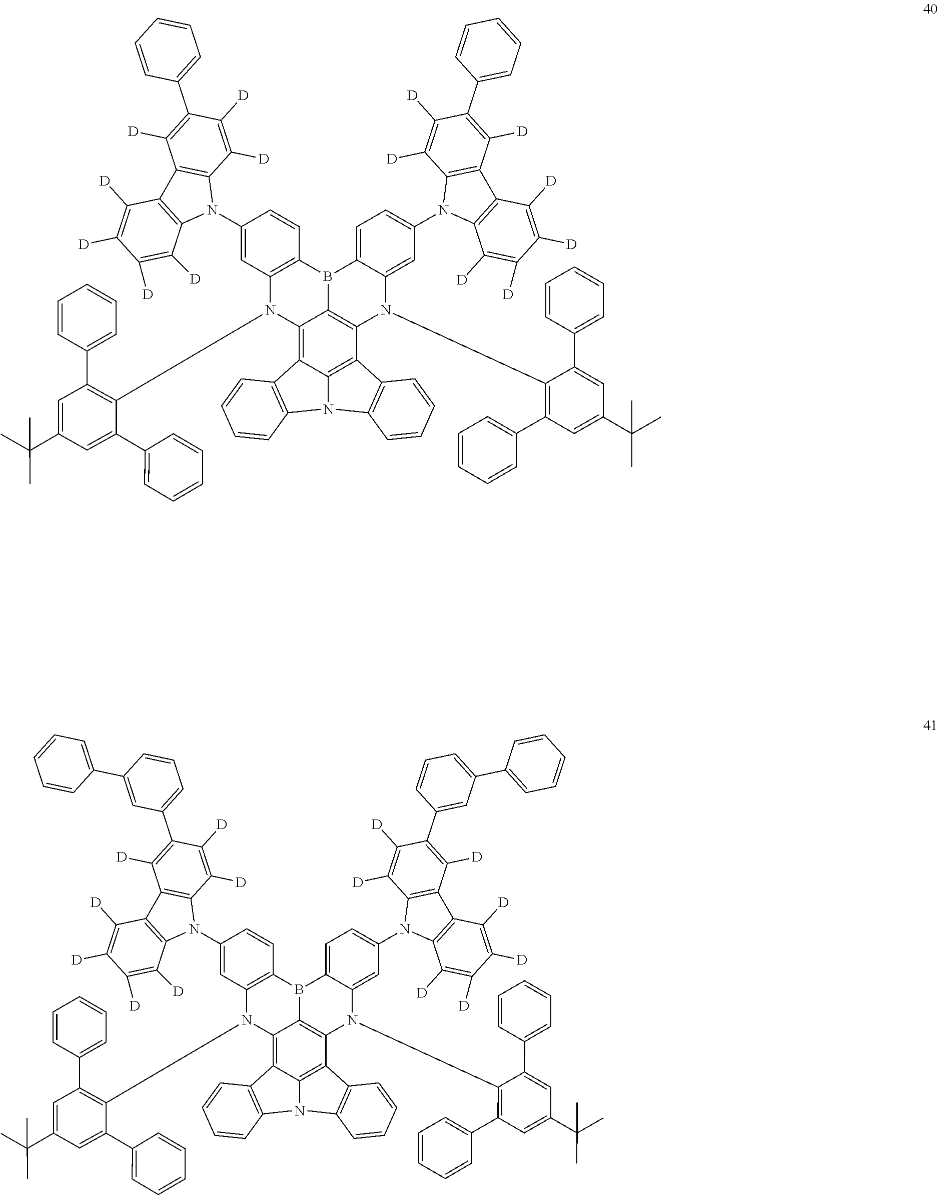 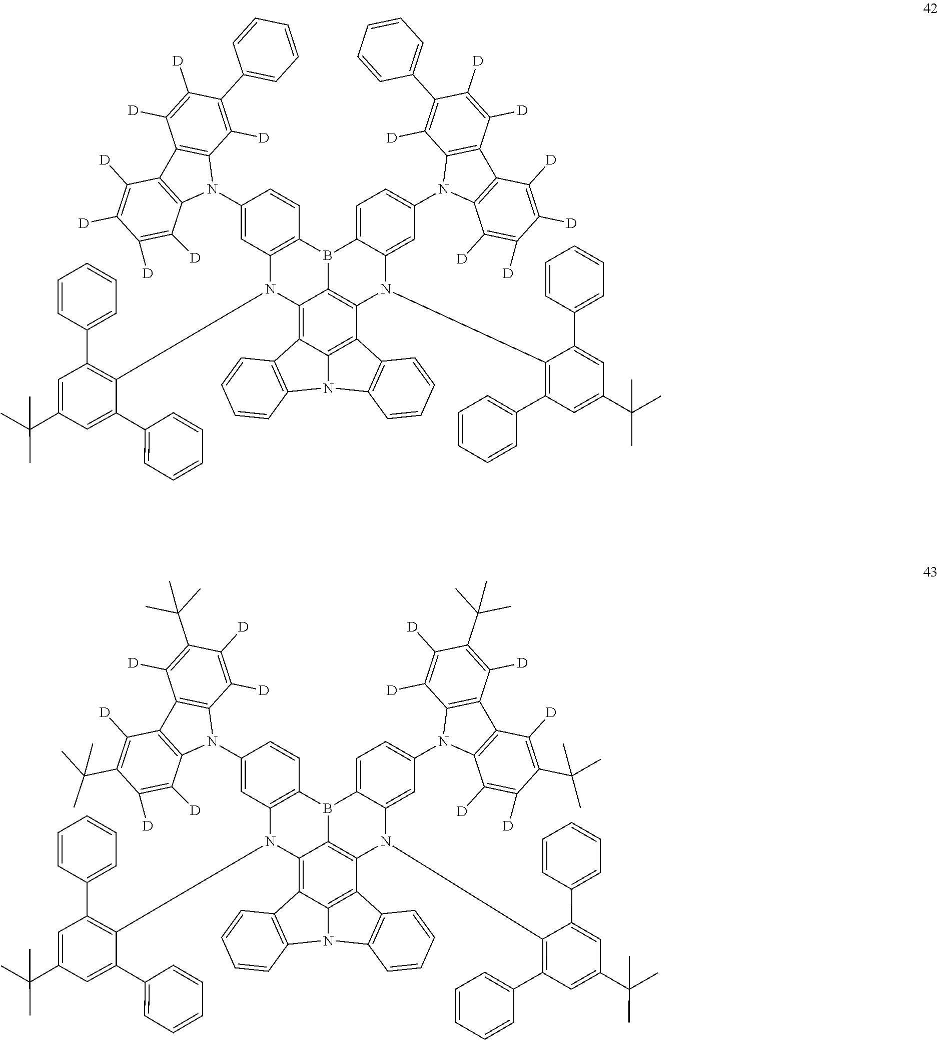 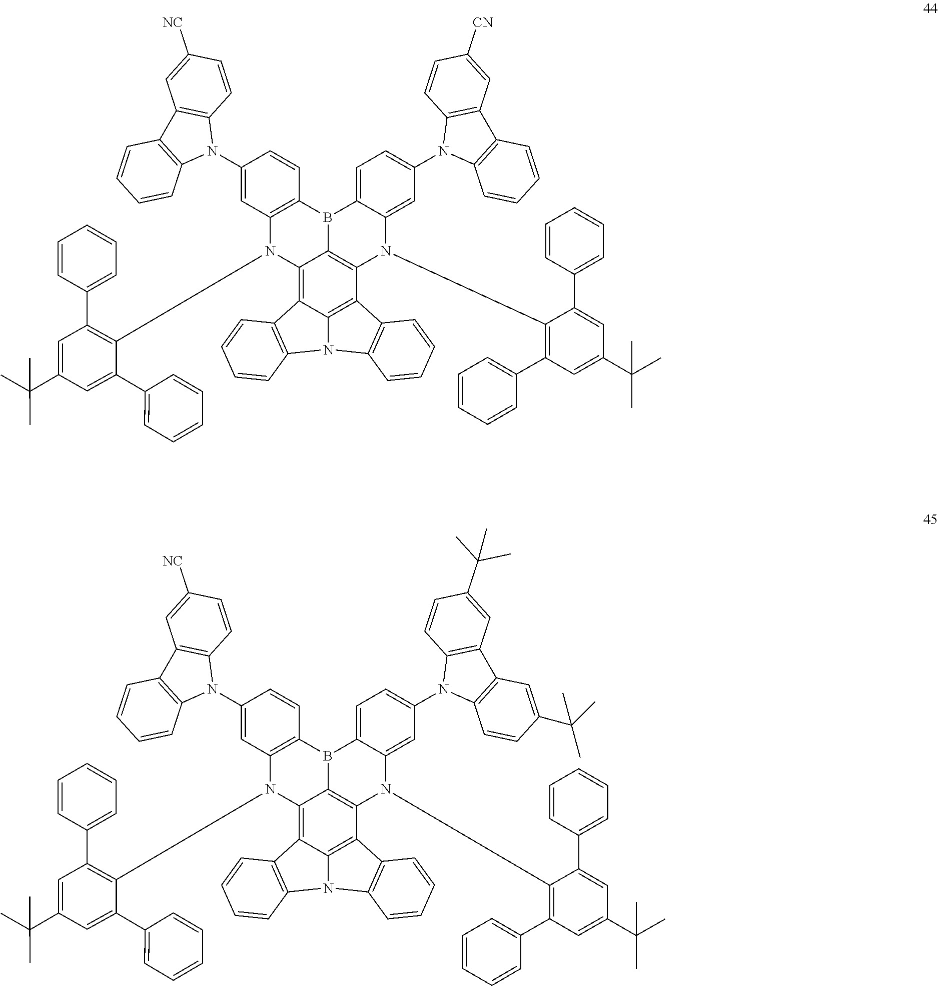 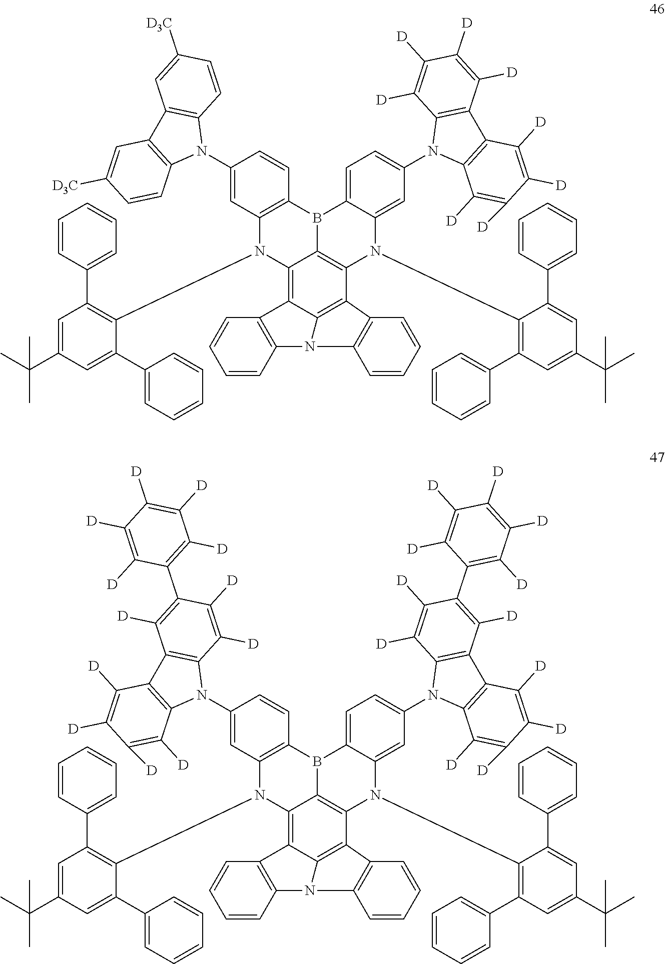 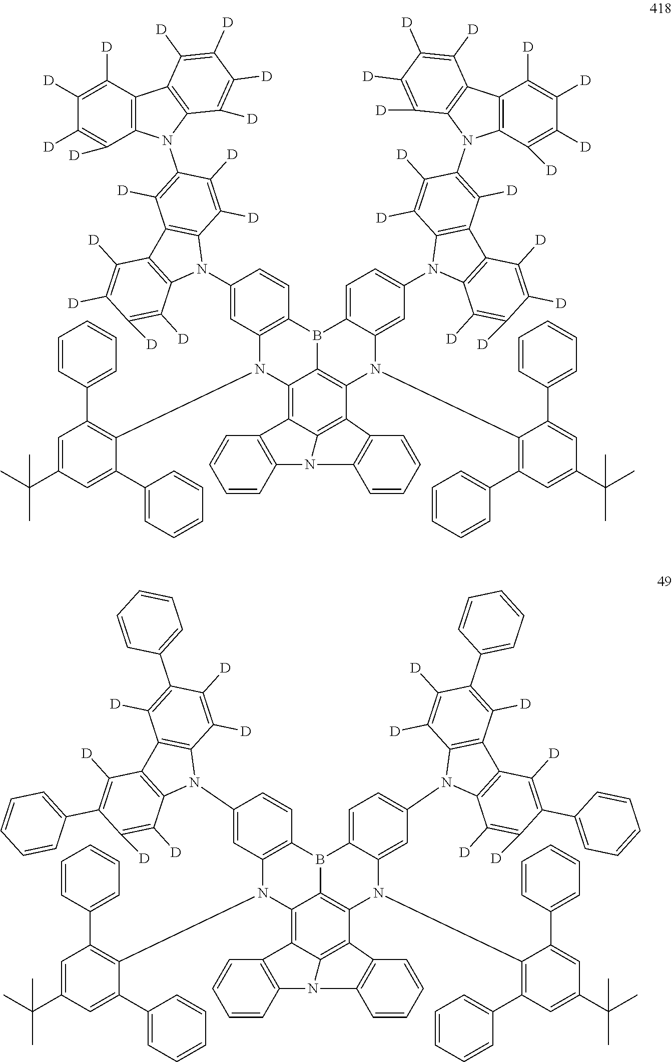 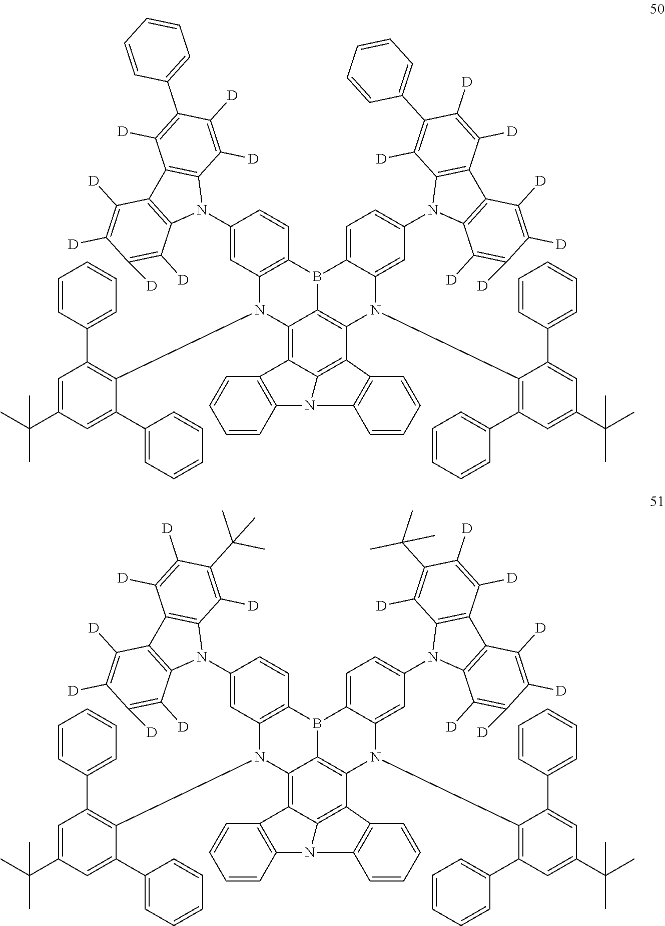 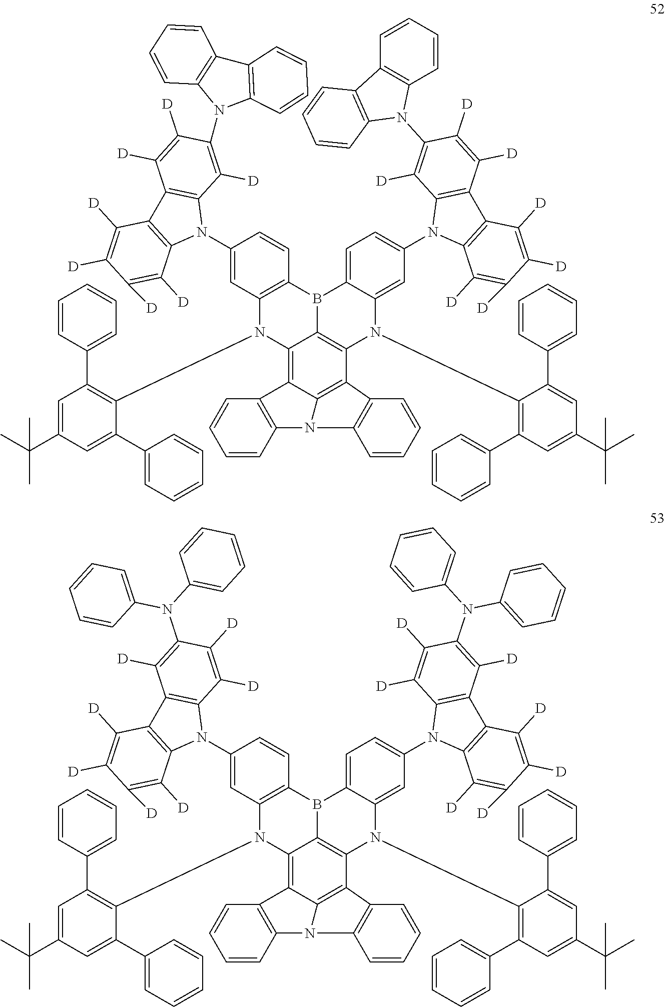 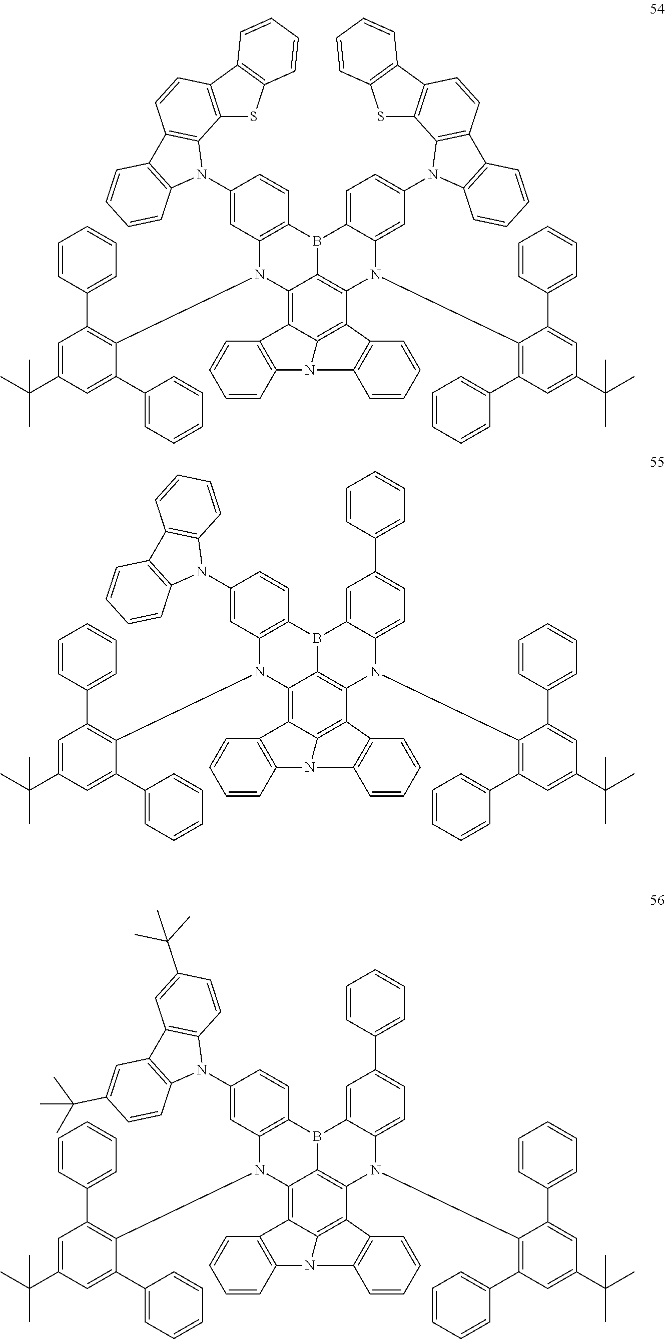 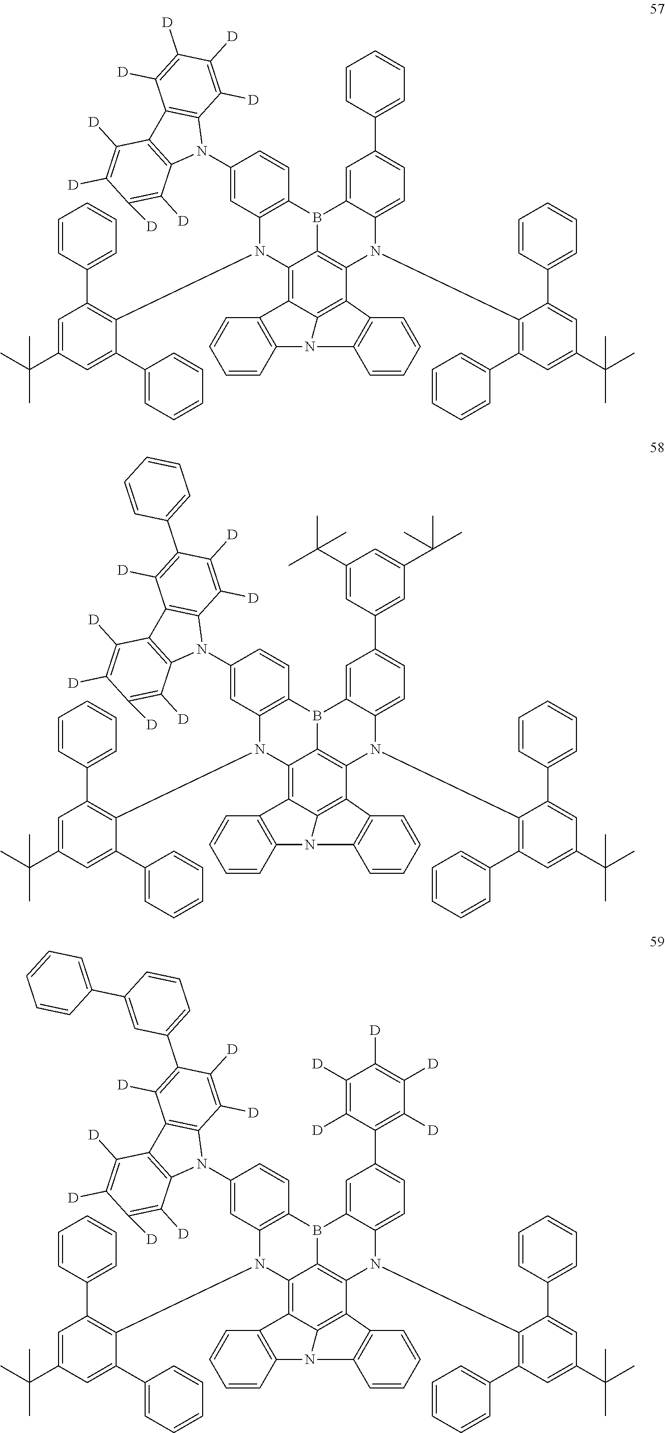 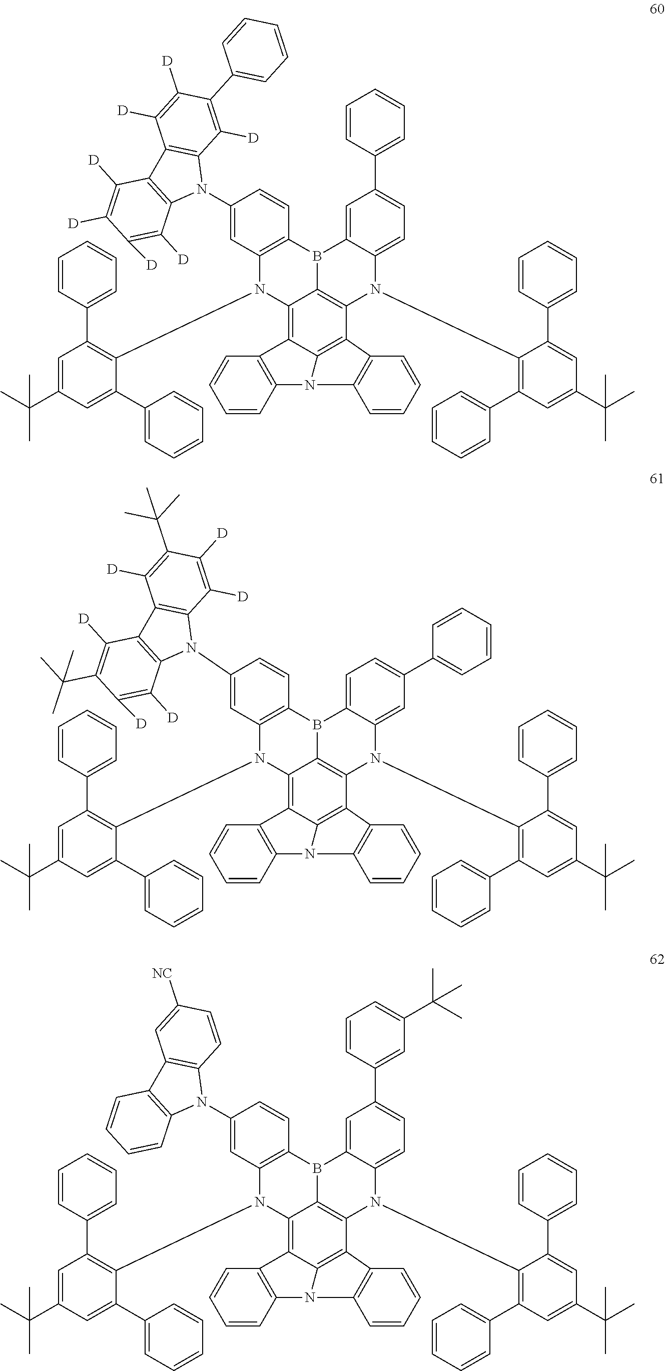 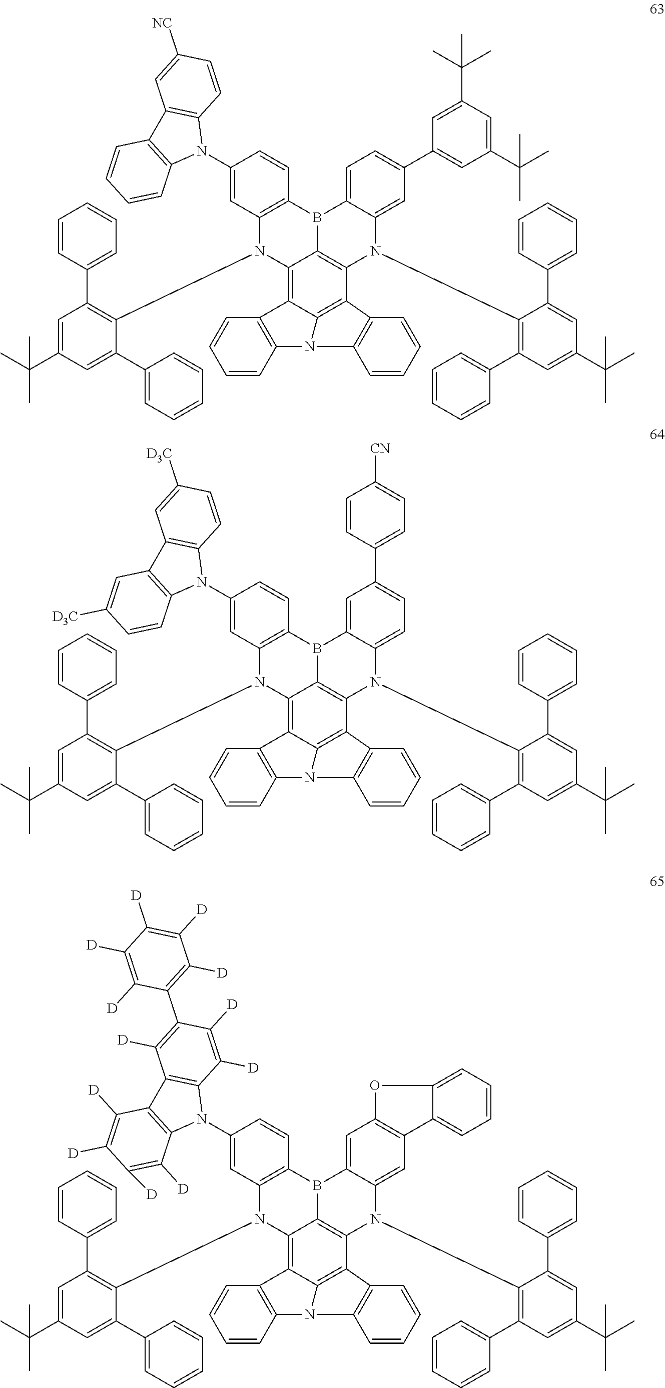 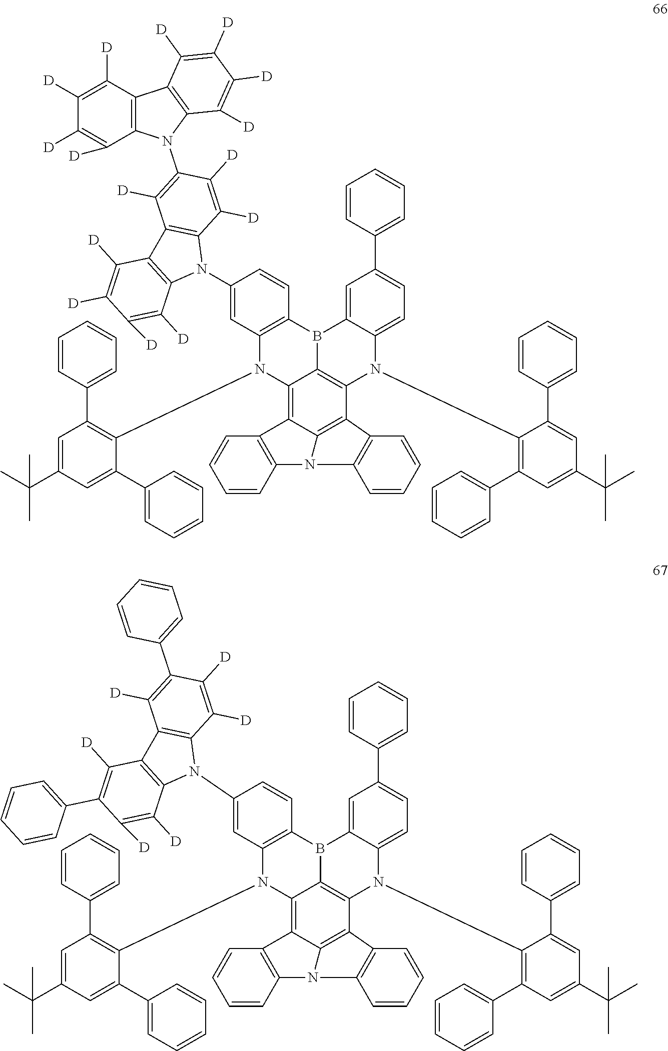 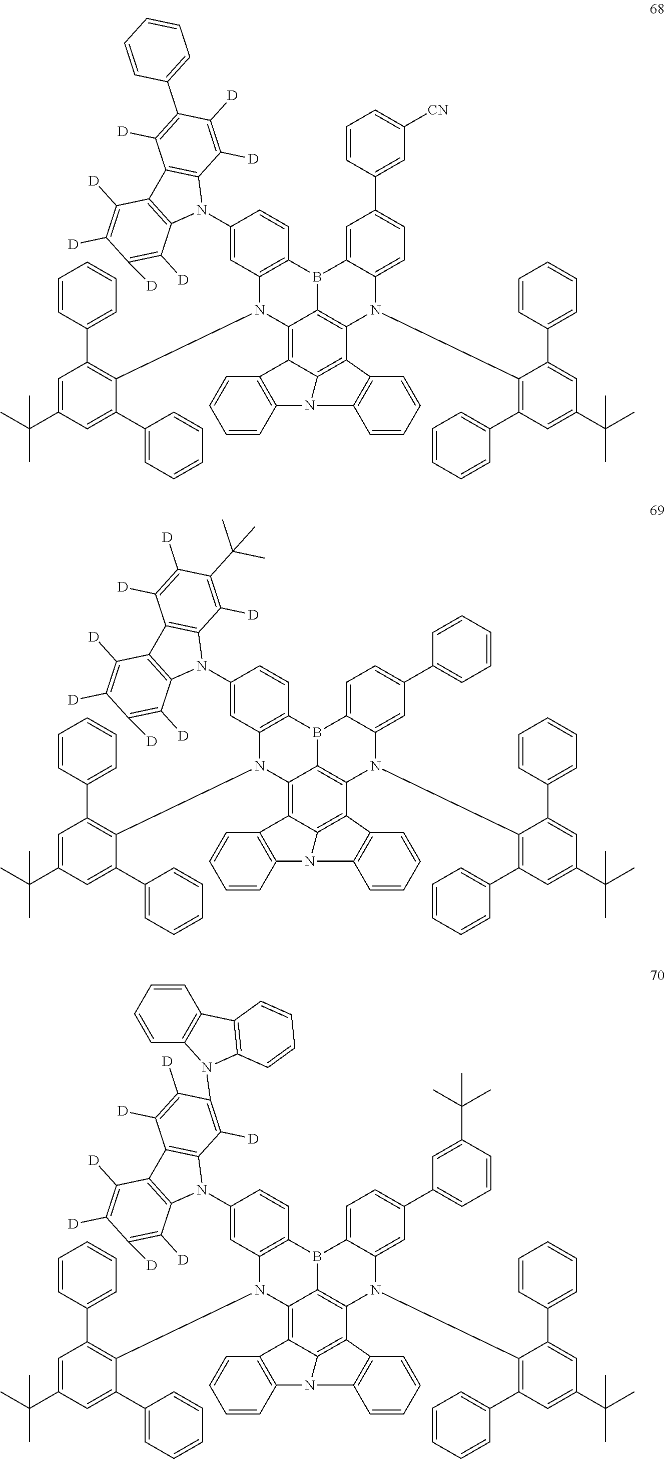 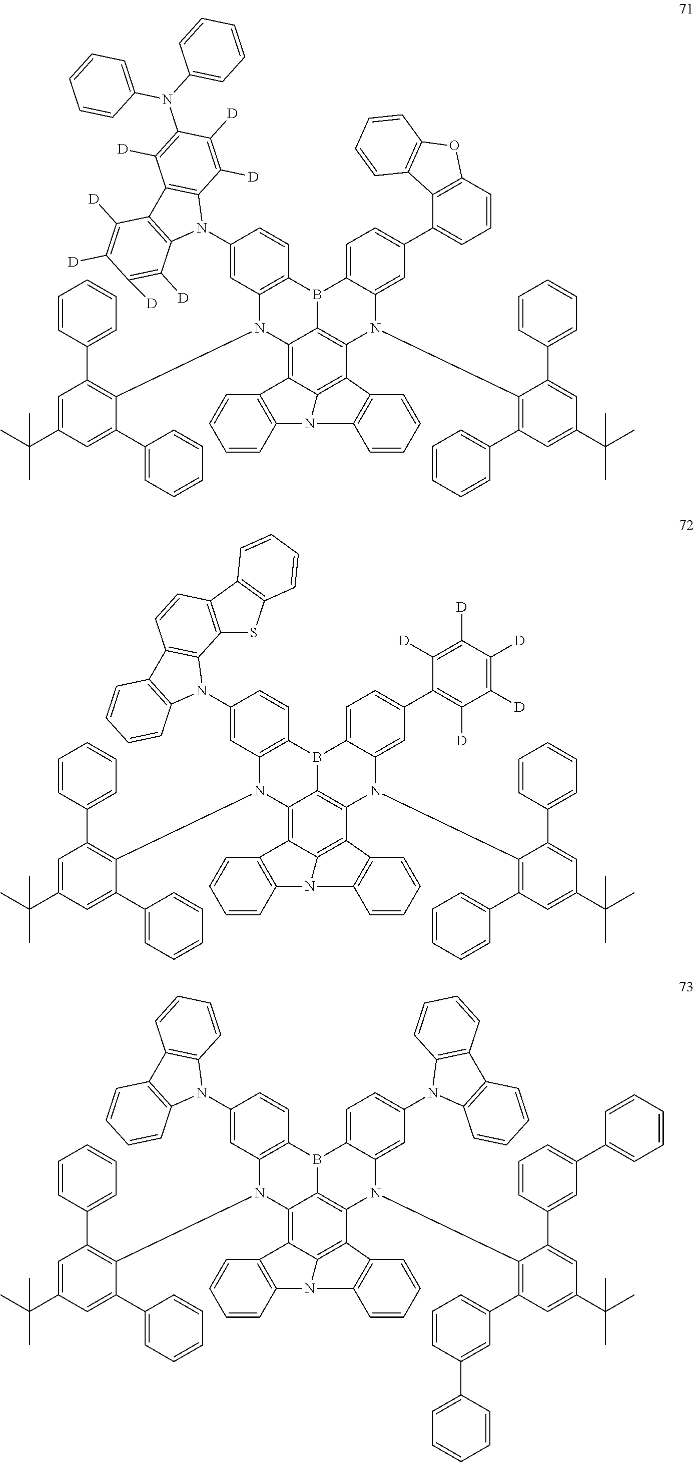 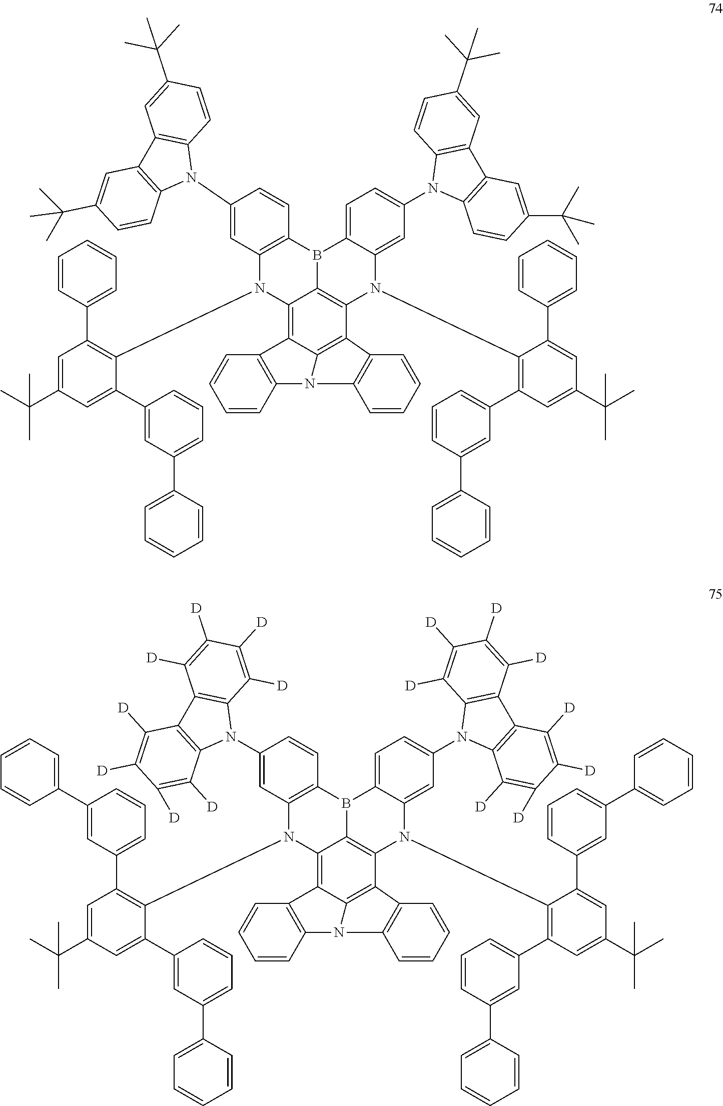 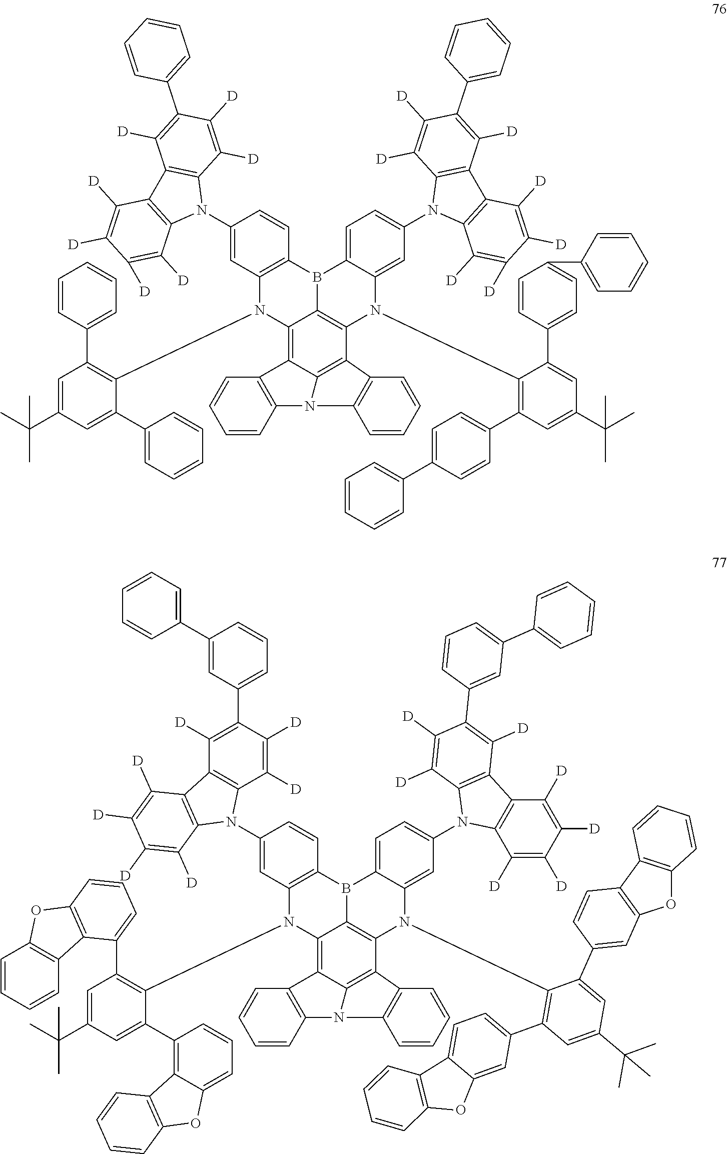 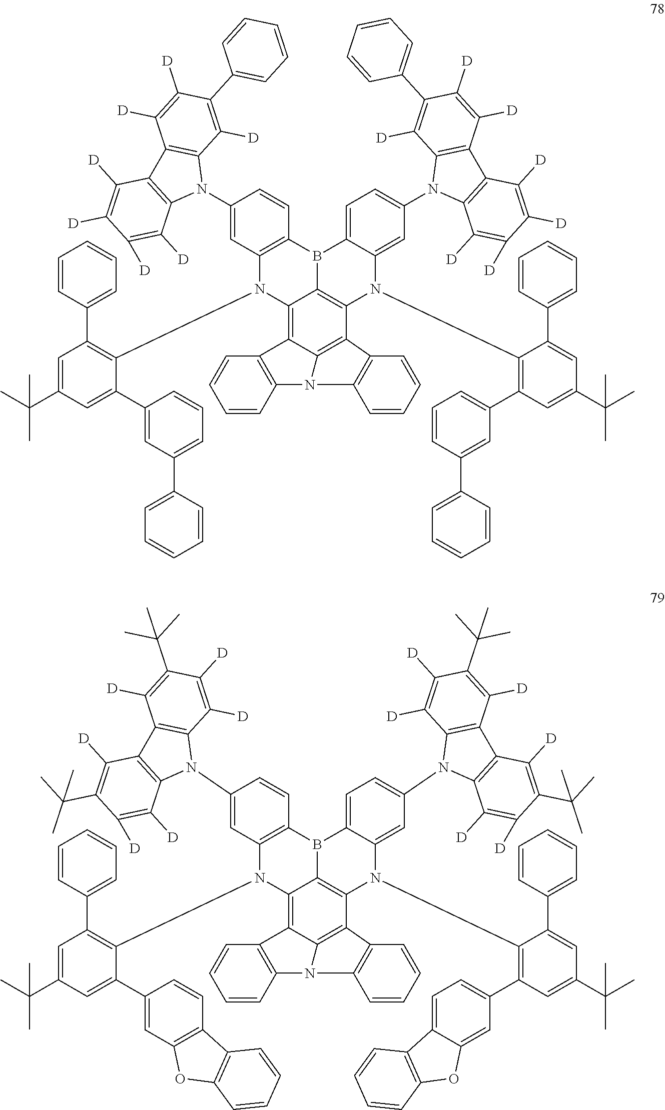 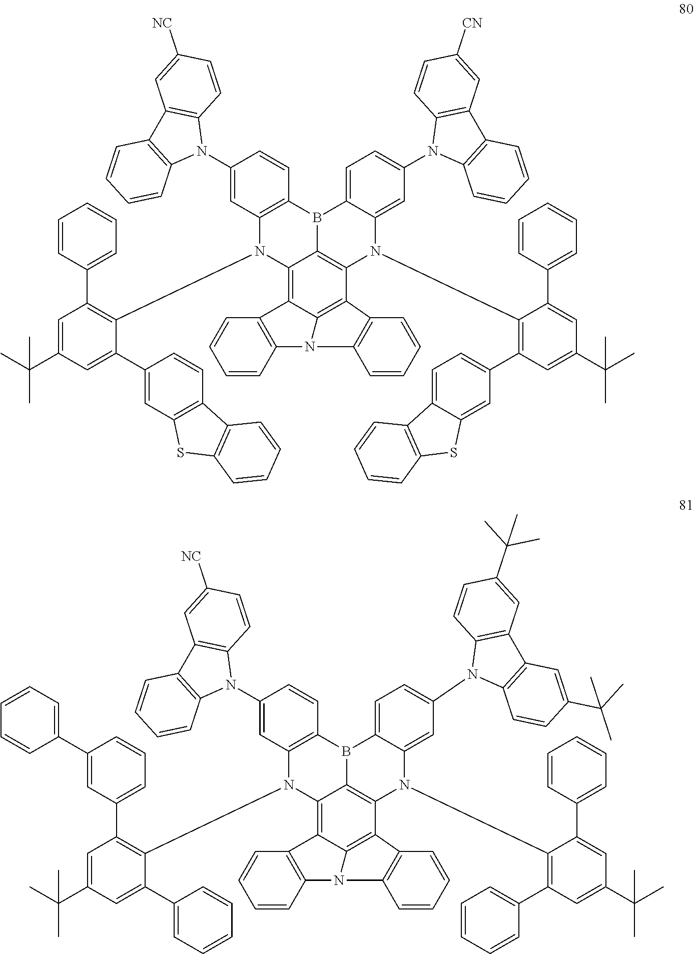 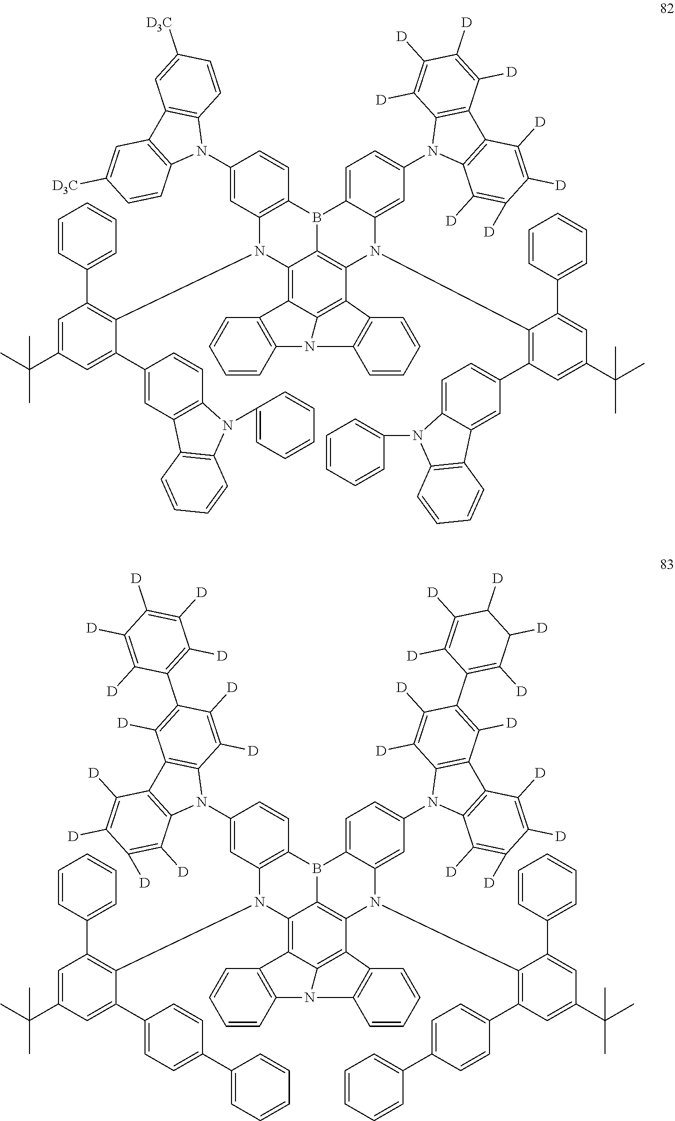 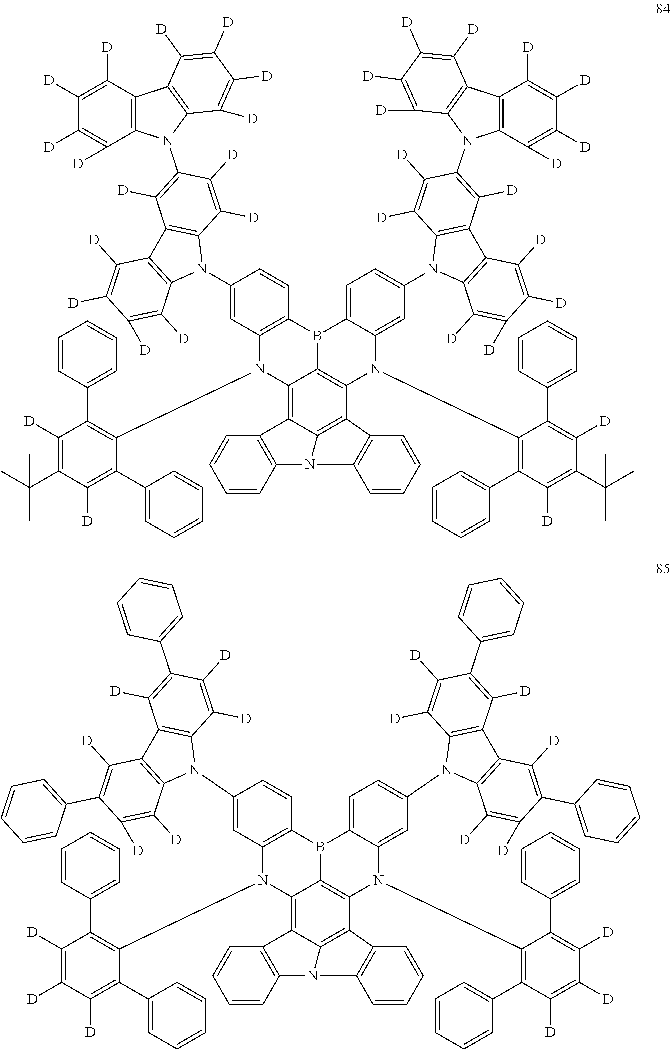 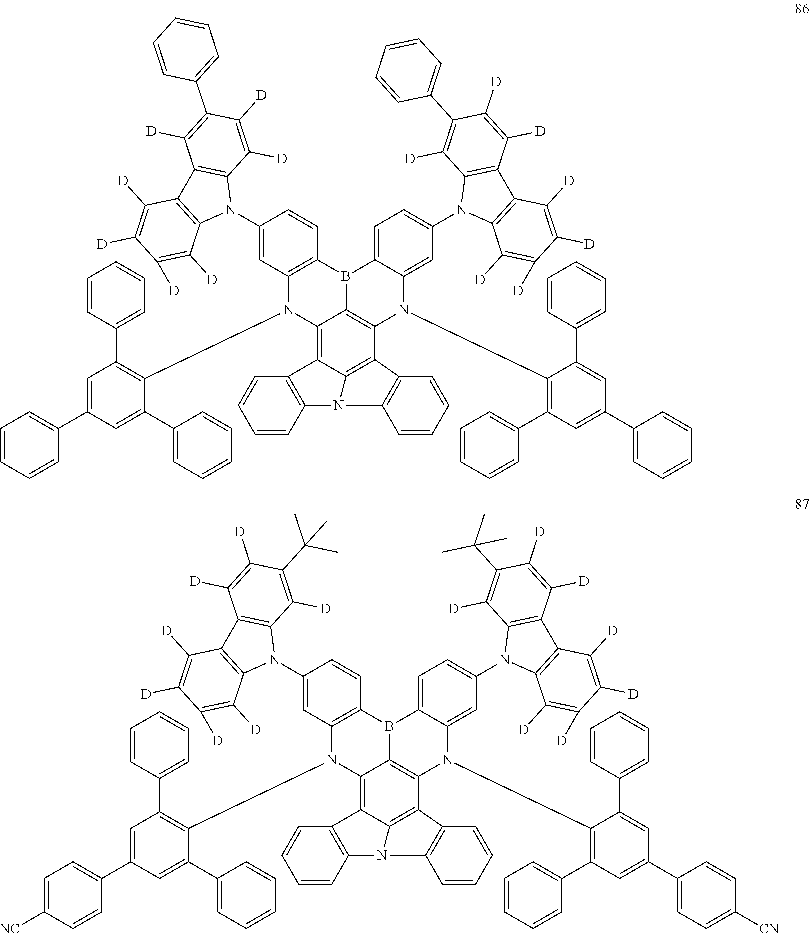 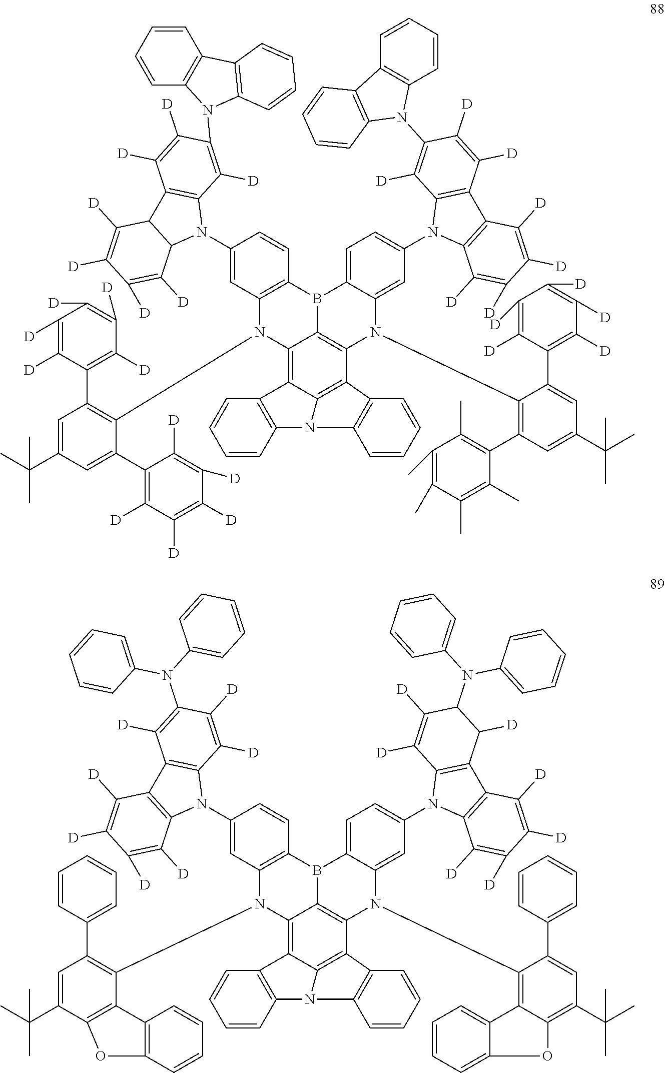 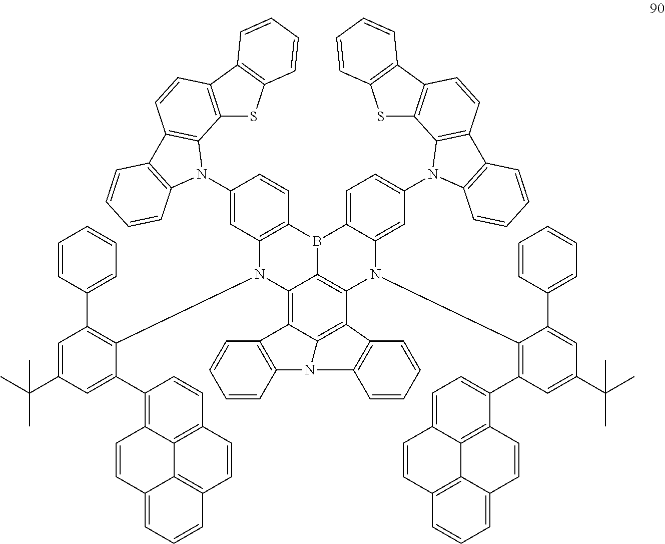 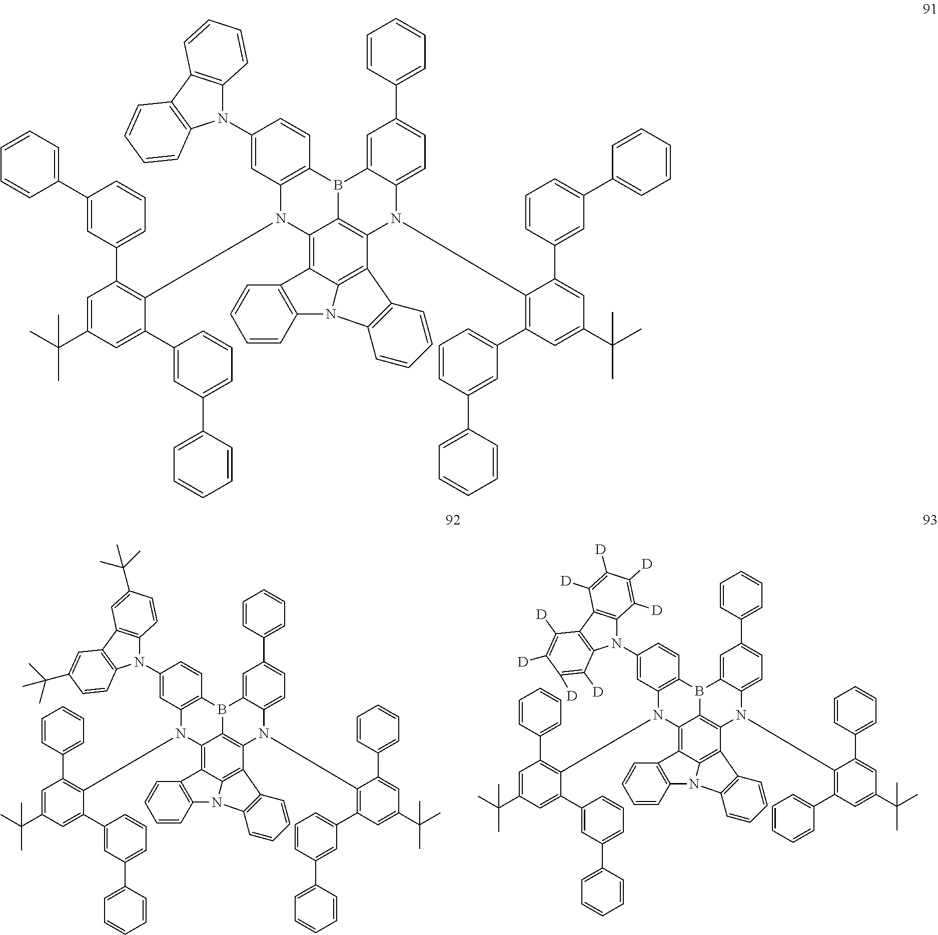 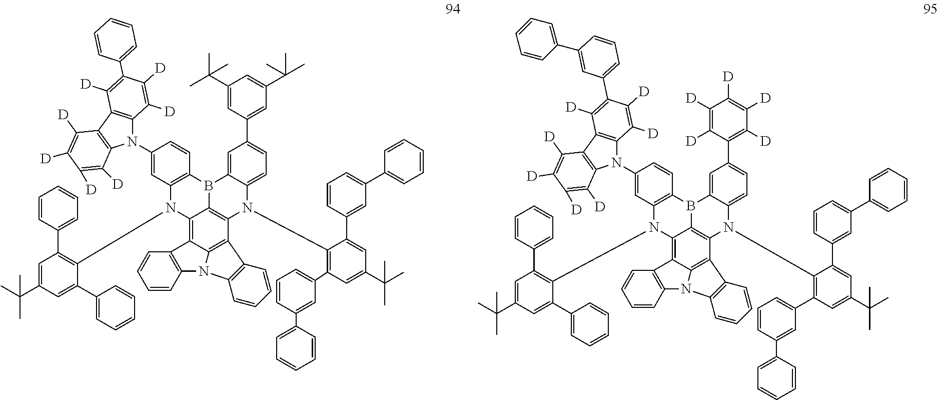 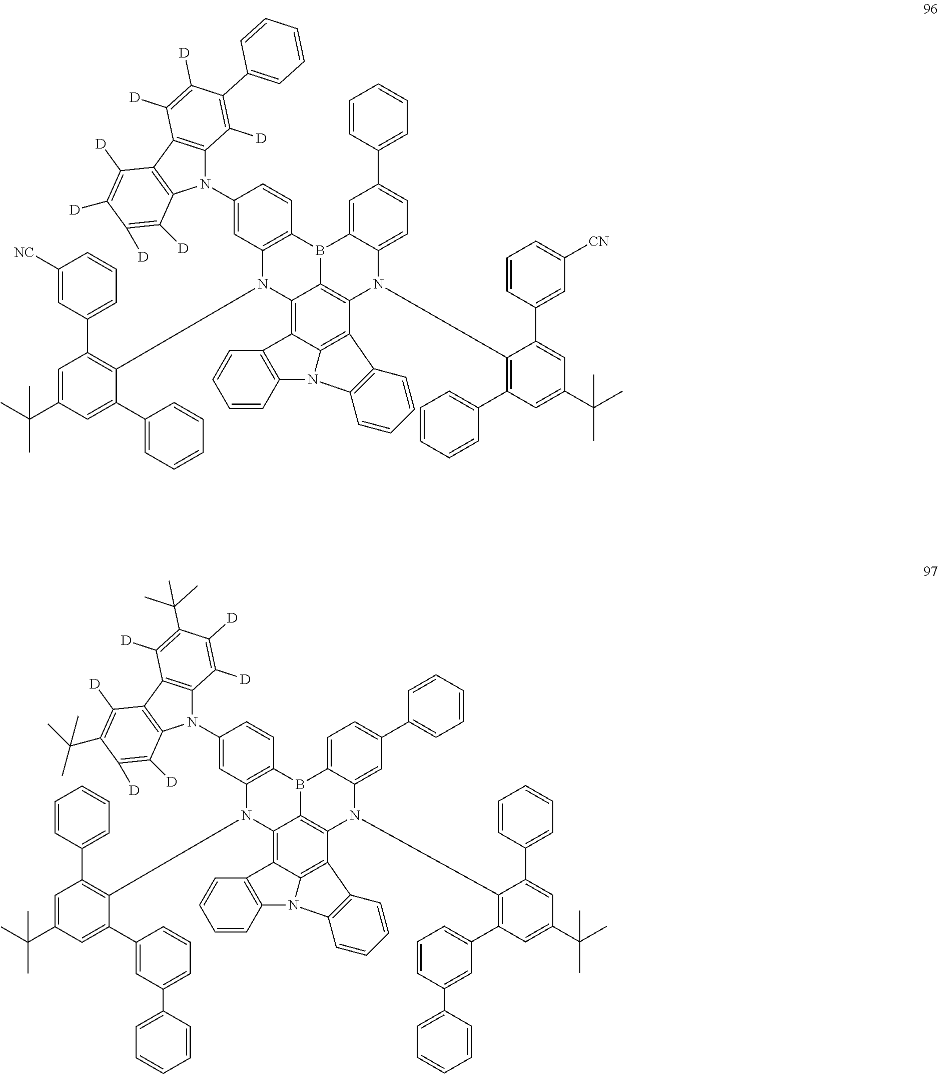 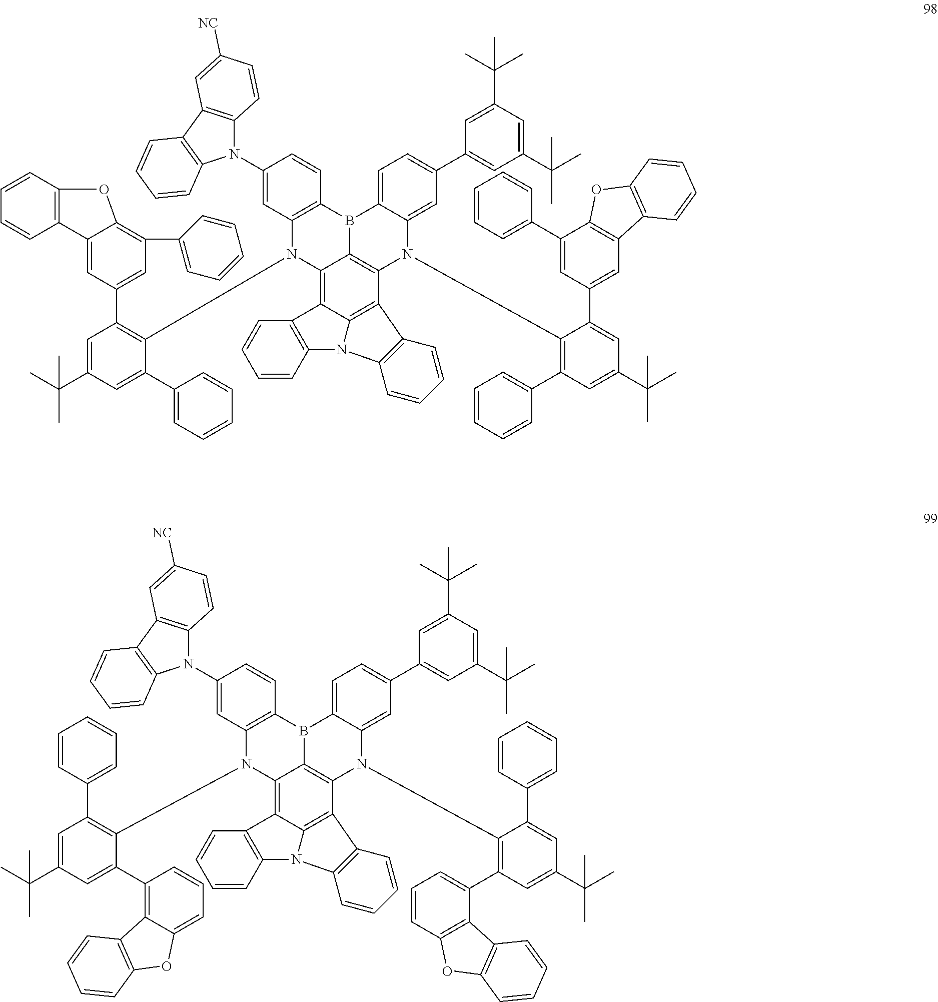 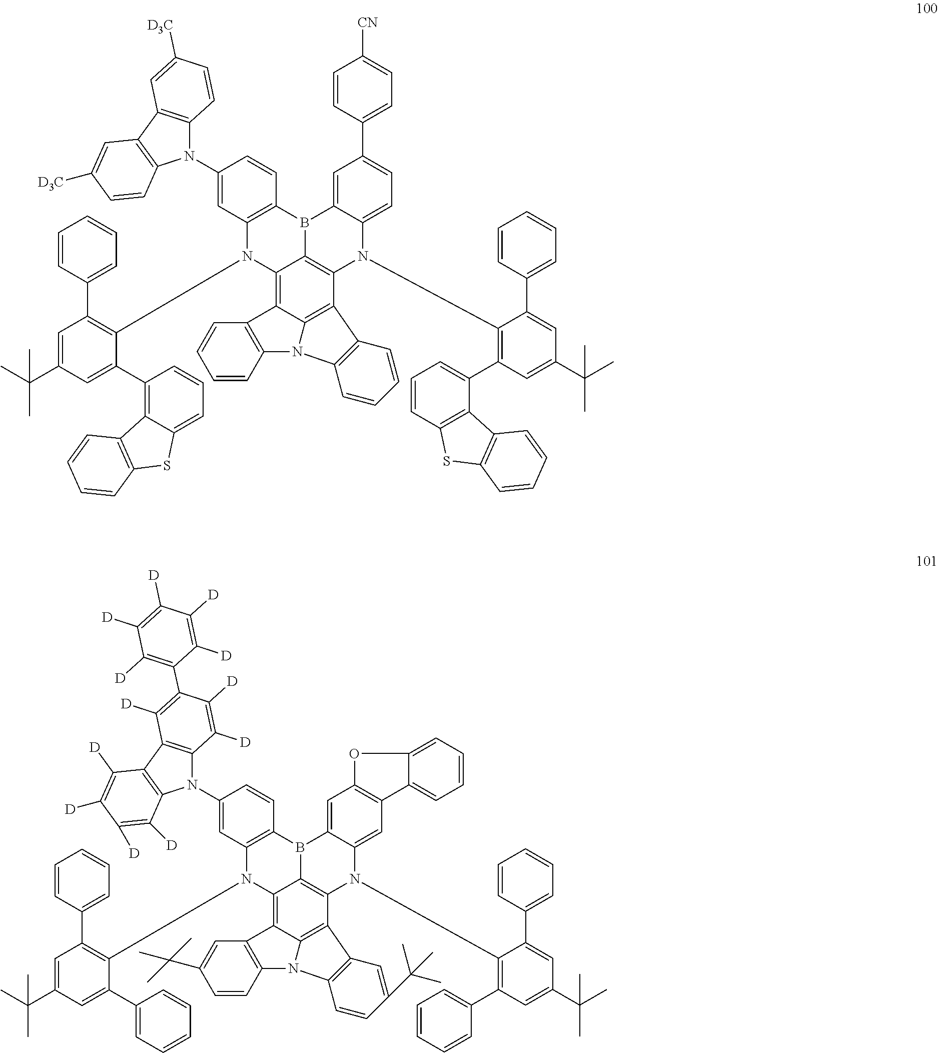 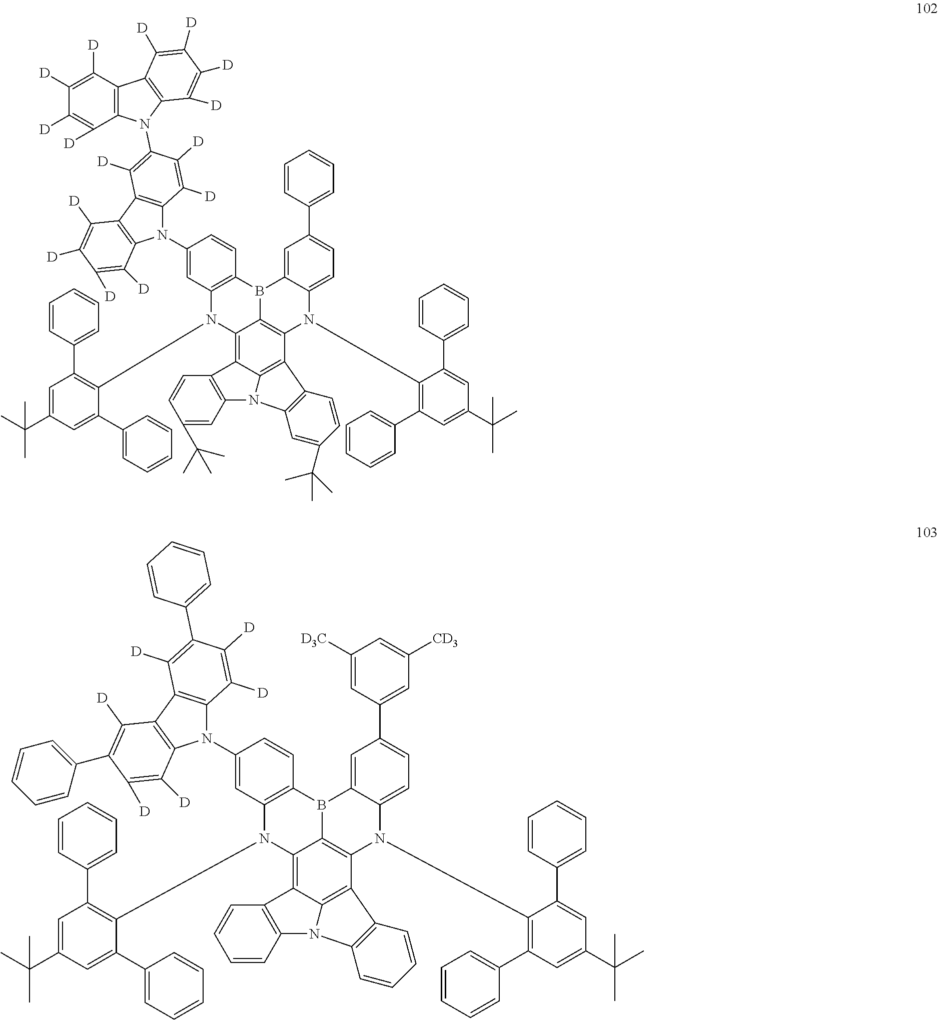 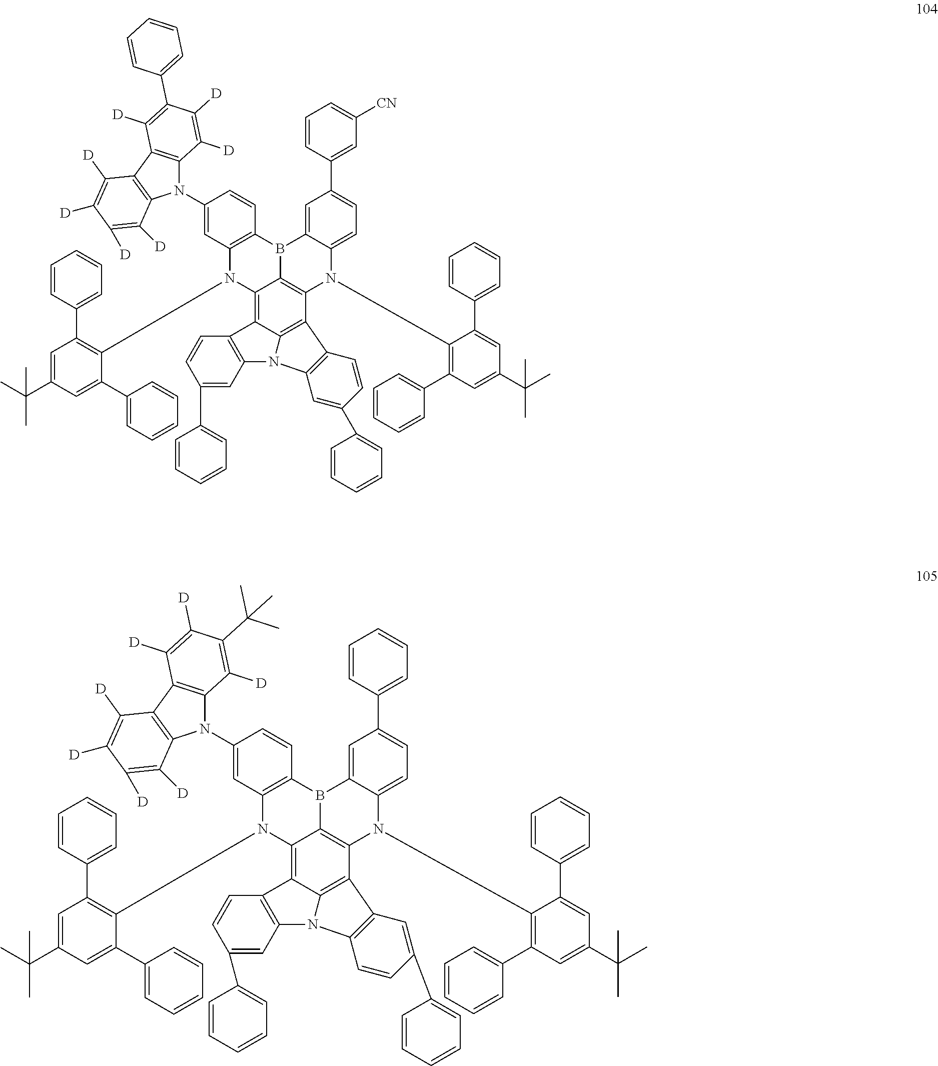 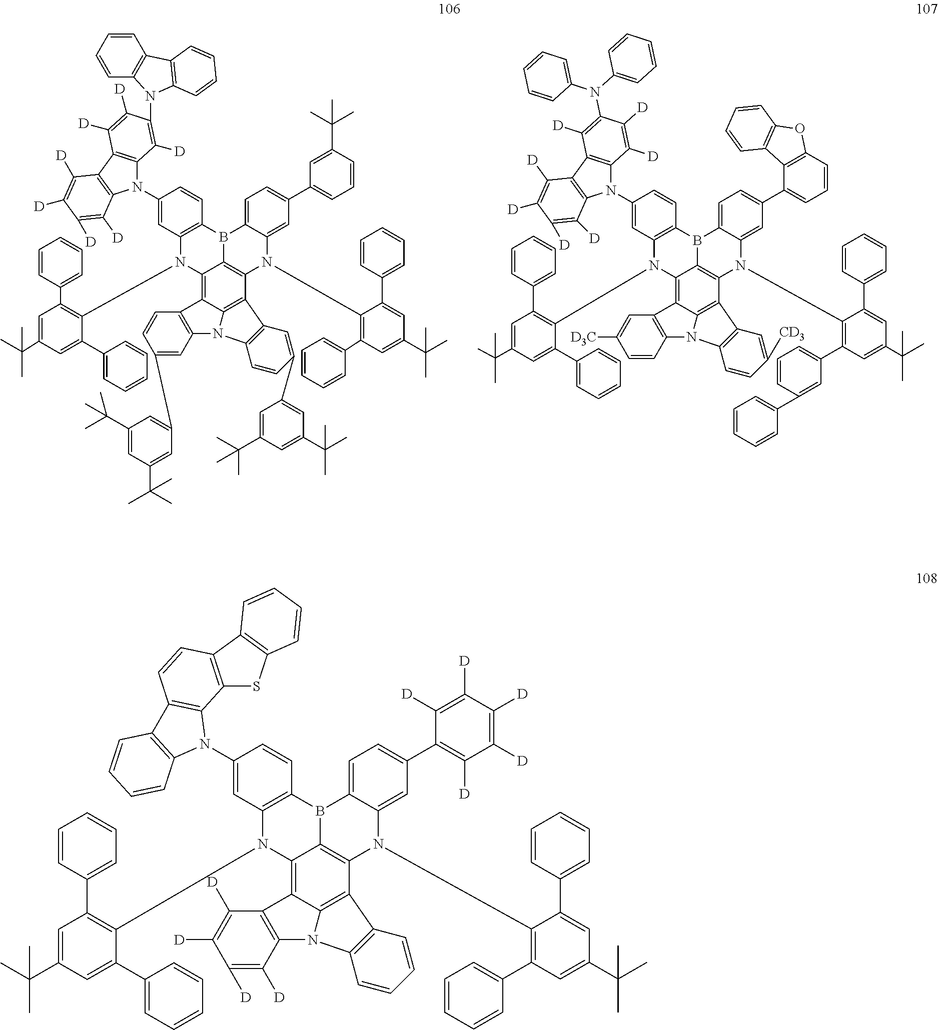 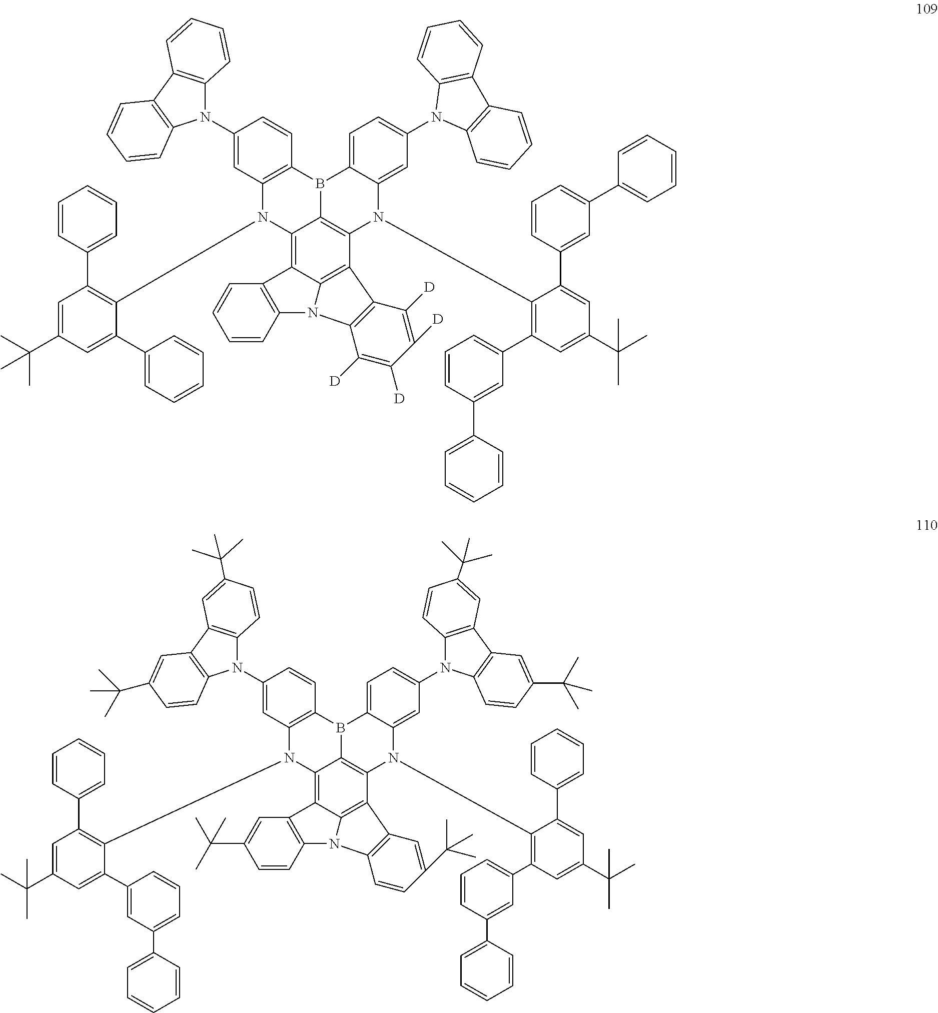 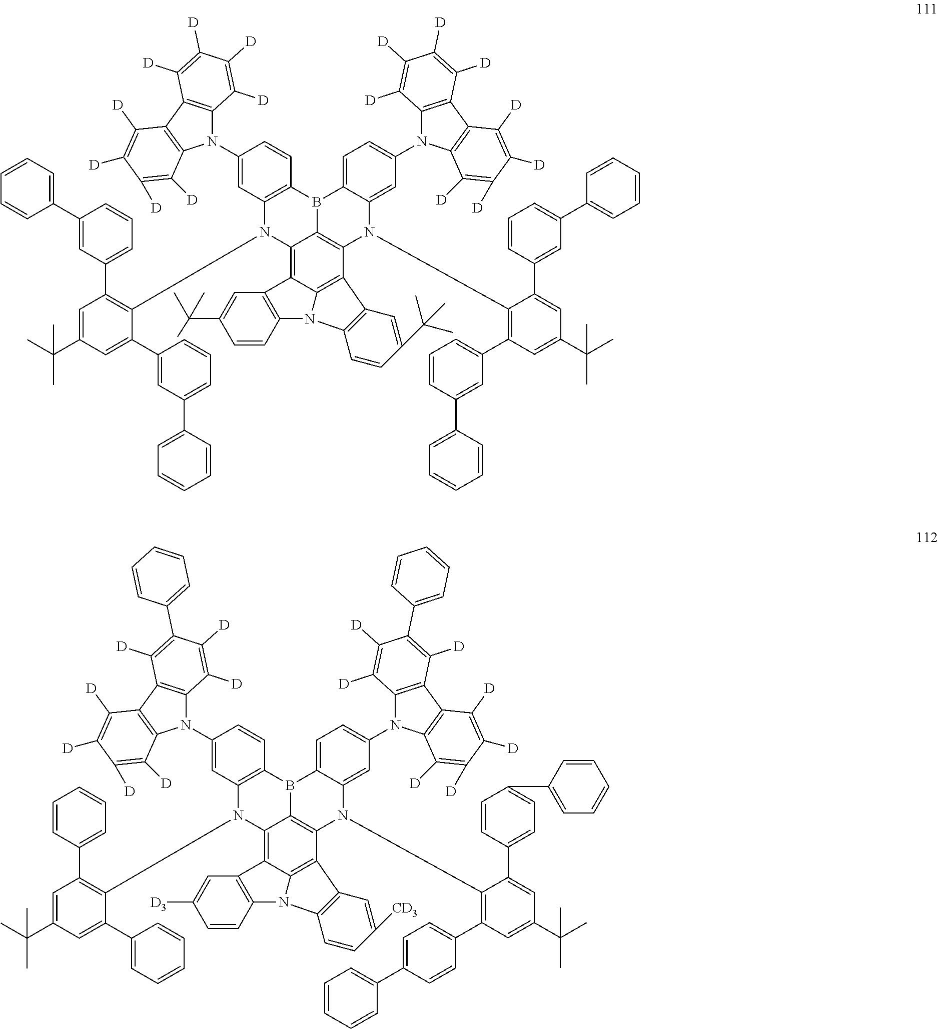 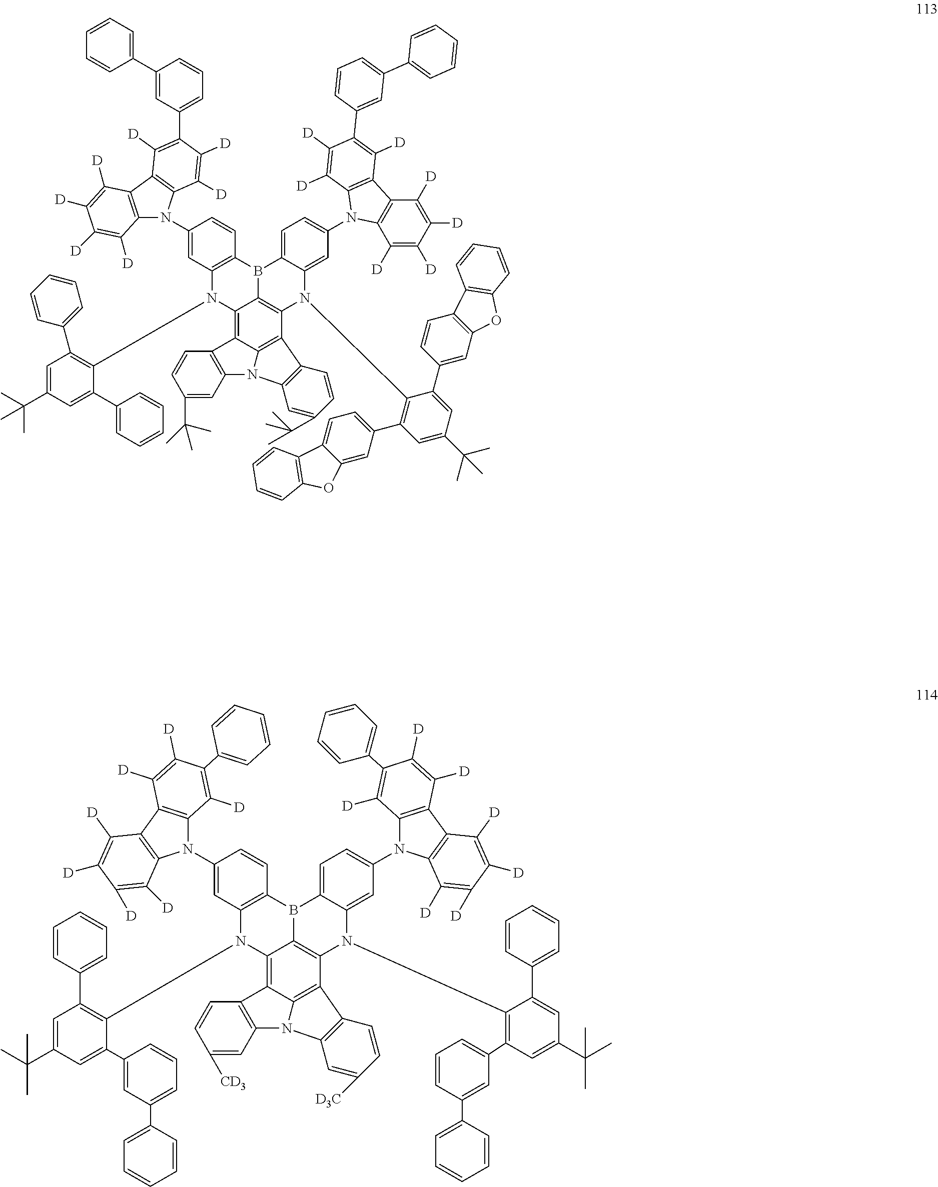 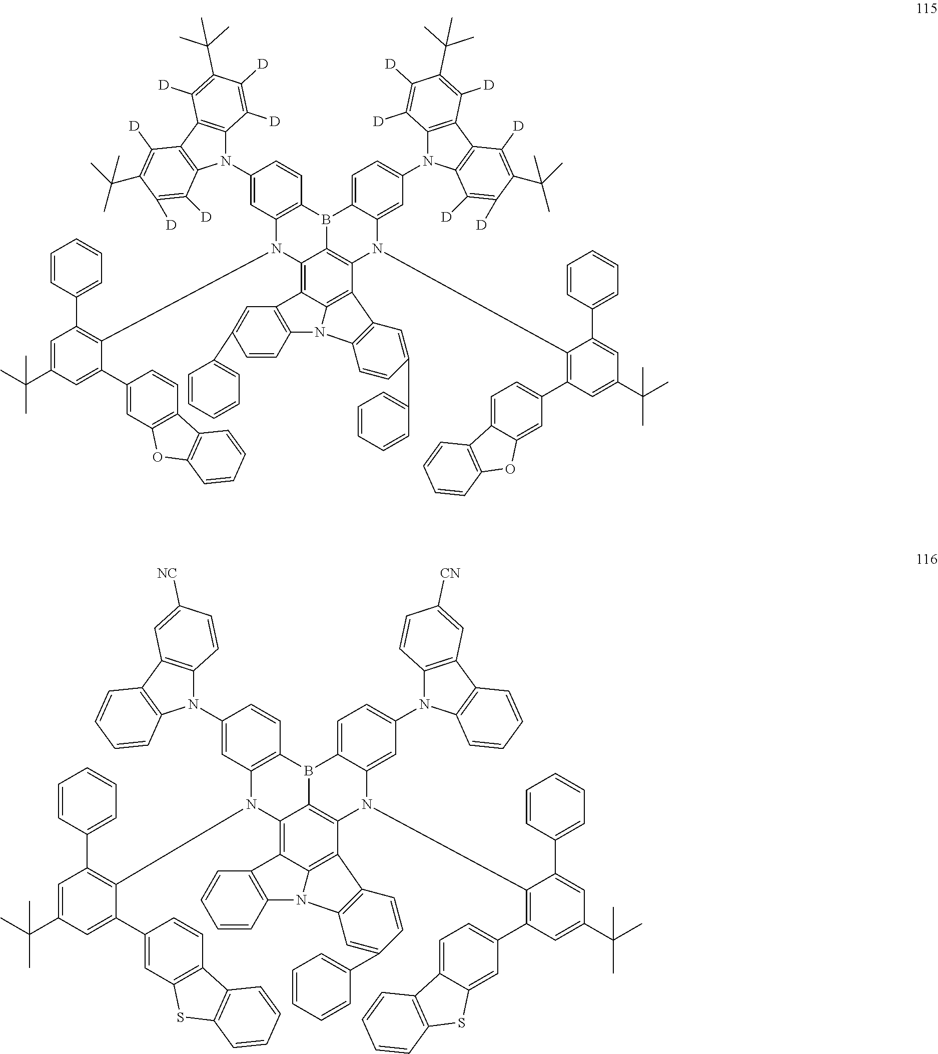 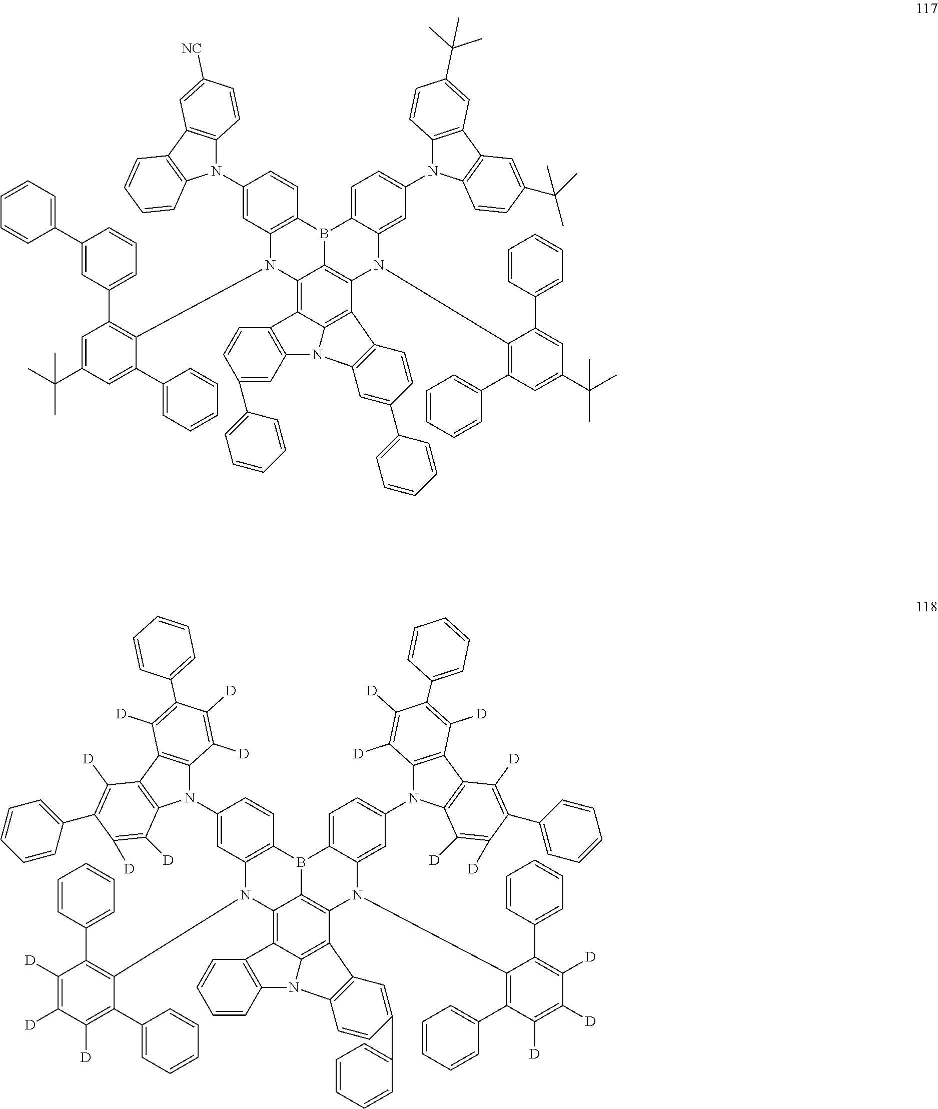 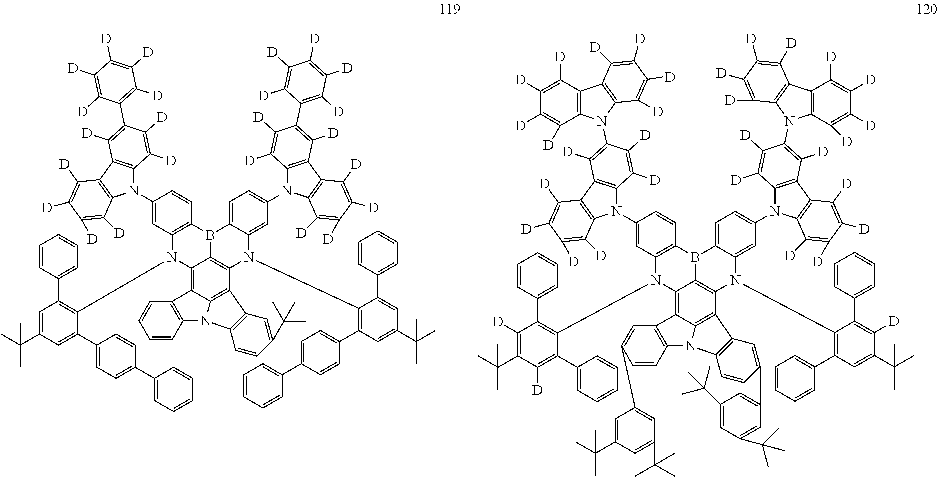 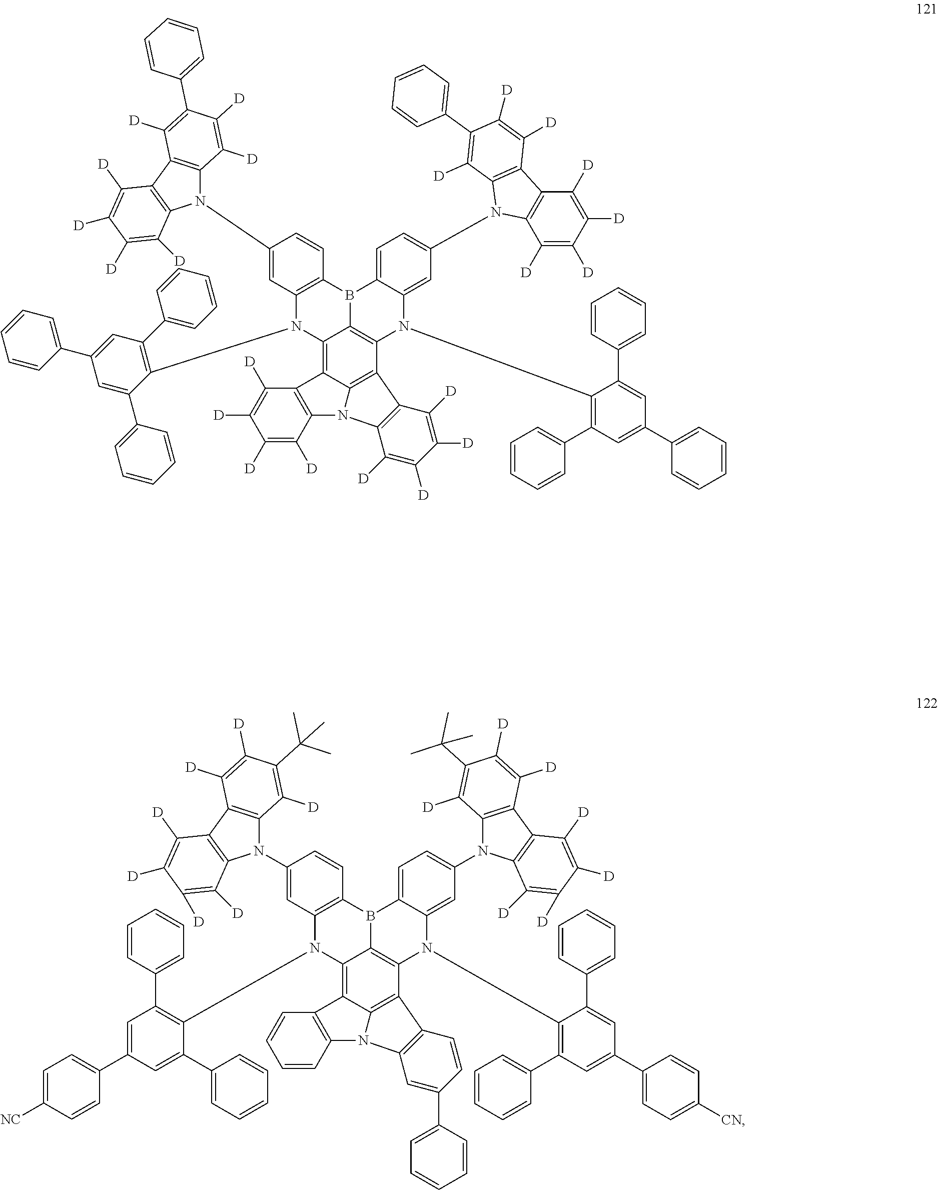
wherein, in Compound Group 1, D is a deuterium atom.

12. A fused polycyclic compound represented by Formula 1: 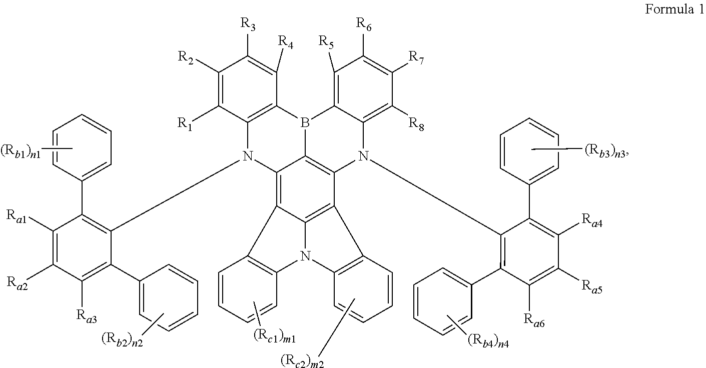
wherein, in Formula 1,
R₁ to R₈ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
n1 to n4 are each independently an integer of 0 to 5,
Rₐ₁ to Rₐ₆ and R_{b1} to R_{b4} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
m1 and m2 are each independently an integer of 0 to 4, and
R_{c1} and R_{c2} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms.

13. The fused polycyclic compound of claim 12, wherein Formula 1 is represented by Formula 1-A: 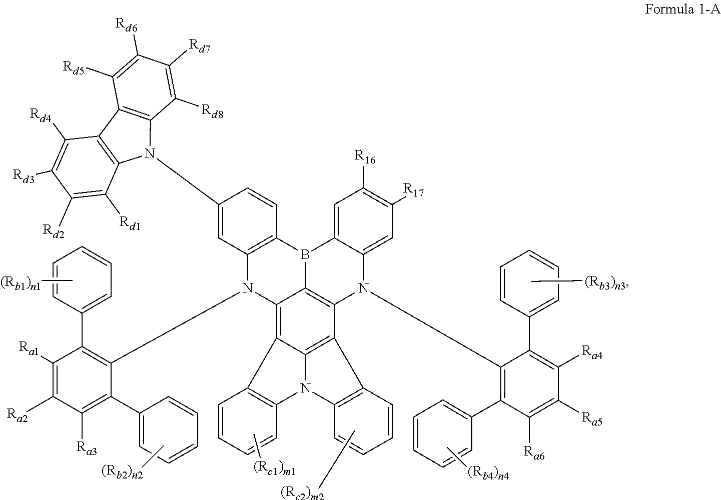
wherein, in Formula 1-A,
R₁₆ and R₁₇ are each independently a hydrogen atom, a deuterium atom, a halogen atom, a substituted or unsubstituted oxy group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms,
R_{d1} to R_{d8} are each independently a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
n1 to n4, Rₐ₁ to Rₐ₆, R_{b1} to R_{b4}, m1, m2, R_{c1}, and R_{c2} are the same as defined in Formula 1.

14. The fused polycyclic compound of claim 13, wherein Formula 1-A is represented by Formula 1-A1: 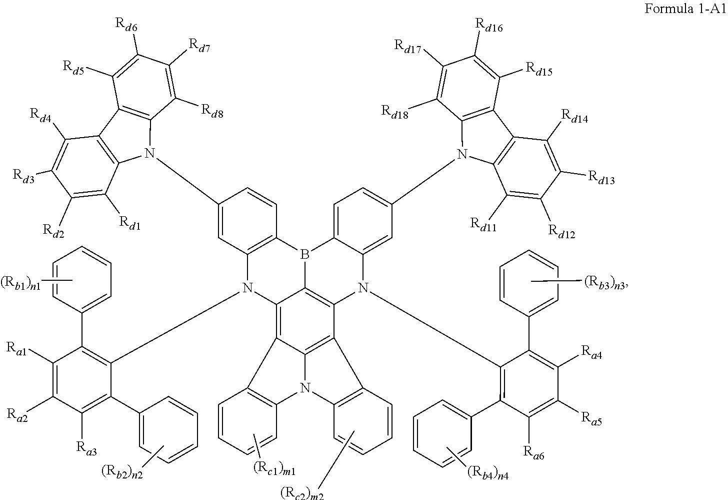
wherein, in Formula 1-A1,
Rₐ₁₁ to Rₐ₁₈ are each independently a hydrogen atom, a deuterium atom, a halogen atom, a cyano group, a substituted or unsubstituted amine group, a substituted or unsubstituted thio group, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and/or combined with an adjacent group to form a ring, and
n1 to n4, Rₐ₁ to Rₐ₆, R_{b1} to R_{b4}, m1, m2, R_{c1}, R_{c2}, R₁₆, R₁₇, and Rₐ₁ to R_{d8} are the same as defined in Formula 1-A.

15. The fused polycyclic compound of claim 12, wherein, in Formula 1, R₁ to R₈ are each independently a hydrogen atom, a deuterium atom, or represented by one selected from among R-1 to R-26: 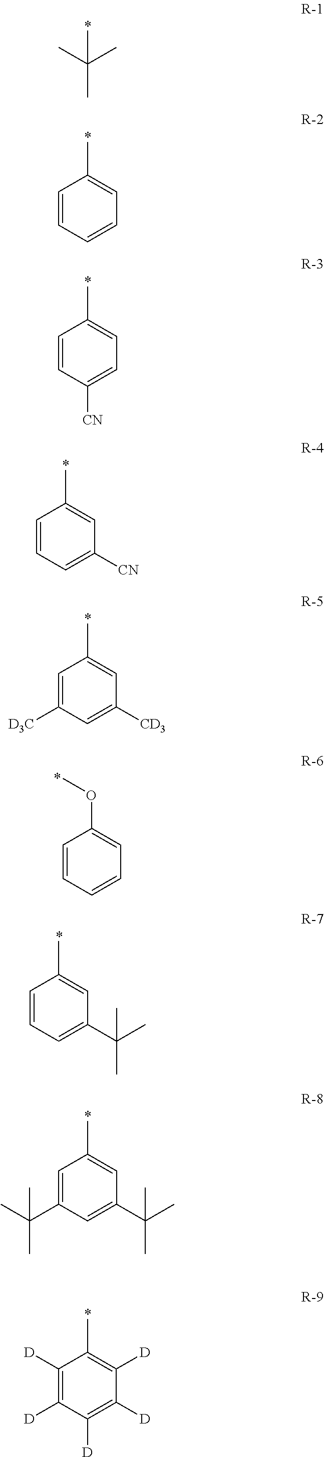 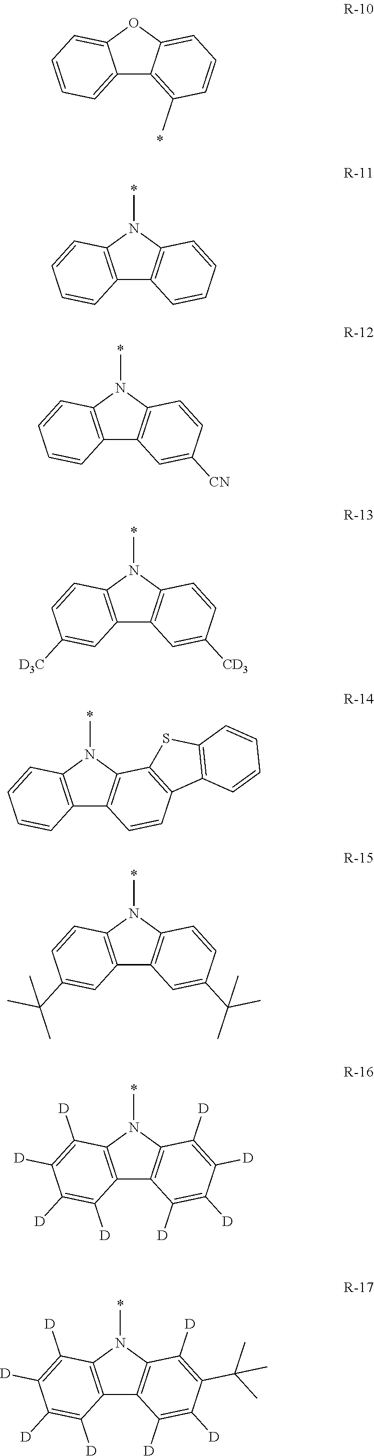 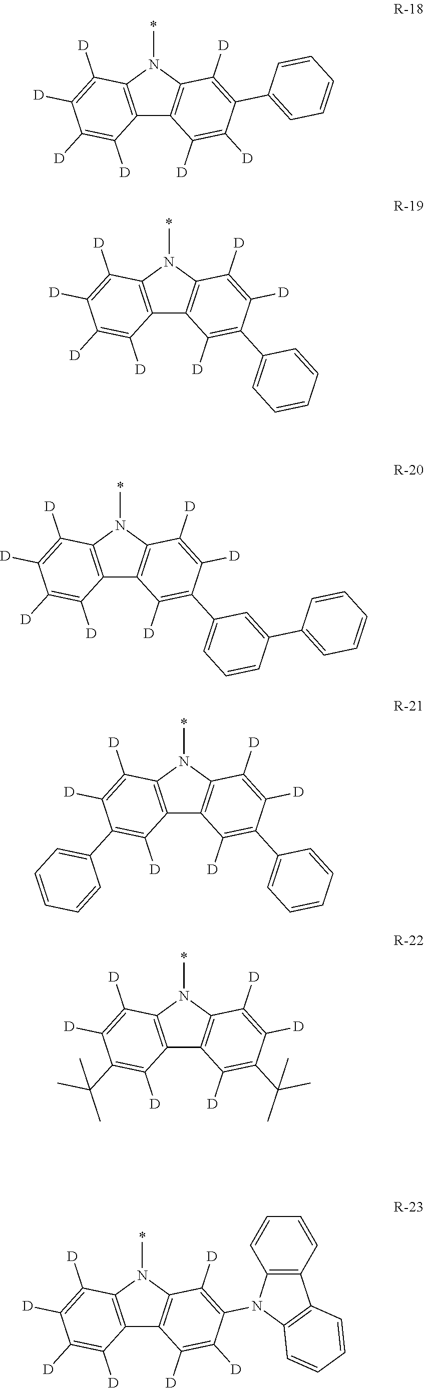 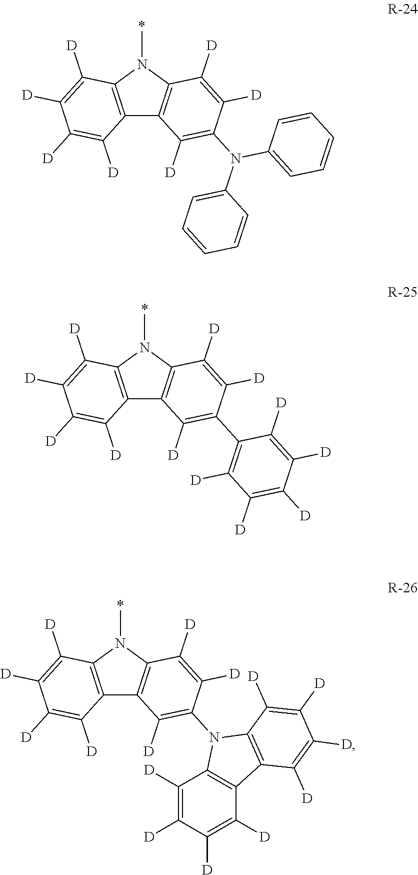
wherein, in R-5, R-9, R-13, and R-16 to R-26, D is a deuterium atom.

16. The fused polycyclic compound of claim 12, wherein, in Formula 1, R₁ to R₈ are each independently a hydrogen atom, a deuterium atom, a substituted or unsubstituted t-butyl group, a substituted or unsubstituted aryl oxy group, a substituted or unsubstituted phenyl group, a substituted or unsubstituted carbazole group, a substituted or unsubstituted dibenzofuran group, or a substituted or unsubstituted benzo thieno carbazole group.

17. The fused polycyclic compound of claim 12, wherein Formula 1 is represented by one selected from among Formula 1-B1 to Formula 1-B3: 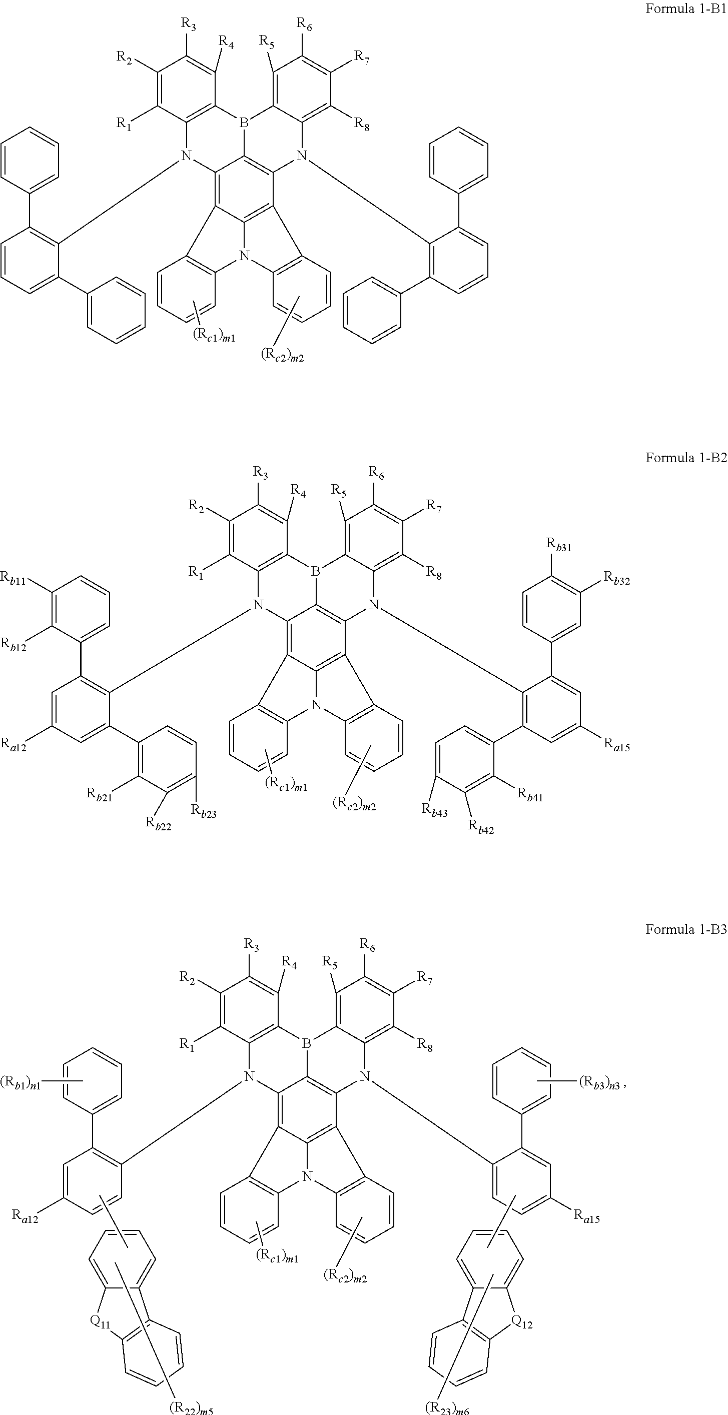
wherein, in Formula 1-B2,
R_{b11}, R_{b12}, R_{b21} to R_{b23}, R_{b31}, R_{b32}, and R_{b41} to R_{b43} are each independently a hydrogen atom, a deuterium atom, a cyano group, a substituted or unsubstituted amine group, a substituted or unsubstituted oxy group, a substituted or unsubstituted thio group, a substituted or unsubstituted alkyl group of 1 to 30 carbon atoms, a substituted or unsubstituted alkenyl group of 2 to 30 carbon atoms, or a substituted or unsubstituted aryl group of 6 to 30 ring-forming carbon atoms, and/or combined with an adjacent group to form a ring,
wherein, in Formula 1-B3,
Q₁₁ and Q₁₂ are each independently NR₂₁, O, or S,
n5 and n6 are each independently an integer of 0 to 7, and
R₂₁ to R₂₃ are each independently a hydrogen atom, a deuterium atom, or a substituted or unsubstituted aryl group of 6 to 30 ring-forming carbon atoms,
wherein, in Formula 1-B2 and Formula 1-B3,
Rₐ₁₂ and Rₐ₁₅ are each independently a hydrogen atom, a deuterium atom, a cyano group, a substituted or unsubstituted alkyl group of 1 to 30 carbon atoms, or a substituted or unsubstituted aryl group of 6 to 30 ring-forming carbon atoms, and
wherein, in Formula 1-B1 to Formula 1-B3,
R₁ to R₈, n1, n3, R_{b1}, R_{b3}, m1, m2, R_{c1}, and R_{c2} are the same as defined in Formula 1.

18. The fused polycyclic compound of claim 12, wherein, in Formula 1, R_{c1} and R_{c2} are each independently a hydrogen atom, a deuterium atom, a substituted or unsubstituted methyl group, a substituted or unsubstituted t-butyl group, or a substituted or unsubstituted phenyl group.

19. The fused polycyclic compound of claim 12, wherein, in Formula 1, R_{c1} and R_{c2} are each independently a hydrogen atom, a deuterium atom, or represented by one selected from among RC-1 to RC-4: 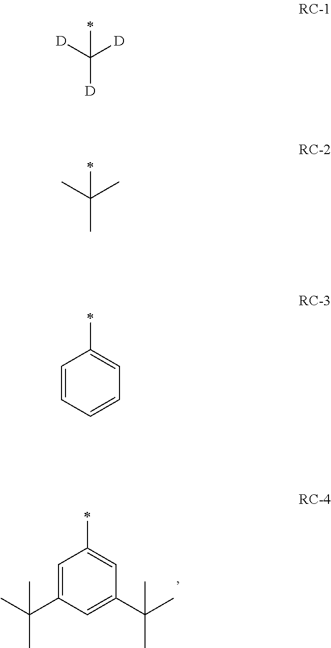
wherein, in RC-1, D is a deuterium atom.

20. The fused polycyclic compound of claim 12, wherein, in Formula 1, at least one selected from among R₁ to R₈, Rai to Rₐ₆, R_{b} to R_{b4}, R_{c1}, and R_{c2} comprises a deuterium atom, or a substituent comprising a deuterium atom.

21. The fused polycyclic compound of claim 12, wherein Formula 1 is represented by one selected from among the compounds in Compound Group 1: 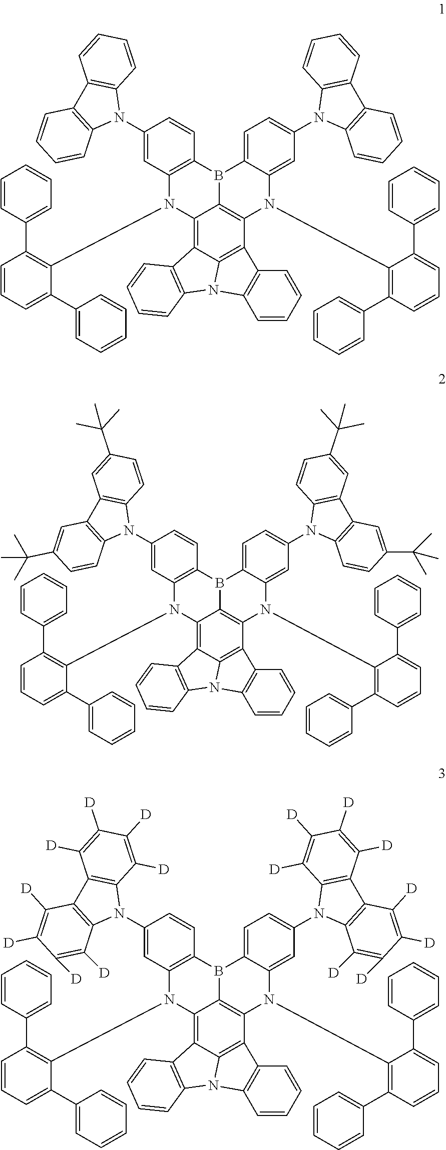 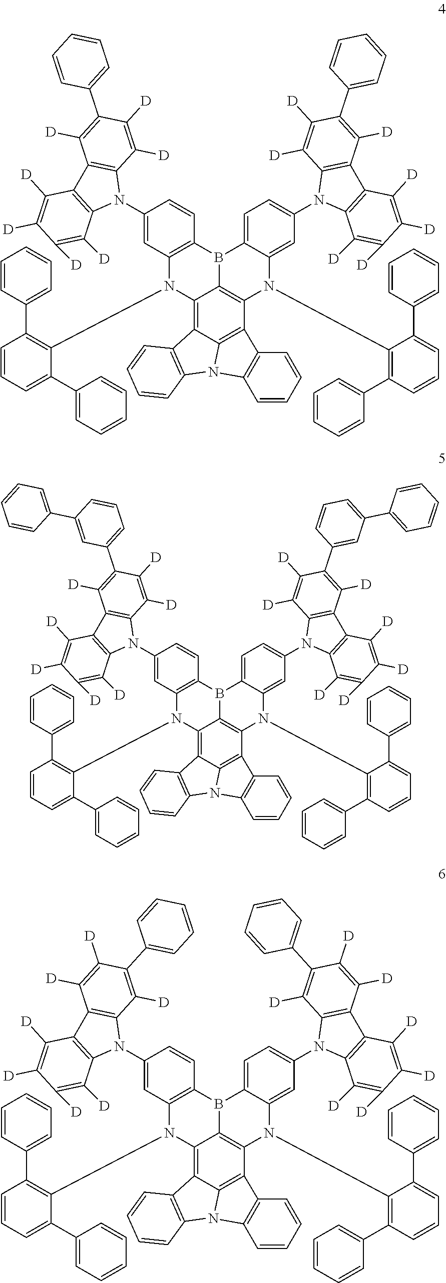 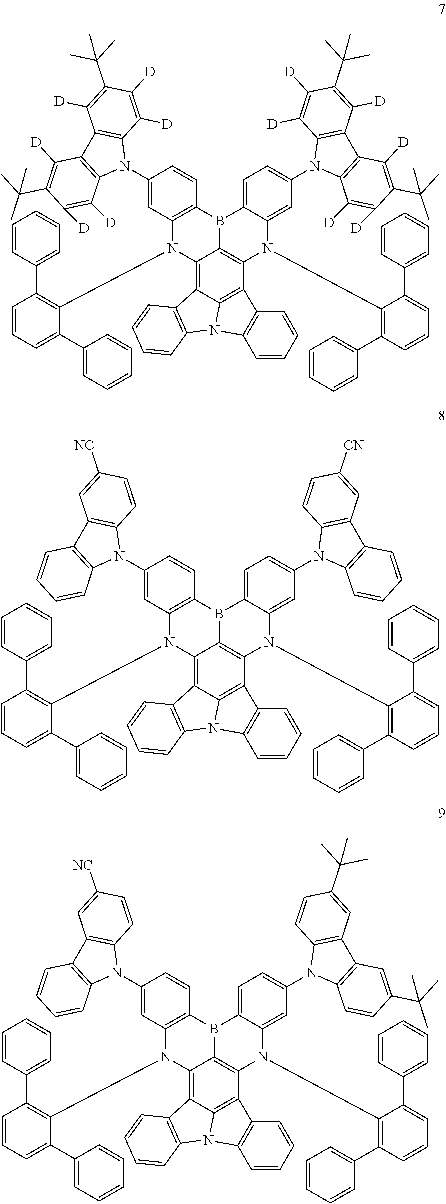 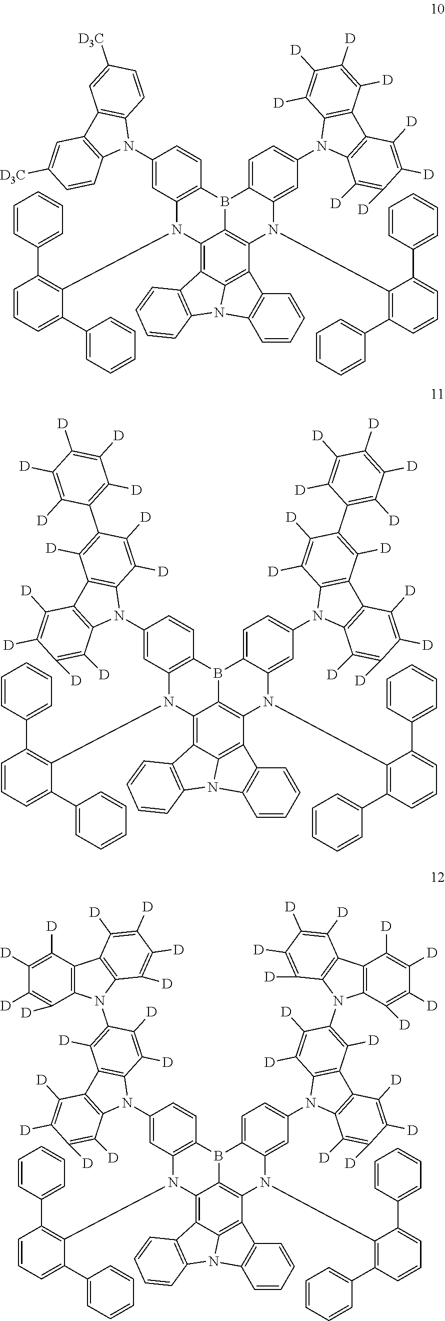 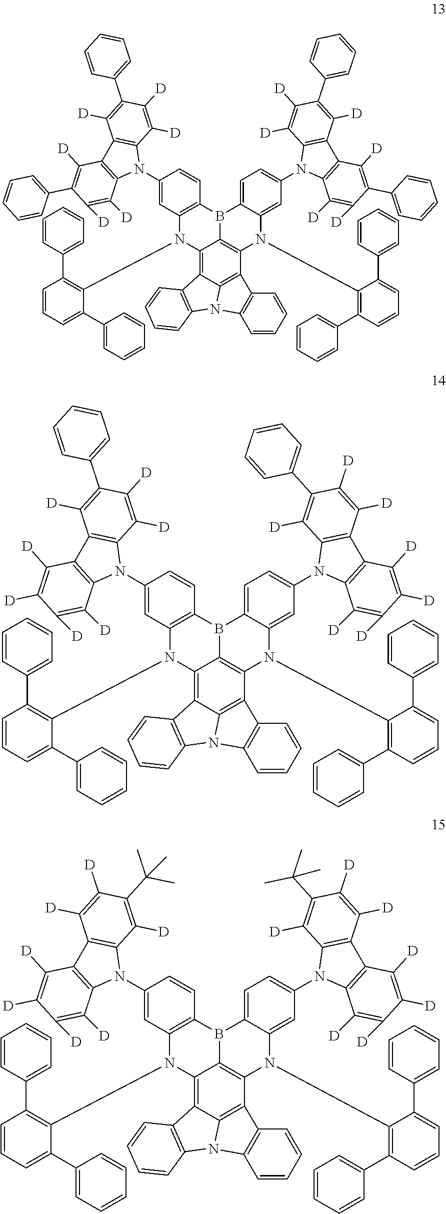 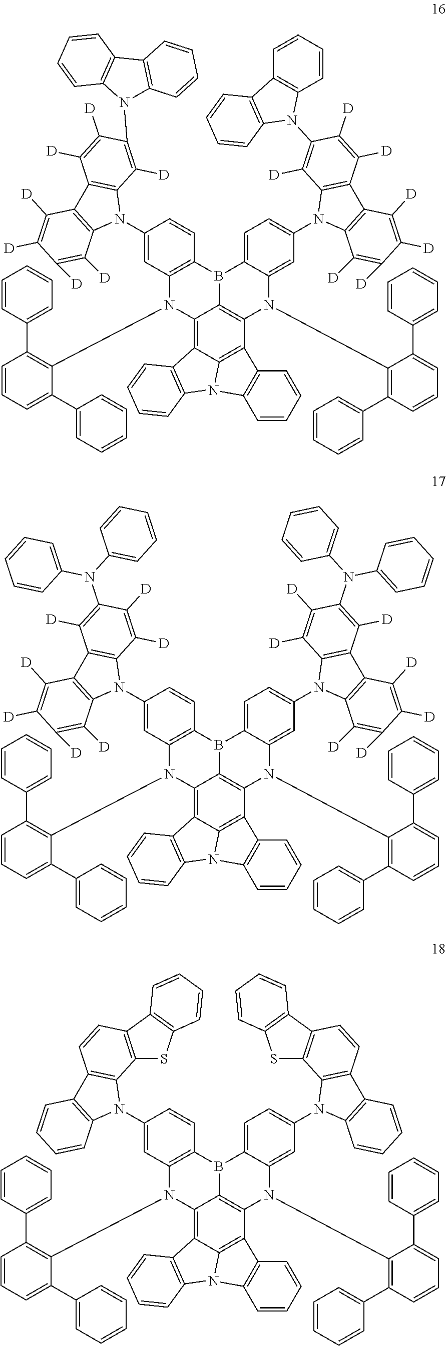 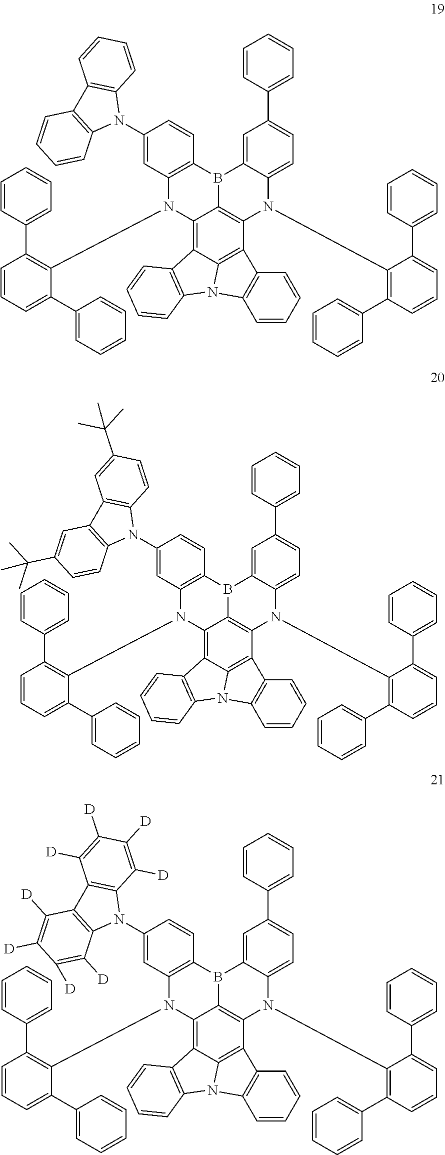 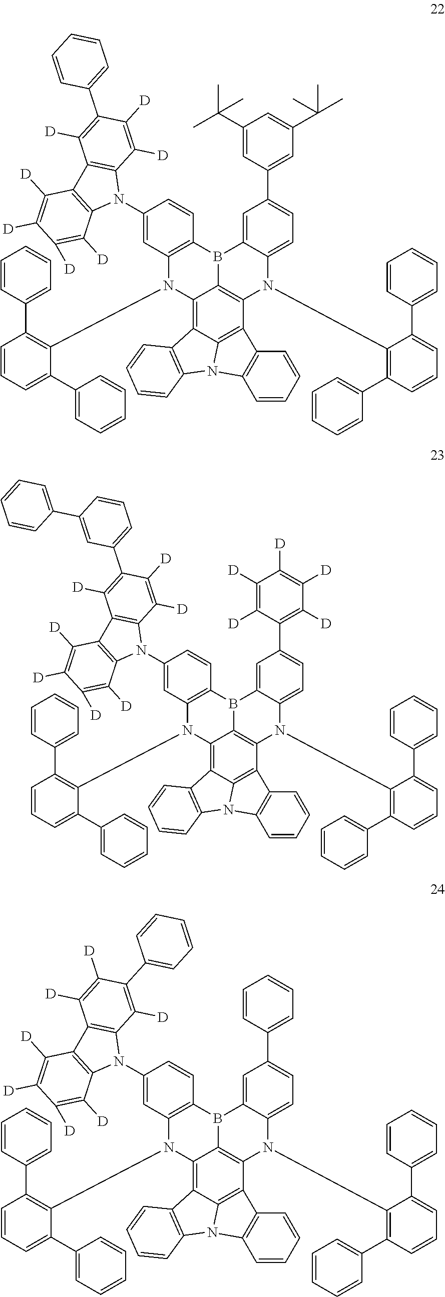 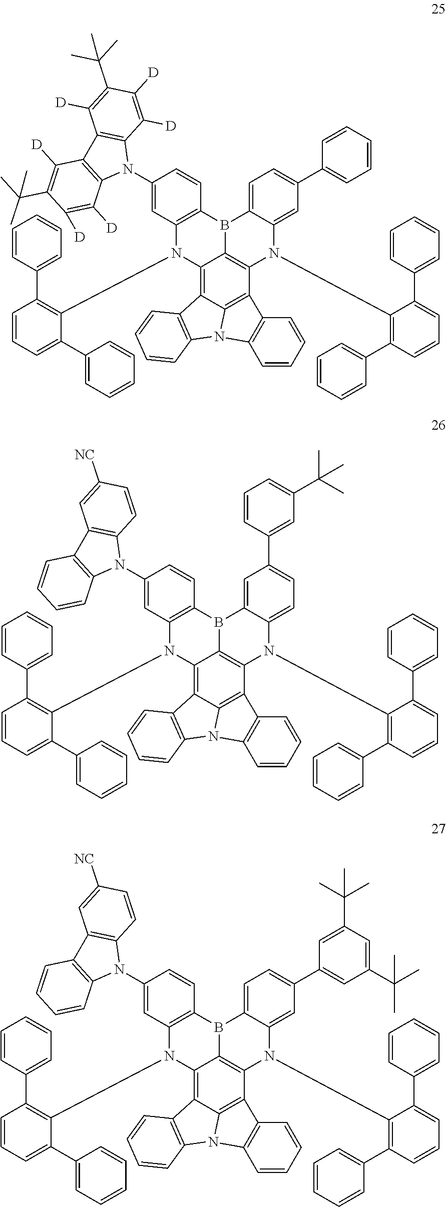 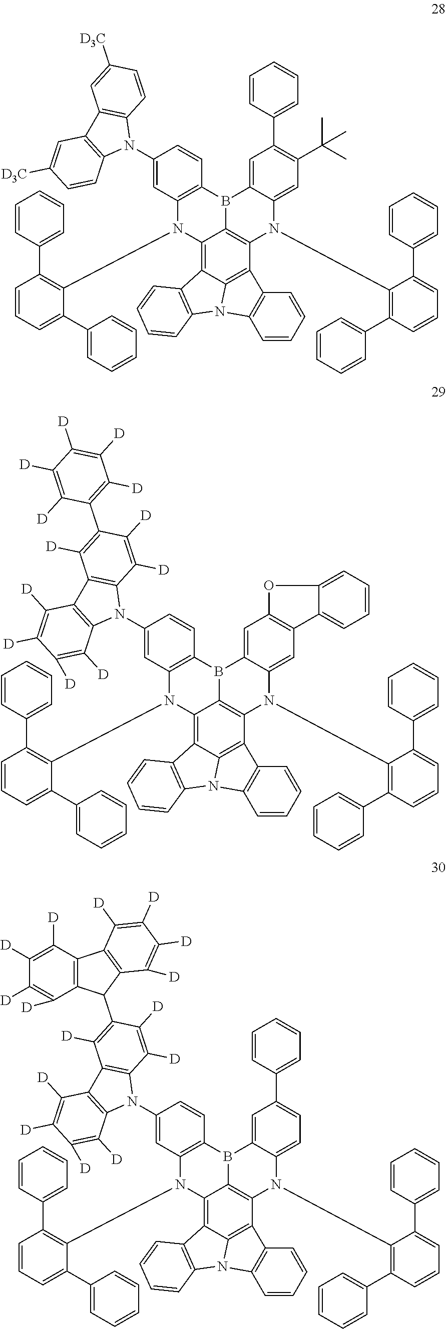 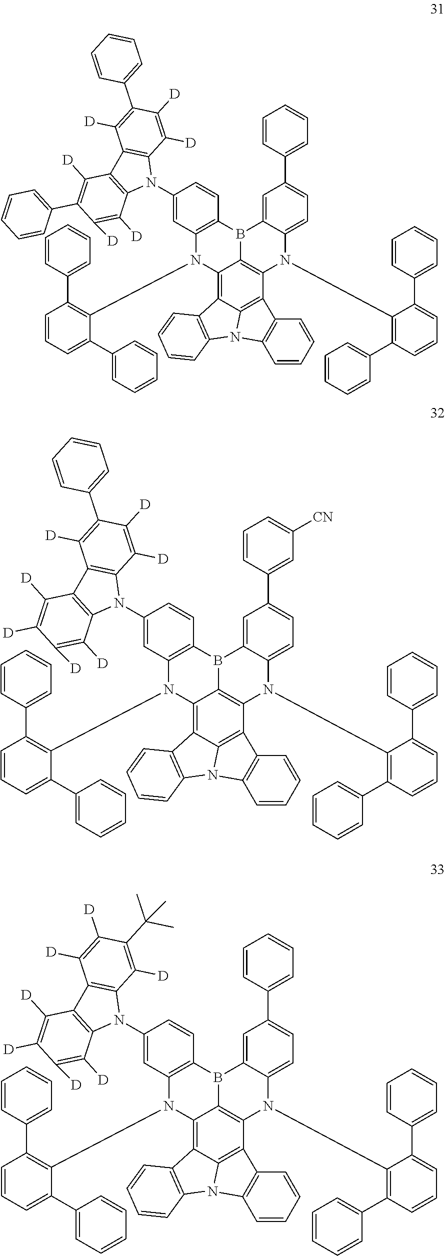 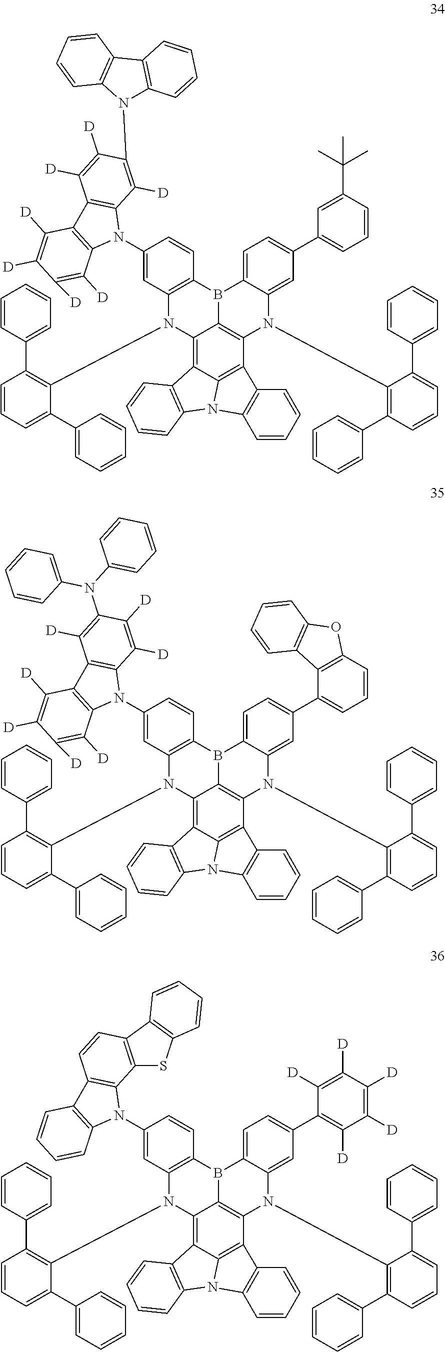 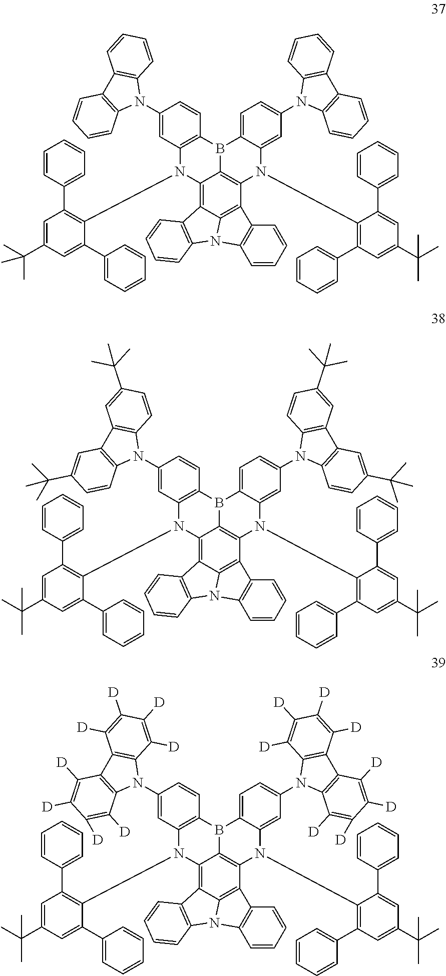 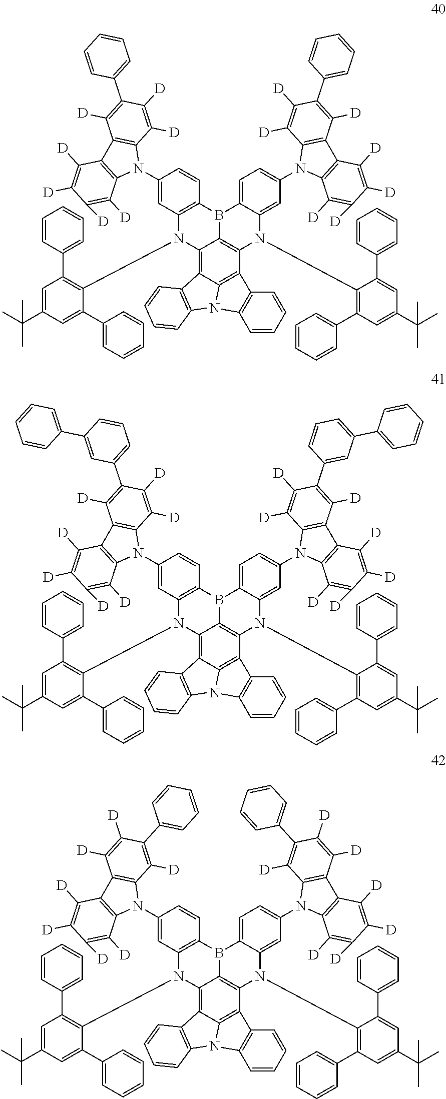 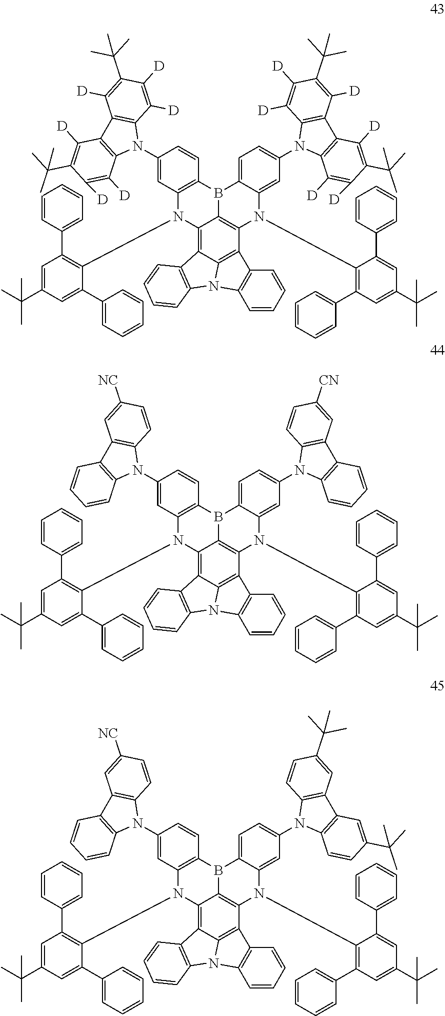 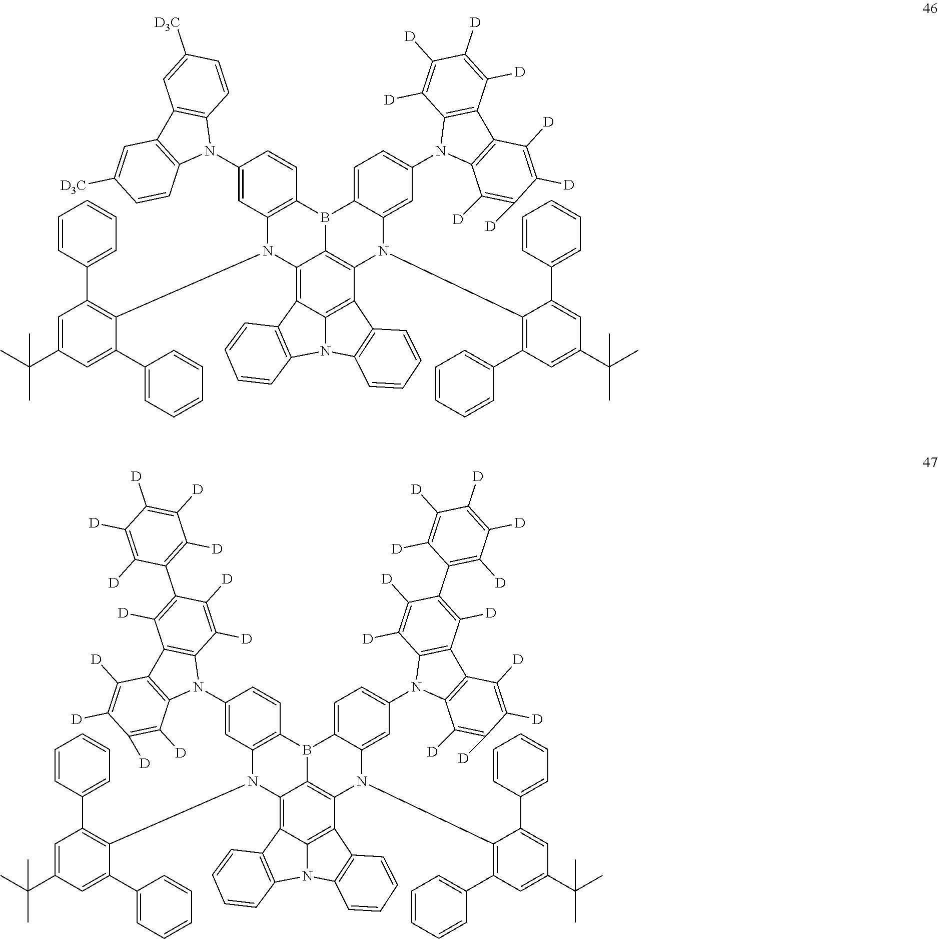 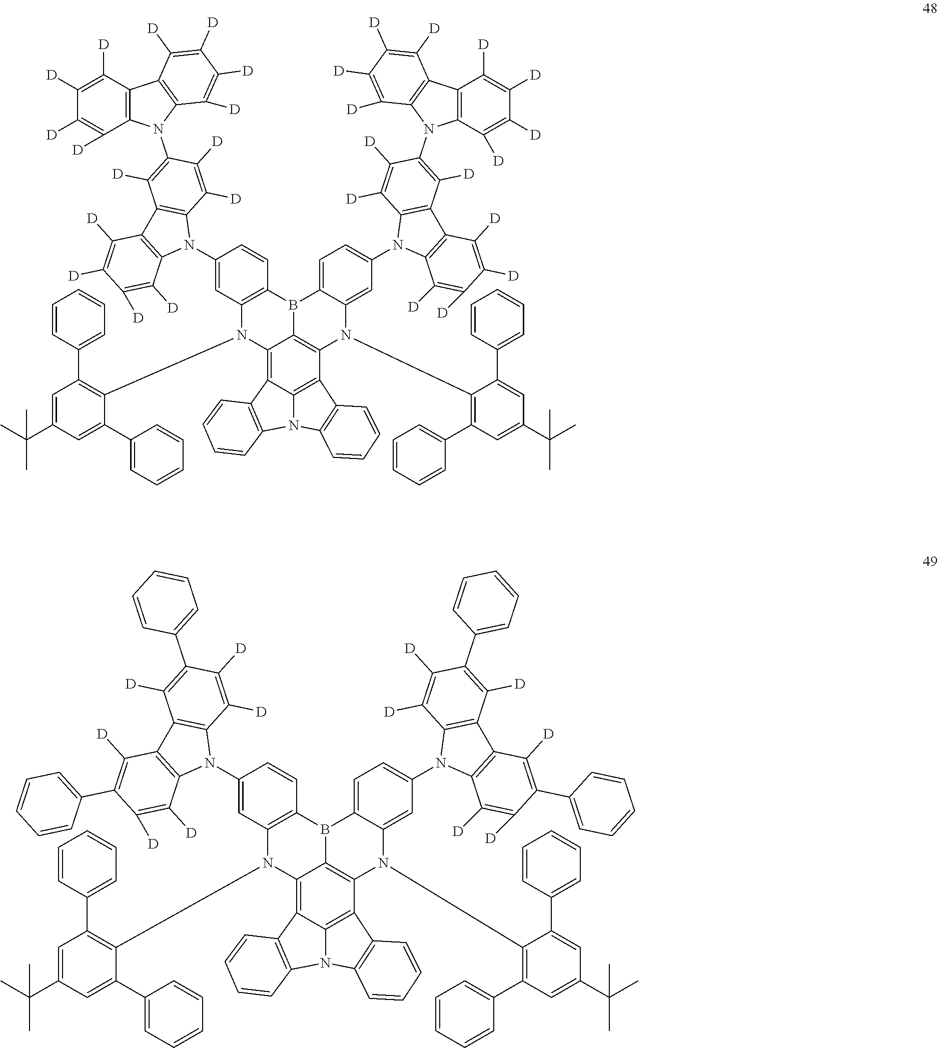 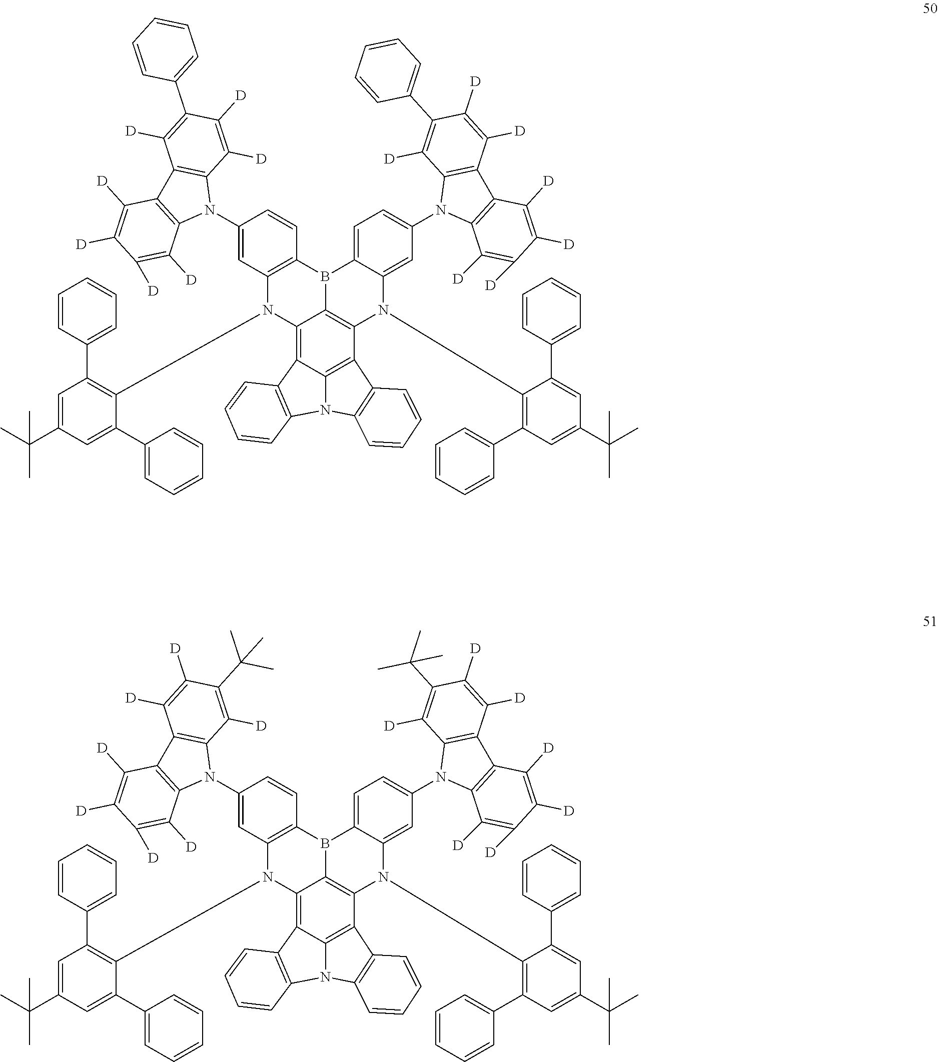 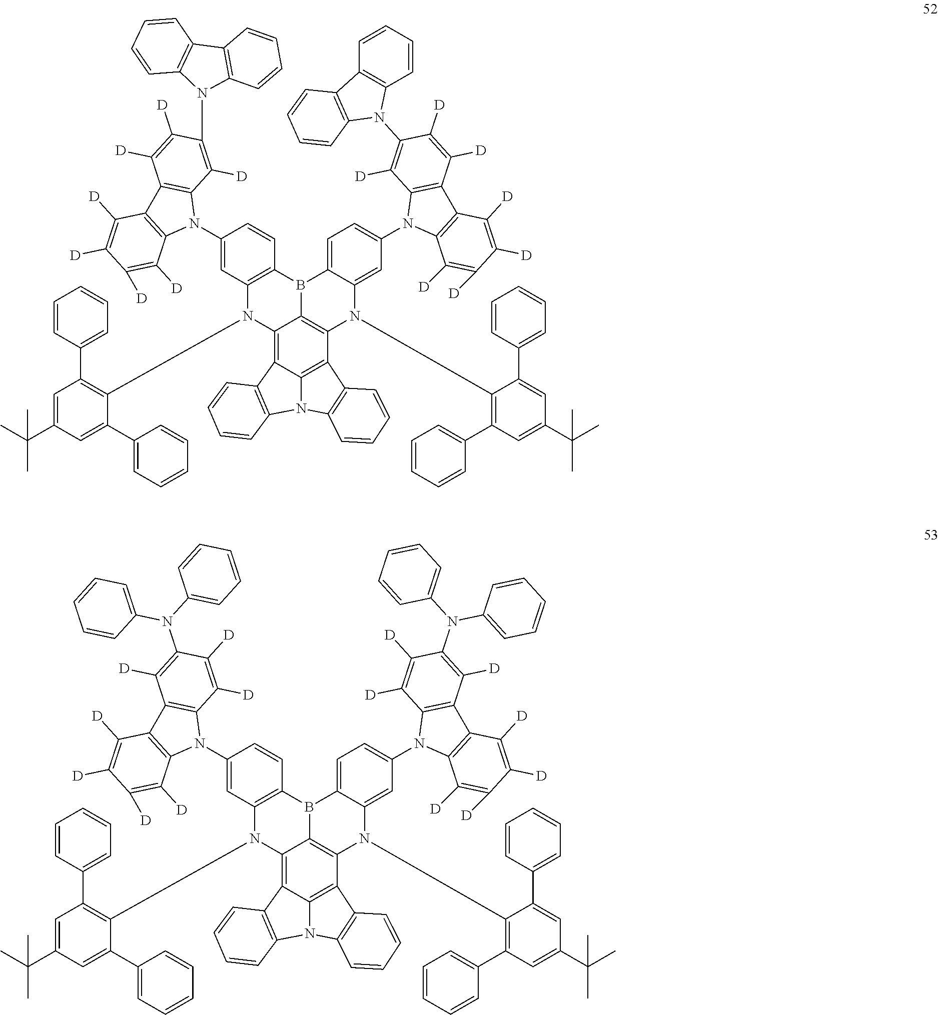 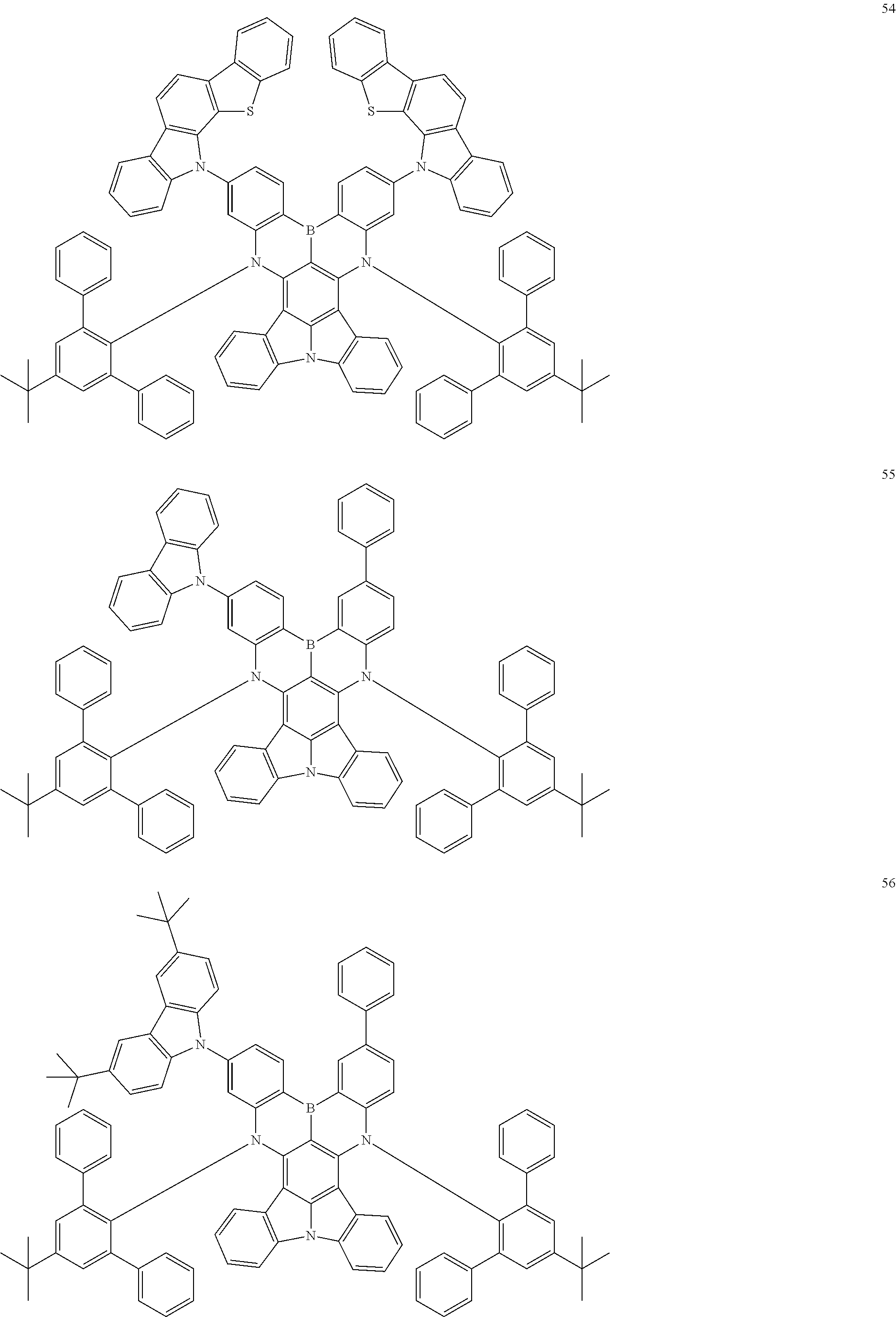 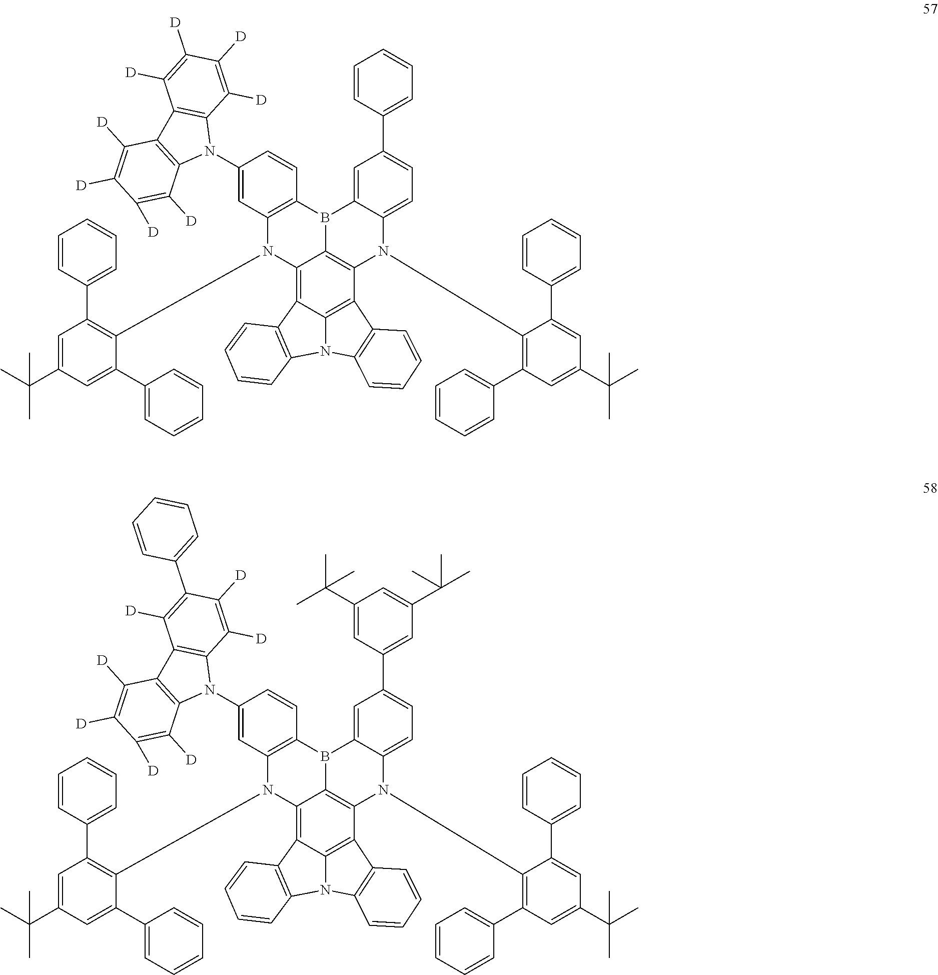 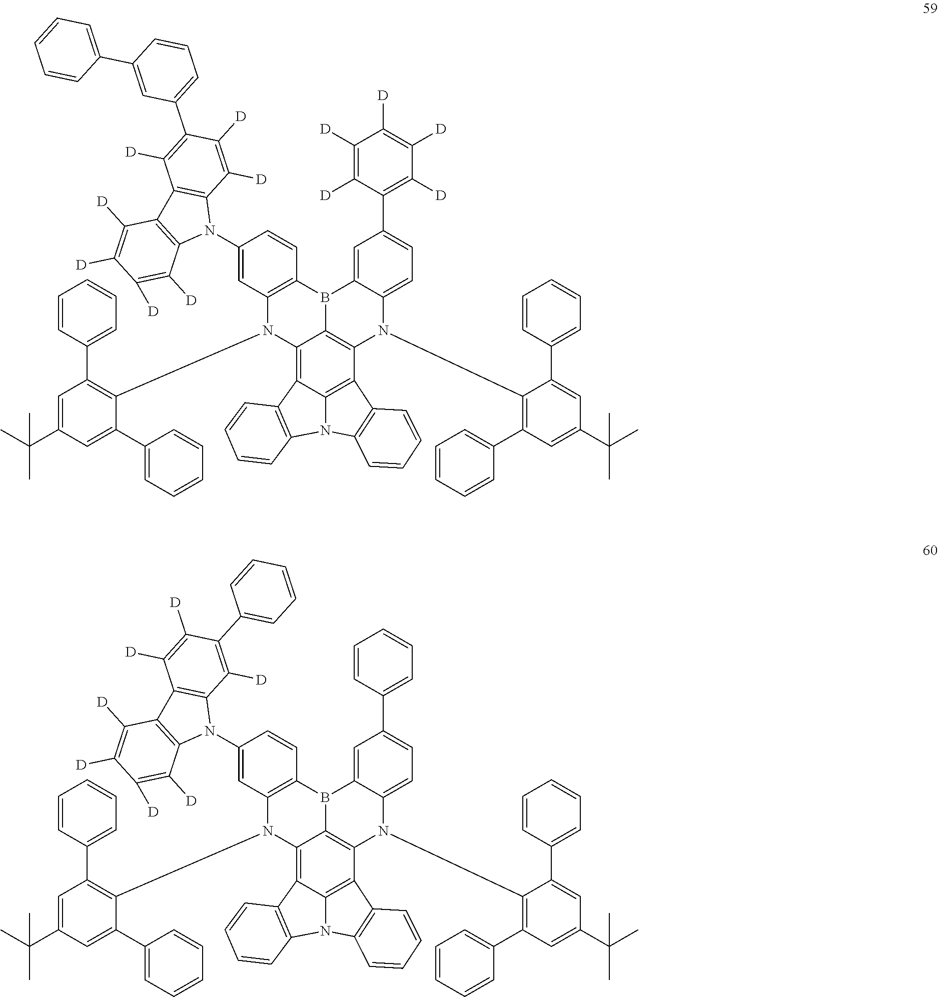 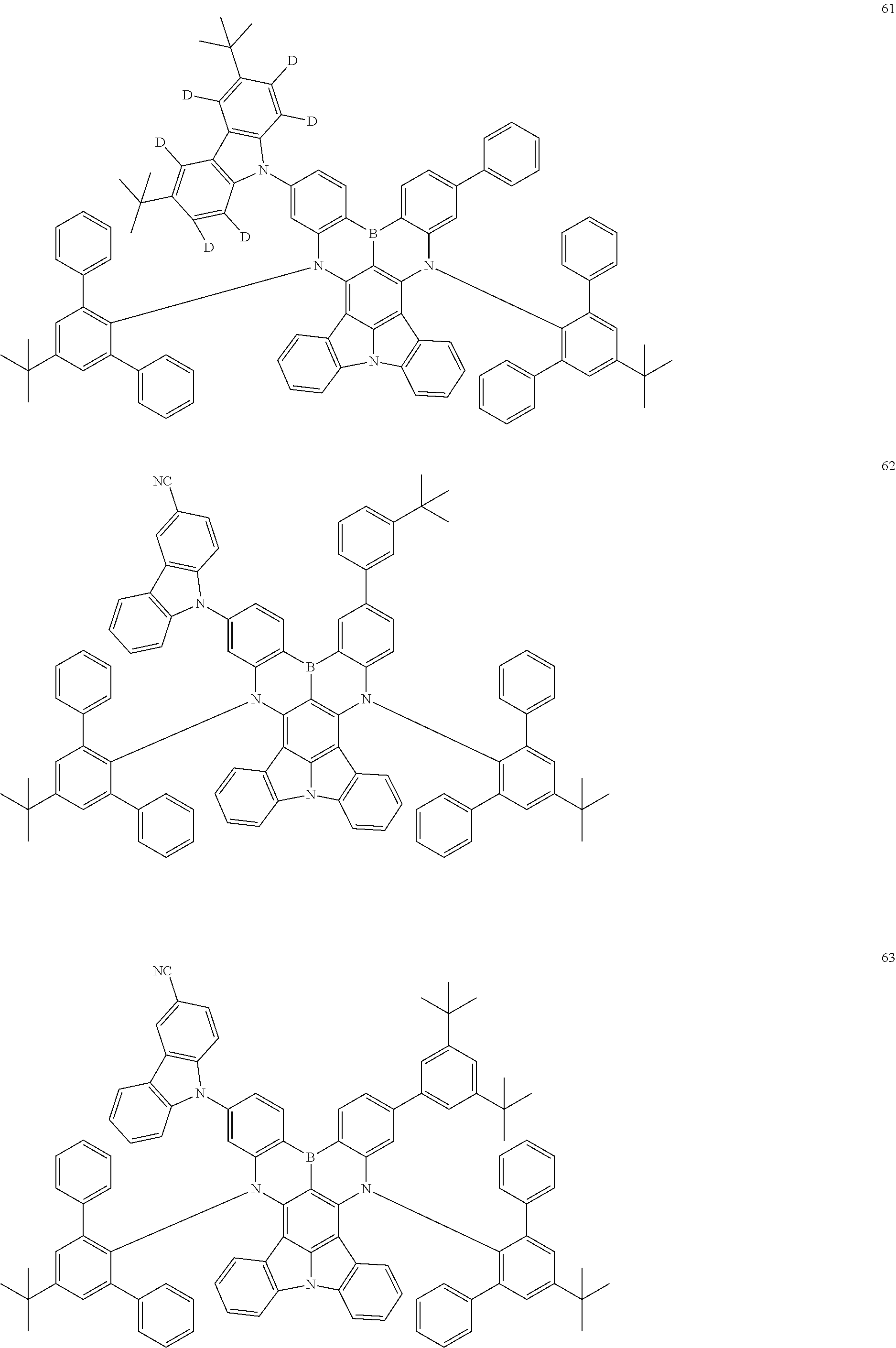 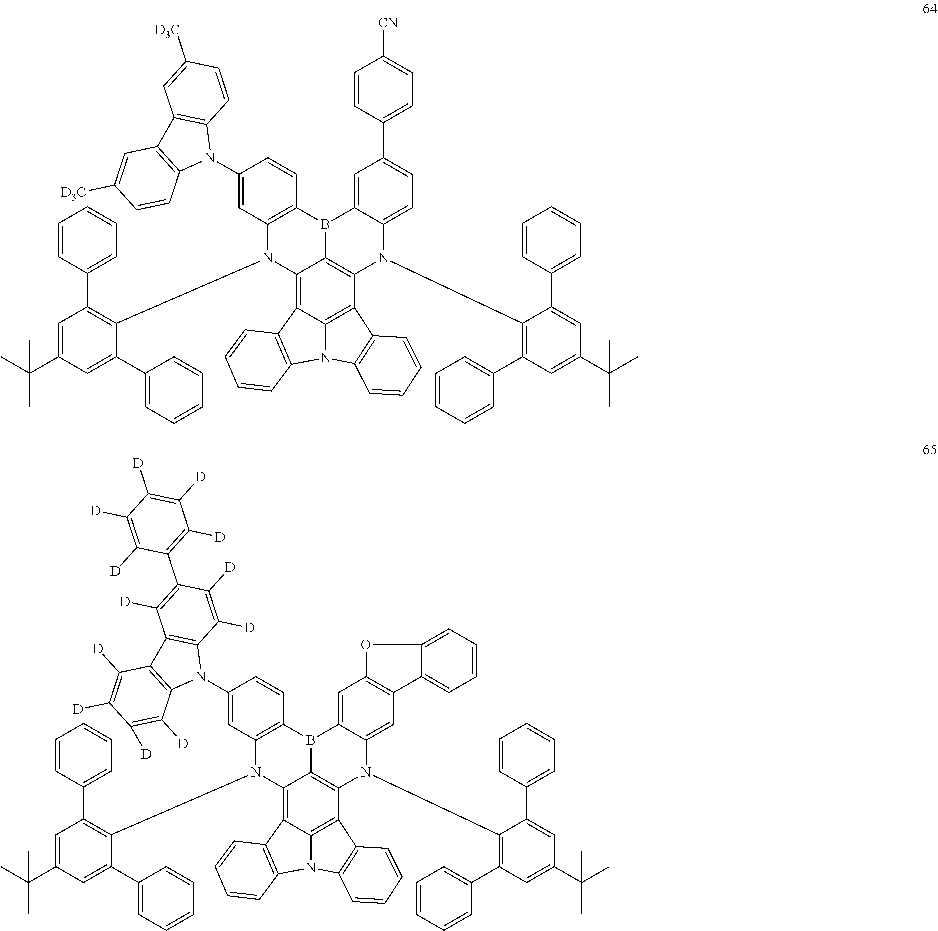 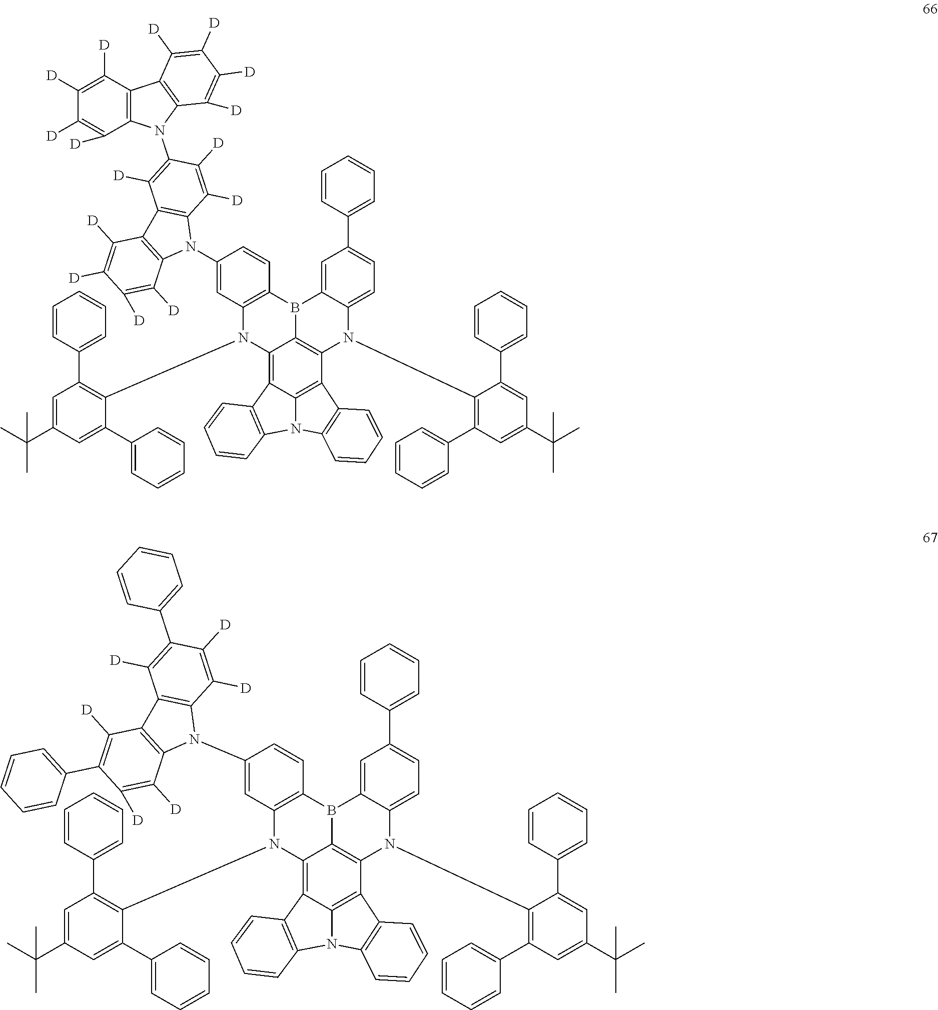 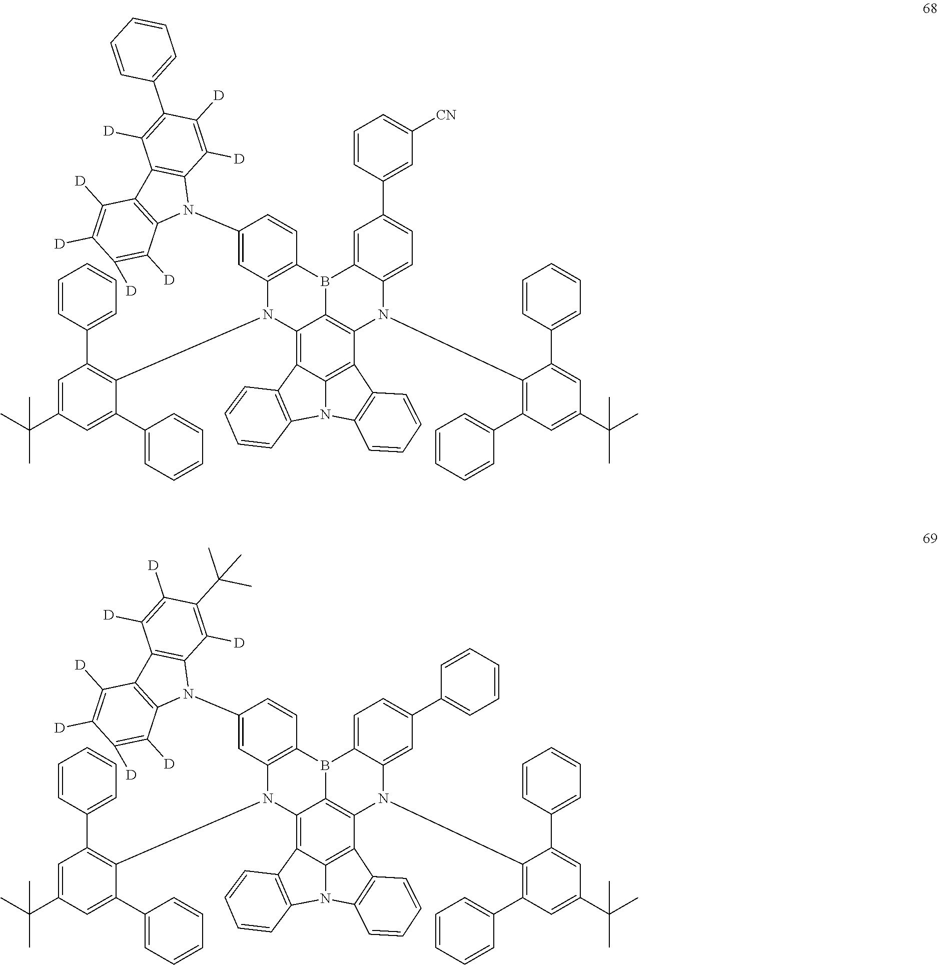 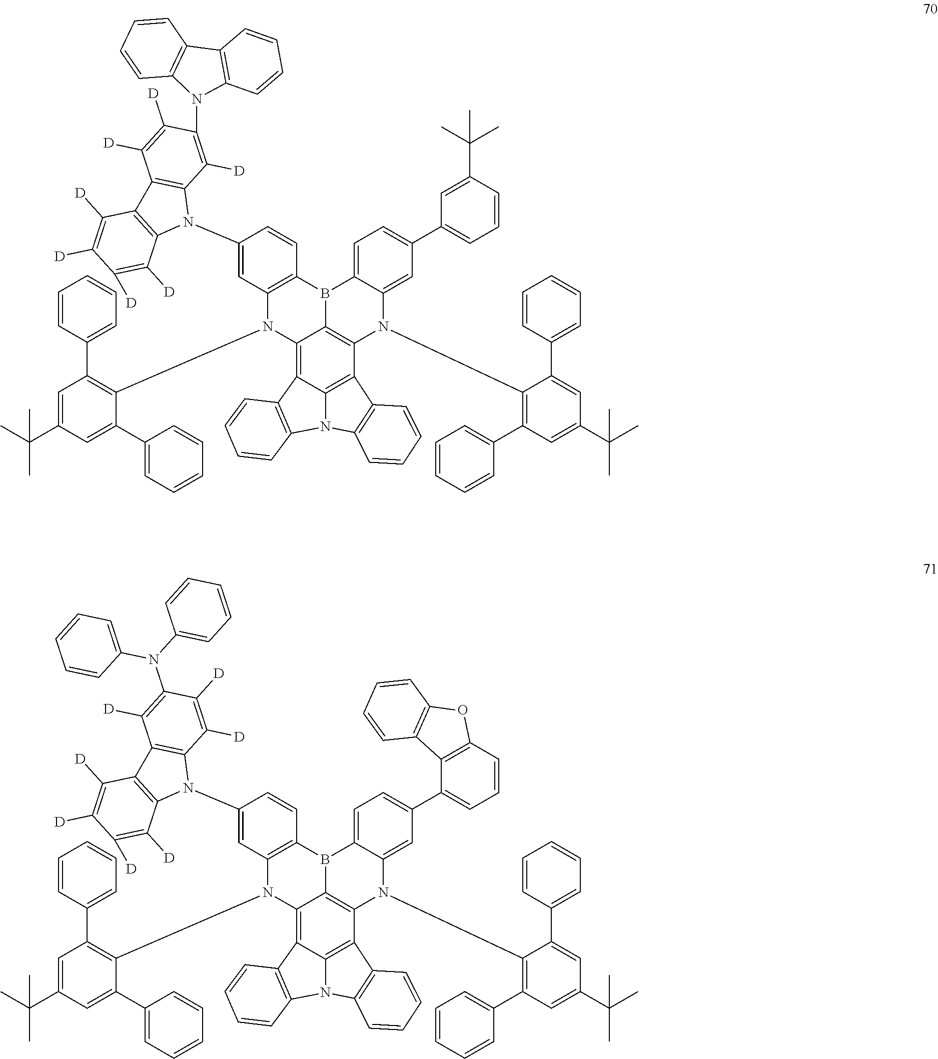 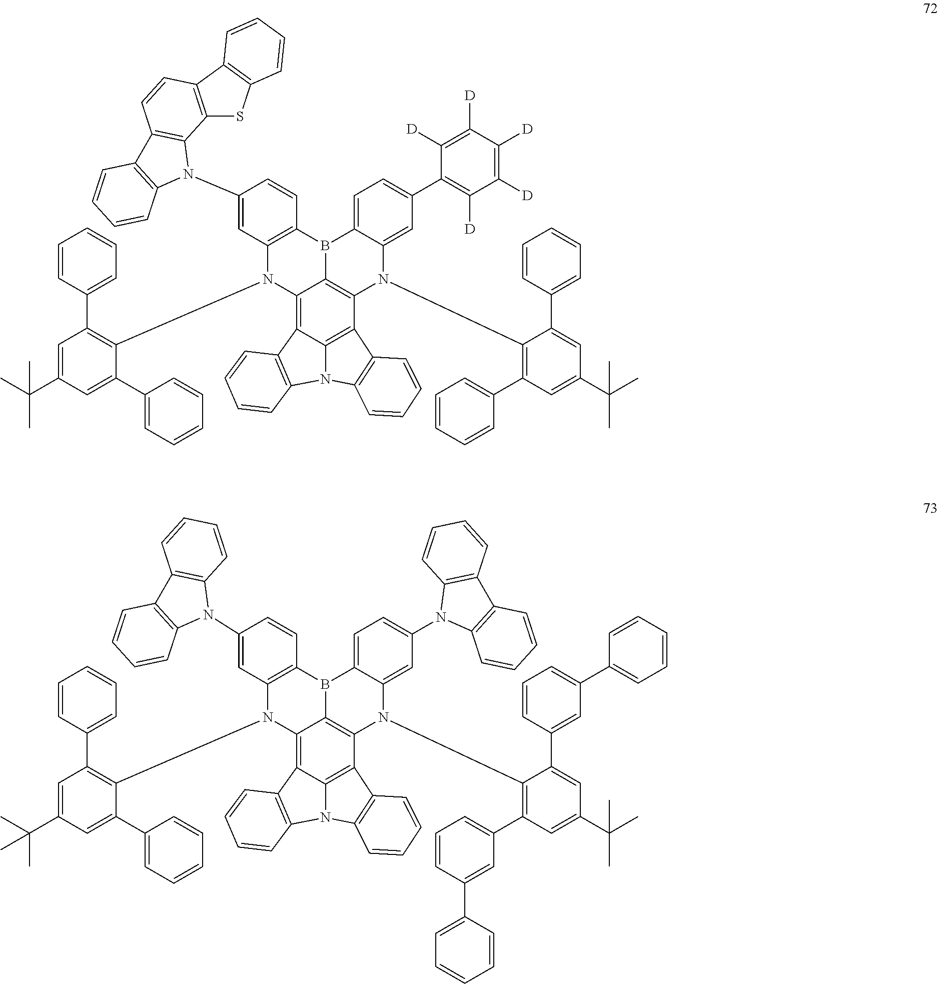 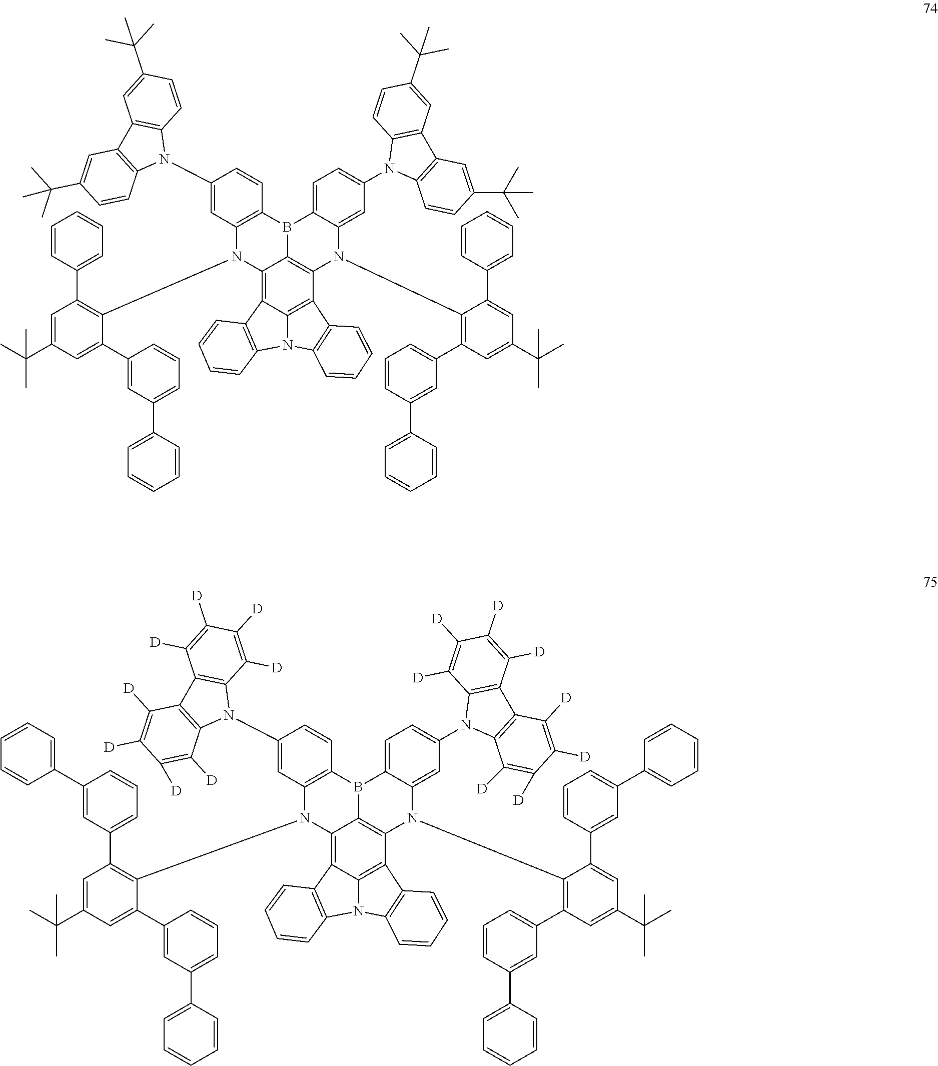 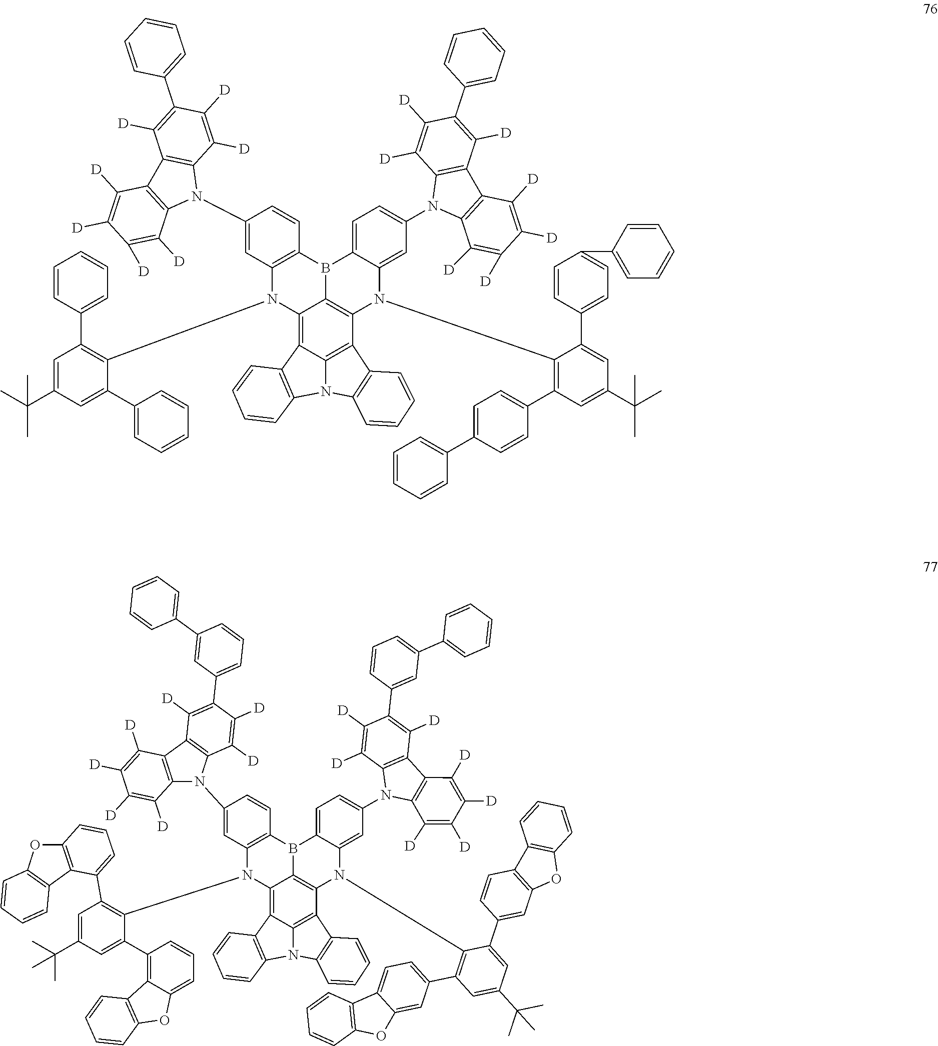 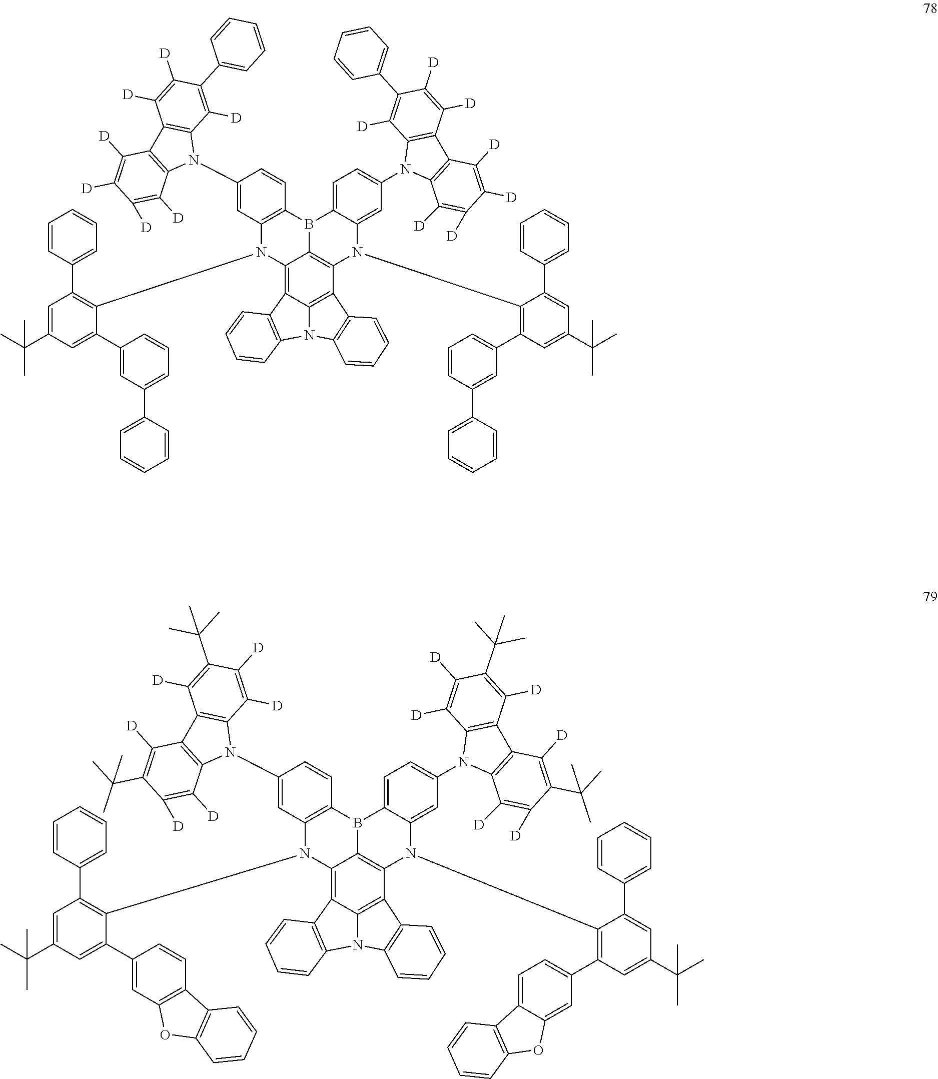 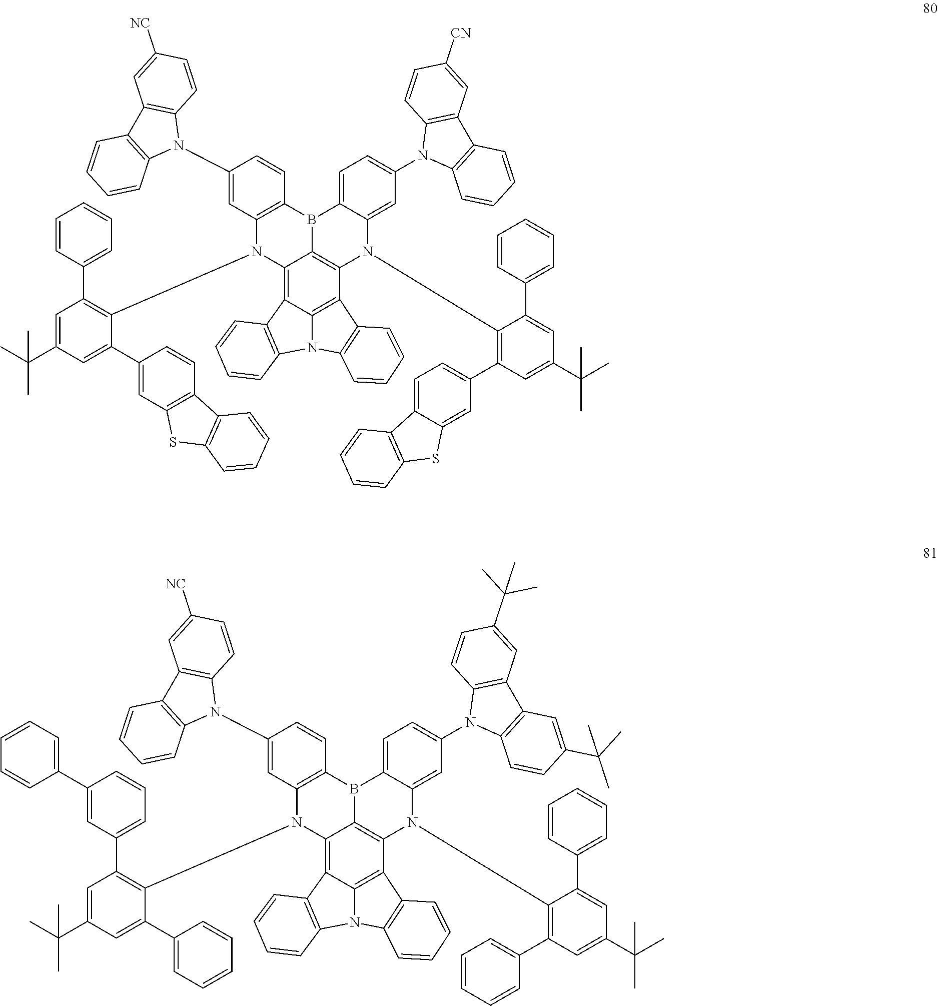 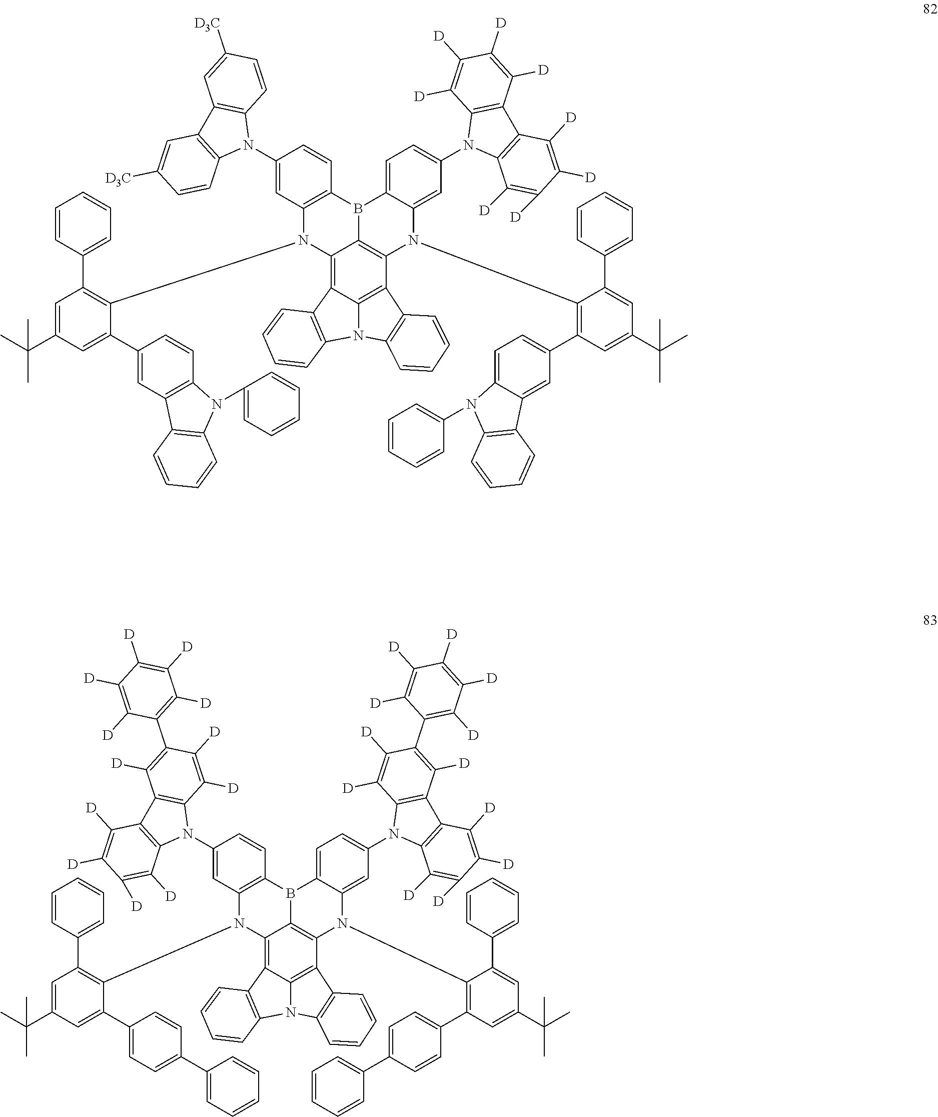 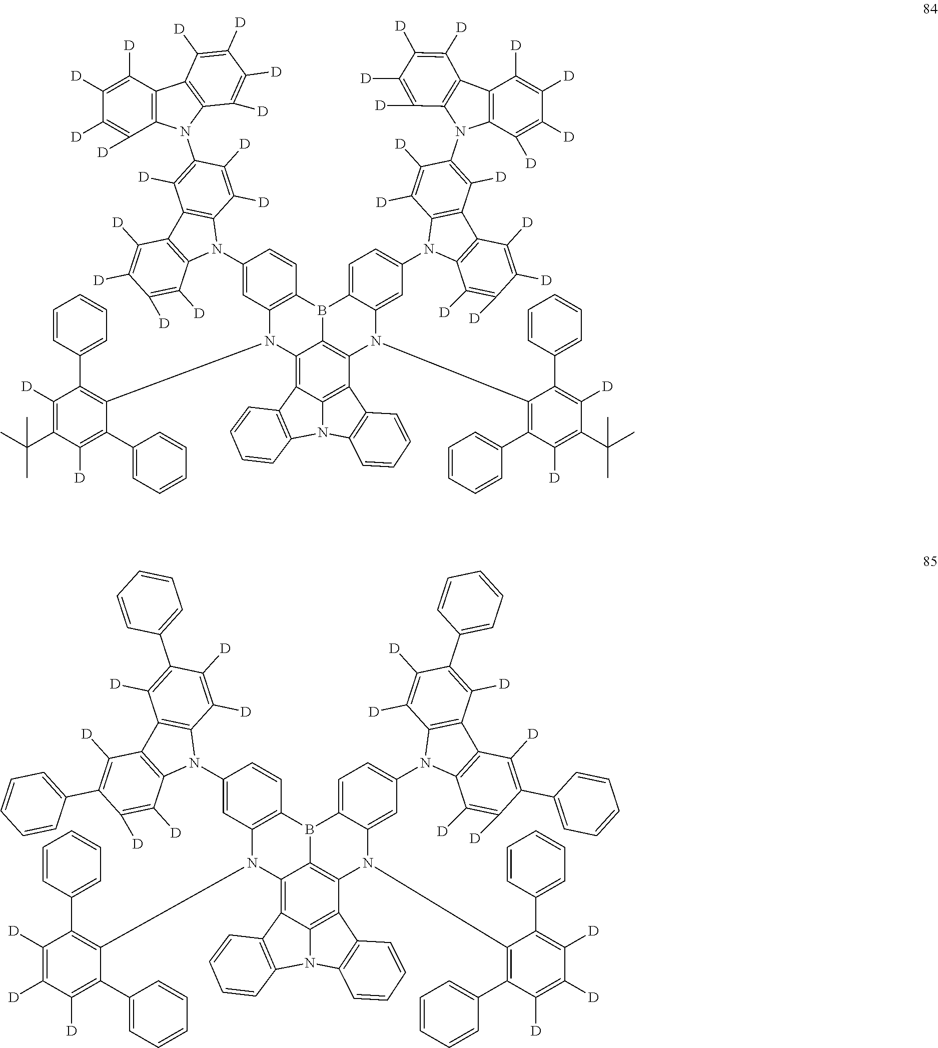 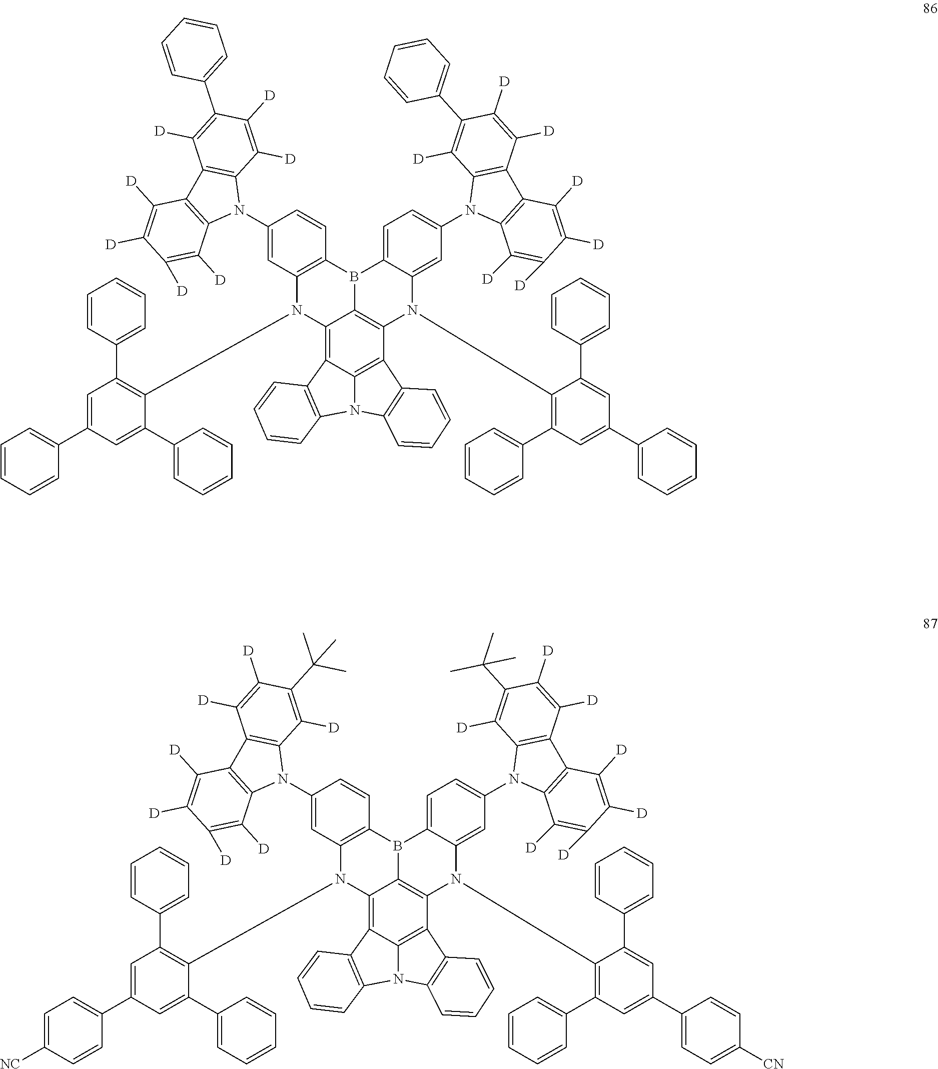 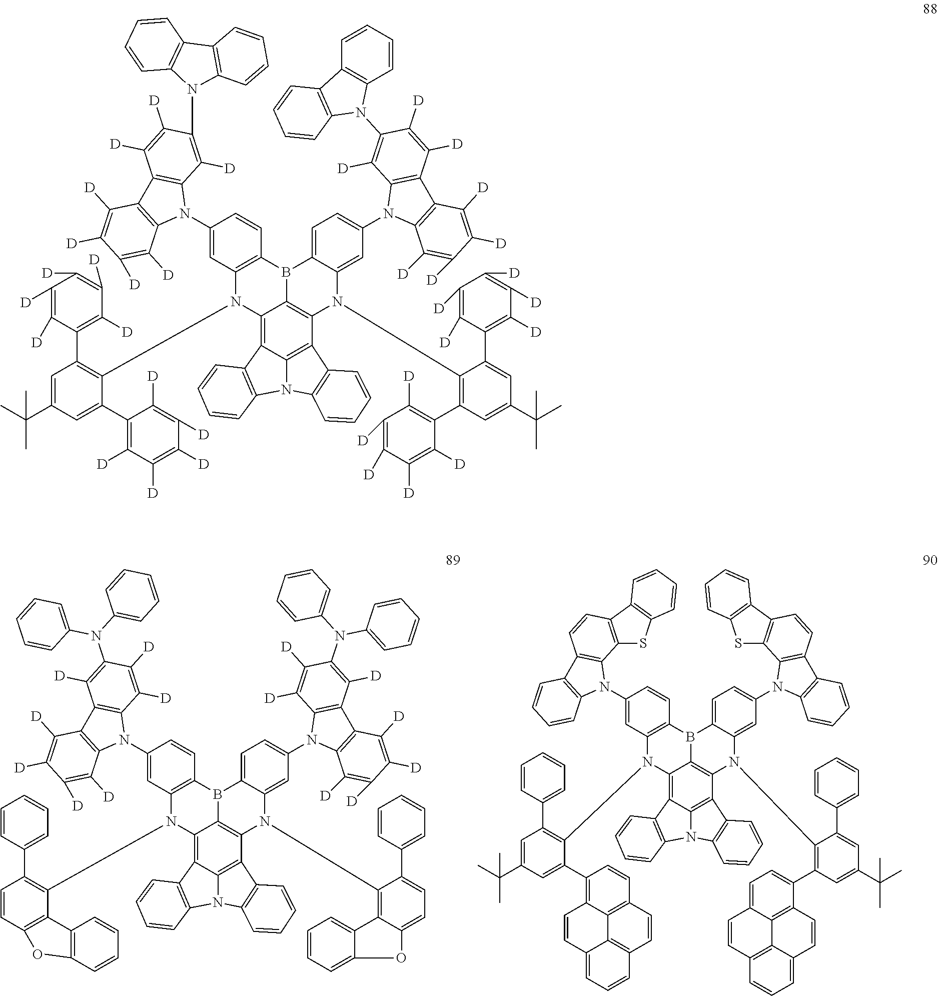 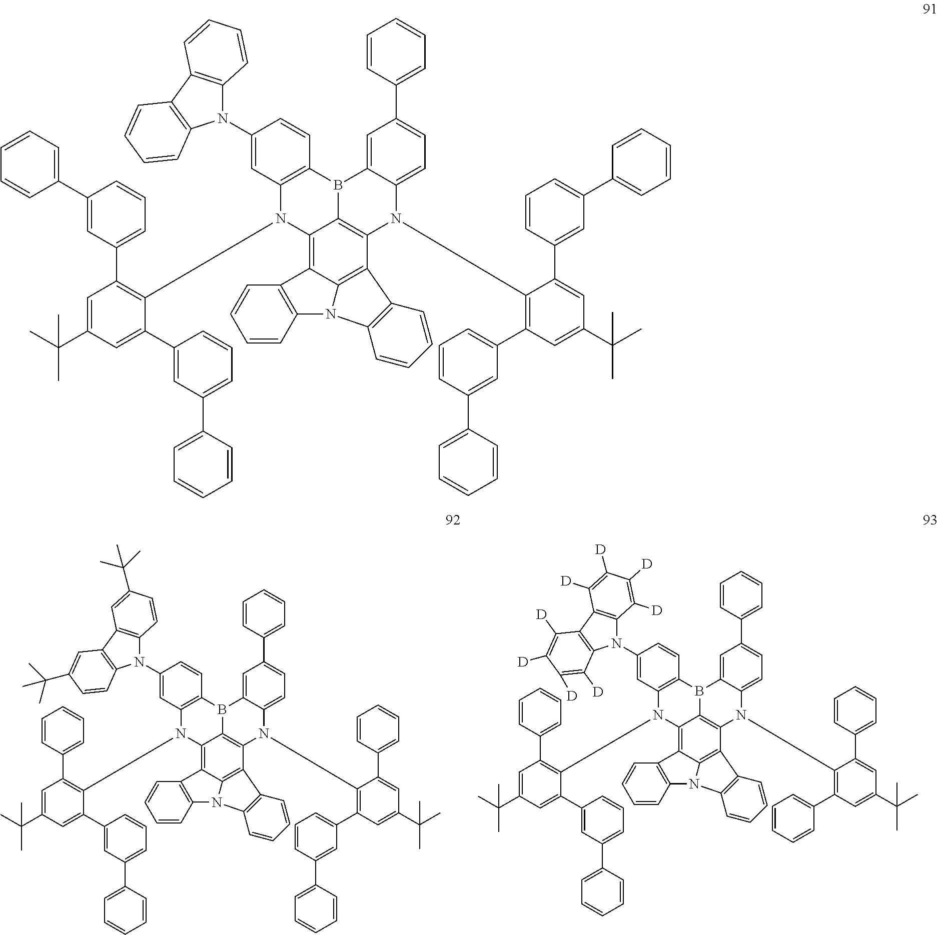 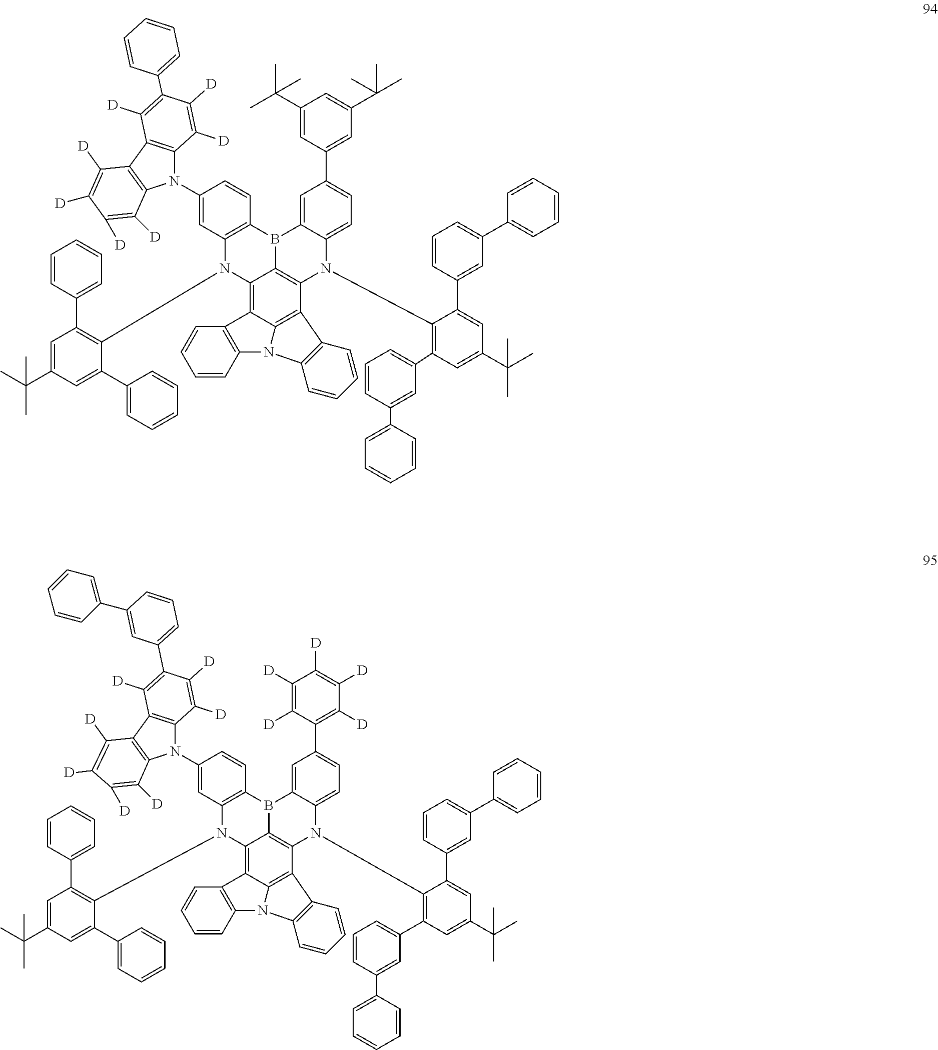 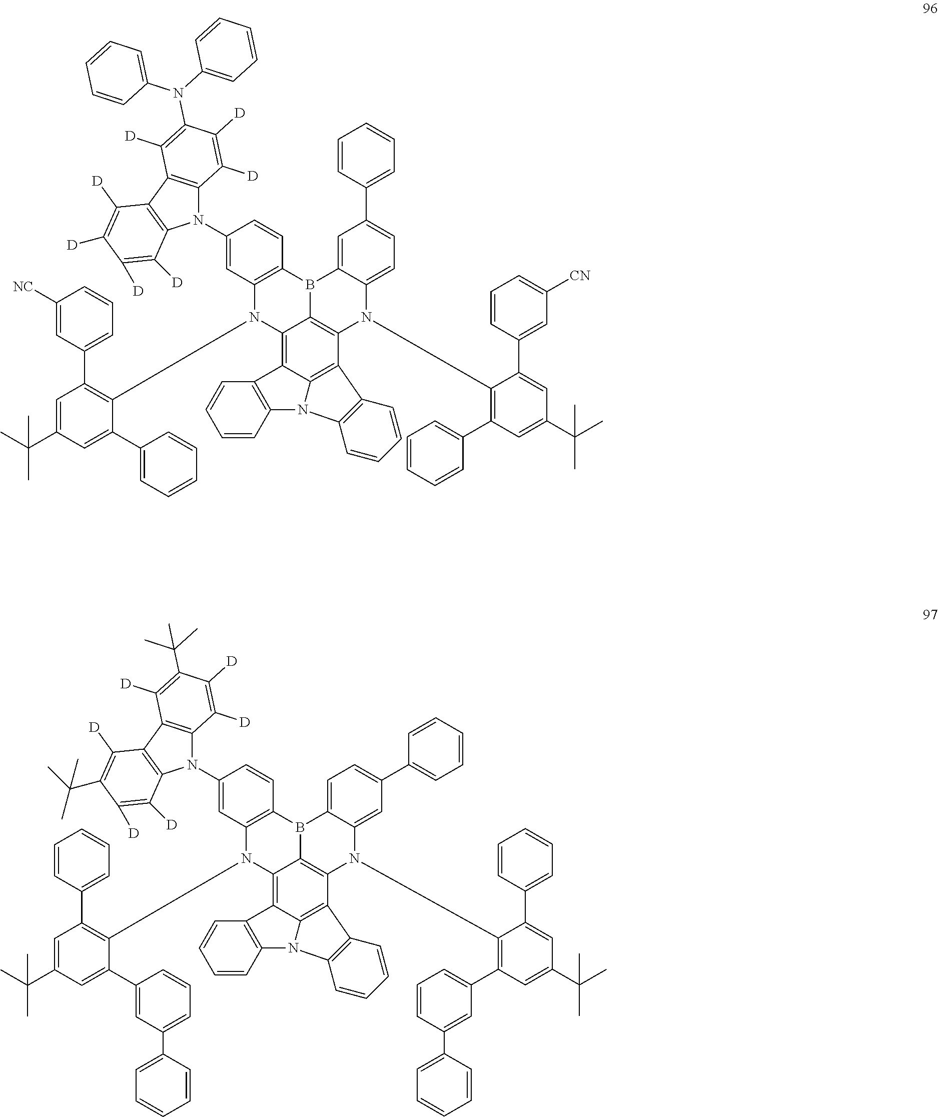 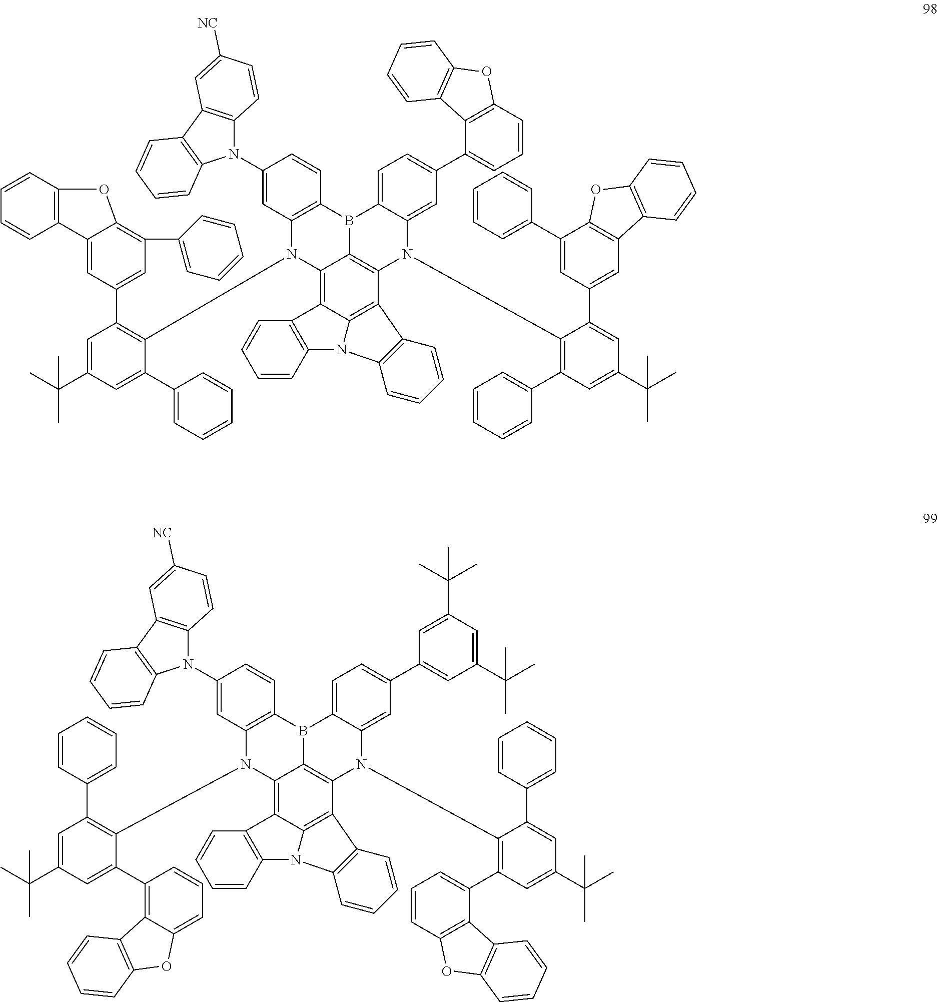 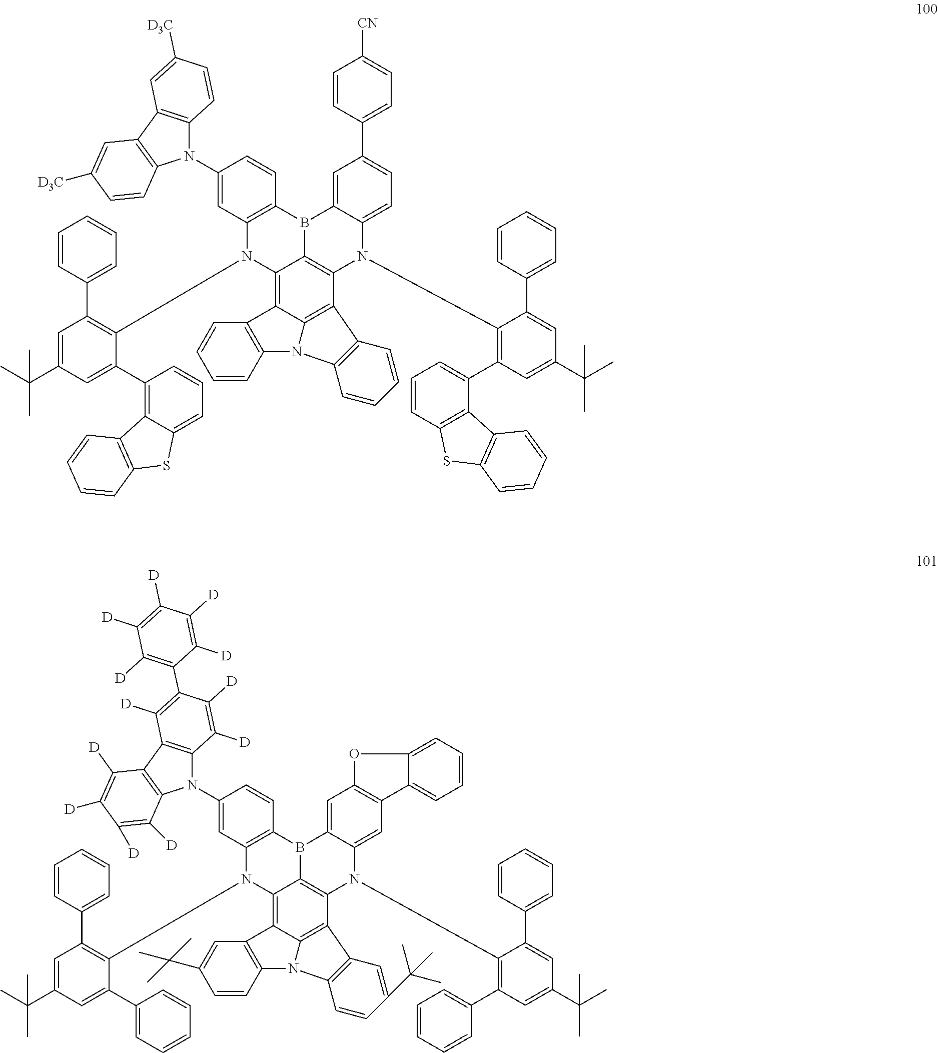 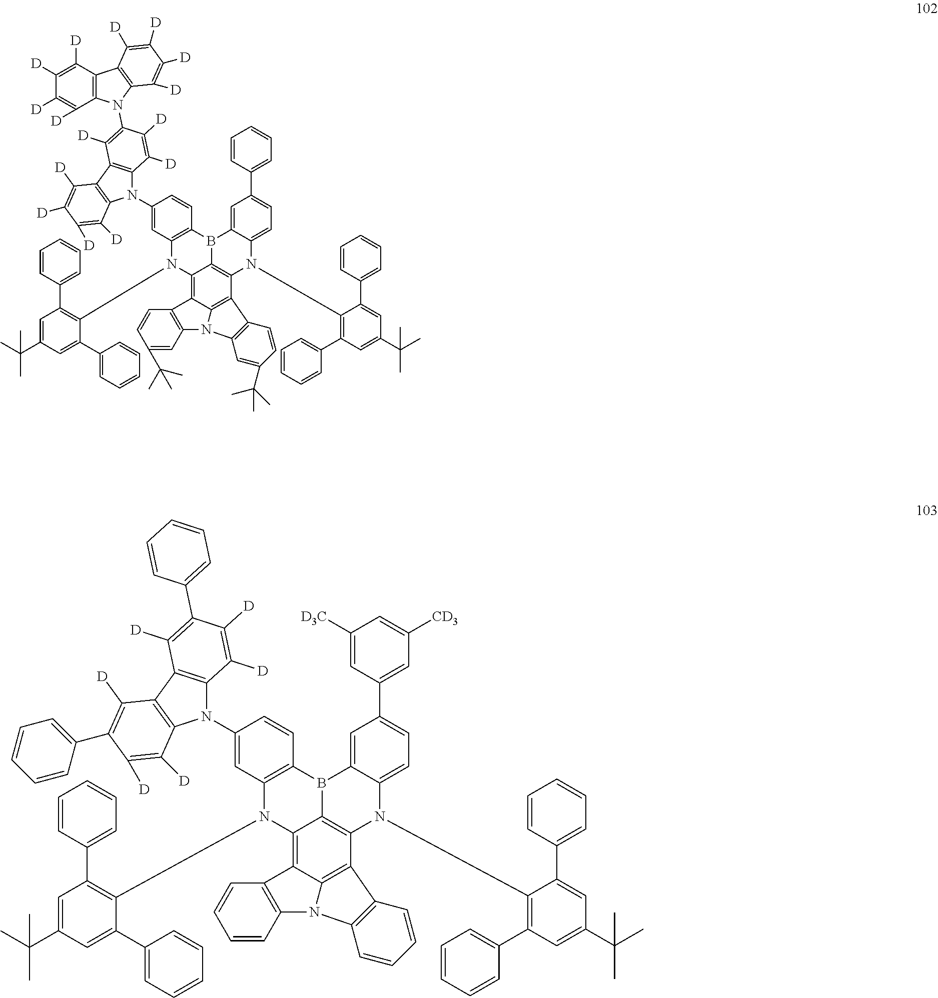 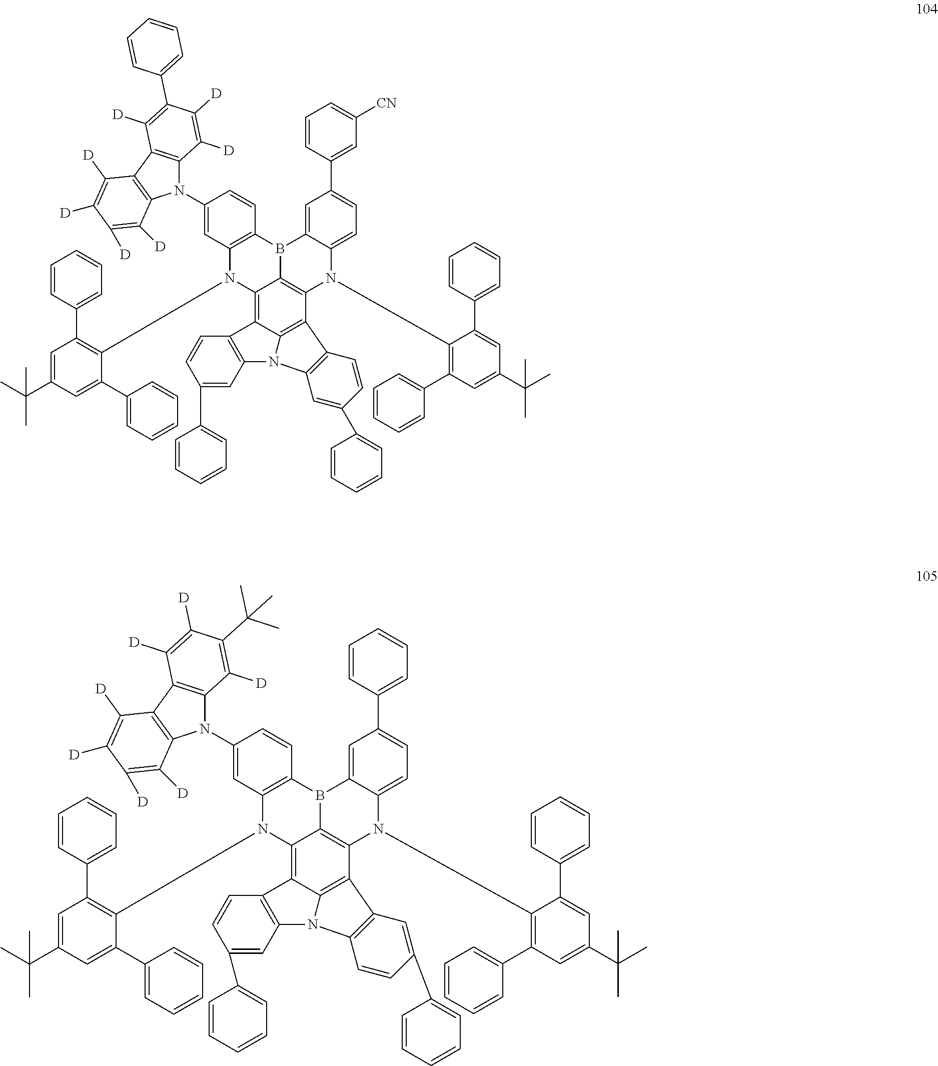 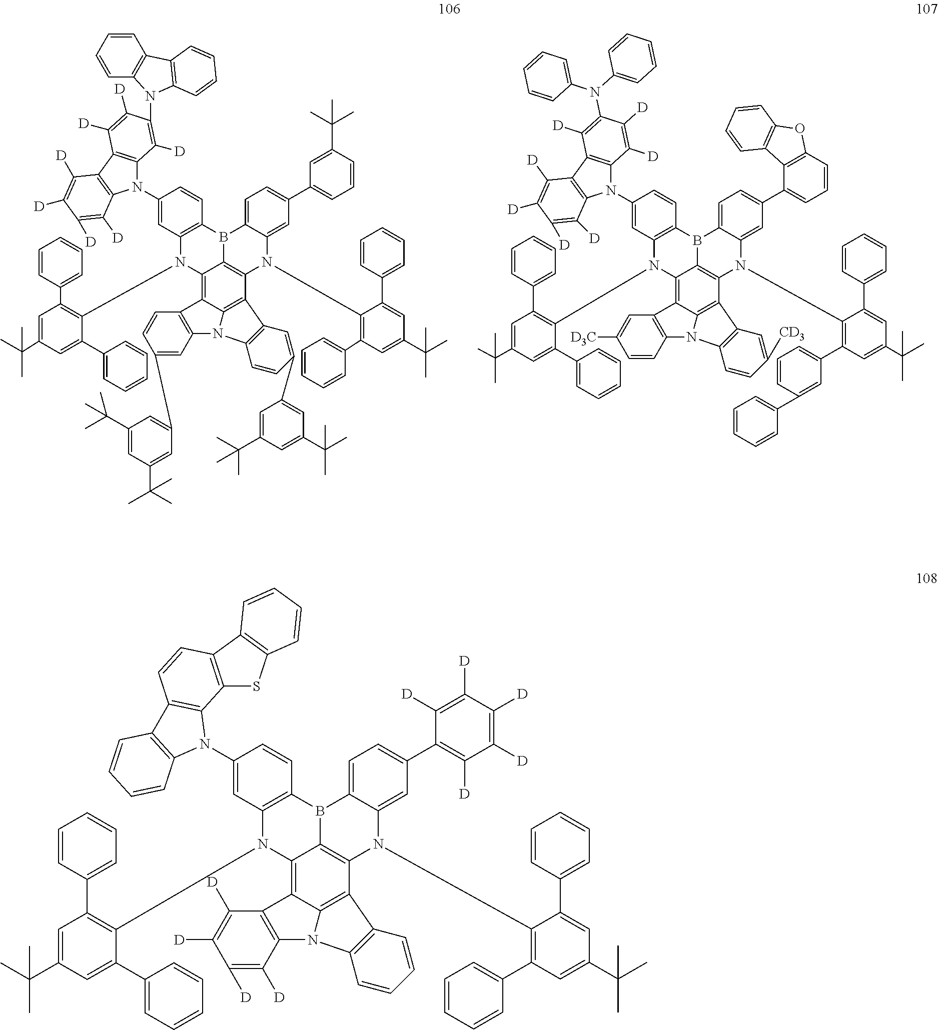 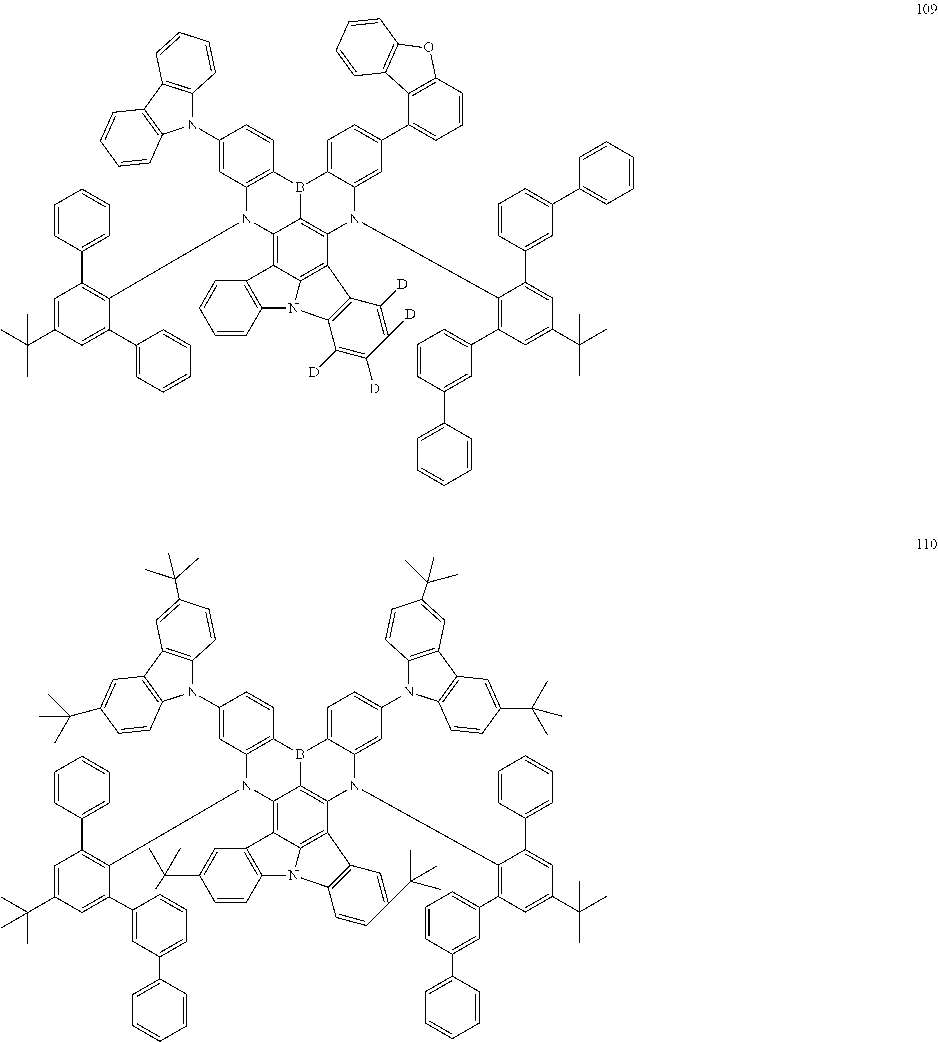 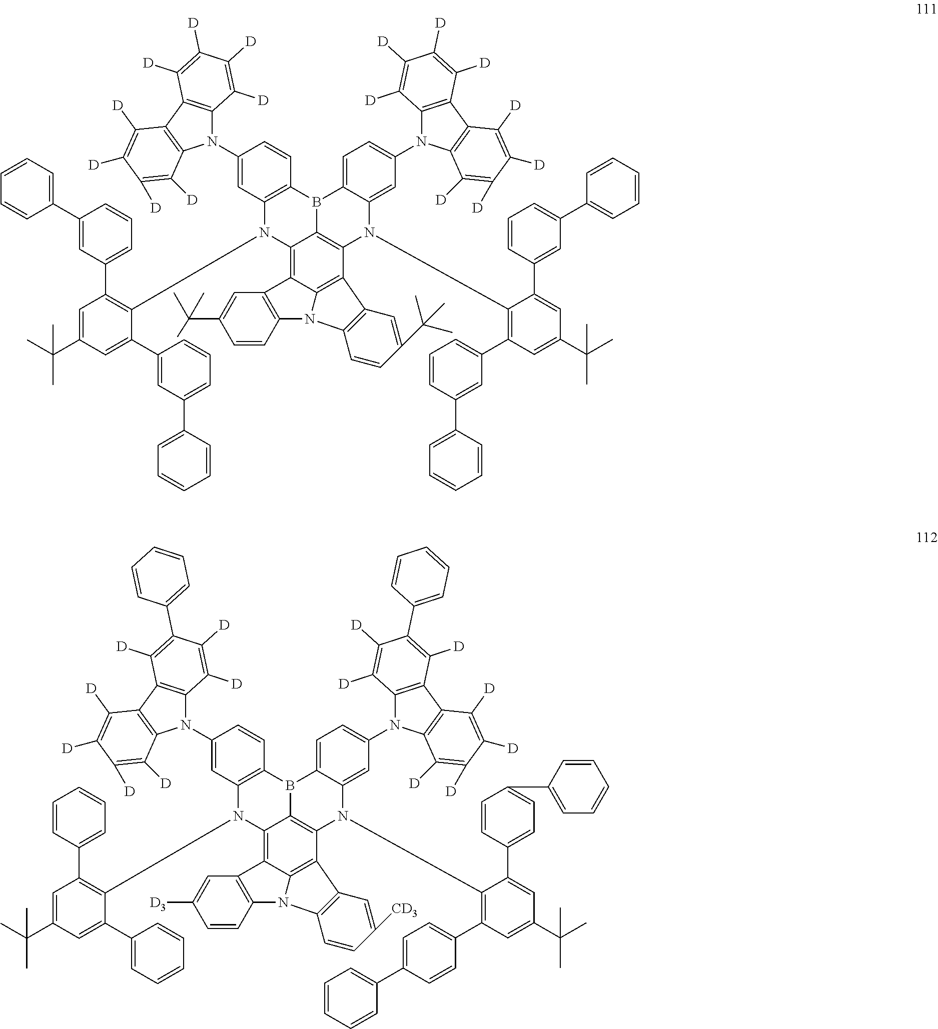 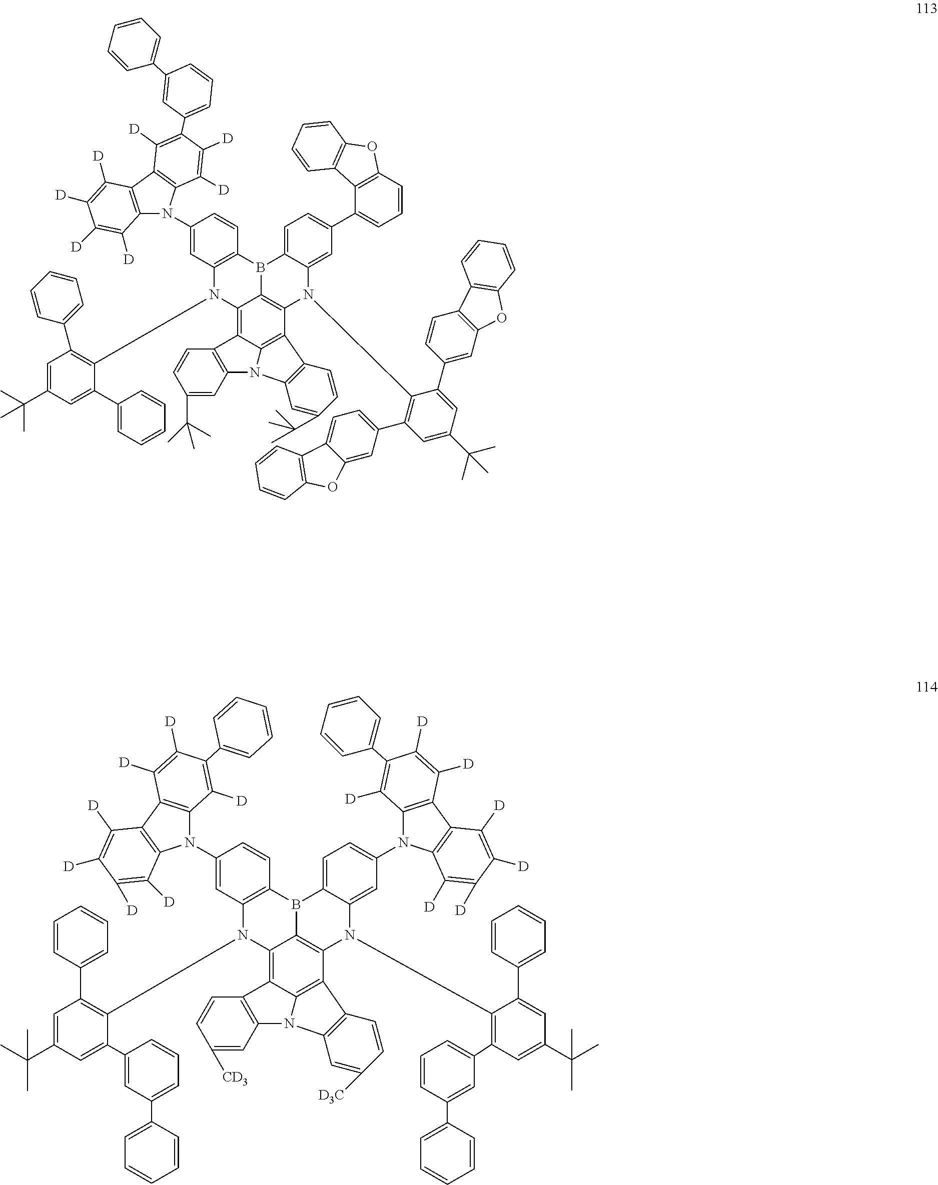 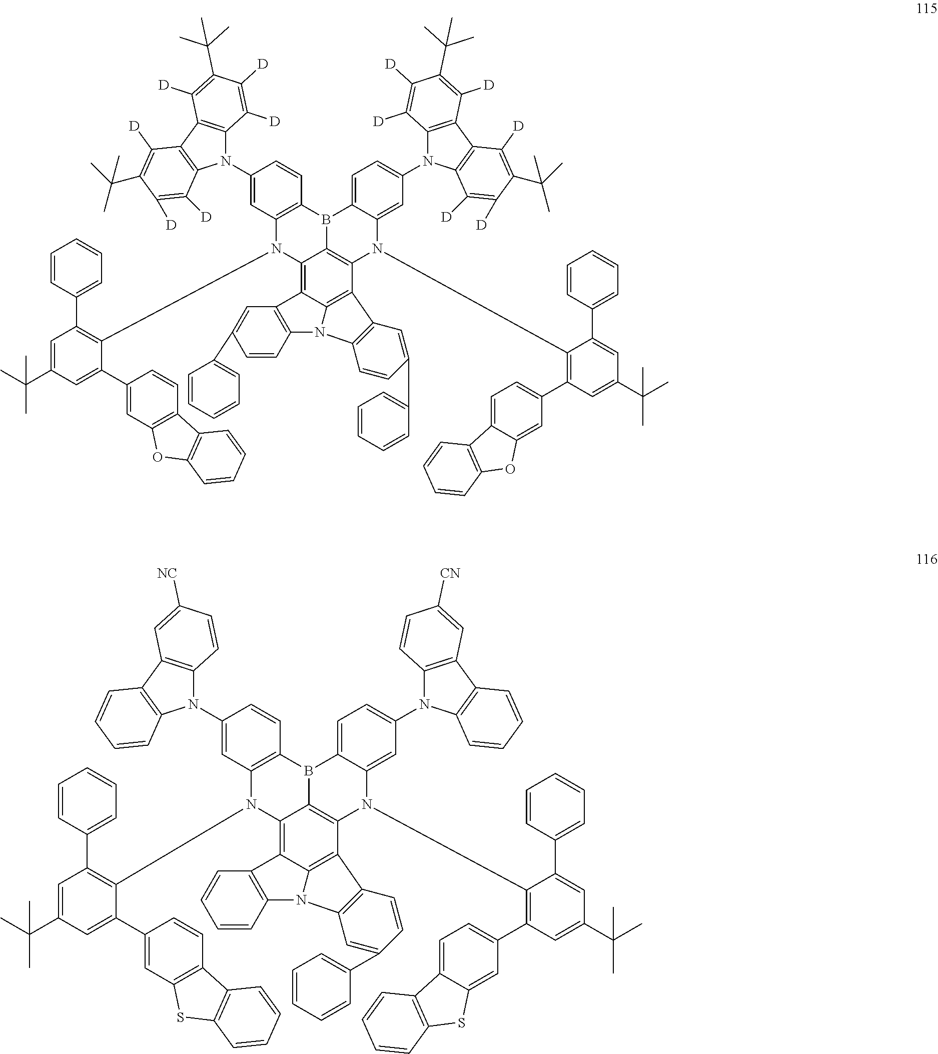 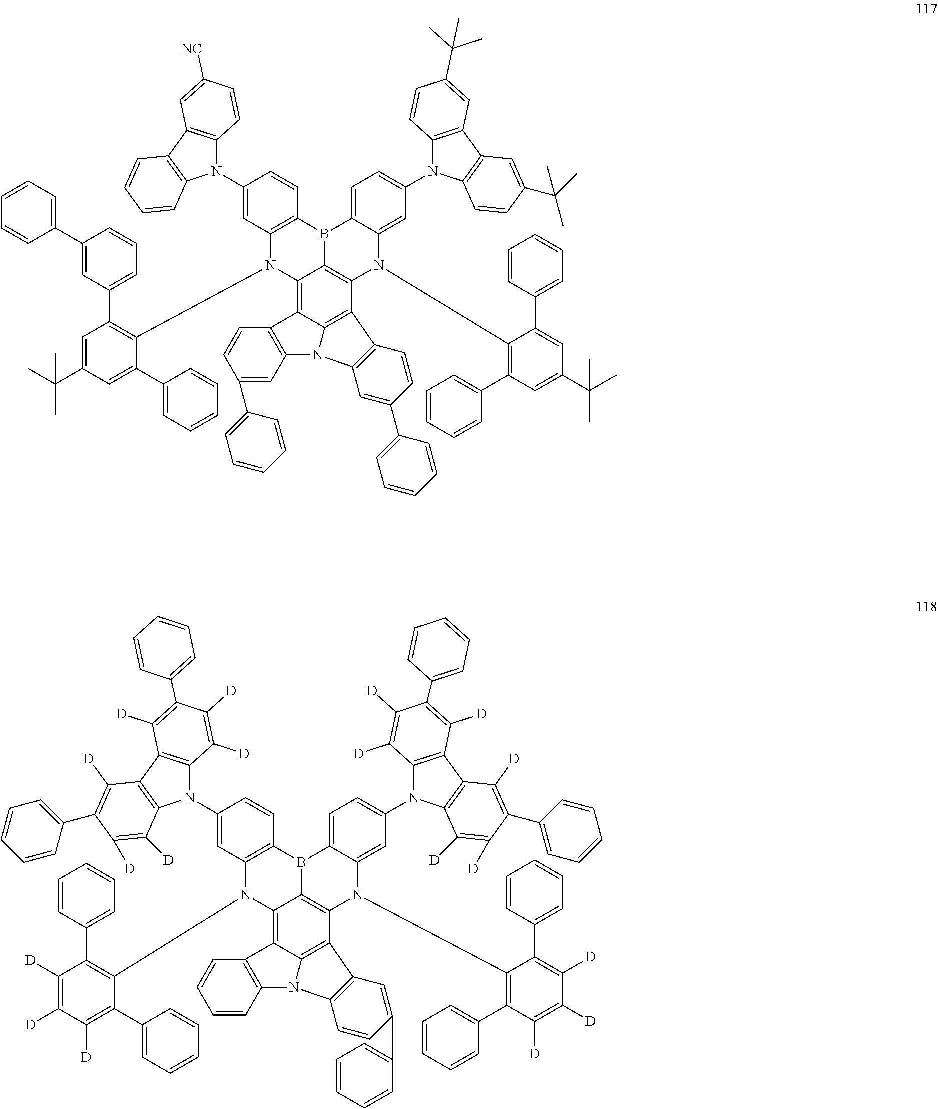 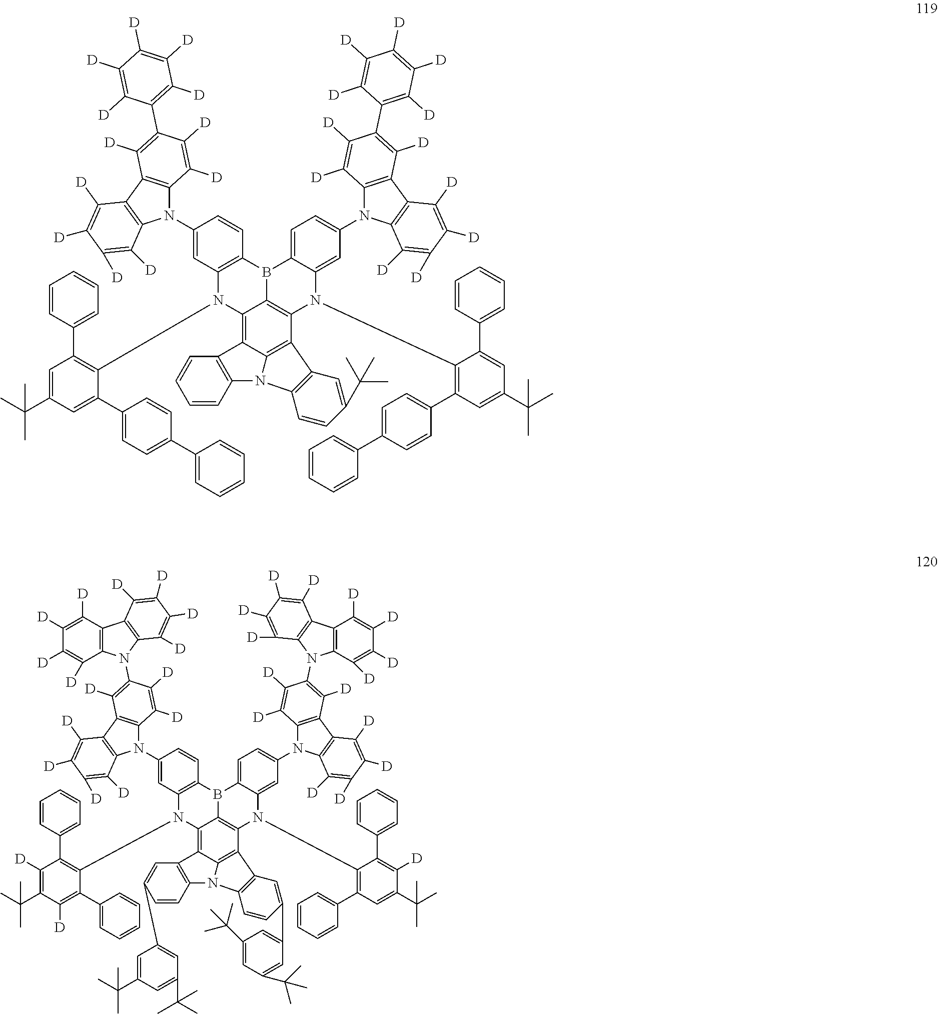 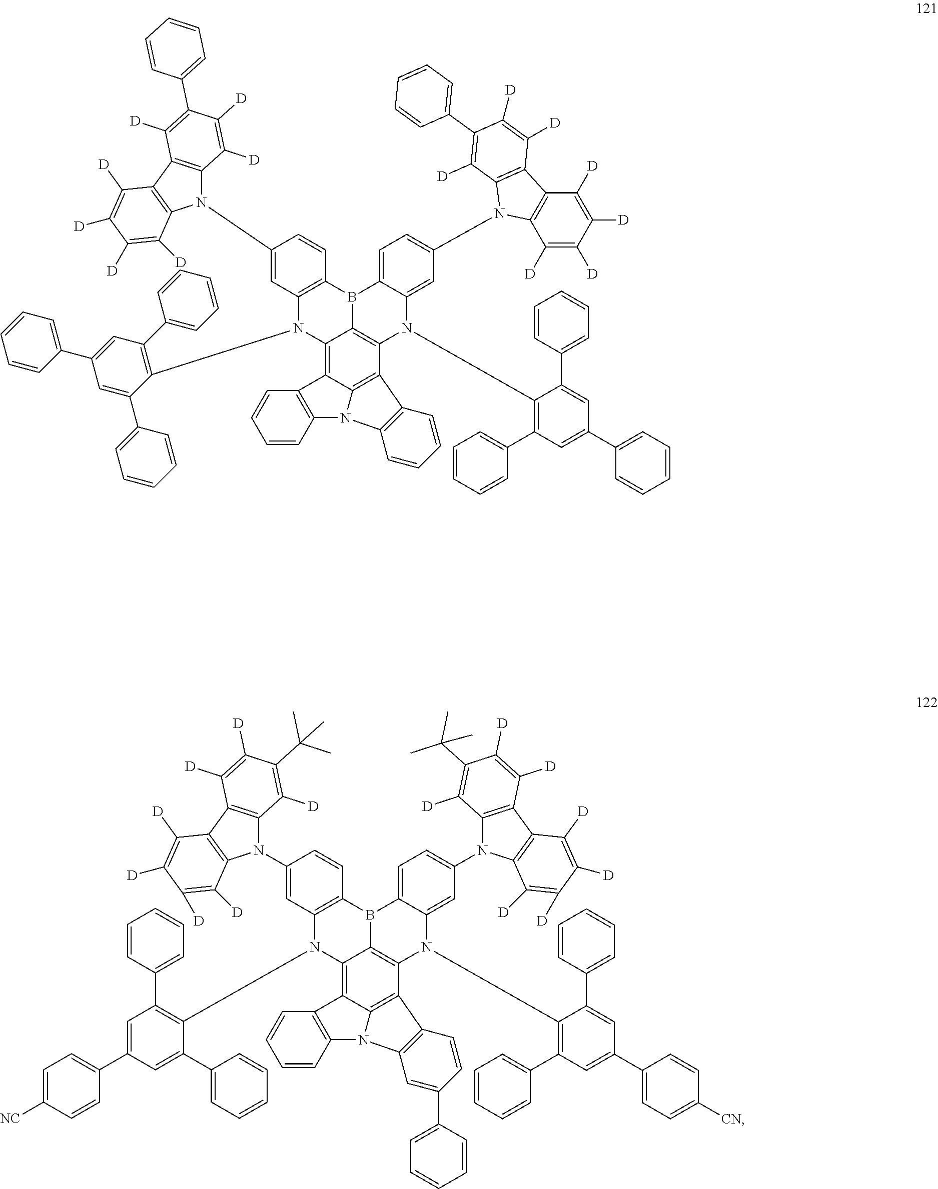
wherein, in Compound Group 1, D is a deuterium atom.

22. A display apparatus comprising:
a base layer;
a circuit layer on the base layer; and
a display device layer on the circuit layer and comprising a light emitting device,
wherein the light emitting device comprises a first electrode, a second electrode on the first electrode, and an emission layer between the first electrode and the second electrode and comprising a fused polycyclic compound represented by Formula 1: 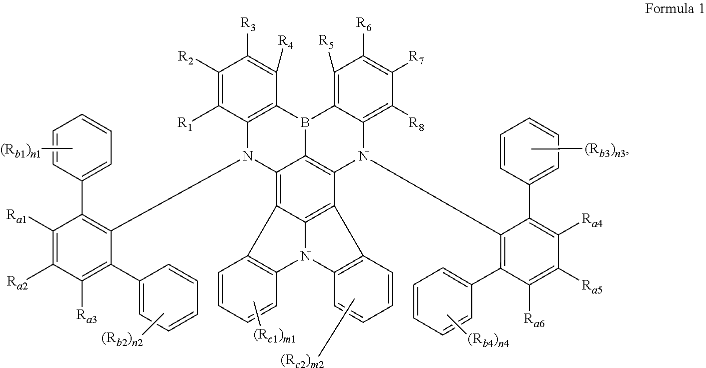
wherein, in Formula 1,
R₁ to R₈ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
n1 to n4 are each independently an integer of 0 to 5,
Rₐ₁ to Rₐ₆ and R_{b1} to R_{b4} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring,
m1 and m2 are each independently an integer of 0 to 4, and
R_{c1} and R_{c2} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms.

23. The display apparatus of claim 22, wherein the light emitting device comprises a first light emitting device configured to emit red light, a second light emitting device configured to emit green light, and a third light emitting device configured to emit blue light, and
the fused polycyclic compound is comprised in the third light emitting device.

24. The display apparatus of claim 22, wherein the light emitting device is configured to emit blue light.

25. The display apparatus of claim 22, further comprising a light control layer on the display device layer and comprising a quantum dot.
